(19) United States
(12) Patent Application Publication
(10) Pub. No.: US 2023/0225208 A1
(43) Pub. Date: Jul. 13, 2023

(54) LIGHT EMITTING ELEMENT AND POLYCYCLIC COMPOUND FOR LIGHT EMITTING ELEMENT

(71) Applicant: Samsung Display Co., Ltd., Yongin-si, Gyeonggi-do (KR)

(72) Inventors: Keigo HOSHI, Yokohama (JP); Ryuhei FURUE, Yokohama (JP); Yoshiro SUGITA, Yokohama (JP)

(21) Appl. No.: 18/146,164

(22) Filed: Dec. 23, 2022

(30) Foreign Application Priority Data
Jan. 12, 2022 (KR) 10-2022-0004542

(51) Int. Cl. H10K 85/60; H10K 50/11; C07F 5/02

(52) U.S. Cl. CPC H10K 85/658; H10K 50/11; H10K 85/6572; H10K 85/6574; H10K 85/6576; H10K 85/631; H10K 85/657; C07F 5/027; H10K 2101/20

(57) ABSTRACT

Provided is a light emitting element includes a polycyclic compound in which an electron donor substituent, which may increase the photoluminescence quantum yield (PLQY) and oscillator strength (f), is introduced at the para-position of a boron atom, thereby exhibiting high efficiency and long service life characteristics.

### CROSS-REFERENCE TO RELATED APPLICATION

This application claims priority to and the benefit of Korean Patent Application No. 10-2022-0004542, filed on Jan. 12, 2022, in the Korean Intellectual Property Office, the entire contents of which are hereby incorporated by reference.

### BACKGROUND

### 1. Field

Embodiments of the present disclosure herein relate to a light emitting element and a polycyclic compound for a light emitting element, and, for example, to a light emitting element including, in an emission layer, a plurality of materials such as a novel polycyclic compound used as a luminescent material.

### 2. Related Art

Recently, the development of an organic electroluminescence display device as an image display device is being actively conducted. The organic electroluminescence display device includes so-called a self-luminescent light emitting element in which holes and electrons injected from a first electrode and a second electrode recombine in an emission layer, and thus, a luminescent material of the emission layer emits light to implement a display.

In the application of an organic electroluminescence element to a display device, there is a demand for an organic electroluminescence element having low driving voltage, high luminous efficiency, and a long service life, and development of materials for an organic electroluminescence element capable of stably attaining such characteristics is being continuously required.

Recently, in order to accomplish an organic electroluminescence element with high efficiency, techniques of phosphorescence emission, which uses energy in a triplet state, or delayed fluorescence emission, which uses the phenomenon of generating singlet excitons by the collision of triplet excitons (triplet-triplet annihilation, TTA), are being developed, and development of a material for thermally activated delayed fluorescence (TADF) using delayed fluorescence phenomenon is being conducted.

### SUMMARY

Embodiments of the present disclosure provide a light emitting element having excellent luminous efficiency and element service life.

Embodiments of the present disclosure also provide a polycyclic compound that can be used as a material for a light emitting element having excellent luminous efficiency and element service life.

An embodiment of the present disclosure provides a light emitting element including a first electrode; a second electrode on the first electrode; and an emission layer between the first electrode and the second electrode, wherein the emission layer includes a first compound represented by Formula 1 below, and at least one of a second compound represented by Formula HT below, a third compound represented by Formula ET below, or a fourth compound represented by Formula D-1 below:

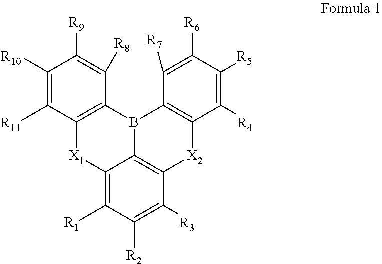

In Formula 1 above, X₁ and X₂ are each independently O, S, Se, or NRₐ, at least one of X₁ or X₂ is S, Se, or NRₐ, Rₐ is a substituted or unsubstituted phenyl group, R₁ to R₄, R₆ to R₉, and R₁₁ are each independently a hydrogen atom, a deuterium atom, a halogen atom, a cyano group, a nitro group, a substituted or unsubstituted boryl group, a substituted or unsubstituted amine group, a substituted or unsubstituted alkyl group having 1 to 20 carbon atoms, a substituted or unsubstituted cycloalkyl group having 6 to 30 ring-forming carbon atoms, a substituted or unsubstituted aryl group having 6 to 30 ring-forming carbon atoms, or a substituted or unsubstituted heteroaryl group having 3 to 30 ring-forming carbon atoms, R₅ and R₁₀ are each independently represented by Formula 2 or Formula 3 below, when each of R₅ and R₁₀ is represented by Formula 2, at least one L₁ is a substituted or unsubstituted arylene group having 6 to 30 ring-forming carbon atoms, and when each of R₅ and R₁₀ is represented by Formula 3, the case where at least one L₂ is a direct linkage, and N among heteroatoms contained in Ar₃ is directly linked to a benzene ring in Formula 1 above is excluded.

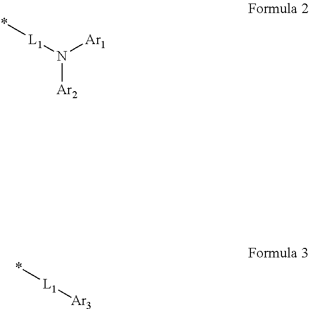

In Formula 2 and Formula 3 above, L₁ and L₂ are each independently a direct linkage, or a substituted or unsubstituted arylene group having 6 to 30 ring-forming carbon atoms, Ar₁ and Ar₂ are each independently a substituted or unsubstituted aryl group having 6 to 30 ring-forming carbon atoms, or a substituted or unsubstituted heteroaryl group having 3 to 30 ring-forming carbon atoms, and Ar₃ is a substituted or unsubstituted heteroaryl group having 3 to 30 ring-forming carbon atoms.

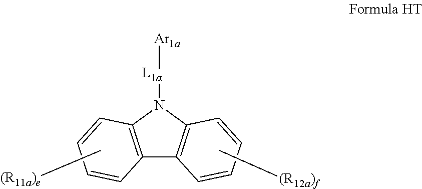

In Formula HT above, L₁ₐ is a direct linkage, a substituted or unsubstituted arylene group having 6 to 30 ring-forming carbon atoms, or a substituted or unsubstituted heteroarylene group having 2 to 30 ring-forming carbon atoms, Aria is a substituted or unsubstituted aryl group having 6 to 30 ring-forming carbon atoms, or a substituted or unsubstituted heteroaryl group having 2 to 30 ring-forming carbon atoms, R₁₁ₐ and R₁₂ₐ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and e and f are each independently an integer of 0 to 4.

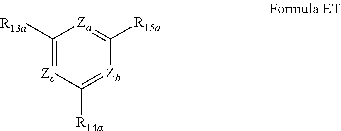

In Formula ET above, at least one selected from among Zₐ to Z_{c} is N, the rest are CR₁₆ₐ, and R₁₃ₐ to R₁₆ₐ are each independently a hydrogen atom, a deuterium atom, a cyano group, a substituted or unsubstituted silyl group, a substituted or unsubstituted aryl group having 6 to 30 ring-forming carbon atoms, or a substituted or unsubstituted heteroaryl group having 2 to 30 ring-forming carbon atoms.

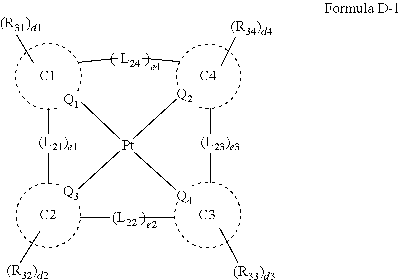

In Formula D-1 above, Q₁ to Q₄ are each independently C or N, C1 to C4 are each independently a substituted or unsubstituted hydrocarbon ring group having 5 to 30 ring-forming carbon atoms, or a substituted or unsubstituted heterocycle having 2 to 30 ring-forming carbon atoms, L₂₁ to L₂₄ are each independently a direct linkage,

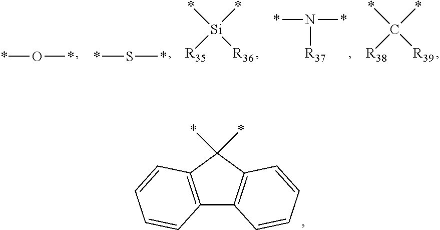

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, e1 to e4 are each independently 0 or 1, R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and d1 to d4 are each independently an integer of 0 to 4.

In an embodiment, Rₐ above may be represented by Formula 4 below:

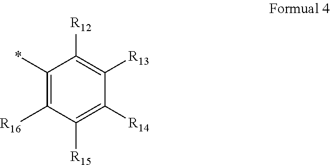

In Formula 4 above, R₁₂ to R₁₆ are each independently a hydrogen atom, a deuterium atom, a halogen atom, a cyano group, a nitro group, a substituted or unsubstituted boryl group, a substituted or unsubstituted amine group, a substituted or unsubstituted alkyl group having 1 to 20 carbon atoms, a substituted or unsubstituted cycloalkyl group having 6 to 30 ring-forming carbon atoms, a substituted or unsubstituted aryl group having 6 to 30 ring-forming carbon atoms, or a substituted or unsubstituted heteroaryl group having 3 to 30 ring-forming carbon atoms. In some embodiments, “* —” is a position linked to N.

In an embodiment, R₁ and R₃ above may be each independently a hydrogen atom or a deuterium atom, and R₂ above may be a hydrogen atom, a deuterium atom, a substituted or unsubstituted i-propyl group, a substituted or unsubstituted t-butyl group, a substituted or unsubstituted hexyl group, a substituted or unsubstituted phenyl group, or a substituted or unsubstituted carbazole group.

In an embodiment, Formula 1 above may be represented by any one selected from among Formula 1-1 to Formula 1-3 below:

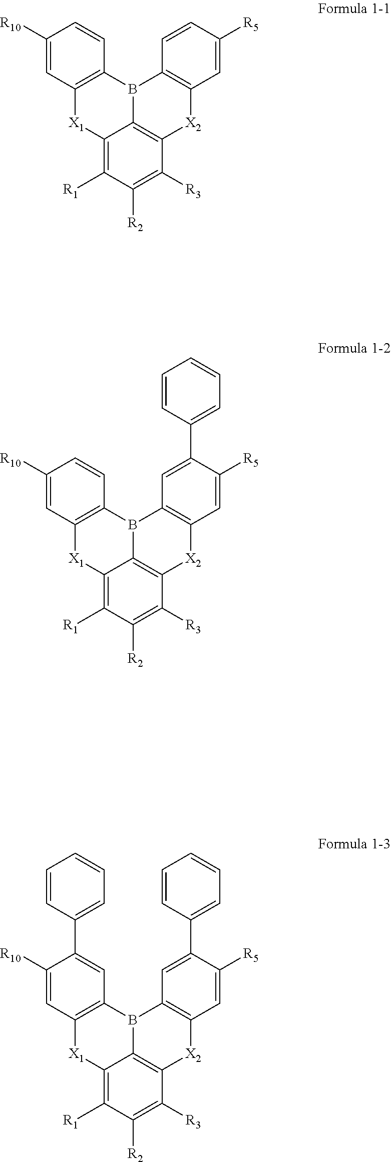

In Formula 1-1 to Formula 1-3 above, each hydrogen atom is unsubstituted or substituted with a deuterium atom, and X₁, X₂, R₁ to R₃, R₅ and R₁₀ are the same as defined with respect to Formula 1 above.

In an embodiment, Ar₃ above may be a substituted or unsubstituted heteroaryl group having 3 to 30 ring-forming carbon atoms and containing a heteroatom such as O, S, or N as a ring-forming atom, and the case where Ar₃ above is a pyridine group, a pyrazine group, a pyrimidine group, or a quinazoline group, or contains at least three Ns as a ring-forming atom may be excluded.

In an embodiment, when any one selected from among R₅ and R₁₀ above is represented by Formula 2 and the other is represented by Formula 3, the case where L₁ is a direct linkage or L₂ is a direct linkage, and N among heteroatoms contained in Ar₃ is directly linked to a benzene ring in Formula 1 above may be excluded.

In an embodiment, any one selected from among X₁ and X₂ above is NRₐ, and the other may be O or NRₐ. Here, Rₐ may be the same as defined with respect to Formula 1 above.

In an embodiment, when R₅ and R₁₀ above are represented by Formula 3 above, any one L2 selected from among R₅ and R₁₀ above is a direct linkage, Ar₃ above is a substituted or unsubstituted heteroaryl group having 3 to 30 ring-forming carbon atoms and having N as a ring-forming atom, and N constituting Ar₃ above is linked to the benzene ring in Formula 1 above, and the other is a dibenzofuran group, a dibenzothiophene group, or

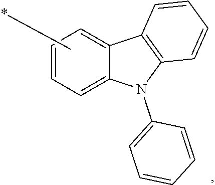

at least one of Rₐ's above may be a substituted phenyl group.

In an embodiment, Rₐ, the substituted phenyl group, may be represented by any one selected from among Formula 4-1 or Formula 4-2 below:

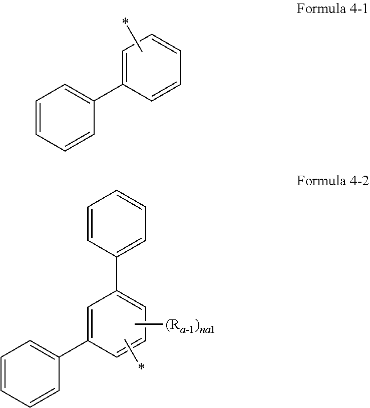

In Formula 4-2 above, Rₐ₋₁ is a hydrogen atom, a deuterium atom, or a substituted or unsubstituted aryl group having 6 to 15 ring-forming carbon atoms, and nₐ₁ is an integer of 0 to 3.

In an embodiment, Formula 2 above may be represented by Formula 2-1 below:

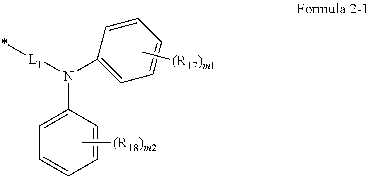

In Formula 2-1 above, R₁₇ and R₁₈ are each independently a hydrogen atom, a deuterium atom, a substituted or unsubstituted alkyl group having 1 to 10 carbon atoms, a substituted or unsubstituted cycloalkyl group having 6 to 15 ring-forming carbon atoms, or a substituted or unsubstituted aryl group having 6 to 15 ring-forming carbon atoms, m1 and m2 are each independently an integer of 0 to 5, and L₁ is the same as defined with respect to Formula 2 above.

In an embodiment, Formula 3 above may be represented by any one selected from among Formula 3-1 to Formula 3-3 below:

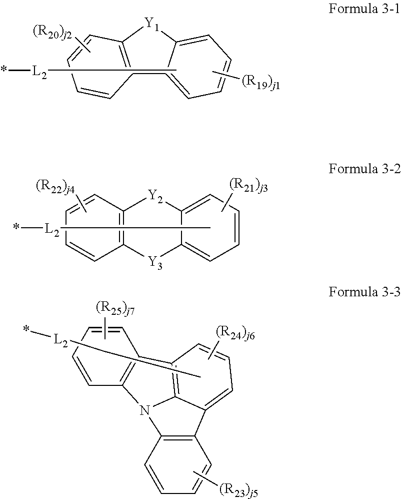

In Formula 3-1 and Formula 3-2 above, Y₁ and Y₂ are each independently 0, S, or NR₂₆, and Y₃ is O, S, NR₂₇, or CR₂₈R₂₉, and in Formula 3-1 to Formula 3-3 above, R₁₉ to R₂₅ are each independently a hydrogen atom, a deuterium atom, a halogen atom, a cyano group, a nitro group, a substituted or unsubstituted boryl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms, R₂₆ is a hydrogen atom, or a substituted or unsubstituted phenyl group, R₂₇ is a substituted or unsubstituted phenyl group, R₂₈ and R₂₉ are each independently a substituted or unsubstituted alkyl group having 1 to 4 carbon atoms, or a substituted or unsubstituted phenyl group, j1 to j5, and j7 are each independently an integer of 0 to 4, j6 is an integer of 0 to 3, and L2 is the same as defined with respect to Formula 3 above.

In an embodiment, the emission layer may emit a delayed fluorescence.

In an embodiment, the emission layer may include the first compound and the second compound, and may further include at least one of the third compound or the fourth compound.

### BRIEF DESCRIPTION OF THE FIGURES

The accompanying drawings are included to provide a further understanding of the subject matter of the present disclosure, and are incorporated in and constitute a part of this specification. The drawings illustrate example embodiments of the present disclosure and, together with the description, serve to explain principles of the present disclosure. In the drawings:

FIG. 1 is a plan view illustrating a display device according to an embodiment of the present disclosure;

FIG. 2 is a cross-sectional view illustrating a part taken along line I-I′ of FIG. 1;

FIG. 3 is a cross-sectional view schematically illustrating a light emitting element of an embodiment of the present disclosure;

FIG. 4 is a cross-sectional view schematically illustrating a light emitting element of an embodiment of the present disclosure;

FIG. 5 is a cross-sectional view schematically illustrating a light emitting element of an embodiment of the present disclosure;

FIG. 6 is a cross-sectional view schematically illustrating a light emitting element of an embodiment of the present disclosure;

FIG. 7 is a cross-sectional view illustrating a display device according to an embodiment of the present disclosure;

FIG. 8 is a cross-sectional view illustrating a display device according to an embodiment of the present disclosure;

FIG. 9 is a cross-sectional view illustrating a display device according to an embodiment of the present disclosure; and

FIG. 10 is a cross-sectional view illustrating a display device according to an embodiment of the present disclosure.

### DETAILED DESCRIPTION

The subject matter of the present disclosure may be modified in many alternate forms, and thus, example embodiments will be illustrated in the drawings and described in this text in more detail. It should be understood, however, that it is not intended to limit the present disclosure to the particular forms disclosed, but rather, is intended to cover all modifications, equivalents, and alternatives falling within the spirit and scope of the present disclosure.

In the present specification, when a component (or a region, a layer, a portion, etc.) is referred to as being “on,” “connected to,” or “coupled to” another component, it means that the component may be directly on/connected to/coupled to the other component, or that a third component may be therebetween.

Like reference numerals refer to like components throughout. Also, in the drawings, the thicknesses, ratios, and dimensions of the components may be exaggerated for effective description of technical contents. The term “and/or” includes all combinations of one or more of which associated configurations may define.

It will be understood that, although the terms “first,” “second,” etc. may be used herein to describe various components, these components should not be limited by these terms. These terms are only used to distinguish one component from another. For example, a first component could be termed a second component, and, similarly, a second component could be termed a first component, without departing from the scope of the present disclosure. As used herein, the singular forms, “a,” “an,” and “the” are intended to include the plural forms as well, unless the context clearly indicates otherwise.

In addition, terms such as “below,” “under,” “on,” and “above” may be used to describe the relationship between components illustrated in the figures. The terms are used as a relative concept and are described with reference to the direction indicated in the drawings.

It should be understood that the terms “comprise,” or “have” are intended to specify the presence of stated features, integers, steps, operations, components, parts, or combinations thereof in the disclosure, but do not preclude the presence or addition of one or more other features, integers, steps, operations, components, parts, or combinations thereof.

Unless otherwise defined, all terms (including technical and scientific terms) used herein have the same meaning as commonly understood by one of ordinary skill in the art to which the present disclosure belongs. In addition, it will be understood that terms, such as those defined in commonly used dictionaries, should be interpreted as having a meaning that is consistent with their meaning in the context of the relevant art and will not be interpreted in an idealized or overly formal sense unless expressly so defined herein.

In the present application, when a part such as a layer, a film, a region, or a plate is referred to as being “on” or “above” another part, it can be directly on the other part, or an intervening part may also be present. On the contrary, when a part such as a layer, a film, a region, or a plate is referred to as being “under” or “below” another part, it can be directly under the other part, or an intervening part may also be present. In addition, it will be understood that when a part is referred to as being “on” another part, it can be above the other part, or under the other part as well.

In the present specification, the term “substituted or unsubstituted” may mean substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the substituents described above may be substituted or unsubstituted. For example, a biphenyl group may be interpreted as an aryl group or a phenyl group substituted with a phenyl group.

In the present specification, the phrase “bonded to an adjacent group to form a ring” may indicate that one is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the present specification, the term “adjacent group” may mean a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the present specification, examples of the halogen atom may include a fluorine atom, a chlorine atom, a bromine atom, or an iodine atom.

In the present specification, the alkyl group may be a linear, branched or cyclic type (e.g., a linear alkyl group, a branched alkyl group, or a cyclic alkyl group). The number of carbons in the alkyl group may be 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-heneicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

The hydrocarbon ring group herein means any suitable functional group or substituent derived from an aliphatic hydrocarbon ring or a ring in which an aliphatic hydrocarbon ring group and an aromatic hydrocarbon ring are fused. The number of ring-forming carbon atoms in the hydrocarbon ring group may be 5 to 60, 5 to 30, or 5 to 30.

In the present specification, an aryl group means any suitable functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments of the present disclosure are not limited thereto.

In the present specification, the heterocyclic group means any suitable functional group or substituent derived from a ring containing at least one of B, O, N, P, Se, Si, or S as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

If the heterocyclic group contains two or more heteroatoms, the two or more heteroatoms may be the same as or different from each other. The heterocyclic group may be a monocyclic heterocyclic group or a polycyclic heterocyclic group and has the concept including a heteroaryl group. The number of ring-forming carbon atoms in the heterocyclic group may be 2 to 60, 2 to 30, 2 to 20, or 2 to 10.

In the present specification, the aliphatic heterocyclic group may contain at least one of B, O, N, P, Se, Si, or S as a heteroatom. The number of ring-forming carbon atoms of the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group etc., but embodiments of the present disclosure are not limited thereto.

In the present specification, the heteroaryl group may contain at least one of B, O, N, P, Se, Si, or S as a heteroatom. When the heteroaryl group contains two or more heteroatoms, the two or more heteroatoms may be the same as or different from each other. The heteroaryl group may be a monocyclic heterocyclic group or polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments of the present disclosure are not limited thereto.

In the present specification, the above description of the aryl group may be applied to an arylene group except that the arylene group is a divalent group. The above description of the heteroaryl group may be applied to a heteroarylene group except that the heteroarylene group is a divalent group.

In the present specification, the fluorenyl group may be substituted, and two substituents may be bonded to each other to form a spiro structure. Examples of cases where the fluorenyl group is substituted are as follows. However, embodiments of the present disclosure are not limited thereto.

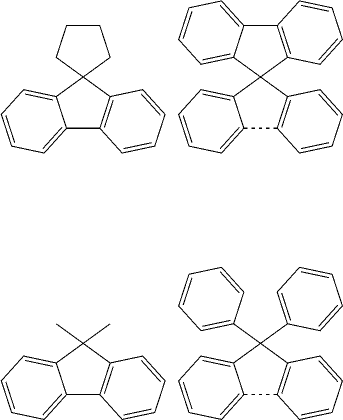

In the present specification, a silyl group includes an alkyl silyl group and an aryl silyl group. Examples of the silyl group may include a trimethylsilyl group, a triethylsilyl group, a t-butyldimethylsilyl group, an ethyldimethylsilyl group, a propyldimethylsilyl group, a triphenylsilyl group, a diphenylsilyl group, a phenylsilyl group, etc., but embodiments of the present disclosure are not limited thereto.

In the present specification, a thio group may include an alkylthio group and an arylthio group. The thio group may mean that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the present specification, an oxy group may mean that an oxygen atom is bonded to the alkyl group or the aryl group as defined above. The oxy group may include an alkoxy group and an aryl oxy group. The alkoxy group may be a linear chain, a branched chain or a ring chain. The number of carbon atoms in the alkoxy group is not specifically limited, but may be, for example, 1 to 60, 1 to 20 or 1 to 10. The number of ring-forming carbon atoms in the aryloxy group is not specifically limited, but may be, for example, 6 to 60, 6 to 30 or 6 to 20. Examples of the oxy group include methoxy, ethoxy, n-propoxy, isopropoxy, butoxy, pentyloxy, hexyloxy, octyloxy, nonyloxy, decyloxy, benzyloxy, etc., but embodiments of the present disclosure are not limited thereto.

The boron group herein may mean that a boron atom is bonded to the alkyl group or the aryl group as defined above. The boron group includes an alkyl boron group and an aryl boron group. Examples of the boron group may include a trimethylboron group, a triethylboron group, a t-butylmethylboron group, a triphenylboron group, a diphenylboron group, a phenylboron group, etc., but embodiments of the present disclosure are not limited thereto.

In the present specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but embodiments of the present disclosure are not limited thereto.

In the present specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

In the present specification, the aryl group among an aryloxy group, an arylthio group, an arylsulfoxy group, an arylamino group, an arylboron group, an arylsilyl group, an arylamine group is the same as the examples of the aryl group described above.

In the present specification, a direct linkage may mean a single bond. In the present specification, “

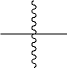

” and “—*” mean a position to be connected.

Hereinafter, a light emitting element according to an embodiment of the present disclosure will be described with reference to the drawings.

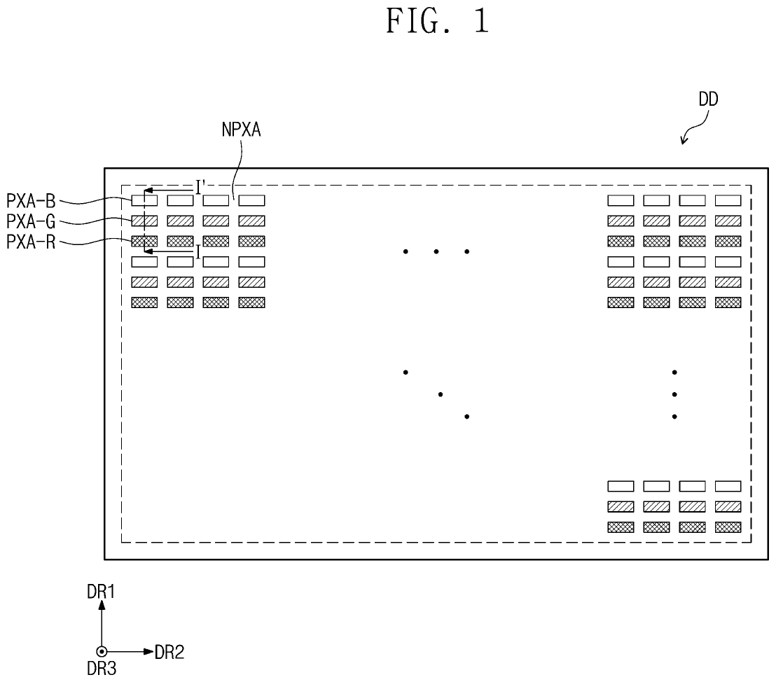

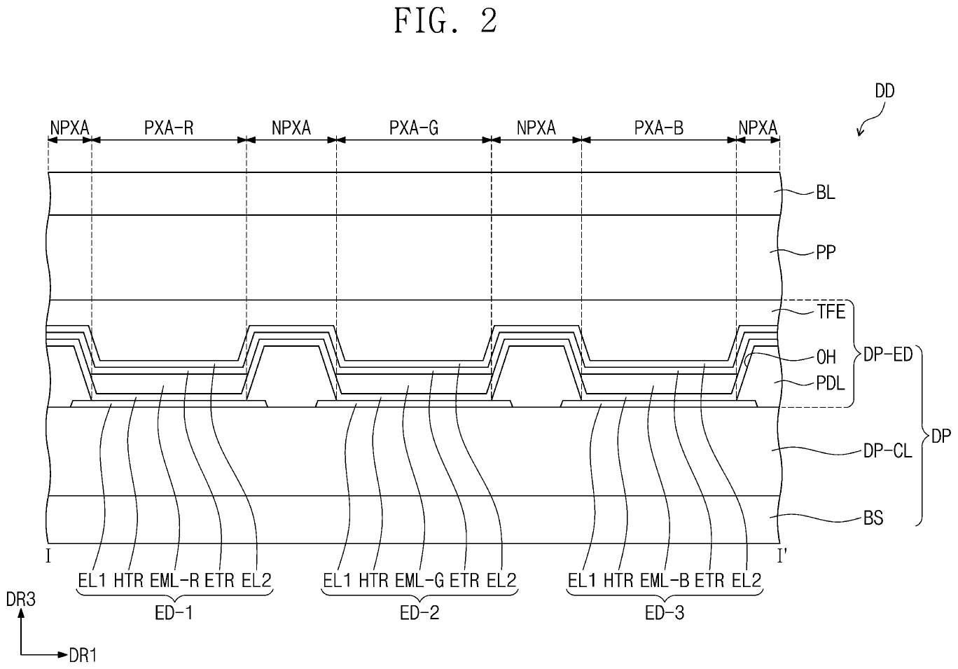

FIG. 1 is a plan view illustrating an embodiment of a display device DD. FIG. 2 is a cross-sectional view of the display device DD of the embodiment of FIG. 1. FIG. 2 is a cross-sectional view illustrating a part taken along line I-I′ of FIG. 1.

The display device DD may include a display panel DP and an optical layer PP on the display panel DP. The display panel DP may include light emitting elements ED-1, ED-2, and ED-3. The display device DD may include a plurality of light emitting elements ED-1, ED-2, and ED-3. The optical layer PP may be on the display panel DP to control reflected light in the display panel DP due to external light. The optical layer PP may include, for example, a polarization layer and/or a color filter layer. In some embodiments, unlike the configuration illustrated in the drawing, the optical layer PP may be omitted from the display device DD of an embodiment.

A base substrate BL may be on the optical layer PP. The base substrate BL may be a member which provides a base surface on which the optical layer PP is located. The base substrate BL may be a glass substrate, a metal substrate, a plastic substrate, etc. However, embodiments of the present disclosure are not limited thereto, and the base substrate BL may be an inorganic layer, an organic layer, or a composite material layer. In addition, unlike the configuration illustrated, in an embodiment, the base substrate BL may be omitted.

The display device DD according to an embodiment may further include a filling layer. The filling layer may be between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display element layer DP-ED. The display element layer DP-ED may include a pixel defining film PDL, the light emitting elements ED-1, ED-2, and ED-3 between portions of the pixel defining film PDL, and an encapsulation layer TFE on the light emitting elements ED-1, ED-2, and ED-3.

The base layer BS may be a member which provides a base surface on which the display element layer DP-ED is located. The base layer BS may be a glass substrate, a metal substrate, a plastic substrate, etc. However, embodiments of the present disclosure are not limited thereto, and the base layer BS may be an inorganic layer, an organic layer, or a composite material layer.

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting elements ED-1, ED-2, and ED-3 of the display element layer DP-ED.

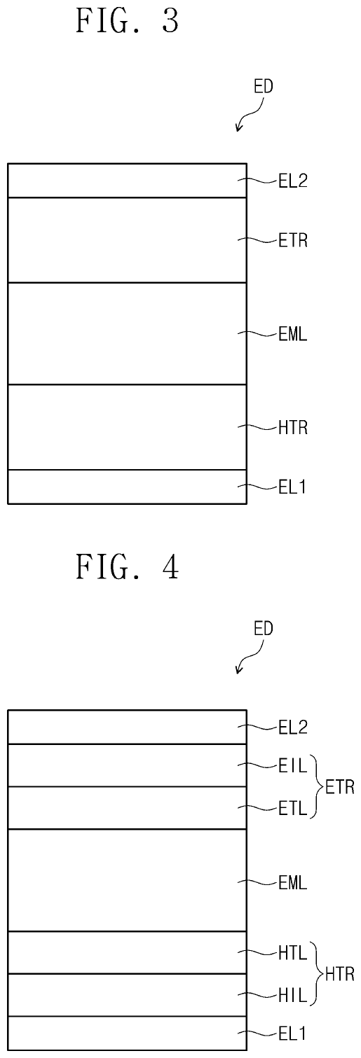

Each of the light emitting elements ED-1, ED-2, and ED-3 may have a structure of a light emitting element ED of an embodiment according to FIGS. 3 to 6, which will be further described herein below. Each of the light emitting elements ED-1, ED-2 and ED-3 may include a first electrode EL1, a hole transport region HTR, emission layers EML-R, EML-G and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are in openings OH defined in the pixel defining film PDL, and the hole transport region HTR, the electron transport region ETR, and the second electrode EL2 are provided as a common layer in the entire light emitting elements ED-1, ED-2, and ED-3. However, embodiments of the present disclosure are not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting elements ED-1, ED-2, and ED-3 in an embodiment may be provided by being patterned utilizing an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film may protect the display element layer DP-ED from moisture/oxygen, and the encapsulation-organic film may protect the display element layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. The encapsulation-organic film may include an acrylic-based compound, an epoxy-based compound, and/or the like. The encapsulation-organic film may include a photopolymerizable organic material, but embodiments of the present disclosure are not particularly limited thereto.

The encapsulation layer TFE may be on the second electrode EL2 and may fill the opening OH.

Referring to FIGS. 1 and 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2 and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to portions of the pixel defining film PDL. In the present specification, the light emitting regions PXA-R, PXA-G, and PXA-B may respectively correspond to pixels. The pixel defining film PDL may divide the light emitting elements ED-1, ED-2, and ED-3. The emission layers EML-R, EML-G, and EML-B of the light emitting elements ED-1, ED-2, and ED-3 may be in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of an embodiment shown in

FIGS. 1 and 2, three light emitting regions PXA-R, PXA-G, and PXA-B which emit red light, green light, and blue light, respectively, are illustrated as examples. For example, the display device DD of an embodiment may include the red light emitting region PXA-R, the green light emitting region PXA-G, and the blue light emitting region PXA-B that are separated from each other.

In the display device DD according to an embodiment, the plurality of light emitting elements ED-1, ED-2, and ED-3 may emit light beams having wavelengths different from each other. For example, in an embodiment, the display device DD may include a first light emitting element ED-1 that emits red light, a second light emitting element ED-2 that emits green light, and a third light emitting element ED-3 that emits blue light. In some embodiments, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may emit light beams in the same (e.g., substantially the same) wavelength range or at least one light emitting element may emit a light beam in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe form. Referring to FIG. 1, the plurality of red light emitting regions PXA-R, the plurality of green light emitting regions PXA-G, and the plurality of blue light emitting regions PXA-B each may be arranged along a second directional axis DR2. In addition, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may mean areas when viewed on a plane defined by the first directional axis DR1 and the second directional axis DR2.

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the characteristics of display quality required in the display device DD. For example, the arrangement form of the light emitting regions PXA-R, PXA-G, and PXA-B may be a PENTILE® arrangement form (e.g., an RGBG matrix, RGBG structure, or RGBG matrix structure) or a diamond arrangement form. PENTILE® is a duly registered trademark of Samsung Display Co., Ltd.

In addition, the areas of the light emitting regions PXA-R, PXA-G, and PXA-B may be different from each other. For example, in an embodiment, the area of the green light emitting region PXA-G may be smaller than that of the blue light emitting region PXA-B, but embodiments of the present disclosure are not limited thereto.

Hereinafter, FIGS. 3 to 6 are cross-sectional views schematically illustrating light emitting elements according to embodiments. Each of the light emitting elements ED according to embodiments may include a first electrode EL1, a second electrode EL2 facing the first electrode EL1, and an emission layer EML between the first electrode EL1 and the second electrode EL2. The light emitting element ED of an embodiment may include a first compound of an embodiment, which will be further described below, in the emission layer EML.

Each of the light emitting elements ED may include a hole transport region HTR, an emission layer EML, and an electron transport region ETR that are at least sequentially stacked. In some embodiments, each of the light emitting elements ED of embodiments may include the first electrode EL1, the hole transport region HTR, the emission layer EML, the electron transport region ETR, and the second electrode EL2 that are sequentially stacked.

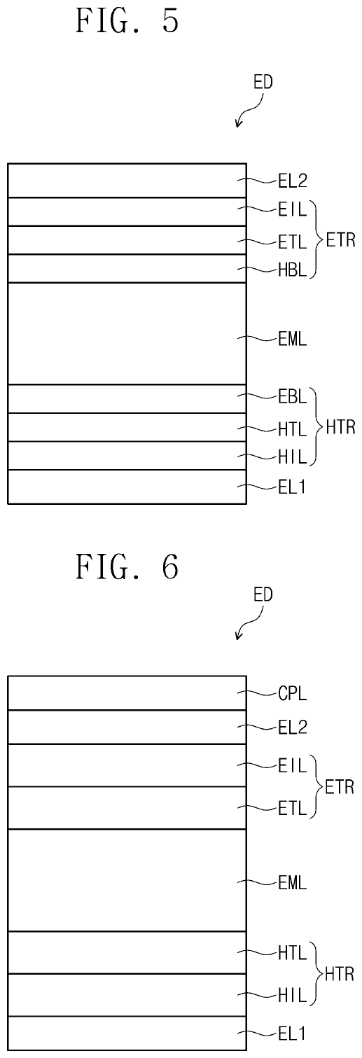

Compared with FIG. 3, FIG. 4 illustrates a cross-sectional view of a light emitting element ED of an embodiment, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting element ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting element ED of an embodiment including a capping layer CPL on a second electrode EL2.

The light emitting element ED of an embodiment may include the first compound of an embodiment, which will be further described below, in the emission layer EML. The first compound may be a polycyclic compound. A display device DD (see FIG. 2) of an embodiment including a plurality of light emitting regions may include the polycyclic compound of an embodiment, which will be further described below, in the emission layer EML constituting at least one light emitting region.

In the light emitting element ED according to an embodiment, the first electrode EL1 has conductivity (e.g., electrical conductivity). The first electrode EL1 may be formed of a metal material, a metal alloy, and/or a conductive compound. The first electrode EL1 may be an anode or a cathode. However, embodiments of the present disclosure are not limited thereto. In addition, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, or an oxide thereof.

If the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/AI (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments of the present disclosure are not limited thereto. In addition, embodiments of the present disclosure are not limited thereto, and the first electrode EL1 may include the above-described metal materials, combinations of at least two metal materials of the above-described metal materials, oxides of the above-described metal materials, or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In addition, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but embodiments of the present disclosure are not limited thereto.

The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-1 below:

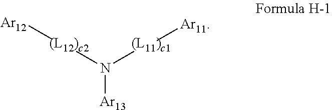

In Formula H-1 above, L₁₁ and L₁₂ may be each independently a direct linkage, a substituted or unsubstituted arylene group having 6 to 30 ring-forming carbon atoms, or a substituted or unsubstituted heteroarylene group having 2 to 30 ring-forming carbon atoms. c1 and c2 may be each independently an integer of 0 to 10. When c1 or c2 is an integer of 2 or more, a plurality of L₁₁'s and L₁₂'s may be each independently a substituted or unsubstituted arylene group having 6 to 30 ring-forming carbon atoms, or a substituted or unsubstituted heteroarylene group having 2 to 30 ring-forming carbon atoms.

In Formula H-1, Ar₁₁ and Ar₁₂ may be each independently a substituted or unsubstituted aryl group having 6 to 30 ring-forming carbon atoms, or a substituted or unsubstituted heteroaryl group having 2 to 30 ring-forming carbon atoms. In addition, in Formula H-1, Ar₁₃ may be a substituted or unsubstituted aryl group having 6 to 30 ring-forming carbon atoms.

The compound represented by Formula H-1 above may be a monoamine compound. In some embodiments, the compound represented by Formula H-1 above may be a diamine compound in which at least one selected from among Ar₁₁ to Ar₁₃ includes the amine group as a substituent. In addition, the compound represented by Formula H-1 above may be a carbazole-based compound including a substituted or unsubstituted carbazole group in at least one of Ar₁₁ or Ar₁₂, or a fluorene-based compound including a substituted or unsubstituted fluorene group in at least one of Ar₁₁ or Ar₁₂.

The compound represented by Formula H-1 may be represented by any one selected from among the compounds of Compound Group H below. However, the compounds listed in Compound Group H below are examples, and the compounds represented by Formula H-1 are not limited to those represented by Compound Group H below:

### Compound Group H

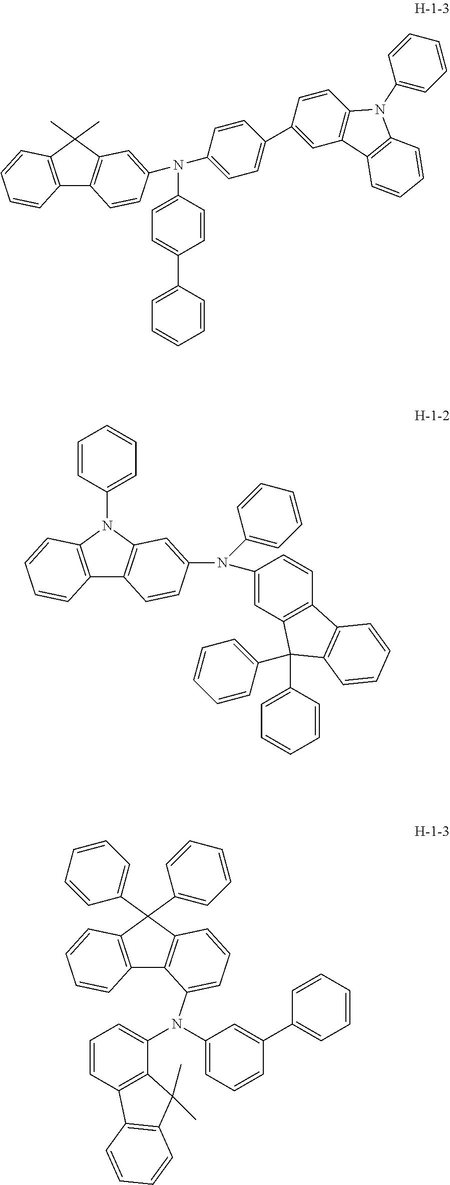 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

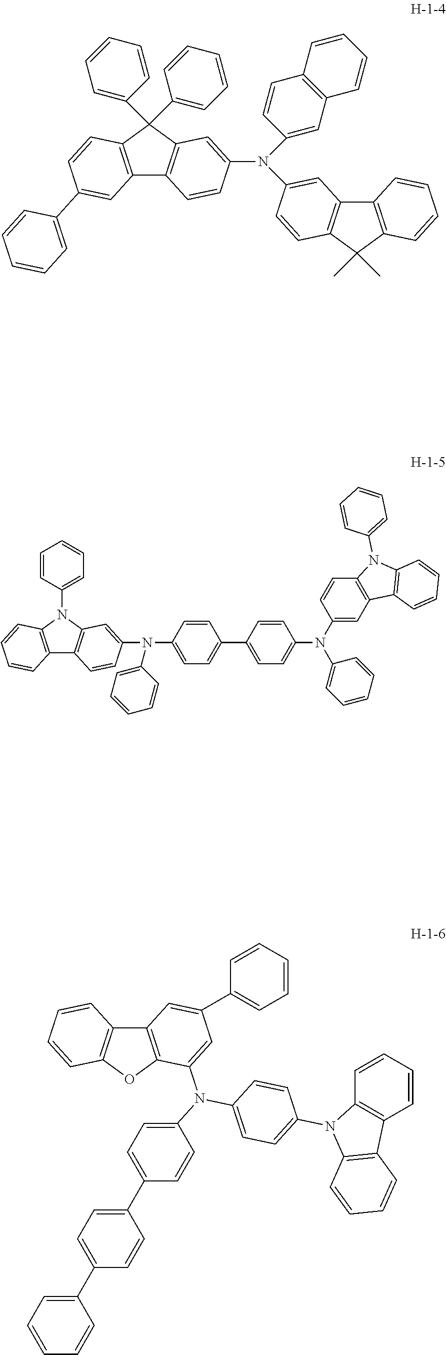 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

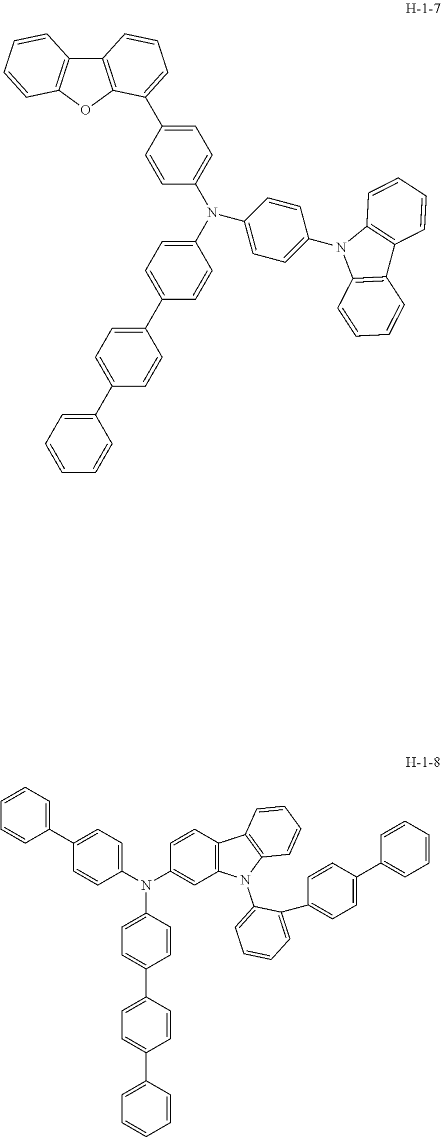 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1]

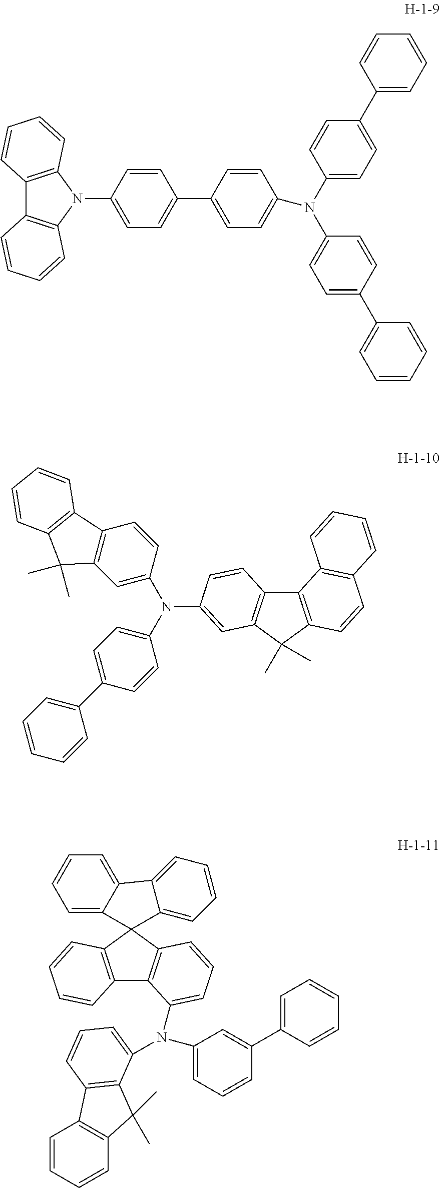 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

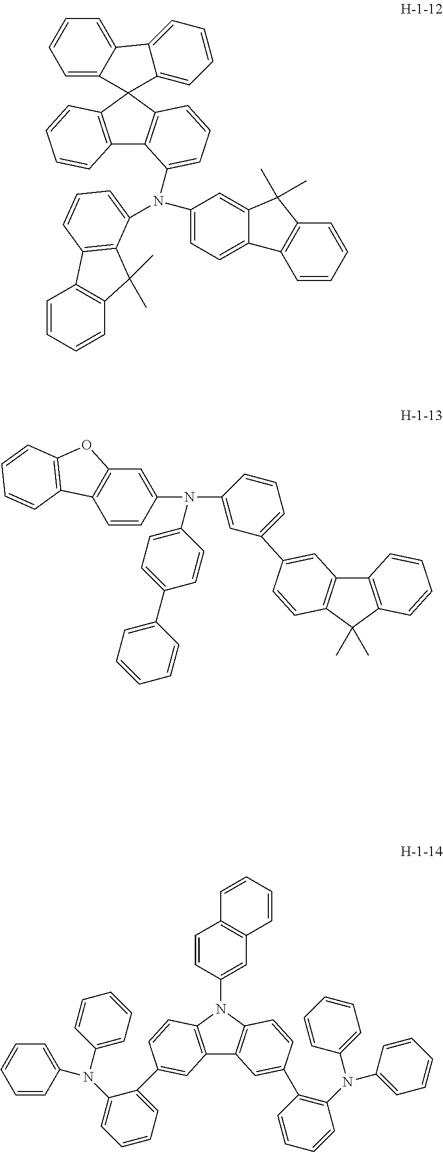 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

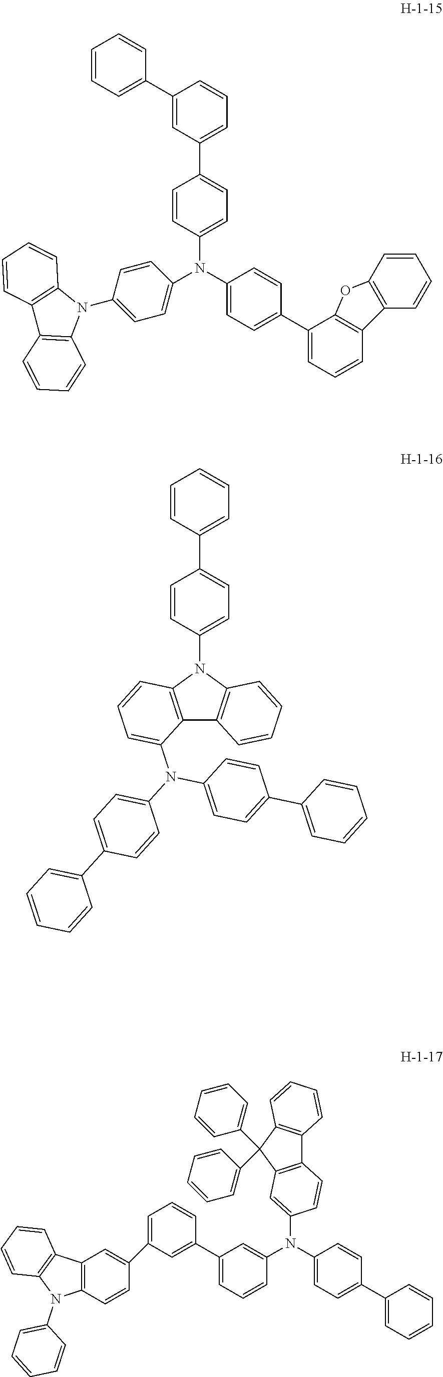 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

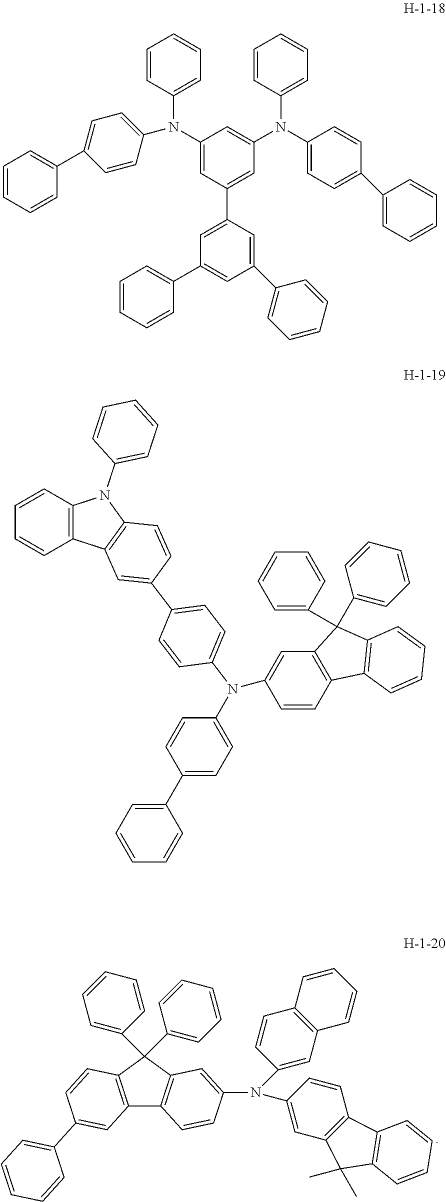 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB (or NPD)), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region HTR in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without a substantial increase in driving voltage.

The hole transport region HTR may further include a charge generating material to increase conductivity (e.g., electrical conductivity) in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, the p-dopant may include a metal halide compound such as CuI and/or RbI, a quinone derivative such as tetracyanoquinodimethane (TCNQ) and/or 2,3,5,6-tetrafluoro-7,7,8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be contained in the hole transport region HTR may be used as a material to be contained in the buffer layer. The electron blocking layer EBL is a layer that serves to prevent or reduce injection of electrons from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In the light emitting element ED of an embodiment, an emission layer EML may include a plurality of luminescent materials. In an embodiment, the emission layer EML may include the first compound, and at least one of a second compound, a third compound, or a fourth compound. In the light emitting element ED of an embodiment, the emission layer EML may include at least one host and at least one dopant. For example, the emission layer EML of an embodiment may include a first dopant, and include a first host and a second host that are different from each other. In addition, the emission layer EML of an embodiment may include the first host and the second host that are different from each other, and the first dopant and a second dopant that are different from each other.

The first compound included in the emission layer EML of an embodiment may include the polycyclic compound represented by Formula 1 below. For the polycyclic compound represented by Formula 1, any hydrogen atom in the molecule may be substituted with a deuterium atom. For example, the polycyclic compound of an embodiment may contain a deuterium atom or a substituent including a deuterium atom. In some embodiments, the polycyclic compound of an embodiment may include at least one deuterium atom as a substituent.

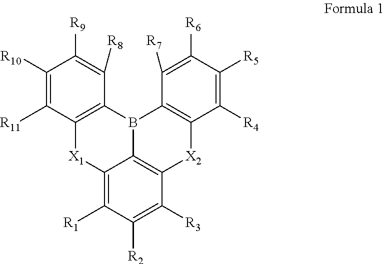

In Formula 1, X₁ and X₂ may be each independently an oxygen atom (O), a sulfur atom (S), a selenium atom (Se), or NRₐ. Here, at least one selected from among X₁ and X₂ may be S, Se, or NRₐ. For example, any one selected from among X₁ and X₂ may be NRₐ, and the other may be O or NRₐ. In some embodiments, each of X₁ and X₂ may be NRₐ. In some embodiments, any one selected from among X₁ and X₂ may be NRₐ, and the other may be O.

In an embodiment, Rₐ may be a substituted or unsubstituted phenyl group. For example, Rₐ may be represented by Formula 4 which will be further described below. In some embodiments, when Rₐ is a substituted phenyl group, at least one hydrogen atom linked to the phenyl group may be substituted with another substituent.

In Formula 1, R₁ to R₄, R₆ to R₉, and Ru may be each independently a hydrogen atom, a deuterium atom, a halogen atom, a cyano group, a nitro group, a substituted or unsubstituted boryl group, a substituted or unsubstituted amine group, a substituted or unsubstituted alkyl group having 1 to 20 carbon atoms, a substituted or unsubstituted cycloalkyl group having 6 to 30 ring-forming carbon atoms, a substituted or unsubstituted aryl group having 6 to 30 ring-forming carbon atoms, or a substituted or unsubstituted heteroaryl group having 3 to 30 ring-forming carbon atoms.

In an embodiment, R₁ to R₃ are each independently a hydrogen atom, a deuterium atom, a substituted or unsubstituted alkyl group having 1 to 10 carbon atoms, a substituted or unsubstituted cycloalkyl group having 6 to 15 ring-forming carbon atoms, a substituted or unsubstituted aryl group having 6 to 15 ring-forming carbon atoms, or a substituted or unsubstituted heteroaryl group having 3 to 15 ring-forming carbon atoms. For example, R₁ and R₃ may be each independently a hydrogen atom or a deuterium atom. R₂ may be a hydrogen atom, a deuterium atom, a substituted or unsubstituted i-propyl group, a substituted or unsubstituted t-butyl group, a substituted or unsubstituted cyclohexyl group, a substituted or unsubstituted phenyl group, or a substituted or unsubstituted carbazole group. In some embodiments, R₂ may be a hydrogen atom or a deuterium atom, or may be represented by any one in Substituent Group S1 below. In Substituent Group S1 below, “—*” is a part linked to the benzene ring in Formula 1.

### Substituent Group S1

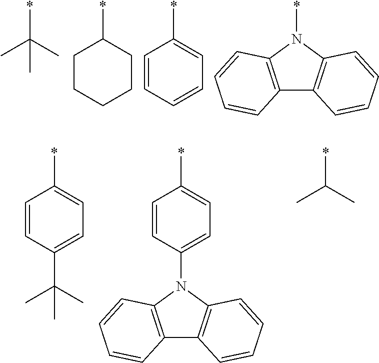

In an embodiment, R₄, R₆ to R₉, and R₁₁ may be each independently a hydrogen atom, a deuterium atom, or a substituted or unsubstituted aryl group having 6 to 15 ring-forming carbon atoms. For example, R₄, R₆ to R₉, and R₁₁ may be each independently a hydrogen atom, a deuterium atom, or a substituted or unsubstituted phenyl group.

In Formula 1, R₅ and R₁₀ may be each independently represented by Formula 2 or Formula 3. The polycyclic compound represented by Formula 1 of an embodiment has an electron donor substituent represented by Formula 2 or Formula 3 below that is linked at the para-position of a boron atom, and thus has excellent stability, thereby improving a service life of the light emitting element when used as a material for the light emitting element.

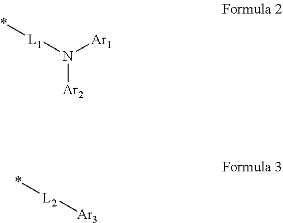

In Formula 2 and Formula 3, L₁ and L₂ may be each independently a direct linkage, or a substituted or unsubstituted arylene group having 6 to 30 ring-forming carbon atoms. For example, L₁ and L₂ may be each independently a direct linkage, a substituted or unsubstituted phenylene group, or a substituted or unsubstituted biphenylene group. In Formulae 2 and 3, “—*” is a position linked to the benzene ring in Formula 1.

In Formula 2, Ar₁ and Ar₂ may be each independently a substituted or unsubstituted aryl group having 6 to 30 ring-forming carbon atoms, or a substituted or unsubstituted heteroaryl group having 3 to 30 ring-forming carbon atoms. In an embodiment, Ar₁ and Ar₂ may be each independently a substituted or unsubstituted aryl group having 6 to 20 ring-forming carbon atoms. For example, Ar₁ and Ar₂ may be each independently an unsubstituted t-butyl group or a phenyl group substituted with a phenyl group, or an unsubstituted phenyl group.

In Formula 3, Ar₃ may be a substituted or unsubstituted heteroaryl group having 3 to 30 ring-forming carbon atoms. In an embodiment, Ar3 may be a substituted or unsubstituted heteroaryl group having 3 to 30 ring-forming carbon atoms and containing a heteroatom such as O, S, or N as a ring-forming atom. In some embodiments, the case where Ar₃ is a pyridine group, a pyrazine group, a pyrimidine group, or a quinazoline group, or contains at least three Ns as a ring-forming atom may be excluded.

In an embodiment, each of R₅ and R₁₀ in Formula 1 may be represented by Formula 2. Each of R₅ and R₁₀ represented by Formula 2 may be the same as or different from each other. When each of R₅ and R₁₀ is represented by Formula 2, at least one L₁ may be a substituted or unsubstituted arylene group having 6 to 30 ring-forming carbon atoms. In some embodiments, when both R₅ and R₁₀ in Formula 1 are represented by Formula 2, at least one L₁ may not be a direct linkage.

In an embodiment, each of R₅ and R₁₀ in Formula 1 may be represented by Formula 3. Each of R₅ and R₁₀ represented by Formula 3 may be the same as or different from each other. When each of R₅ and R₁₀ is represented by Formula 3, the case where at least one L₂ is a direct linkage, and thus, a nitrogen atom among heteroatoms contained in Ar₃ is directly linked to a benzene ring in Formula 1 above may be excluded. In some embodiments, when both R₅ and R₁₀ in Formula 1 are represented by Formula 3, for any one selected from among R₅ and R₁₀, the nitrogen atom (N) of Ar₃ containing a nitrogen atom as a ring-forming atom is not linked to the benzene ring in Formula 1. For example, when both R₅ and R₁₀ are represented by Formula 3 and two Ar₃'s are heteroaryl groups containing a nitrogen atom (N) as a ring-forming atom, the nitrogen atom (N) in any one selected from among two Ar₃'s may be linked to Formula 1 via a linker such as L₂, or a carbon atom (C) constituting Ar₃ may be linked to Formula 1.

In an embodiment, each of R₅ and R₁₀ in Formula 1 may be represented by Formula 3 and each of X₁ and X₂ may be NRₐ. For example, L₂ in any one selected from among R₅ and R₁₀ may be a direct linkage, Ar₃ above may be a substituted or unsubstituted heteroaryl group having 3 to 30 ring-forming carbon atoms and having N as a ring-forming atom, and N constituting Ar₃ above may be linked to the benzene ring in Formula 1 above. In addition, the other among R₅ and R₁₀ may be a dibenzofuran group, a dibenzothiophene group, or

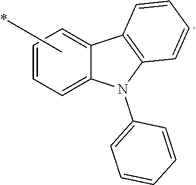

In this case, at least one selected from among Rₐ's may be a substituted phenyl group. In an embodiment, Rₐ, a substituted phenyl group, may be represented by Formula 4-1 or Formula 4-2 below, which will be further described below.

In an embodiment, any one selected from among R₅ and R₁₀ in Formula 1 may be represented by Formula 2, and the other may be represented by Formula 3. In this case, the case where L₁ is a direct linkage and L₂ is a direct linkage, and N among heteroatoms contained in Ar₃ is directly linked to the benzene ring in Formula 1 above may be excluded. For example, when R₅ is represented by Formula 2 and R₁₀ is represented by Formula 3, L1 may not be a direct linkage, and may be a substituted or unsubstituted arylene group having 6 to 30 ring-forming carbon atoms. In some embodiments, when R₅ is represented by Formula 2 and R₁₀ is represented by Formula 3, L₂ is a direct linkage, and the nitrogen atom (N) of Ar₃ containing a nitrogen atom as a ring-forming atom is not linked to the benzene ring in Formula 1.

In an embodiment, Rₐ above may be represented by Formula 4 below:

### Formula 4

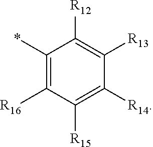

In Formula 4, R₁₂ to R₁₆ may be each independently a hydrogen atom, a deuterium atom, a halogen atom, a cyano group, a nitro group, a substituted or unsubstituted boryl group, a substituted or unsubstituted amine group, a substituted or unsubstituted alkyl group having 1 to 20 carbon atoms, a substituted or unsubstituted cycloalkyl group having 6 to 30 ring-forming carbon atoms, a substituted or unsubstituted aryl group having 6 to 30 ring-forming carbon atoms, or a substituted or unsubstituted heteroaryl group having 3 to 30 ring-forming carbon atoms.

In an embodiment, R₁₂ to R₁₆ may be each independently a hydrogen atom, a deuterium atom, a substituted or unsubstituted alkyl group having 1 to 10 carbon atoms, a substituted or unsubstituted cycloalkyl group having 6 to 15 ring-forming carbon atoms, or a substituted or unsubstituted aryl group having 6 to 15 ring-forming carbon atoms. For example, R₁₂ to R₁₆ may be each independently a hydrogen atom, a deuterium atom, a substituted or unsubstituted i-propyl group, a substituted or unsubstituted phenyl group, or a substituted or unsubstituted cyclohexyl group. However, embodiments of the present disclosure are not limited thereto. In Formula 4, “—*” is a position linked to N.

In an embodiment, Formula 4 may be represented by Formula 4-1 or Formula 4-2 below. Formula 4-1 and Formula 4-2 correspond to embodiments in which any one selected from among R₁₂ to R₁₆ in Formula 4 is substituted with a phenyl group and two among R₁₂ to R₁₆ are substituted with phenyl groups, respectively.

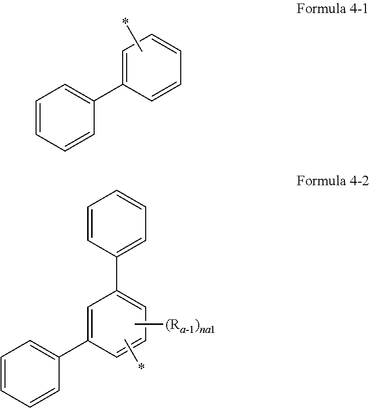

In Formula 4-1 and Formula 4-2 above, Rₐ₋₁ may be a hydrogen atom, a deuterium atom, or a substituted or unsubstituted aryl group having 6 to 15 ring-forming carbon atoms. For example, Rₐ₋₁ may be a hydrogen atom, a deuterium atom, or a substituted or unsubstituted phenyl group. nₐ₁ may be an integer of 0 to 3. When nₐ₁ is an integer of 2 or more, a plurality of Rₐ₋₁'s may be the same as or different from each other. In some embodiments, the case where nₐ₁ is 0 may be the same as the case where nₐ₁ is 3 and Rₐ₋₁'s are hydrogen atoms.

The polycyclic compound represented by Formula 1 of an embodiment may be represented by any one selected from among Formula 1-1 to Formula 1-3 below. Formula 1-1 to Formula 1-3 correspond to the case where in Formula 1, R₄, R₇, R₈, and R₁₁ are hydrogen atoms, and both R₆ and R₉ are hydrogen atoms or phenyl groups, or any one selected from among R₆ and R₉ is a hydrogen atom and the other is a phenyl group. In Formula 1-1 to Formula 1-3, the same as described with respect to Formula 1 above may be applied to X₁, X₂, R₁ to R₃, R₅, and R₁₀. In Formula 1-1 to Formula 1-3, each hydrogen atom may be unsubstituted or substituted with a deuterium atom.

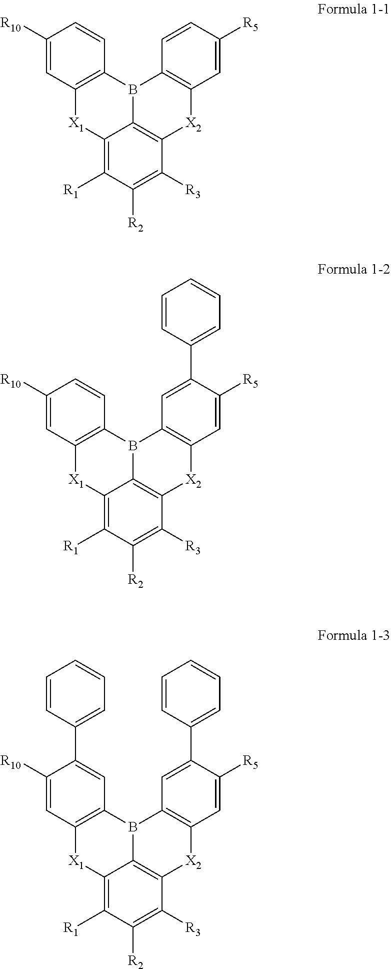

In an embodiment, Formula 2 may be represented by Formula 2-1 below. Formula 2-1 corresponds to the case where Ar₁ and Ar₂ are specified in Formula 2. Accordingly, the same as described in Formula 2 above may be applied to L₁ in Formula 2-1.

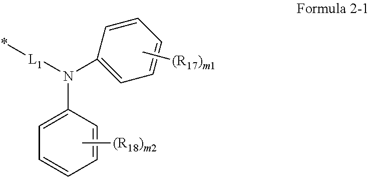

In Formula 2-1, R₁₇ and R₁₈ may be each independently a hydrogen atom, a deuterium atom, a substituted or unsubstituted alkyl group having 1 to 10 carbon atoms, a substituted or unsubstituted cycloalkyl group having 6 to 15 ring-forming carbon atoms, or a substituted or unsubstituted aryl group having 6 to 15 ring-forming carbon atoms. For example, R₁₇ and R₁₈ may be each independently a hydrogen atom, a deuterium atom, a substituted or unsubstituted t-butyl group, a substituted or unsubstituted cyclohexyl group, or a substituted or unsubstituted phenyl group. However, embodiments of the present disclosure are not limited thereto.

In Formula 2-1, m1 and m2 may be each independently an integer of 0 to 5. When each of m1 and m2 is an integer of 2 or more, a plurality of R₁₇'s and R₁₈'s may each be the same or different. The case where each of m1 and m2 is 0 may be the same as the case where each of m1 and m2 is 5 and R₁₇'s and R₁₈'s are each hydrogen atoms.

In an embodiment, Formula 3 may be represented by any one selected from among Formula 3-1 to Formula 3-3 below. Formula 3-1 to Formula 3-3 are the cases where Ar₃ is specified in Formula 3. Accordingly, in Formula 3-1 to Formula 3-3, the same as described in Formula 3 above may be applied to L₂.

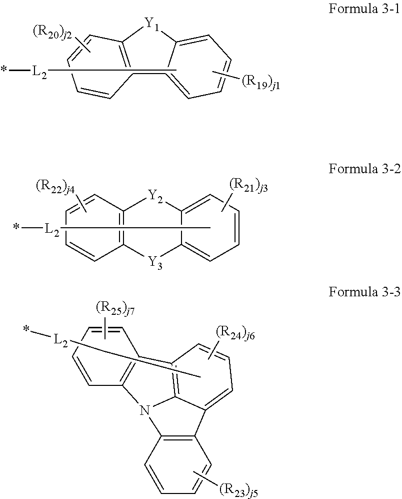

In Formula 3-1 and Formula 3-2, Y₁ and Y₂ may be each independently O, S, or NR₂₆, and Y₃ may be O, S, NR₂₇, or CR₂₈R₂₉. In some embodiments, each of R₅ and R₁₀ represented by Formula 3-1 may be a substituted or unsubstituted carbazole derivative, a substituted or unsubstituted dibenzofuran derivative, or a substituted or unsubstituted dibenzothiophene derivative. In some embodiments, each of R₅ and R₁₀ represented by Formula 3-2 may be a substituted or unsubstituted diphenylene dioxide derivative, a substituted or unsubstituted thianthrene derivative, or a substituted or unsubstituted phenoxathiine derivative. In some embodiments, each of R₅ and R₁₀ represented by Formula 3-3 may be an indolocarbazole derivative.

In Formula 3-1 to Formula 3-3, R₁₉ to R₂₅ may be each independently a hydrogen atom, a deuterium atom, a halogen atom, a cyano group, a nitro group, a substituted or unsubstituted boryl group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted cycloalkyl group having 3 to 30 ring-forming carbon atoms. In an embodiment, R₁₉ to R₂₅ may be each independently a hydrogen atom, a deuterium atom, a substituted or unsubstituted alkyl group having 1 to 10 carbon atoms, a substituted or unsubstituted cycloalkyl group having 6 to 15 ring-forming carbon atoms, or a substituted or unsubstituted aryl group having 6 to 15 ring-forming carbon atoms. For example, R₁₉ to R₂₅ may be each independently a hydrogen atom, a deuterium atom, a substituted or unsubstituted t-butyl group, a substituted or unsubstituted cyclohexyl group, or a substituted or unsubstituted phenyl group. However, embodiments of the present disclosure are not limited thereto.

In Formula 3-1 to Formula 3-3, R₂₆ may be a hydrogen atom, or a substituted or unsubstituted phenyl group. R₂₇ may be a substituted or unsubstituted phenyl group, and R₂₈ and R₂₉ may be each independently a substituted or unsubstituted alkyl group having 1 to 4 carbon atoms, or a substituted or unsubstituted phenyl group.

In Formulae 3-1 to 3-3, j1, j5, and j7 may be each independently an integer of 0 to 4, and j6 may be an integer of 0 to 3. When each of j1 to j5 is an integer of 2 or more, a plurality of R₁₉'s to R₂₅'s may each be the same or different. The case where each of j1 to j5, and j7 is 0 may be the same as the case where each of j1 to j5, and j7 is 4 and R₁₉'s and R₂₃'s are each hydrogen atoms. The case where j6 is 0 may be the same as the case where j6 is 3 and R₂₄'s are hydrogen atoms.

The first compound of an embodiment may be any one selected from among the compounds represented in Compound Group 1 below. The light emitting element ED of an embodiment may include at least one compound among the compounds represented by Compound Group 1 as the first compound in the emission layer EML.

### Compound Group 1

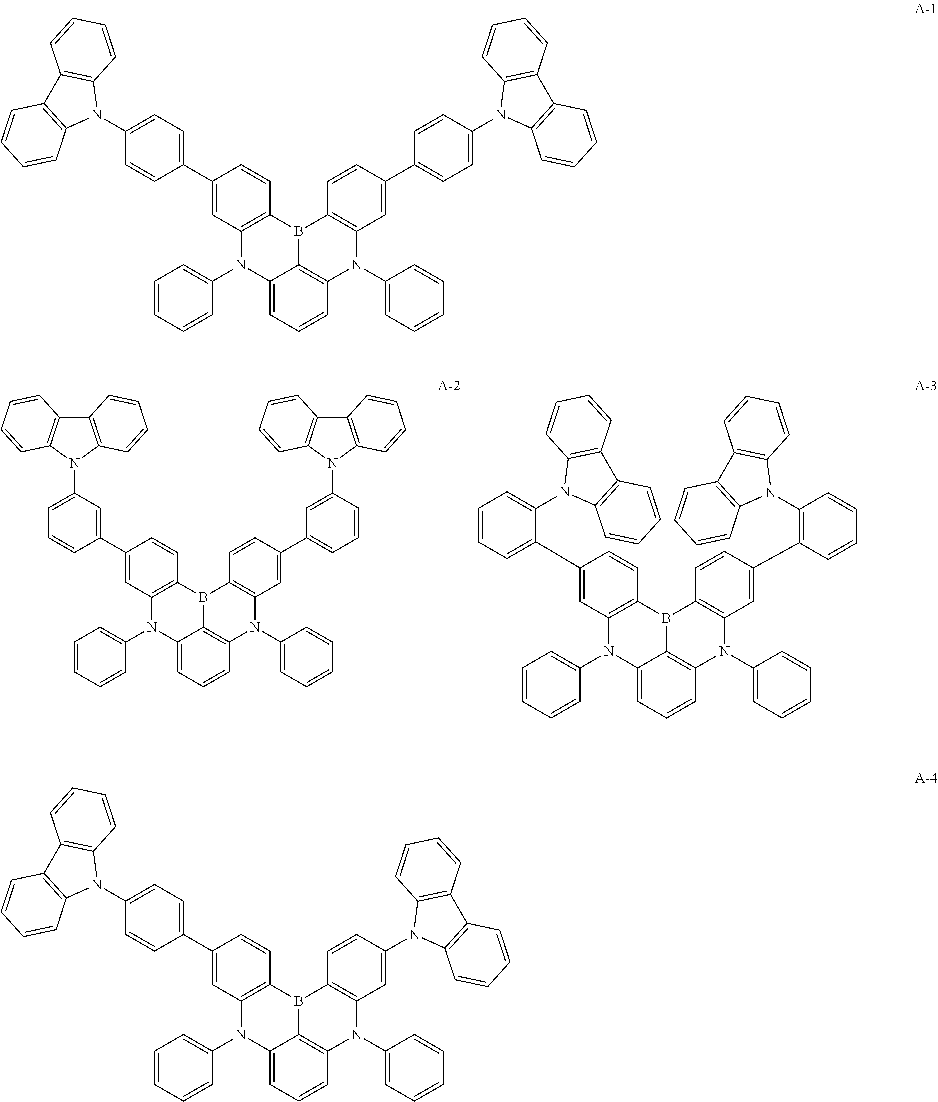 [SMILES: c1ccc(N2c3cc(-c4ccc(-n5c6ccccc6c6ccccc65)cc4)ccc3B3c4ccc(-c5ccc(-n6c7ccccc7c7ccccc76)cc5)cc4N(c4ccccc4)c4cccc2c43)cc1 ; c1ccc(N2c3cc(-c4cccc(-n5c6ccccc6c6ccccc65)c4)ccc3B3c4ccc(-c5cccc(-n6c7ccccc7c7ccccc76)c5)cc4N(c4ccccc4)c4cccc2c43)cc1 ; c1ccc(N2c3cc(-c4ccccc4-n4c5ccccc5c5ccccc54)ccc3B3c4ccc(-c5ccccc5-n5c6ccccc6c6ccccc65)cc4N(c4ccccc4)c4cccc2c43)cc1 ; c1ccc(N2c3cc(-c4ccc(-n5c6ccccc6c6ccccc65)cc4)ccc3B3c4ccc(-n5c6ccccc6c6ccccc65)cc4N(c4ccccc4)c4cccc2c43)cc1]

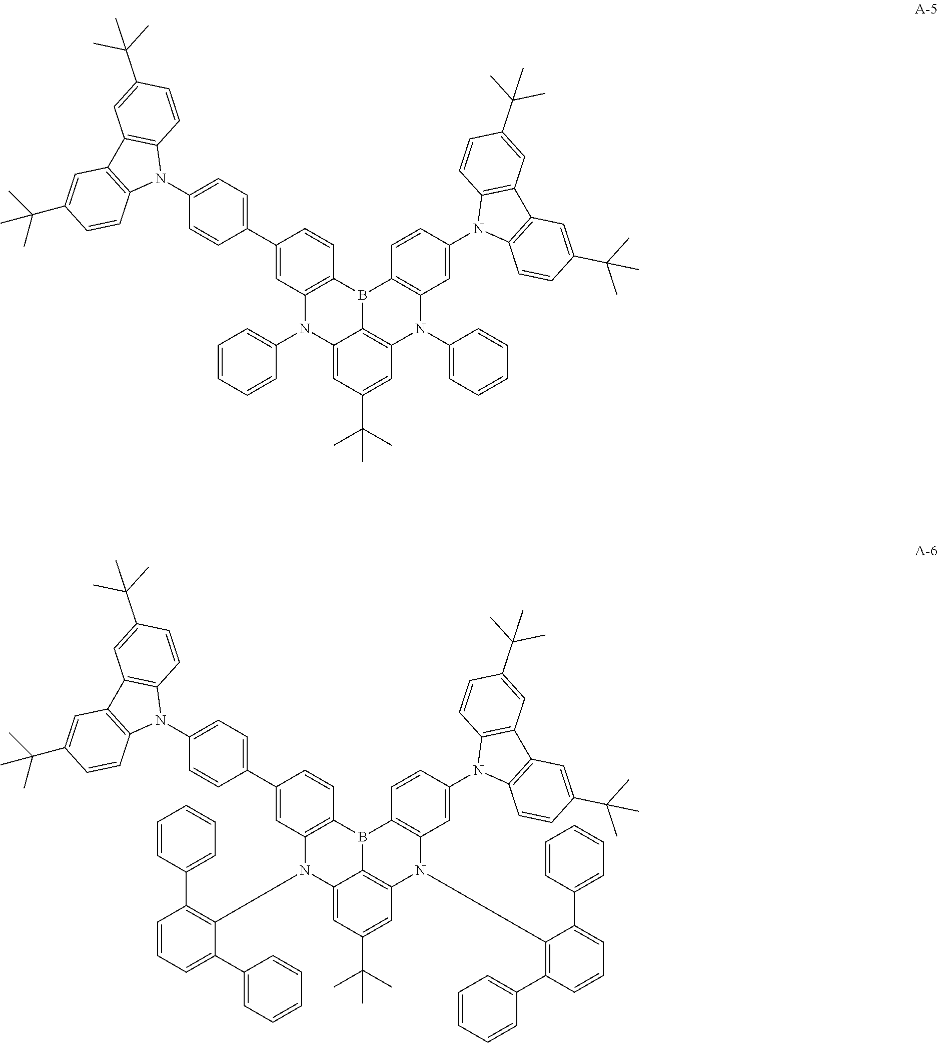

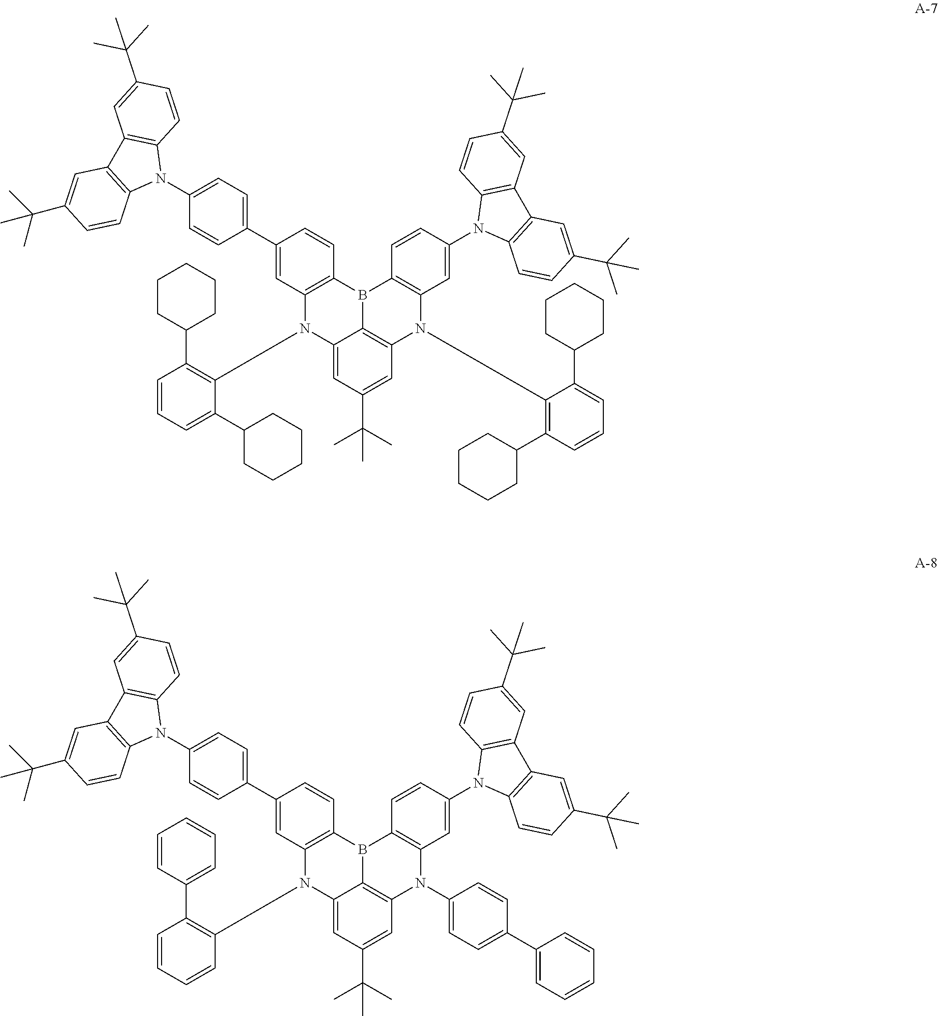

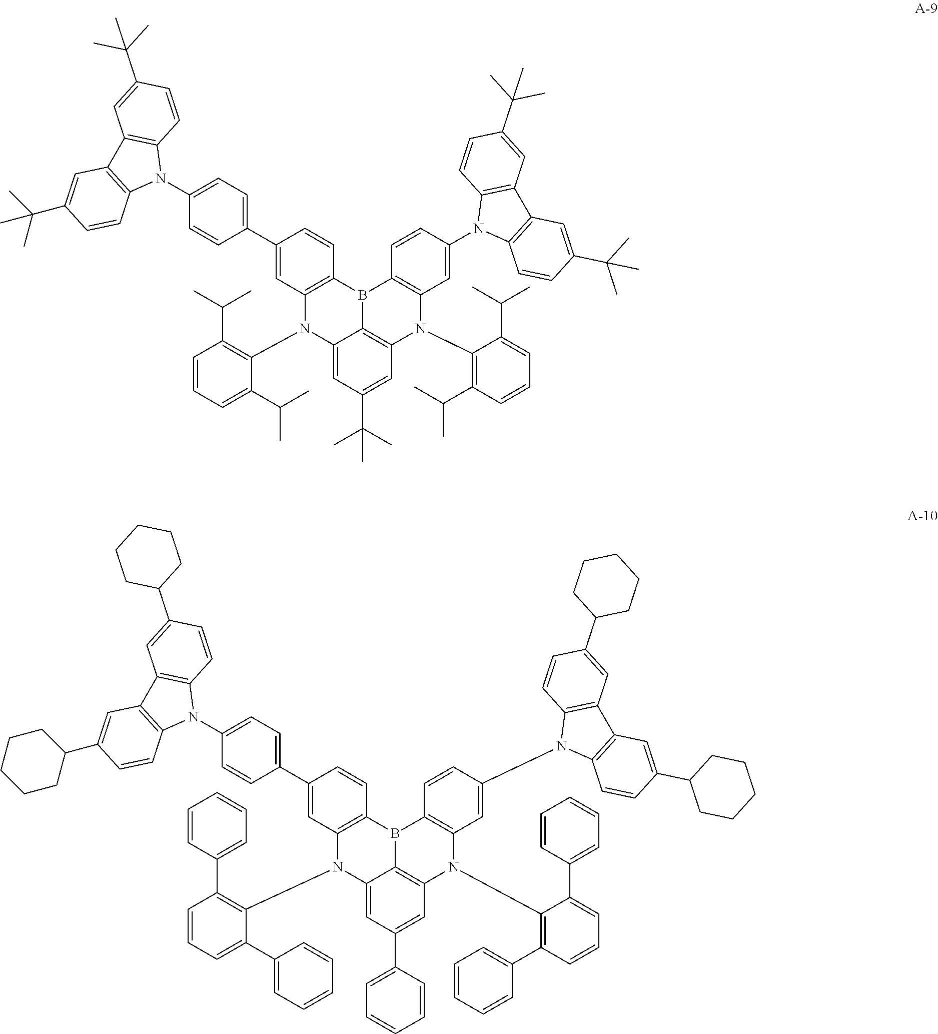 [SMILES: CC(C)c1cccc(C(C)C)c1N1c2cc(-c3ccc(-n4c5ccc(C(C)(C)C)cc5c5cc(C(C)(C)C)ccc54)cc3)ccc2B2c3ccc(-n4c5ccc(C(C)(C)C)cc5c5cc(C(C)(C)C)ccc54)cc3N(c3c(C(C)C)cccc3C(C)C)c3cc(C(C)(C)C)cc1c32 ; c1ccc(-c2cc3c4c(c2)N(c2c(-c5ccccc5)cccc2-c2ccccc2)c2cc(-n5c6ccc(C7CCCCC7)cc6c6cc(C7CCCCC7)ccc65)ccc2B4c2ccc(-c4ccc(-n5c6ccc(C7CCCCC7)cc6c6cc(C7CCCCC7)ccc65)cc4)cc2N3c2c(-c3ccccc3)cccc2-c2ccccc2)cc1]

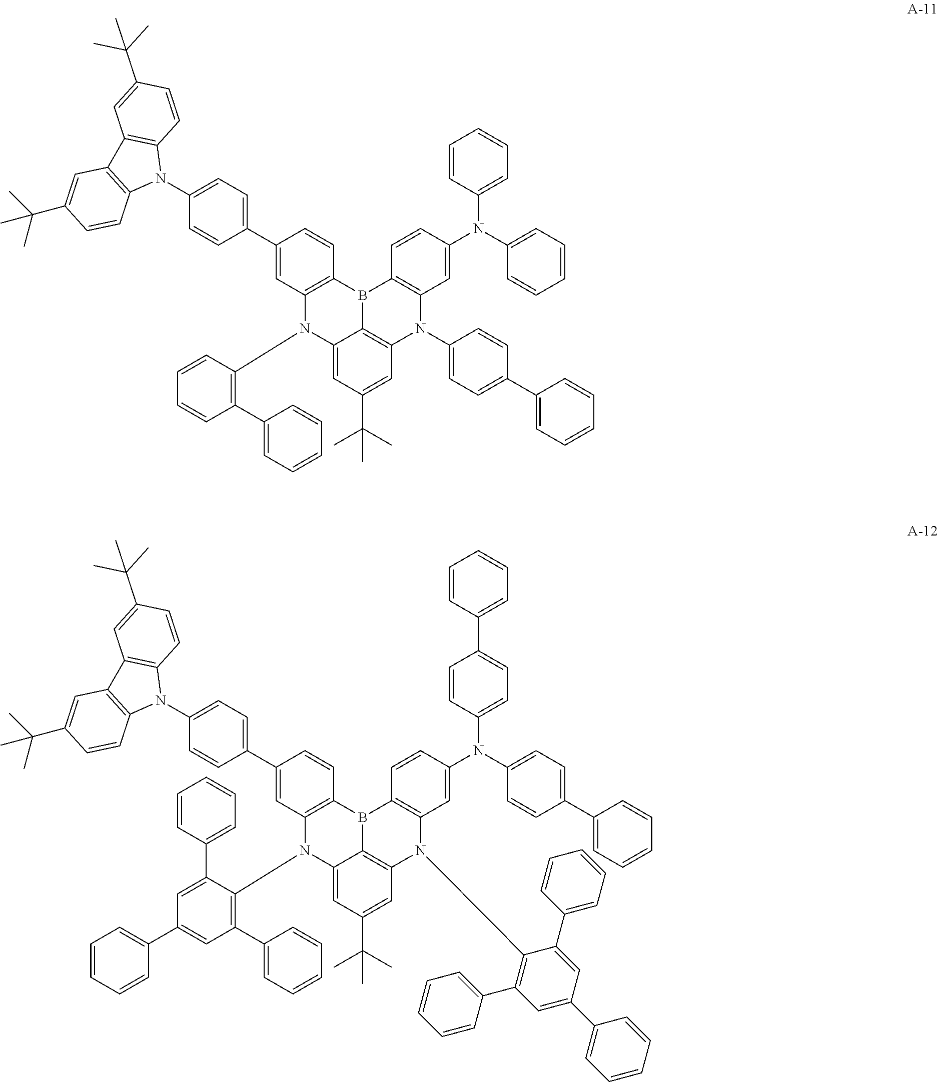 [SMILES: CC(C)(C)c1cc2c3c(c1)N(c1ccccc1-c1ccccc1)c1cc(-c4ccc(-n5c6ccc(C(C)(C)C)cc6c6cc(C(C)(C)C)ccc65)cc4)ccc1B3c1ccc(N(c3ccccc3)c3ccccc3)cc1N2c1ccc(-c2ccccc2)cc1 ; CC(C)(C)c1cc2c3c(c1)N(c1c(-c4ccccc4)cc(-c4ccccc4)cc1-c1ccccc1)c1cc(N(c4ccc(-c5ccccc5)cc4)c4ccc(-c5ccccc5)cc4)ccc1B3c1ccc(-c3ccc(-n4c5ccc(C(C)(C)C)cc5c5cc(C(C)(C)C)ccc54)cc3)cc1N2c1c(-c2ccccc2)cc(-c2ccccc2)cc1-c1ccccc1]

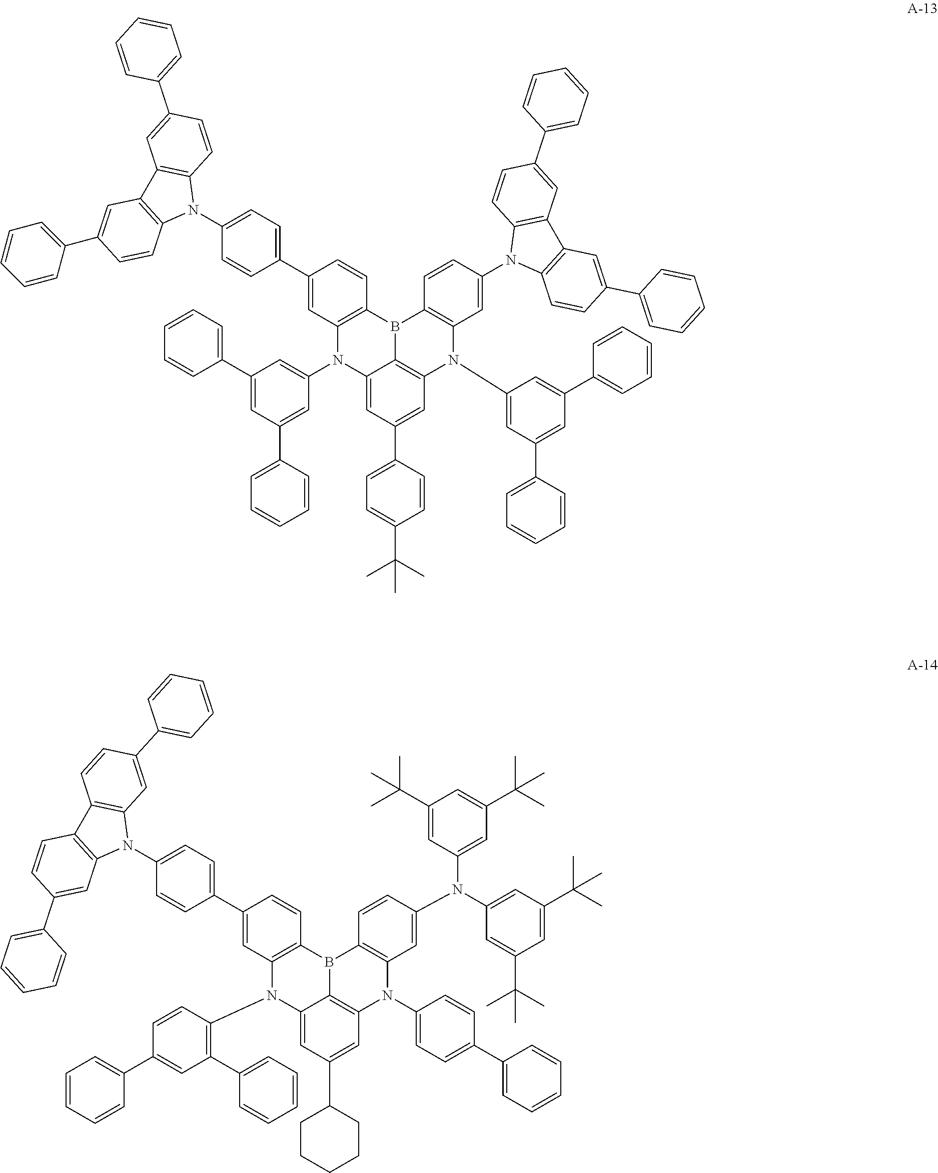 [SMILES: CC(C)(C)c1ccc(-c2cc3c4c(c2)N(c2cc(-c5ccccc5)cc(-c5ccccc5)c2)c2cc(-n5c6ccc(-c7ccccc7)cc6c6cc(-c7ccccc7)ccc65)ccc2B4c2ccc(-c4ccc(-n5c6ccc(-c7ccccc7)cc6c6cc(-c7ccccc7)ccc65)cc4)cc2N3c2cc(-c3ccccc3)cc(-c3ccccc3)c2)cc1 ; CC(C)(C)c1cc(N(c2cc(C(C)(C)C)cc(C(C)(C)C)c2)c2ccc3c(c2)N(c2ccc(-c4ccccc4)cc2)c2cc(C4CCCCC4)cc4c2B3c2ccc(-c3ccc(-n5c6cc(-c7ccccc7)ccc6c6ccc(-c7ccccc7)cc65)cc3)cc2N4c2ccc(-c3ccccc3)cc2-c2ccccc2)cc(C(C)(C)C)c1]

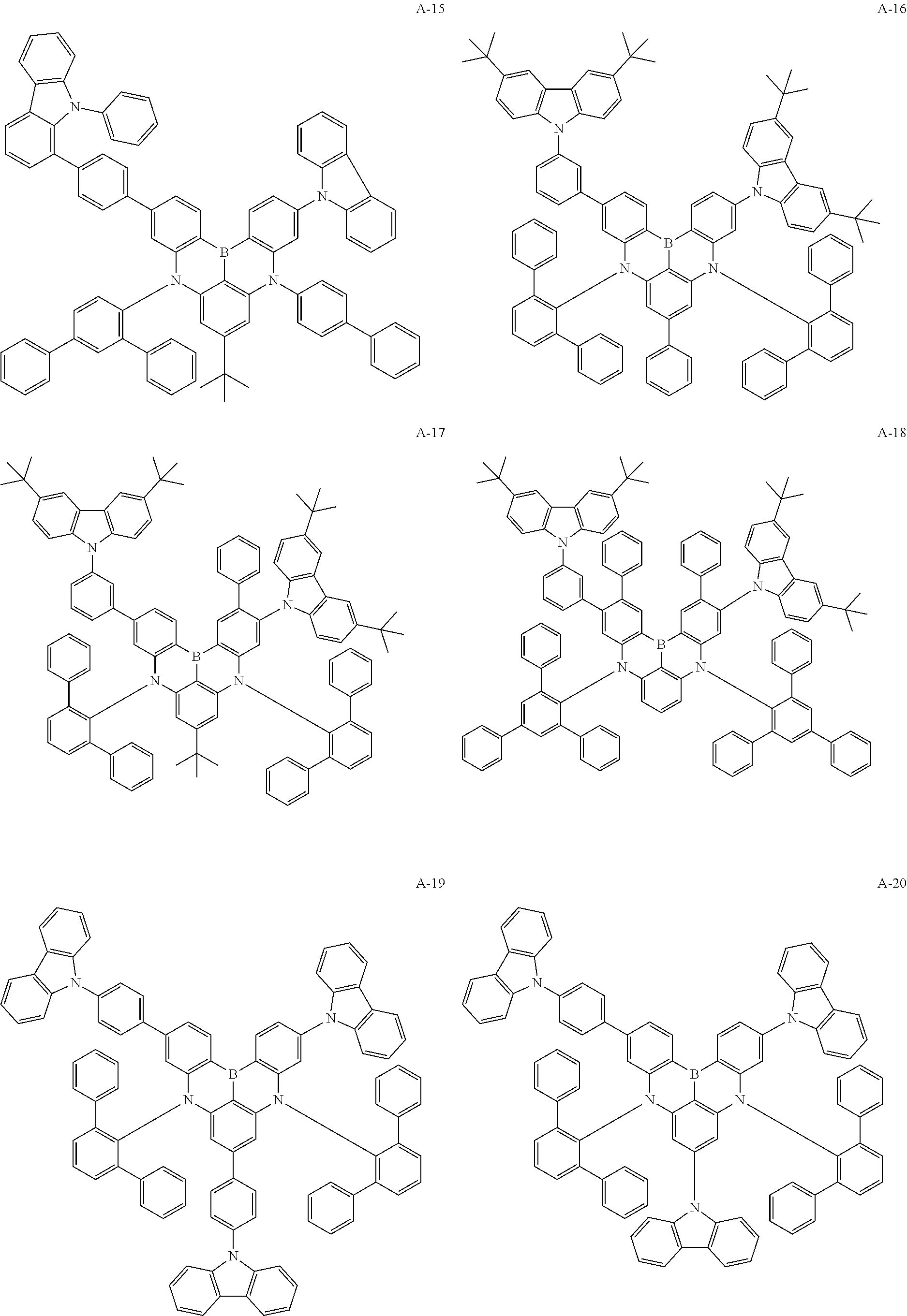

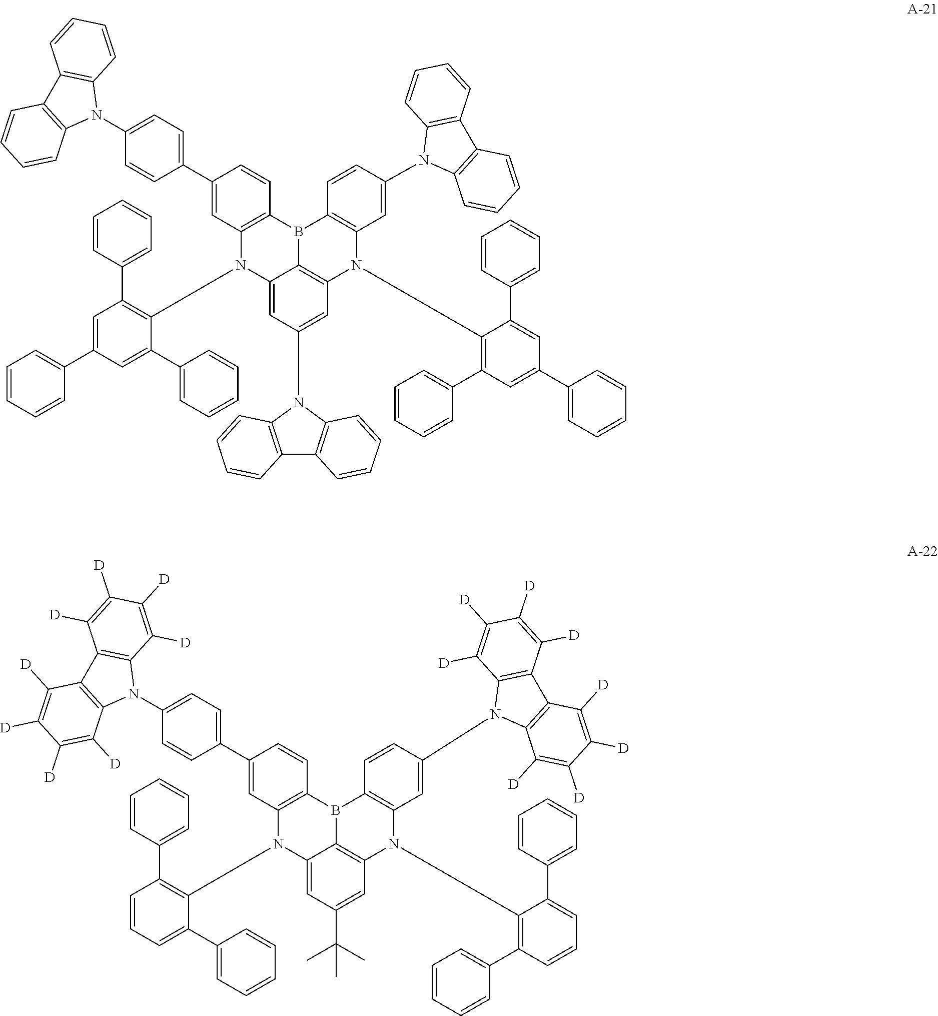 [SMILES: c1ccc(-c2cc(-c3ccccc3)c(N3c4cc(-c5ccc(-n6c7ccccc7c7ccccc76)cc5)ccc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; [2H]c1c([2H])c([2H])c2c(c1[2H])c1c([2H])c([2H])c([2H])c([2H])c1n2-c1ccc(-c2ccc3c(c2)N(c2c(-c4ccccc4)cccc2-c2ccccc2)c2cc(C(C)(C)C)cc4c2B3c2ccc(-n3c5c([2H])c([2H])c([2H])c([2H])c5c5c([2H])c([2H])c([2H])c([2H])c53)cc2N4c2c(-c3ccccc3)cccc2-c2ccccc2)cc1]

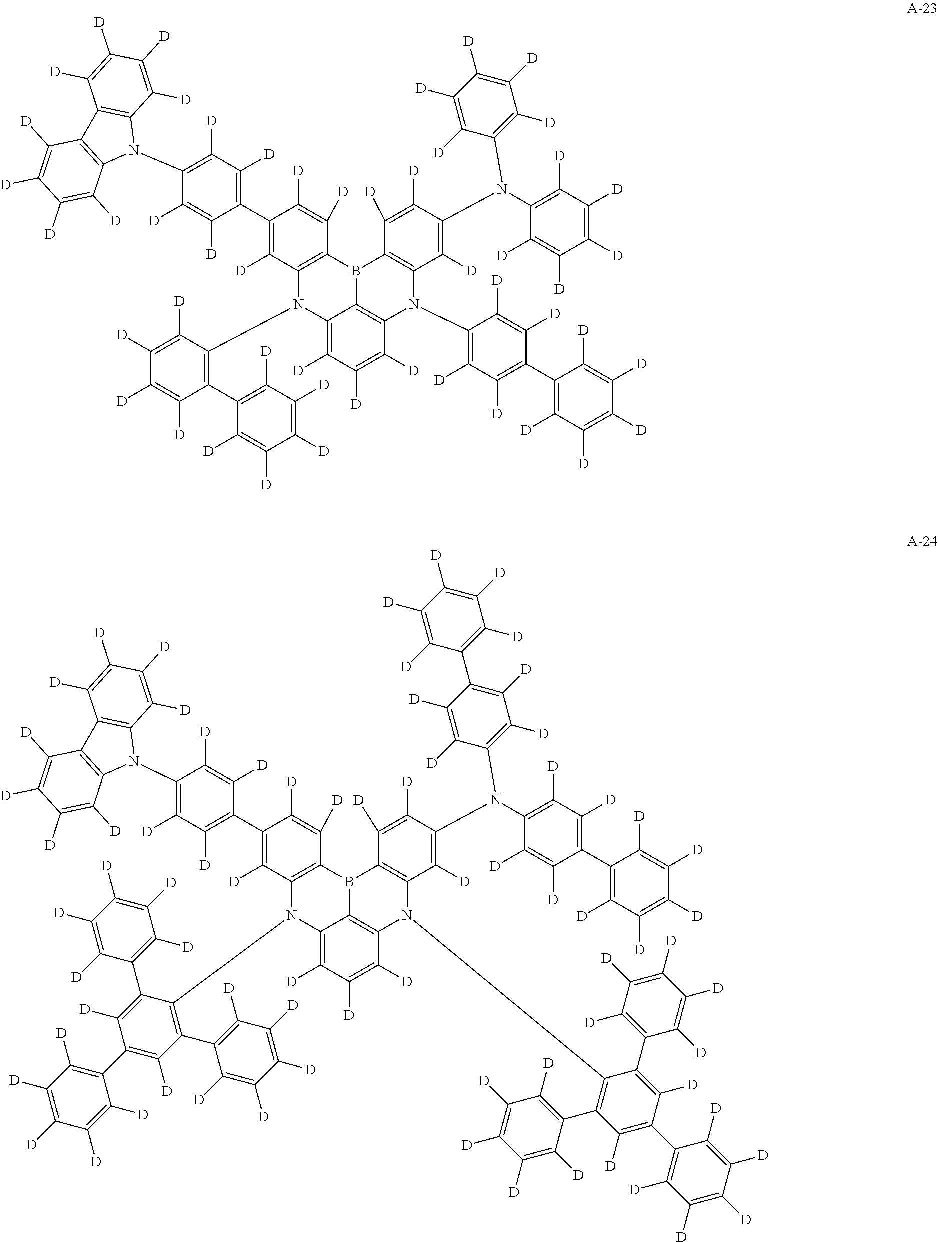

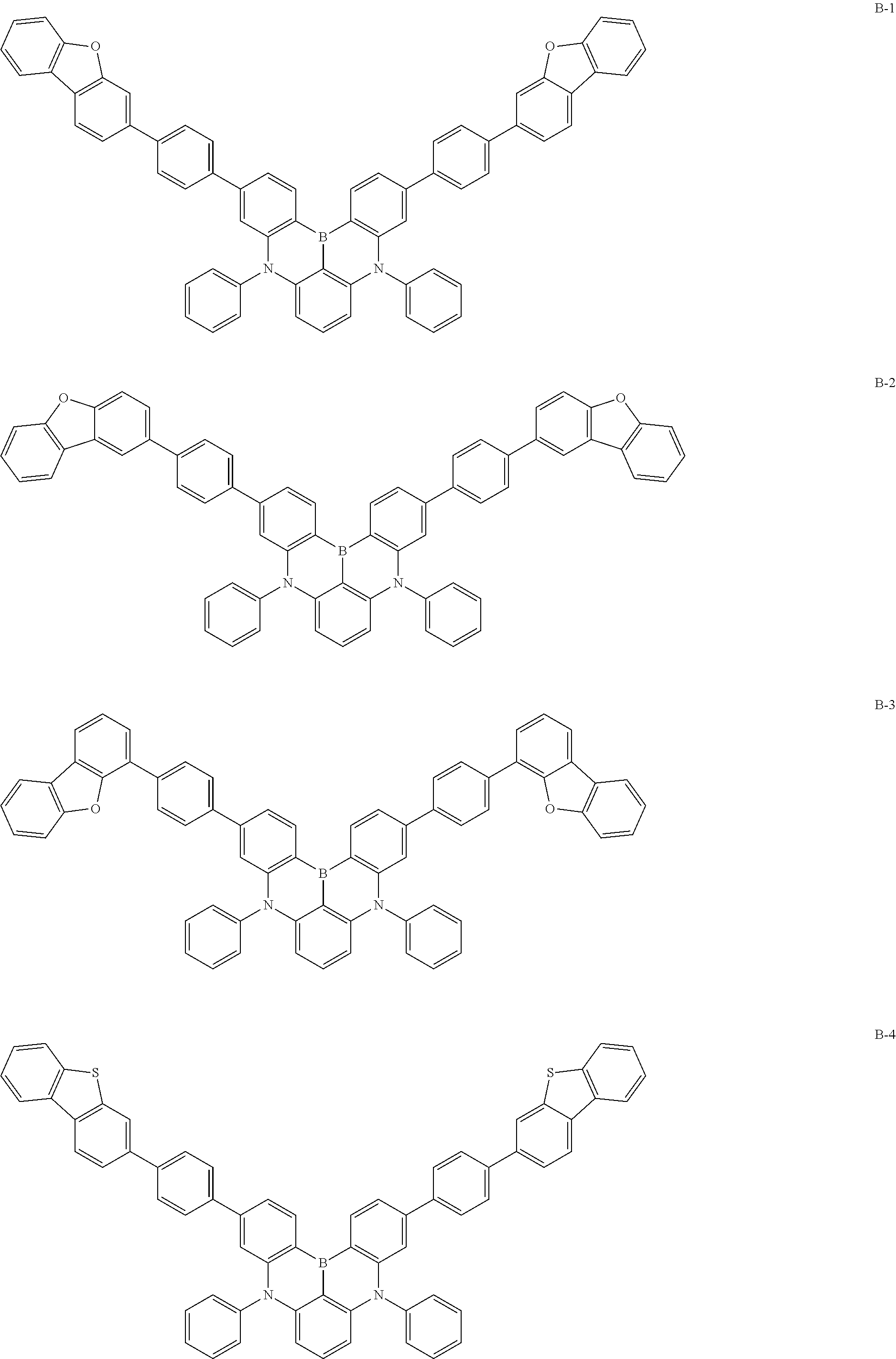 [SMILES: c1ccc(N2c3cc(-c4ccc(-c5ccc6c(c5)oc5ccccc56)cc4)ccc3B3c4ccc(-c5ccc(-c6ccc7c(c6)oc6ccccc67)cc5)cc4N(c4ccccc4)c4cccc2c43)cc1 ; c1ccc(N2c3cc(-c4ccc(-c5ccc6oc7ccccc7c6c5)cc4)ccc3B3c4ccc(-c5ccc(-c6ccc7oc8ccccc8c7c6)cc5)cc4N(c4ccccc4)c4cccc2c43)cc1 ; c1ccc(N2c3cc(-c4ccc(-c5cccc6c5oc5ccccc56)cc4)ccc3B3c4ccc(-c5ccc(-c6cccc7c6oc6ccccc67)cc5)cc4N(c4ccccc4)c4cccc2c43)cc1 ; c1ccc(N2c3cc(-c4ccc(-c5ccc6c(c5)sc5ccccc56)cc4)ccc3B3c4ccc(-c5ccc(-c6ccc7c(c6)sc6ccccc67)cc5)cc4N(c4ccccc4)c4cccc2c43)cc1]

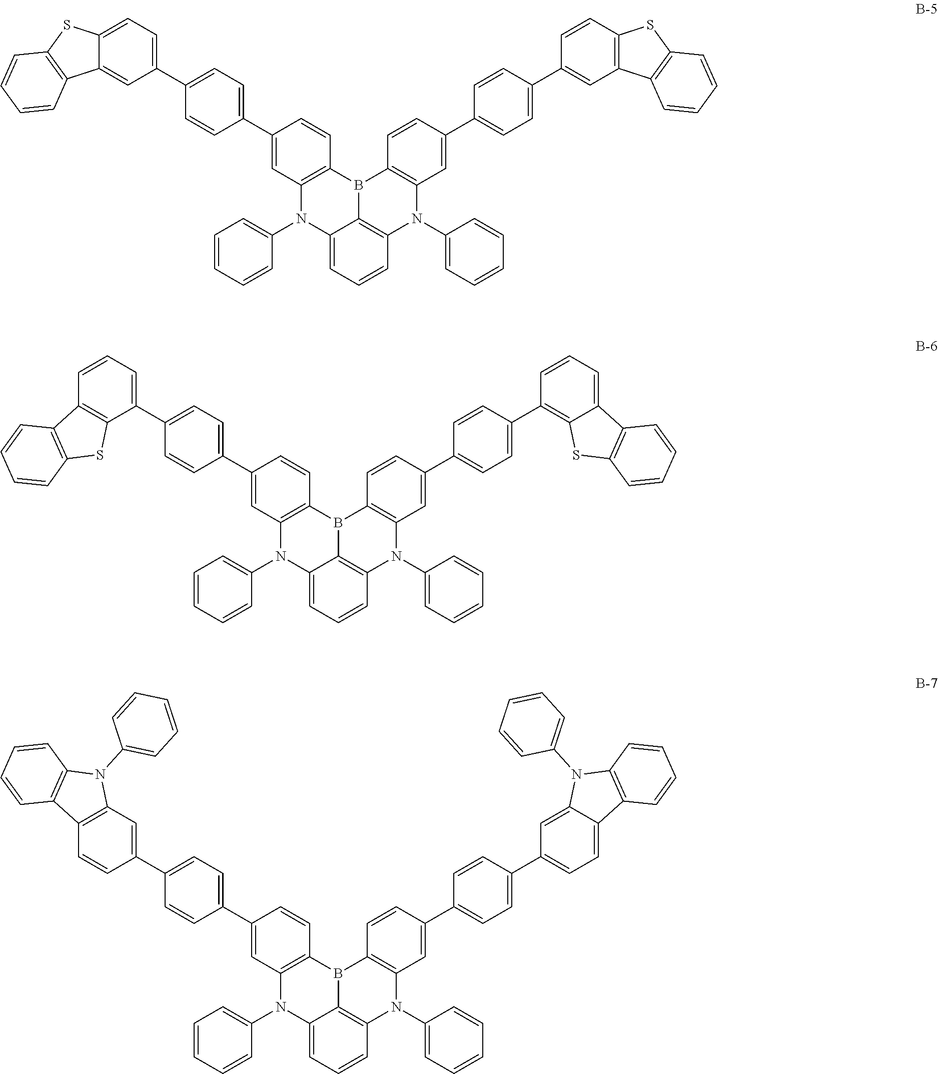 [SMILES: c1ccc(N2c3cc(-c4ccc(-c5ccc6sc7ccccc7c6c5)cc4)ccc3B3c4ccc(-c5ccc(-c6ccc7sc8ccccc8c7c6)cc5)cc4N(c4ccccc4)c4cccc2c43)cc1 ; c1ccc(N2c3cc(-c4ccc(-c5cccc6c5sc5ccccc56)cc4)ccc3B3c4ccc(-c5ccc(-c6cccc7c6sc6ccccc67)cc5)cc4N(c4ccccc4)c4cccc2c43)cc1 ; c1ccc(N2c3cc(-c4ccc(-c5ccc6c7ccccc7n(-c7ccccc7)c6c5)cc4)ccc3B3c4ccc(-c5ccc(-c6ccc7c8ccccc8n(-c8ccccc8)c7c6)cc5)cc4N(c4ccccc4)c4cccc2c43)cc1]

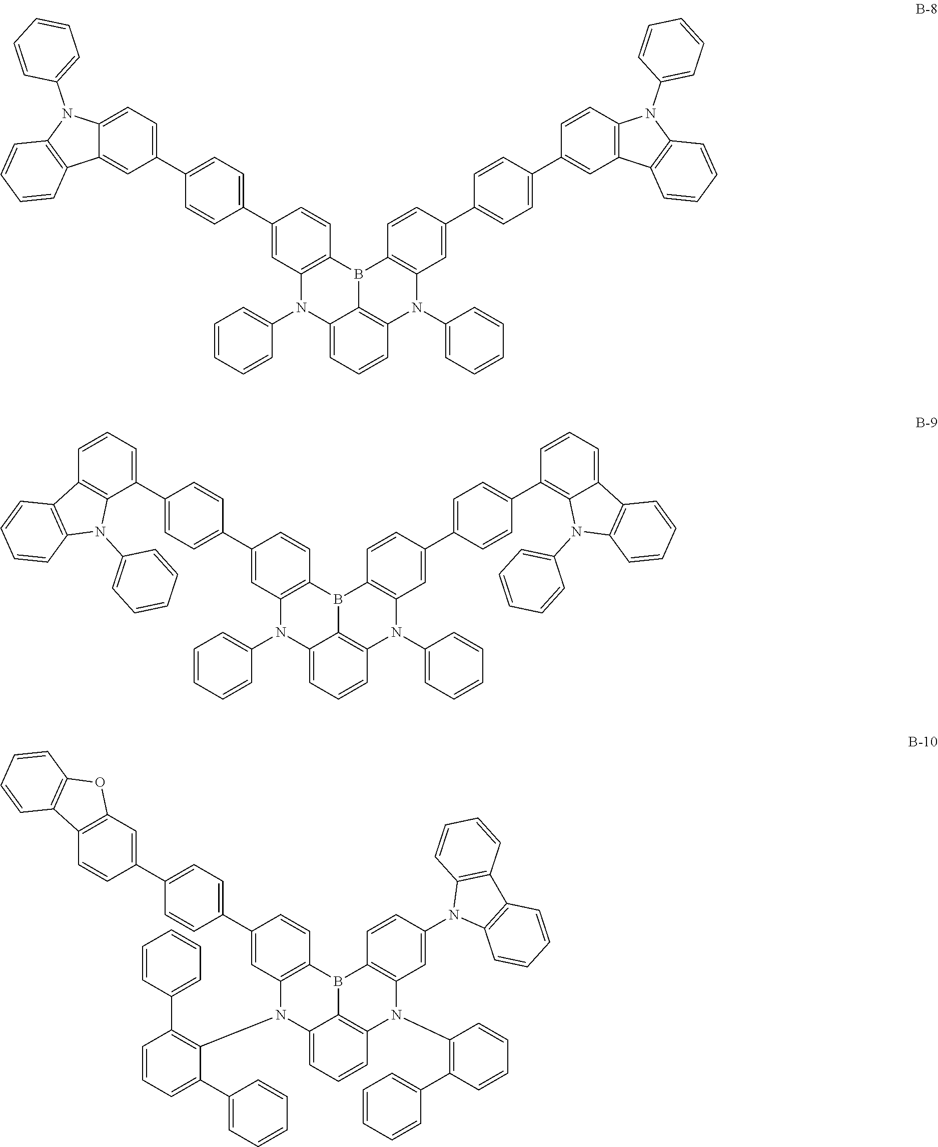 [SMILES: c1ccc(N2c3cc(-c4ccc(-c5ccc6c(c5)c5ccccc5n6-c5ccccc5)cc4)ccc3B3c4ccc(-c5ccc(-c6ccc7c(c6)c6ccccc6n7-c6ccccc6)cc5)cc4N(c4ccccc4)c4cccc2c43)cc1 ; c1ccc(N2c3cc(-c4ccc(-c5cccc6c7ccccc7n(-c7ccccc7)c56)cc4)ccc3B3c4ccc(-c5ccc(-c6cccc7c8ccccc8n(-c8ccccc8)c67)cc5)cc4N(c4ccccc4)c4cccc2c43)cc1 ; c1ccc(-c2ccccc2N2c3cc(-n4c5ccccc5c5ccccc54)ccc3B3c4ccc(-c5ccc(-c6ccc7c(c6)oc6ccccc67)cc5)cc4N(c4c(-c5ccccc5)cccc4-c4ccccc4)c4cccc2c43)cc1]

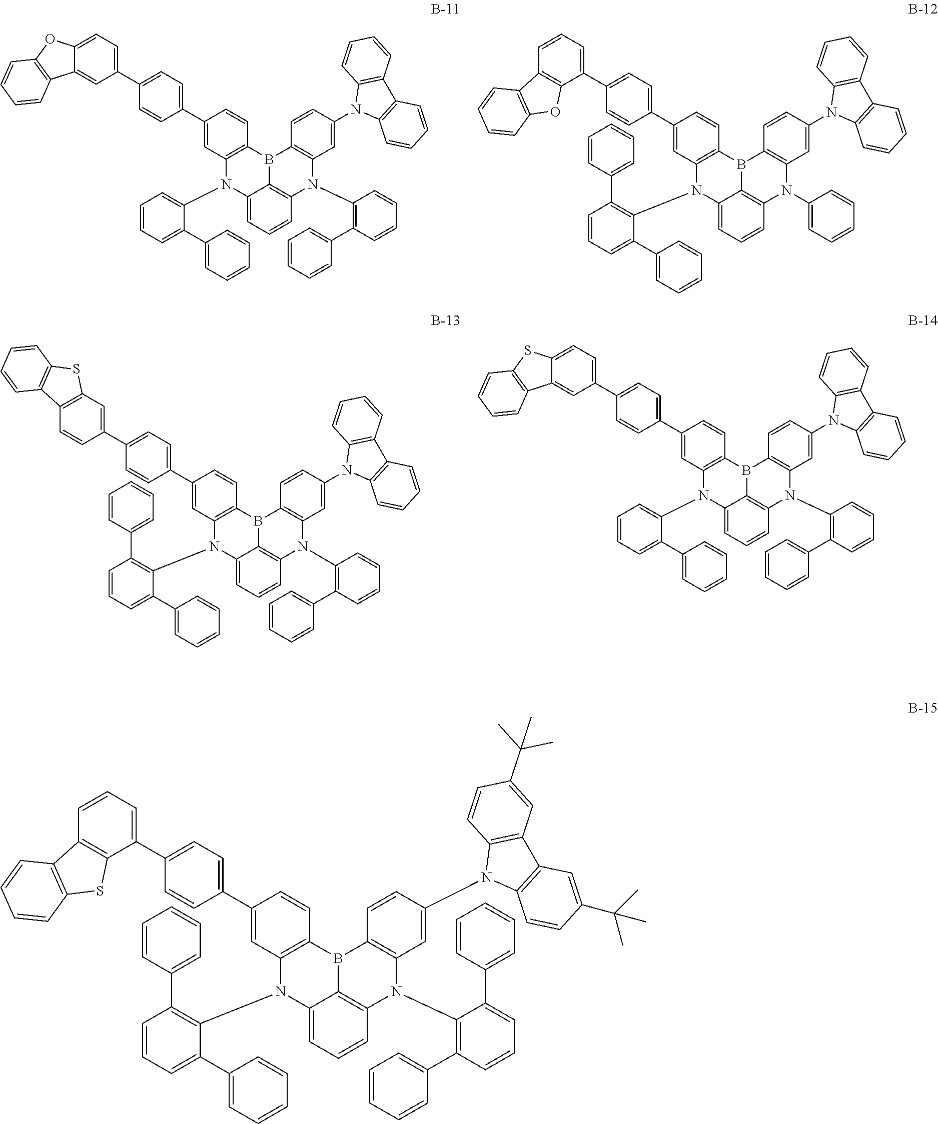

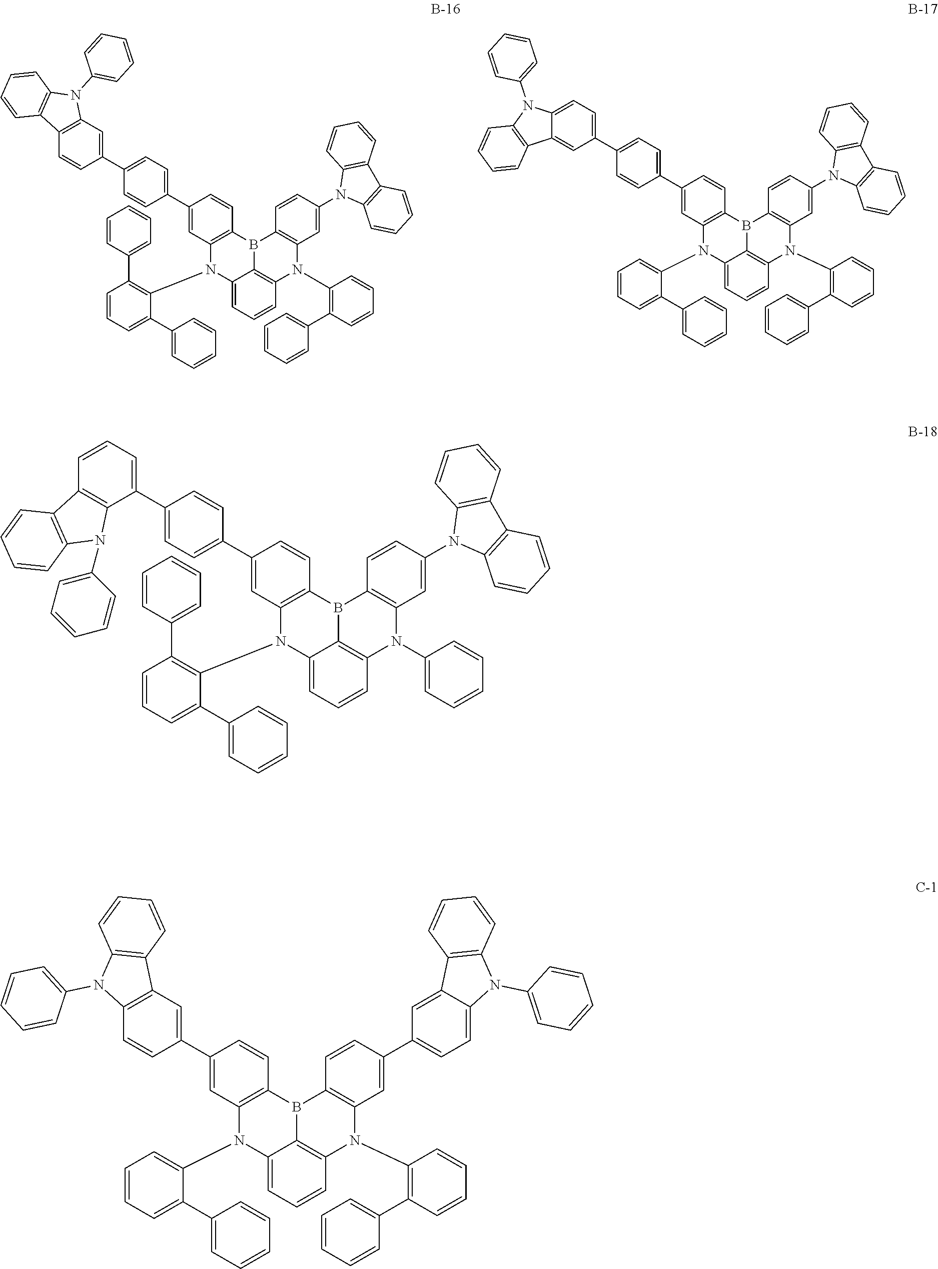

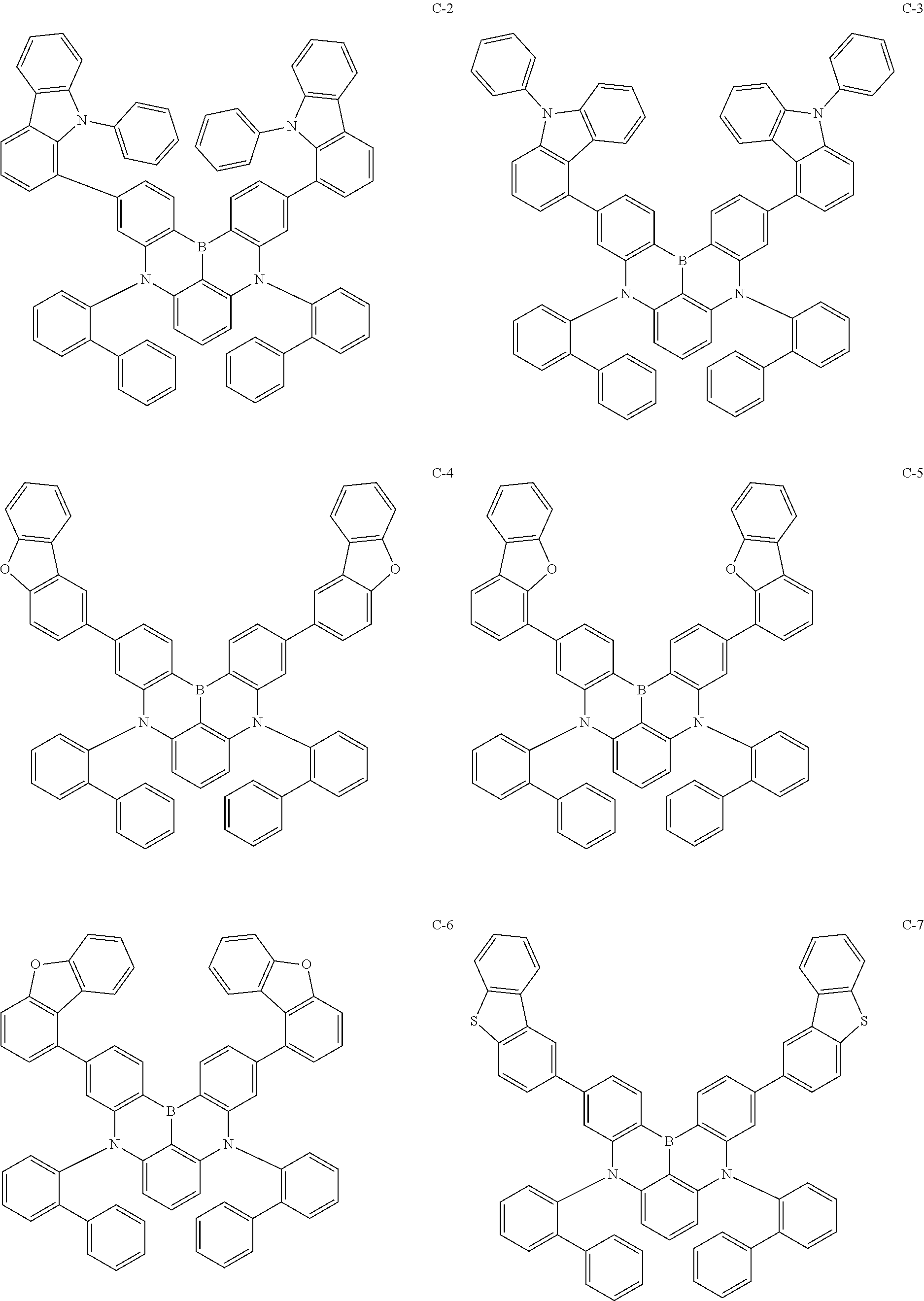

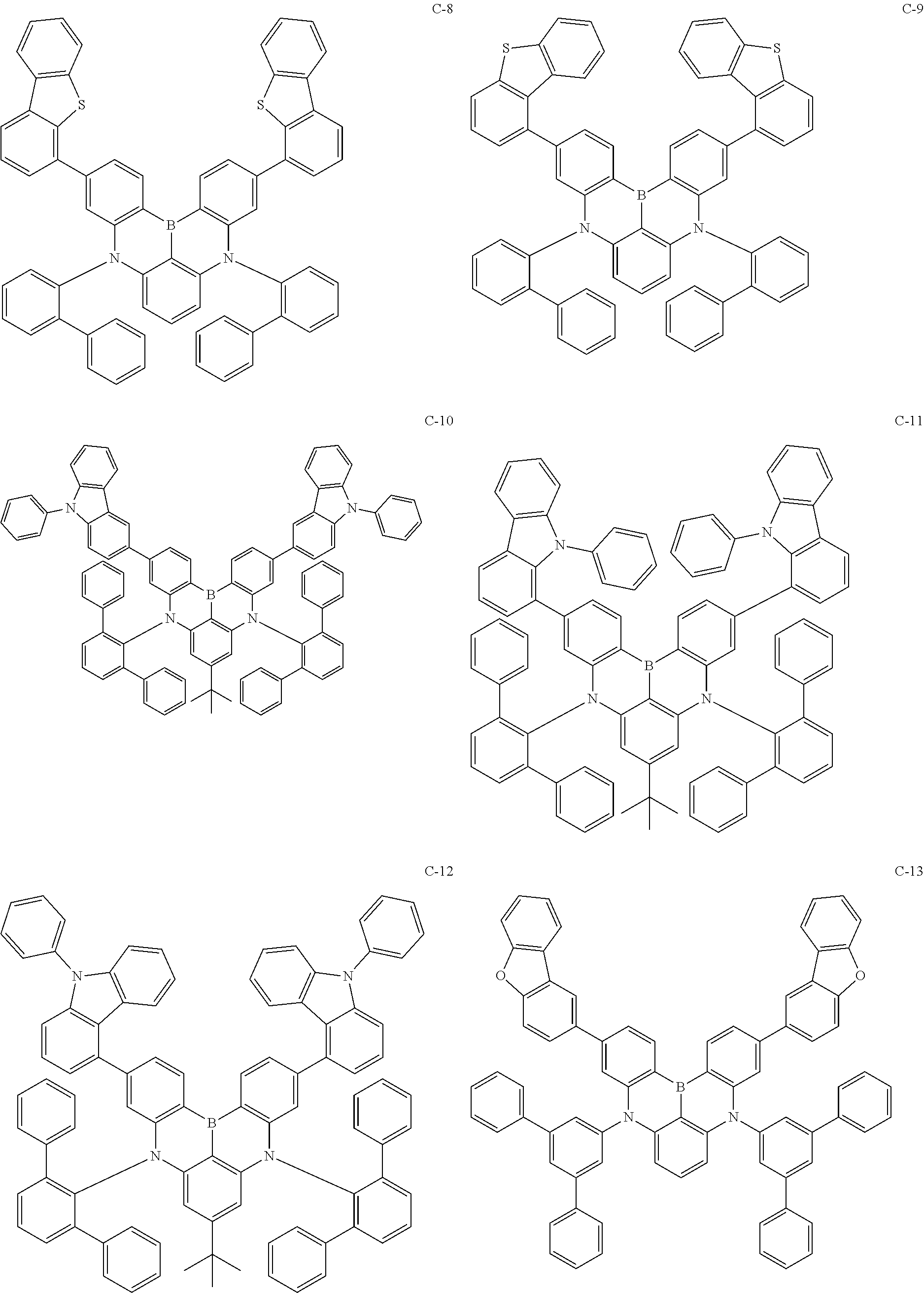

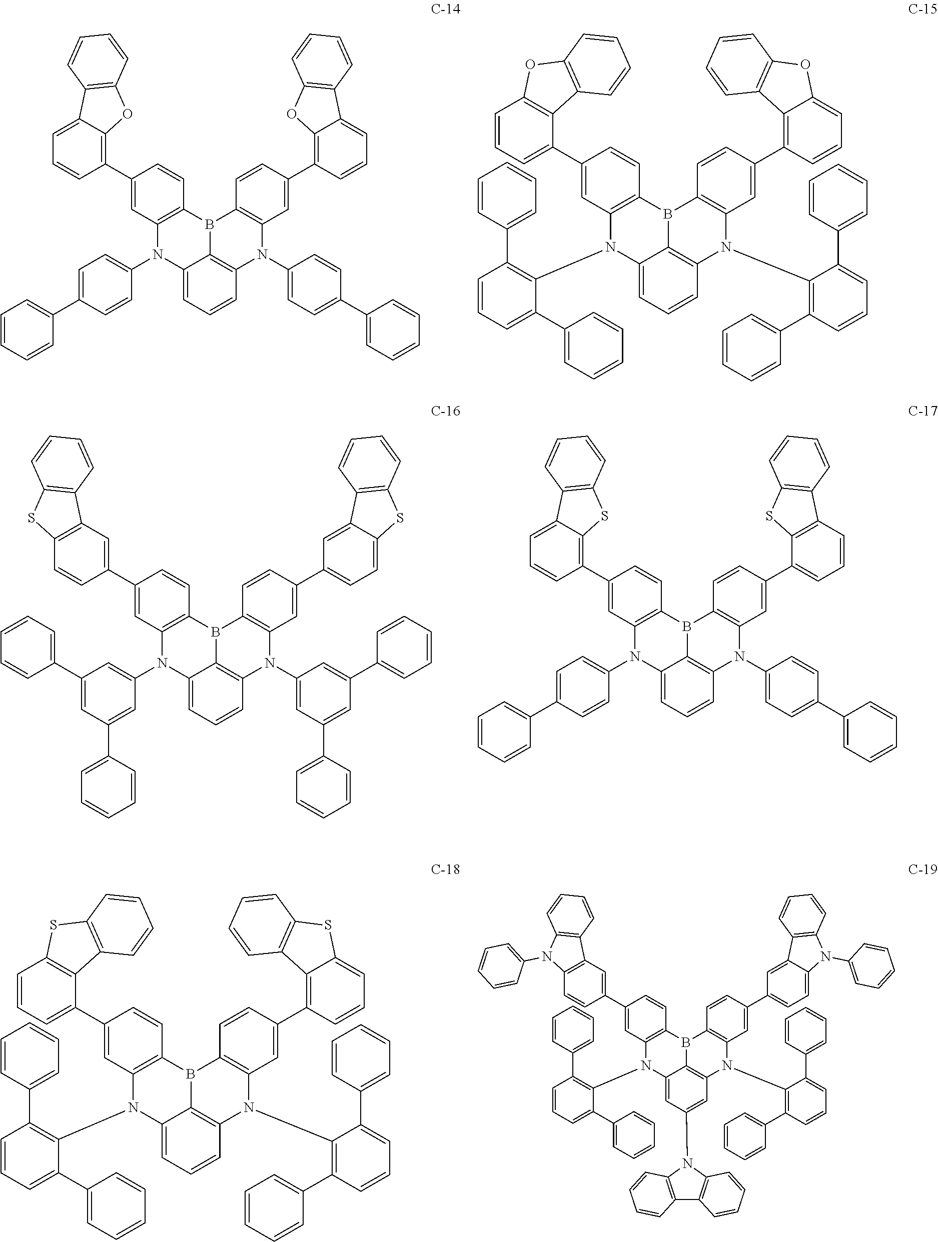

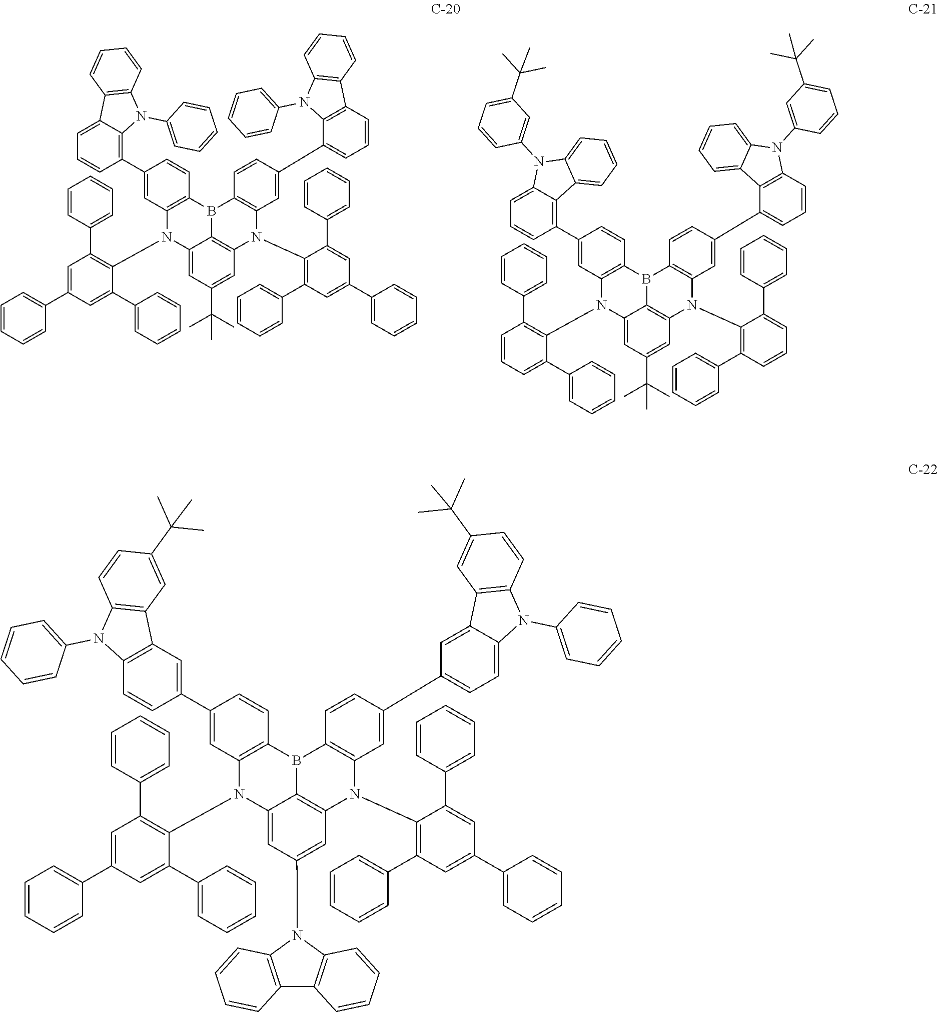

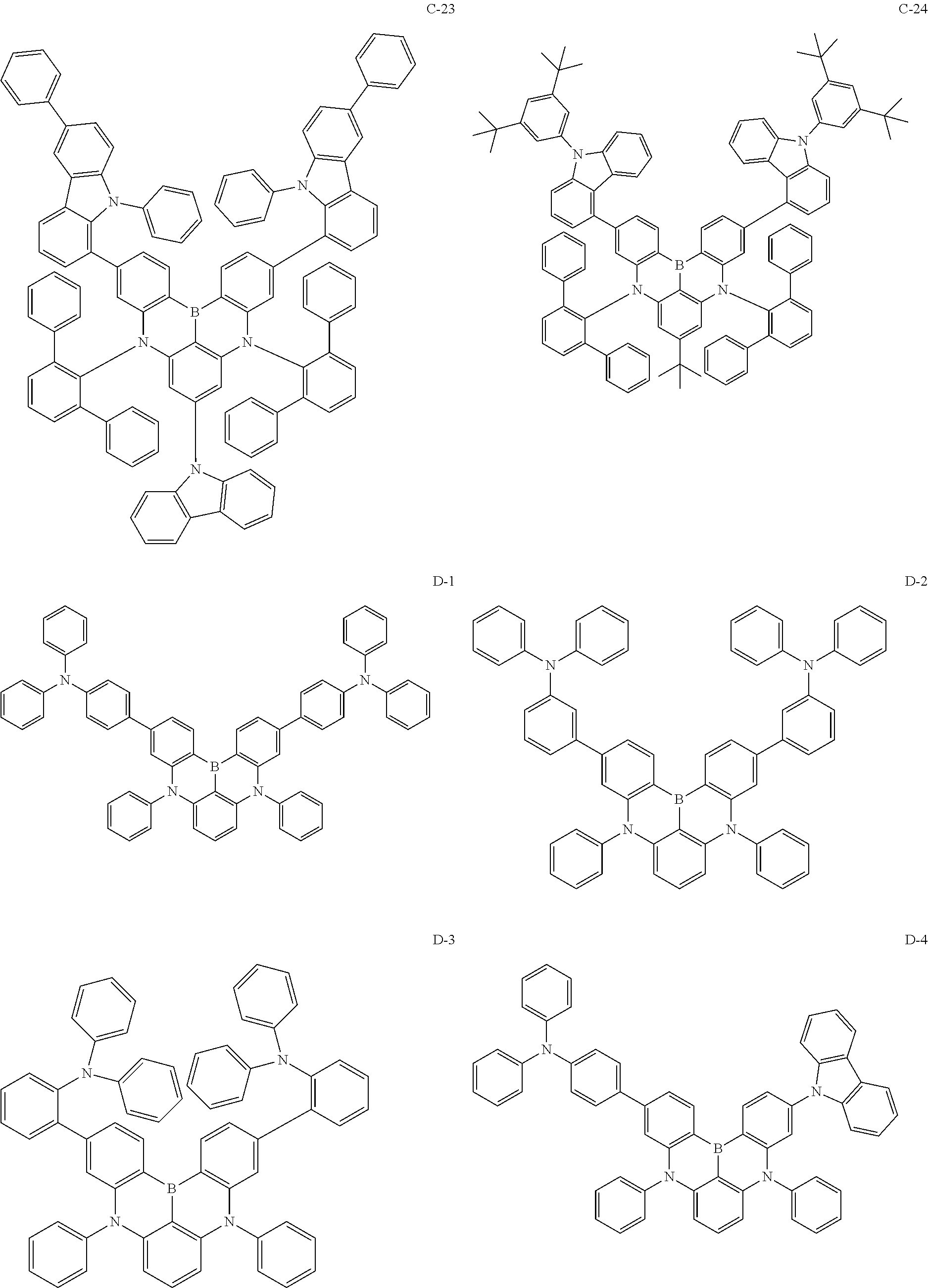

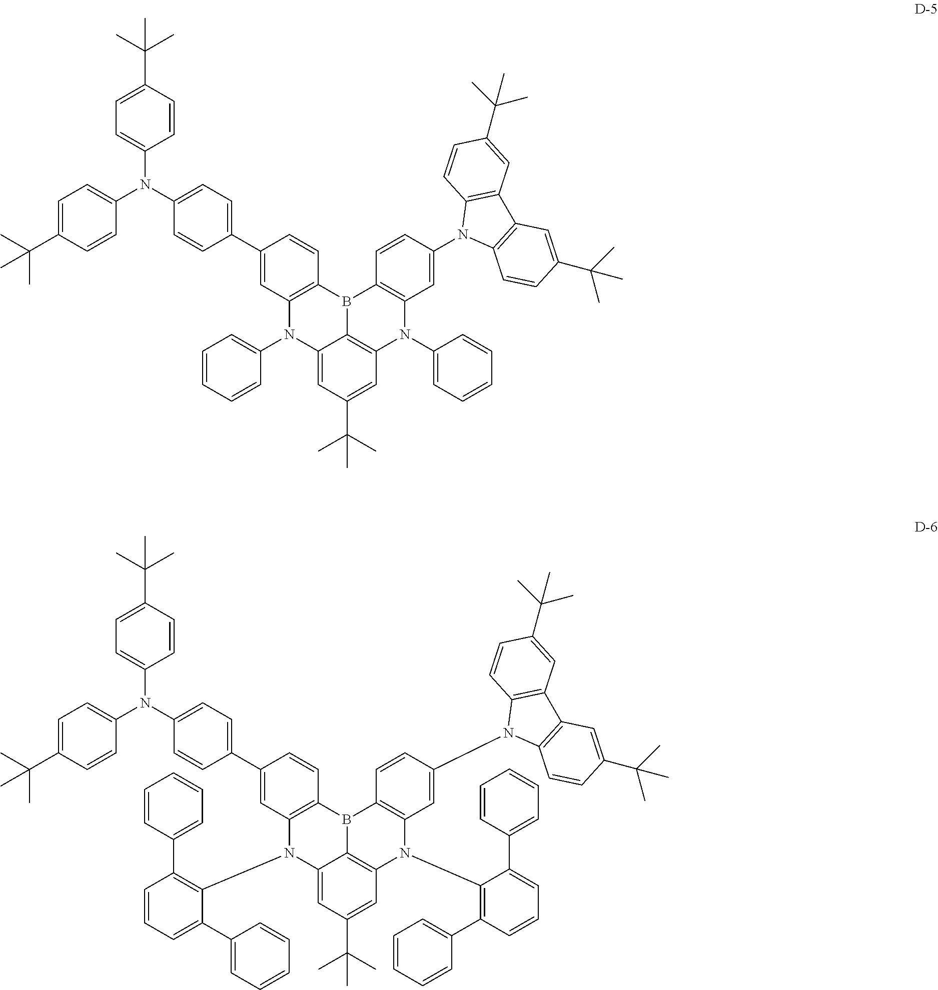

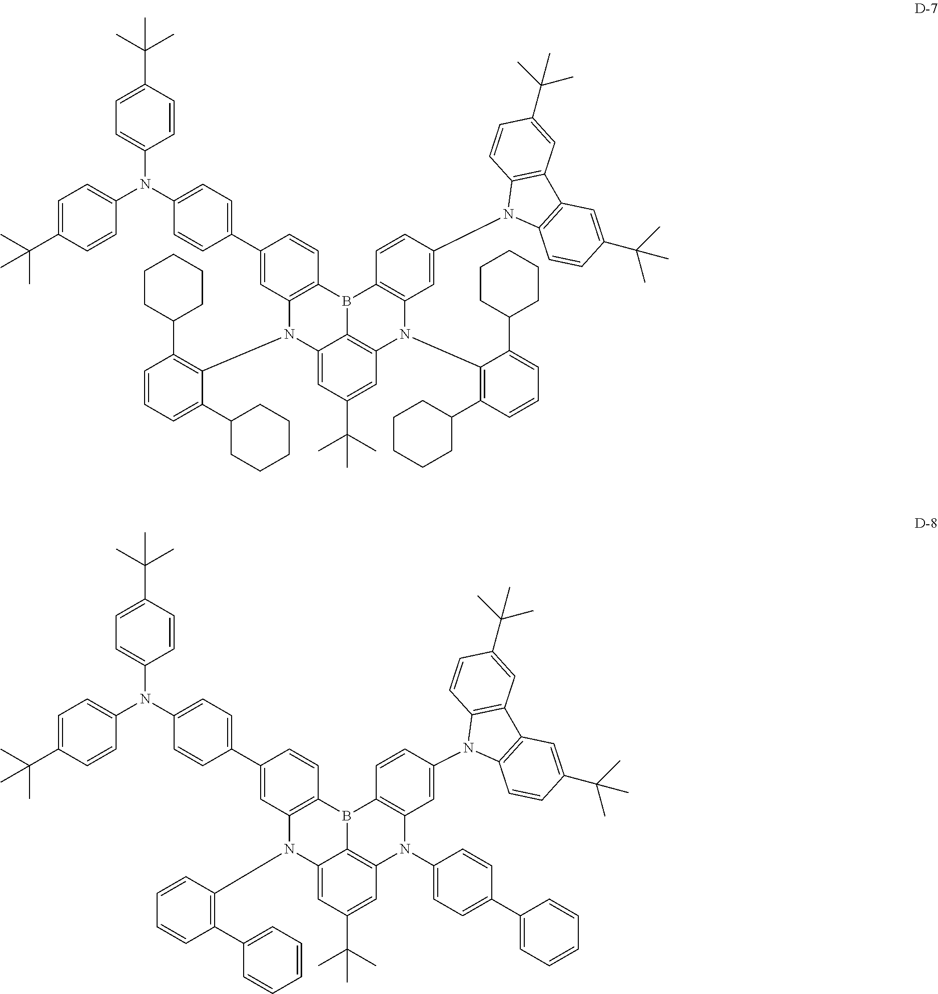

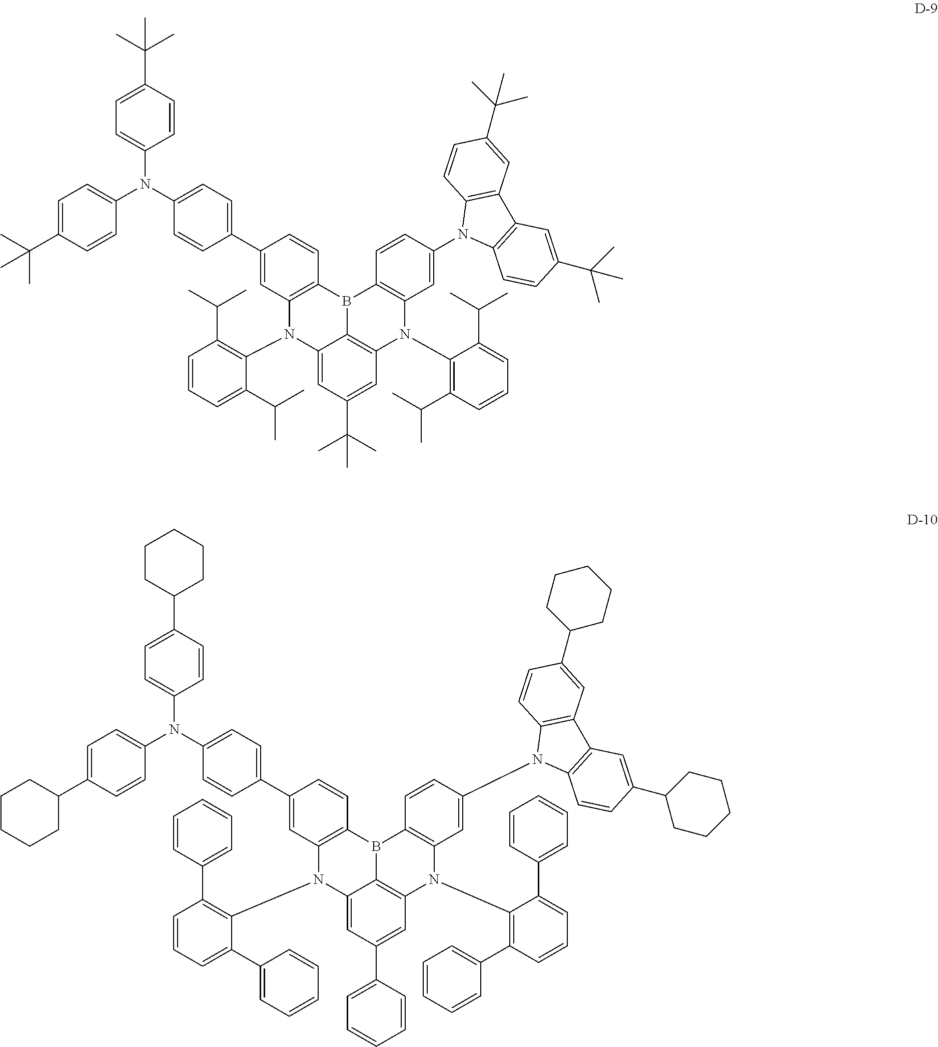 [SMILES: CC(C)c1cccc(C(C)C)c1N1c2cc(-c3ccc(N(c4ccc(C(C)(C)C)cc4)c4ccc(C(C)(C)C)cc4)cc3)ccc2B2c3ccc(-n4c5ccc(C(C)(C)C)cc5c5cc(C(C)(C)C)ccc54)cc3N(c3c(C(C)C)cccc3C(C)C)c3cc(C(C)(C)C)cc1c32 ; c1ccc(-c2cc3c4c(c2)N(c2c(-c5ccccc5)cccc2-c2ccccc2)c2cc(-n5c6ccc(C7CCCCC7)cc6c6cc(C7CCCCC7)ccc65)ccc2B4c2ccc(-c4ccc(N(c5ccc(C6CCCCC6)cc5)c5ccc(C6CCCCC6)cc5)cc4)cc2N3c2c(-c3ccccc3)cccc2-c2ccccc2)cc1]

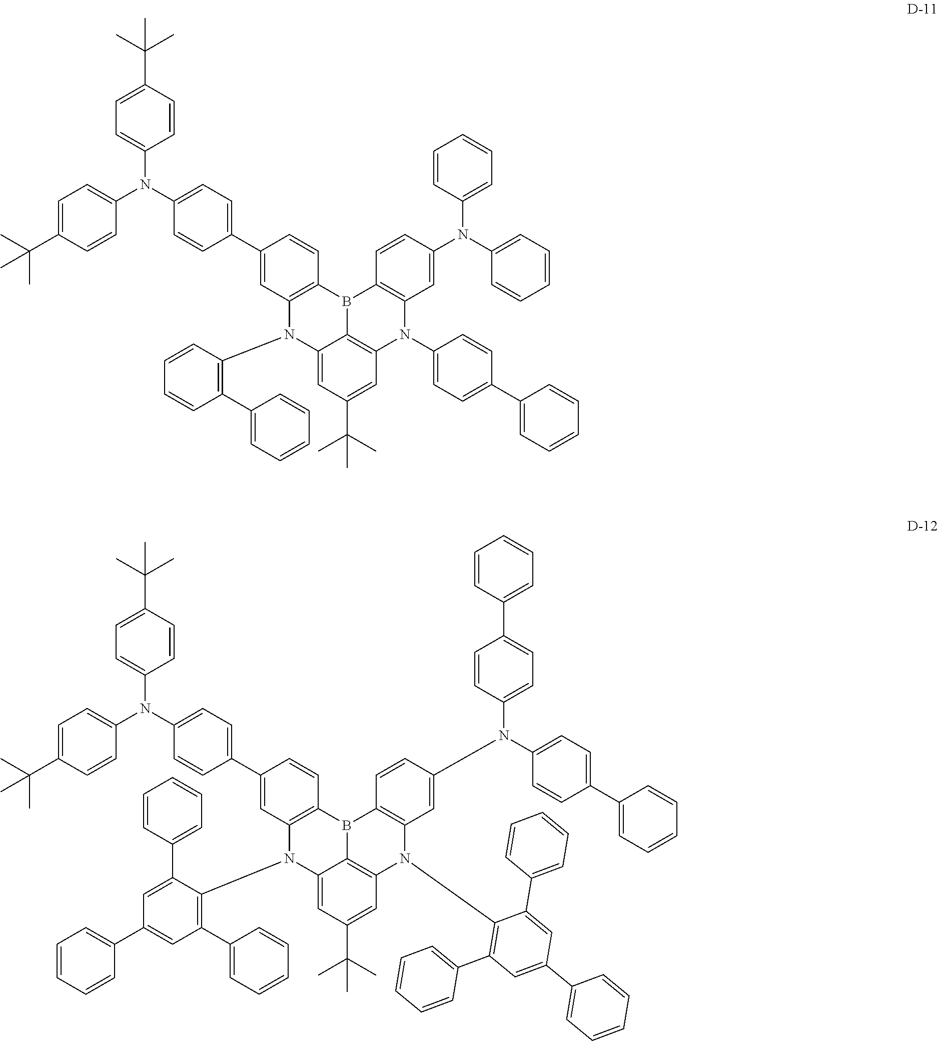 [SMILES: CC(C)(C)c1ccc(N(c2ccc(-c3ccc4c(c3)N(c3ccccc3-c3ccccc3)c3cc(C(C)(C)C)cc5c3B4c3ccc(N(c4ccccc4)c4ccccc4)cc3N5c3ccc(-c4ccccc4)cc3)cc2)c2ccc(C(C)(C)C)cc2)cc1 ; CC(C)(C)c1ccc(N(c2ccc(-c3ccc4c(c3)N(c3c(-c5ccccc5)cc(-c5ccccc5)cc3-c3ccccc3)c3cc(C(C)(C)C)cc5c3B4c3ccc(N(c4ccc(-c6ccccc6)cc4)c4ccc(-c6ccccc6)cc4)cc3N5c3c(-c4ccccc4)cc(-c4ccccc4)cc3-c3ccccc3)cc2)c2ccc(C(C)(C)C)cc2)cc1]

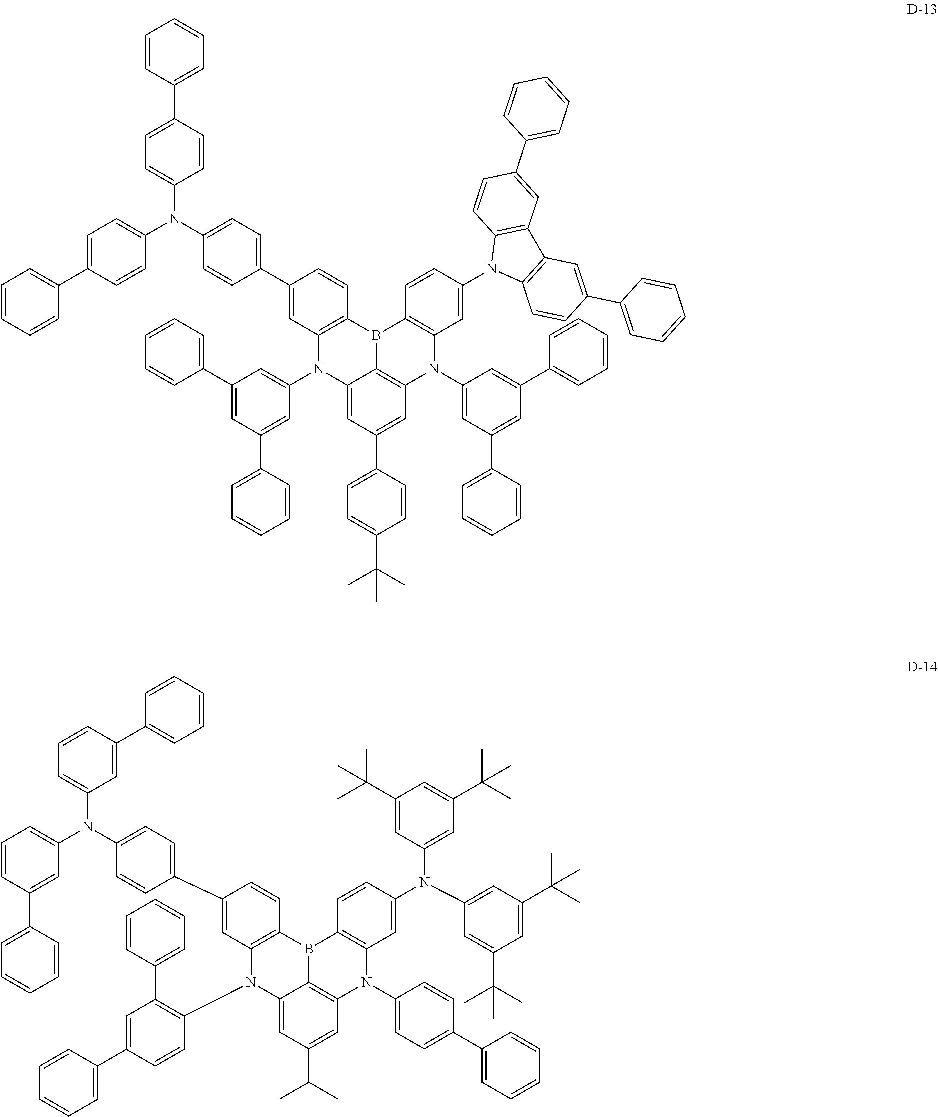 [SMILES: CC(C)(C)c1ccc(-c2cc3c4c(c2)N(c2cc(-c5ccccc5)cc(-c5ccccc5)c2)c2cc(-n5c6ccc(-c7ccccc7)cc6c6cc(-c7ccccc7)ccc65)ccc2B4c2ccc(-c4ccc(N(c5ccc(-c6ccccc6)cc5)c5ccc(-c6ccccc6)cc5)cc4)cc2N3c2cc(-c3ccccc3)cc(-c3ccccc3)c2)cc1 ; CC(C)c1cc2c3c(c1)N(c1ccc(-c4ccccc4)cc1-c1ccccc1)c1cc(-c4ccc(N(c5cccc(-c6ccccc6)c5)c5cccc(-c6ccccc6)c5)cc4)ccc1B3c1ccc(N(c3cc(C(C)(C)C)cc(C(C)(C)C)c3)c3cc(C(C)(C)C)cc(C(C)(C)C)c3)cc1N2c1ccc(-c2ccccc2)cc1]

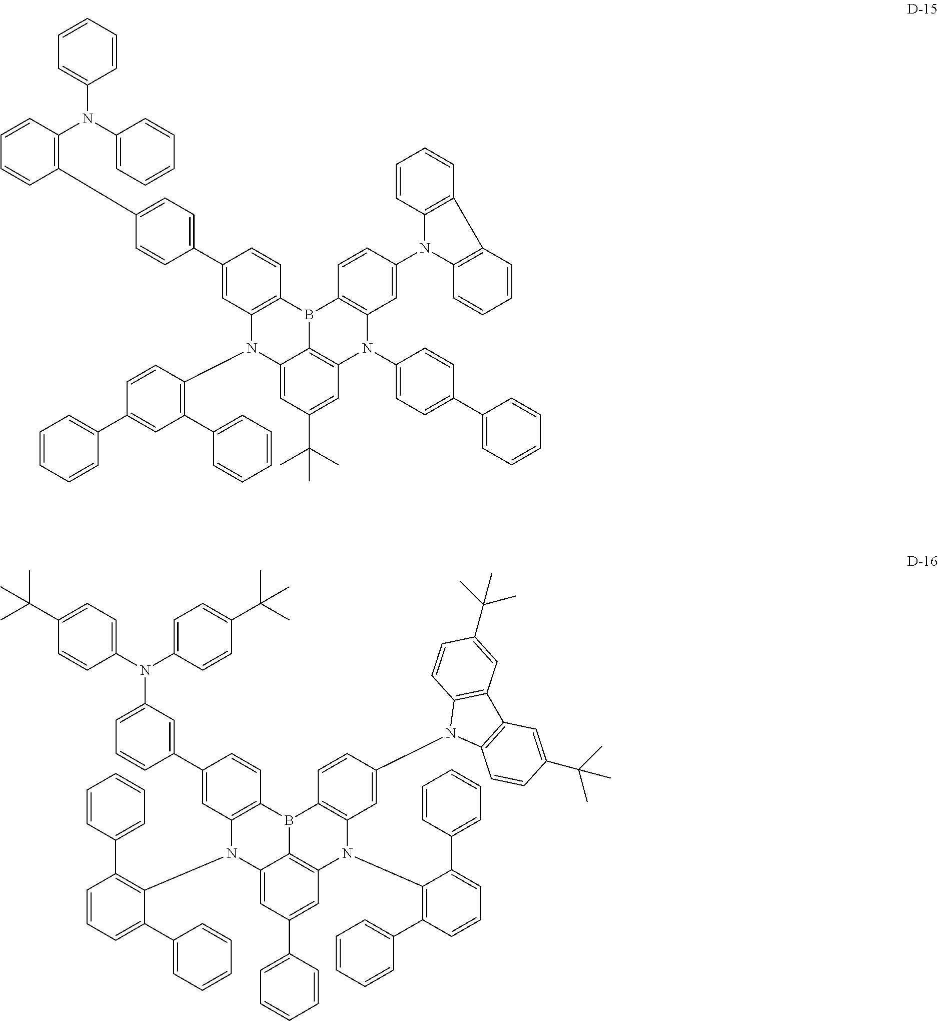 [SMILES: CC(C)(C)c1cc2c3c(c1)N(c1ccc(-c4ccccc4)cc1-c1ccccc1)c1cc(-c4ccc(-c5ccccc5N(c5ccccc5)c5ccccc5)cc4)ccc1B3c1ccc(-n3c4ccccc4c4ccccc43)cc1N2c1ccc(-c2ccccc2)cc1 ; CC(C)(C)c1ccc(N(c2ccc(C(C)(C)C)cc2)c2cccc(-c3ccc4c(c3)N(c3c(-c5ccccc5)cccc3-c3ccccc3)c3cc(-c5ccccc5)cc5c3B4c3ccc(-n4c6ccc(C(C)(C)C)cc6c6cc(C(C)(C)C)ccc64)cc3N5c3c(-c4ccccc4)cccc3-c3ccccc3)c2)cc1]

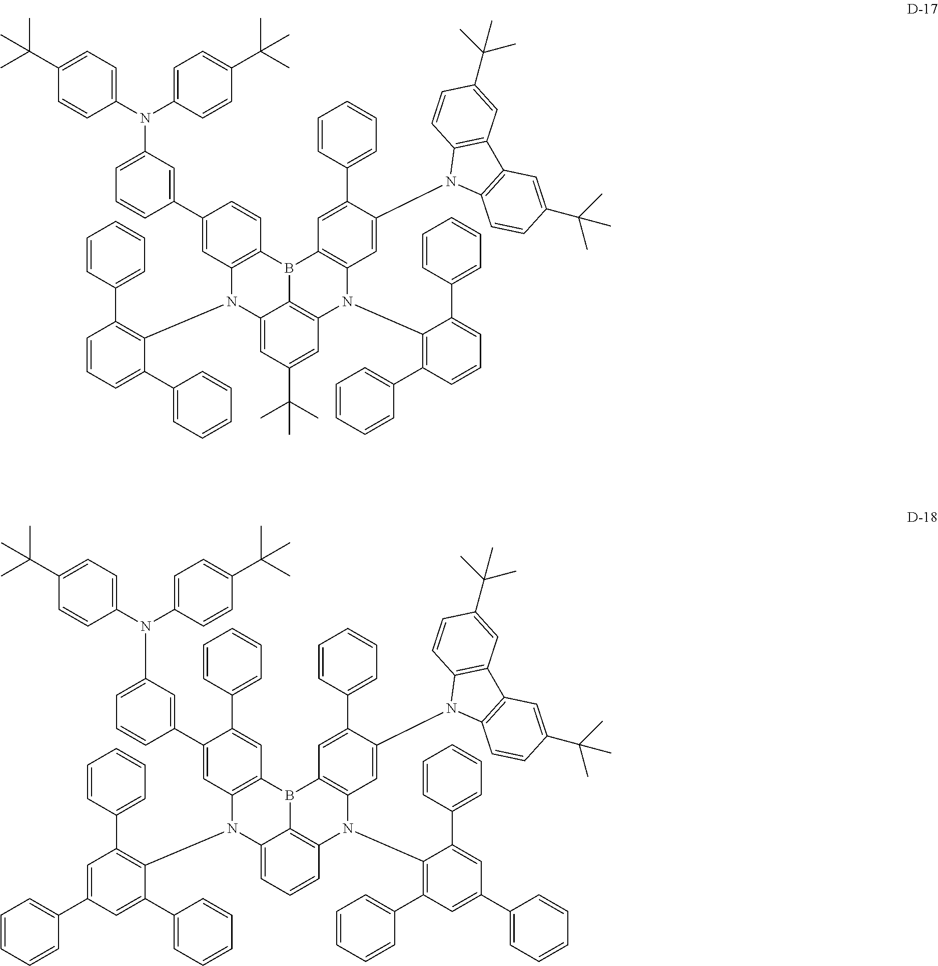 [SMILES: CC(C)(C)c1ccc(N(c2ccc(C(C)(C)C)cc2)c2cccc(-c3ccc4c(c3)N(c3c(-c5ccccc5)cccc3-c3ccccc3)c3cc(C(C)(C)C)cc5c3B4c3cc(-c4ccccc4)c(-n4c6ccc(C(C)(C)C)cc6c6cc(C(C)(C)C)ccc64)cc3N5c3c(-c4ccccc4)cccc3-c3ccccc3)c2)cc1 ; CC(C)(C)c1ccc(N(c2ccc(C(C)(C)C)cc2)c2cccc(-c3cc4c(cc3-c3ccccc3)B3c5cc(-c6ccccc6)c(-n6c7ccc(C(C)(C)C)cc7c7cc(C(C)(C)C)ccc76)cc5N(c5c(-c6ccccc6)cc(-c6ccccc6)cc5-c5ccccc5)c5cccc(c53)N4c3c(-c4ccccc4)cc(-c4ccccc4)cc3-c3ccccc3)c2)cc1]

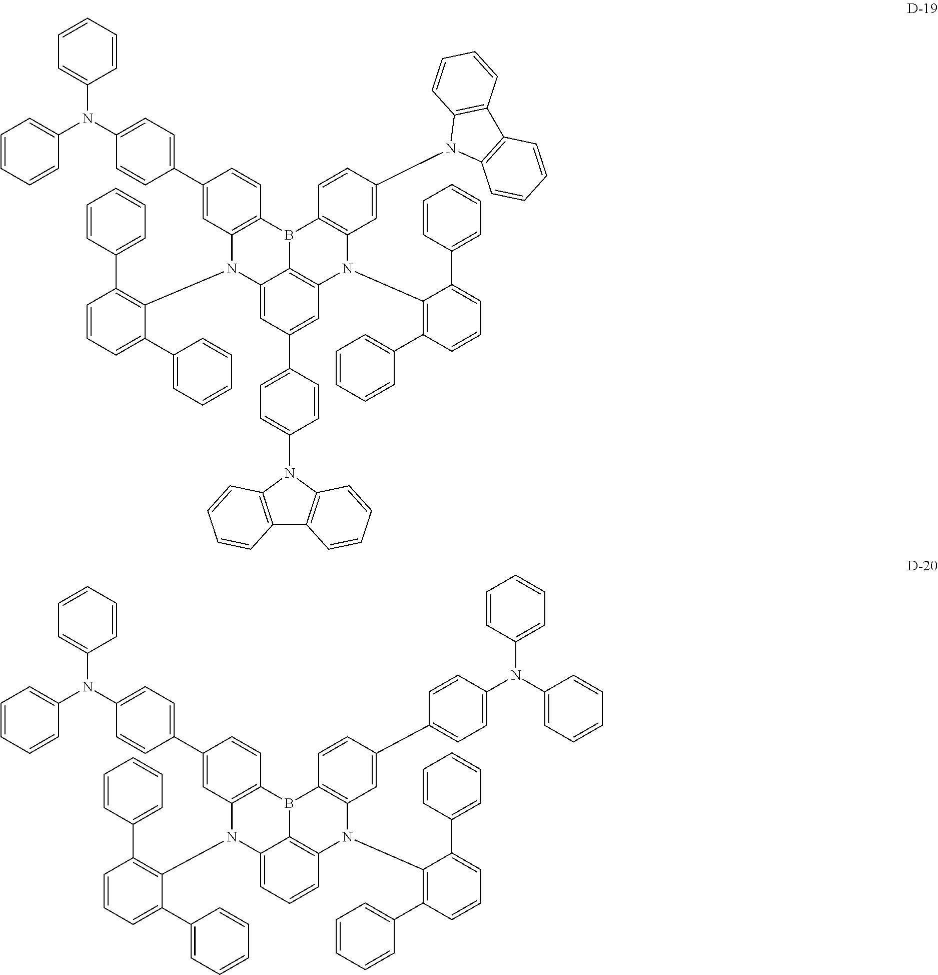 [SMILES: c1ccc(-c2cccc(-c3ccccc3)c2N2c3cc(-c4ccc(N(c5ccccc5)c5ccccc5)cc4)ccc3B3c4ccc(-n5c6ccccc6c6ccccc65)cc4N(c4c(-c5ccccc5)cccc4-c4ccccc4)c4cc(-c5ccc(-n6c7ccccc7c7ccccc76)cc5)cc2c43)cc1 ; c1ccc(-c2cccc(-c3ccccc3)c2N2c3cc(-c4ccc(N(c5ccccc5)c5ccccc5)cc4)ccc3B3c4ccc(-c5ccc(N(c6ccccc6)c6ccccc6)cc5)cc4N(c4c(-c5ccccc5)cccc4-c4ccccc4)c4cccc2c43)cc1]

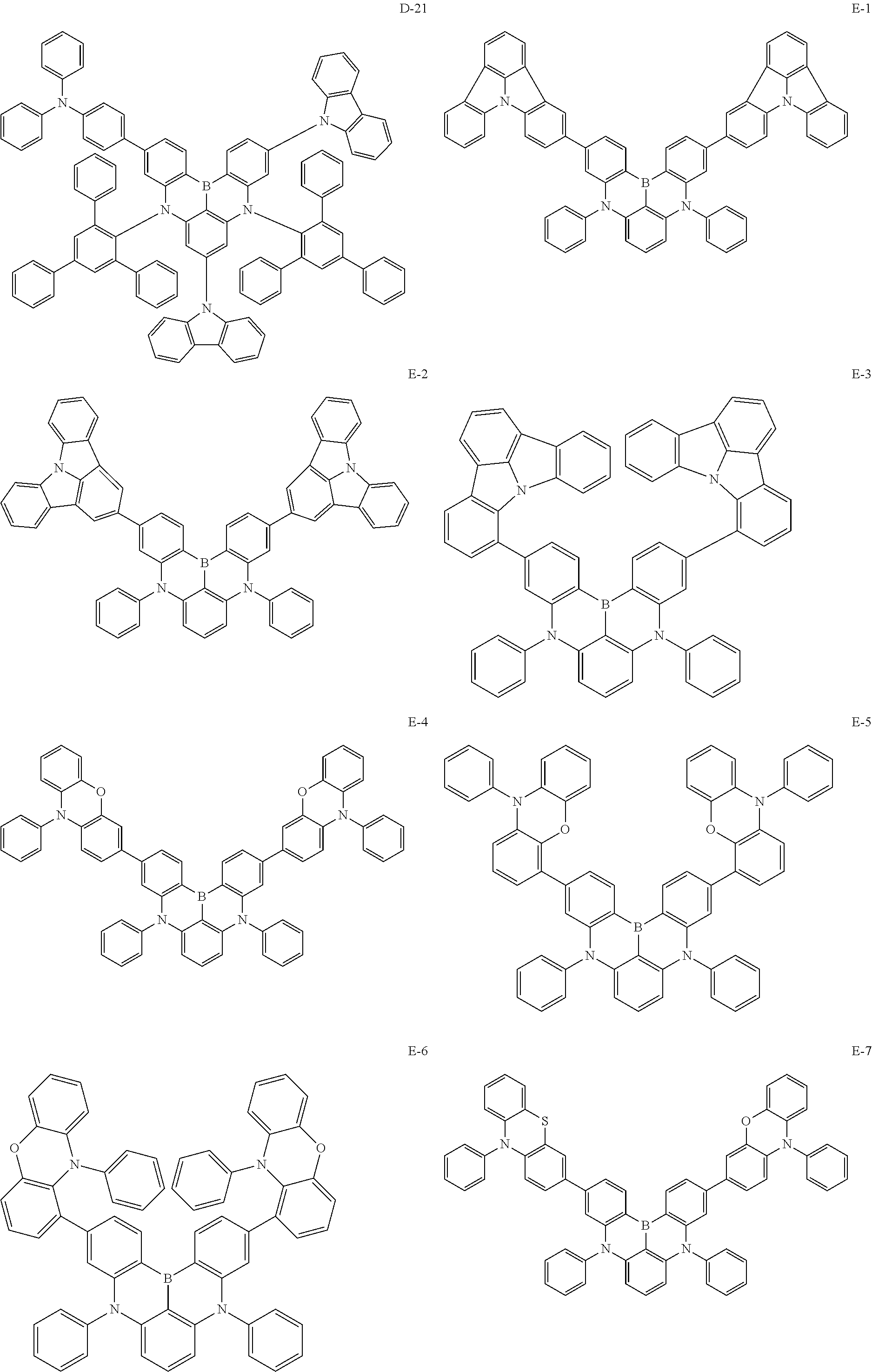

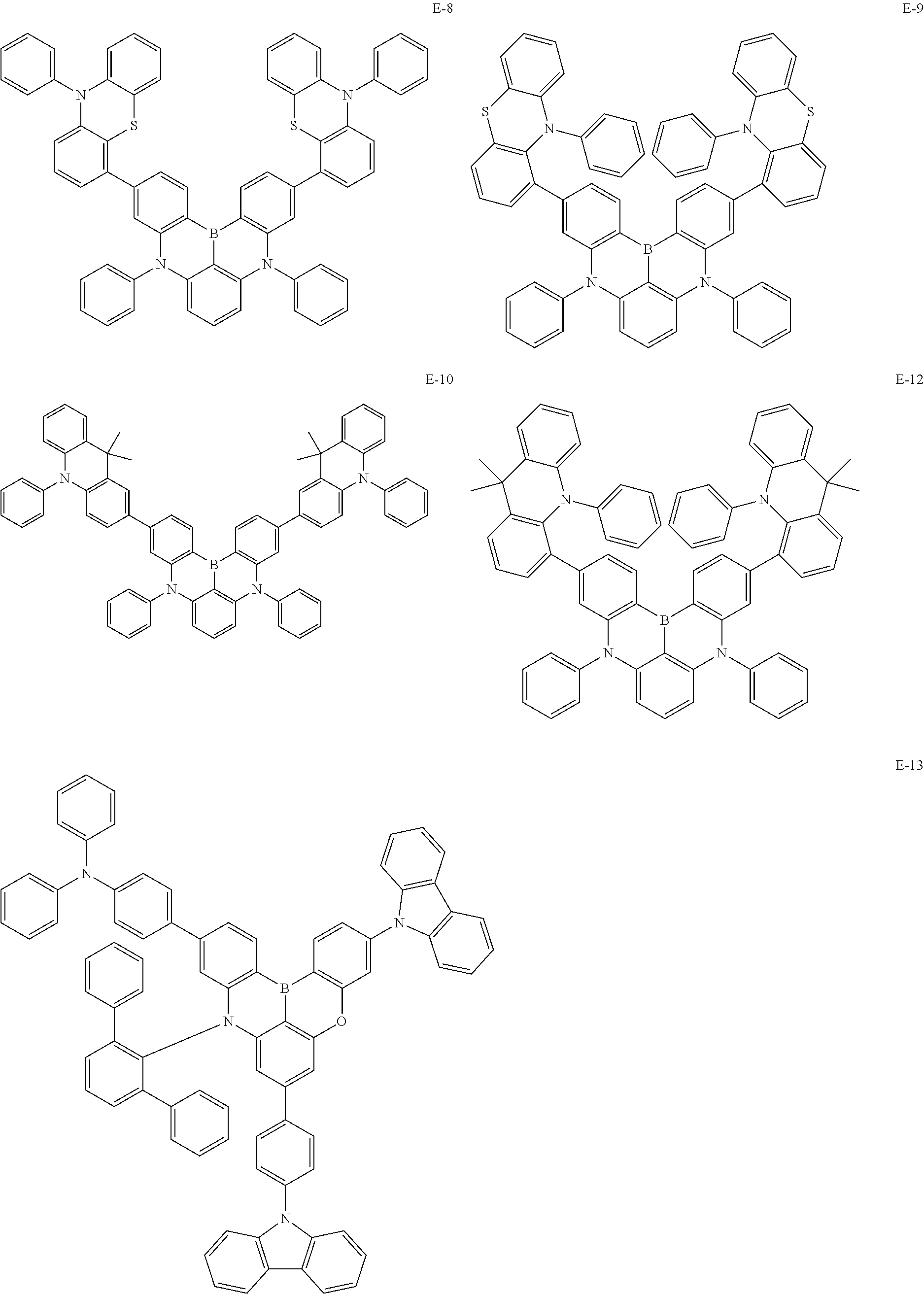

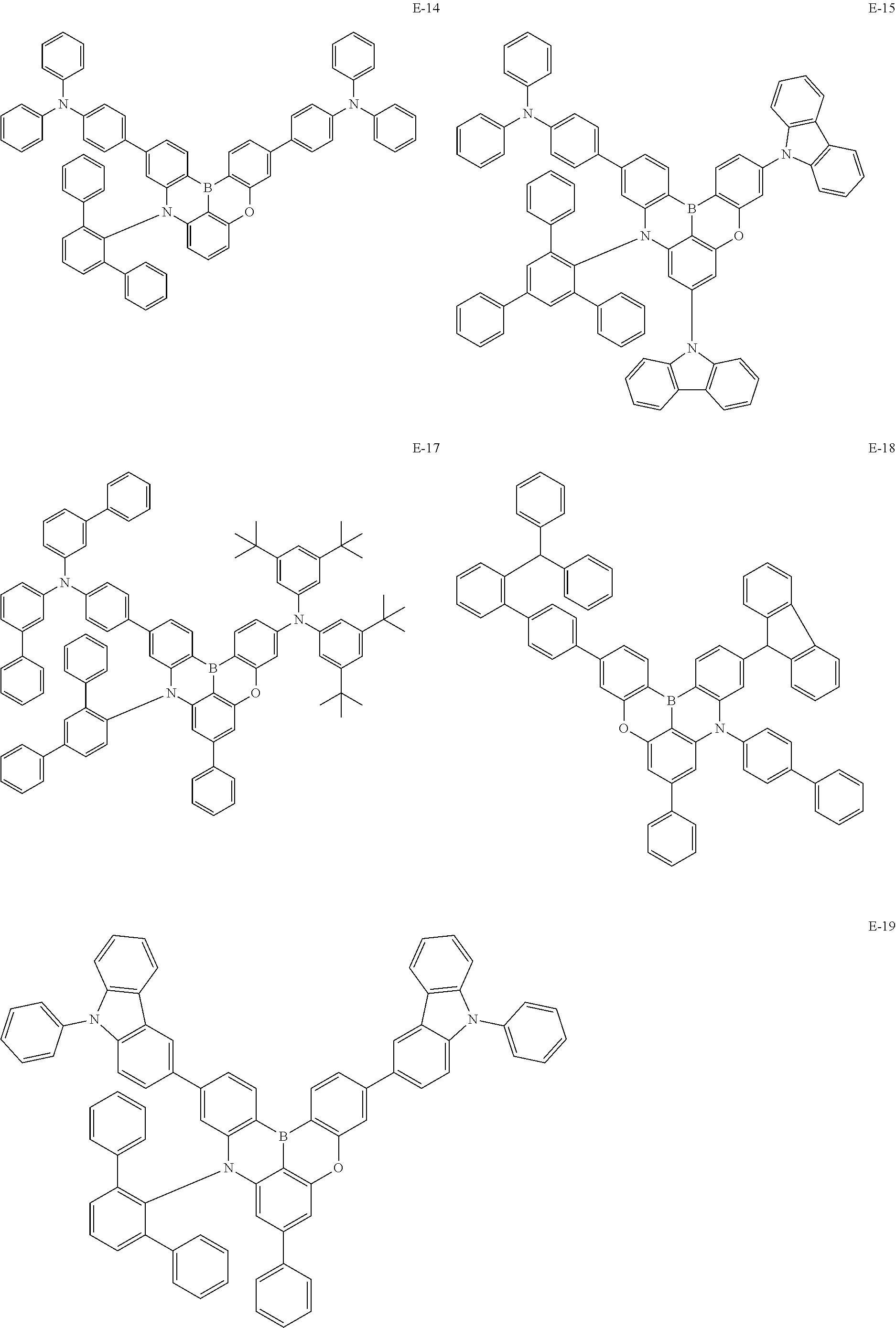

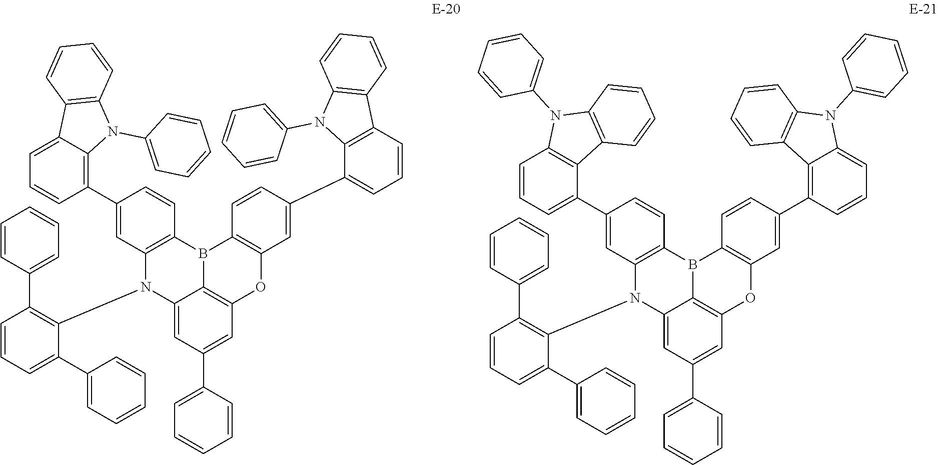 [SMILES: c1ccc(-c2cc3c4c(c2)N(c2c(-c5ccccc5)cccc2-c2ccccc2)c2cc(-c5cccc6c7ccccc7n(-c7ccccc7)c56)ccc2B4c2ccc(-c4cccc5c6ccccc6n(-c6ccccc6)c45)cc2O3)cc1 ; c1ccc(-c2cc3c4c(c2)N(c2c(-c5ccccc5)cccc2-c2ccccc2)c2cc(-c5cccc6c5c5ccccc5n6-c5ccccc5)ccc2B4c2ccc(-c4cccc5c4c4ccccc4n5-c4ccccc4)cc2O3)cc1]

D in the structures of the compounds in Compound Group 1 above means a deuterium atom.

The emission spectrum of the first compound represented by Formula 1 of an embodiment has a full width of half maximum (FWHM) of about 20 nm to about 60 nm. The emission spectrum of the first compound represented by Formula 1 of an embodiment has the above range of FWHM, thereby improving luminous efficiency when applied to an element. In addition, when the first compound of an embodiment is used as a blue light emitting element material for the light emitting element, the element service life may be improved.

The first compound represented by Formula 1 of an embodiment may be a thermally activated delayed fluorescence emitting material. Furthermore, the first compound represented by Formula 1 of an embodiment may be a thermally activated delayed fluorescence dopant having the difference (ΔE_{ST}) between the lowest triplet exciton energy (T1 level) and the lowest singlet exciton energy level (S1) of about 0.2 eV or less.

The first compound represented by Formula 1 of an embodiment may be a luminescent material having a luminescence center wavelength in a wavelength region of about 440 nm to about 480 nm. For example, the first compound represented by Formula 1 of an embodiment may be a blue thermally activated delayed fluorescence (TADF) dopant. However, embodiments of the present disclosure are not limited thereto, when the first compound of an embodiment is used as a luminescent material, the first compound may be used as a dopant material that emits light in various suitable wavelength regions, such as a red emitting dopant and a green emitting dopant.

The emission layer EML in the light emitting element ED of an embodiment may emit delayed fluorescence. For example, the emission layer EML may emit thermally activated delayed fluorescence (TADF).

In addition, the emission layer EML of the light emitting element ED may emit blue light. For example, the emission layer EML of the light emitting element ED of an embodiment may emit blue light having a center wavelength of about 440 nm to about 480 nm. However, embodiments of the present disclosure are not limited thereto, and the emission layer EML may emit blue light having a center wavelength greater than about 480 nm, or may emit green light or red light.

The emission layer EML in the light emitting element ED of an embodiment may include a host for emitting delayed fluorescence and a dopant for emitting delayed fluorescence, and may include the above-described first compound as a dopant for emitting delayed fluorescence. The emission layer EML may include at least one selected from among the polycyclic compounds represented in Compound Group 1 as described above as a thermally activated delayed fluorescent dopant.

As described above, in the light emitting element ED of an embodiment, the emission layer EML may include a host. The host may serve to deliver energy to the dopant without emitting light in the light emitting element ED. The emission layer EML may include at least one kind of host. For example, the emission layer EML may include two kinds of different hosts. When the emission layer EML includes two kinds of hosts, the two kinds of hosts may include a hole transporting host and an electron transporting host. However, embodiments of the present disclosure are not limited thereto, and the emission layer EML may include one kind of host, or a mixture of two kinds of different hosts.

In an embodiment, the emission layer EML may include two different hosts. The host may include the second compound, and the third compound different from the second compound. The host may include the second compound having a hole transporting moiety and the third compound having an electron transporting moiety. In the light emitting element ED of an embodiment, for the host, the second compound and the third compound may form an exciplex.

In an embodiment, the emission layer EML may include the second compound represented by Formula HT below. For example, the second compound may be used as a hole transporting host material of the emission layer EML.

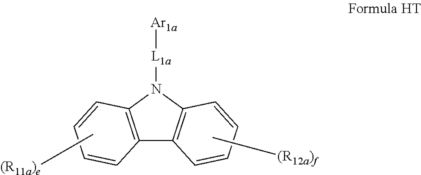

In Formula HT, L₁ₐ may be a direct linkage, a substituted or unsubstituted arylene group having 6 to 30 ring-forming carbon atoms, or a substituted or unsubstituted heteroaryl group having 2 to 30 ring-forming carbon atoms. In addition, Ar₁ₐ may be a substituted or unsubstituted aryl group having 6 to 30 ring-forming carbon atoms, or a substituted or unsubstituted heteroaryl group having 2 to 30 ring-forming carbon atoms.

In Formula HT, R₁₁ₐ and R₁₂ₐ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₁ₐ and R₁₂ₐ may be each independently a hydrogen atom or a deuterium atom.

In Formula HT, e and f are each independently an integer of 0 to 4, R₁₁ₐ and R₁₂ₐ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, when each of e and f is an integer of 2 or more, a plurality of R₁₁ₐ's and a plurality of R₁₂ₐ's may be the same or at least one may be different. For example, in Formula HT, e and f may be 0. In this case, the carbazole group in Formula HT is an unsubstituted carbazole group.

In Formula HT, L₁ₐ may be a direct linkage, a phenylene group, a divalent biphenyl group, a divalent carbazole group, etc., but embodiments of the present disclosure are not limited thereto. Furthermore, Ar₁ₐ may be a substituted or unsubstituted carbazole group, a substituted or unsubstituted dibenzofuran group, a substituted or unsubstituted dibenzothiophene group, a substituted or unsubstituted biphenyl group, etc., but embodiments of the present disclosure are not limited thereto.

The emission layer EML in the light emitting element ED of an embodiment may include a compound represented by Formula ET below as the third compound:

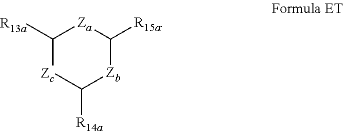

In Formula ET above, at least one selected from among Zₐ to Z_{c} may be N. The rest other than N among Zₐ to Z_{c} may be CR₁₆ₐ. In some embodiments, the third compound represented by Formula ET may include a pyridine moiety, a pyrimidine moiety, or a triazine moiety.

In Formula ET, R₁₃ₐ to R₁₆ₐ may be each independently a hydrogen atom, a deuterium atom, a cyano group, a substituted or unsubstituted silyl atoms, a substituted or unsubstituted aryl group having 6 to 30 ring-forming carbon atoms, or a substituted or unsubstituted heteroaryl group having 2 to 30 ring-forming carbon atoms.

In Formula ET, R₁₃ₐ to R₁₆ₐ may be each independently a substituted or unsubstituted phenyl group, a substituted or unsubstituted carbazole group, etc., but embodiments of the present disclosure are not limited thereto.

When the emission layer EML of the light emitting element ED of an embodiment includes the second compound represented by Formula HT and the third compound represented by Formula ET in the emission layer EML at the same time, an excellent long service life characteristic may be exhibited. For example, in the emission layer EML of the light emitting element ED of an embodiment, for the host, the second compound represented by Formula HT and the third compound represented by Formula ET may form an exciplex.

The second compound among the two host materials concurrently (e.g., simultaneously) included in the emission layer EML may be a hole transporting host, and the third compound may be an electron transporting host. The light emitting element ED of an embodiment may include, in the emission layer EML, both the second compound which has excellent hole transport characteristics and the third compound which has excellent electron transport characteristics, thereby efficiently delivering energy to dopant compounds which will be further described below.

The emission layer EML in the light emitting element ED of an embodiment may further include the fourth compound besides the first compound represented by Formula 1 as described above. The emission layer EML may include, as the fourth compound, an organometallic complex containing platinum (Pt) as a central metal atom and ligands linked (e.g., bonded) to the central metal atom. The emission layer EML in the light emitting element ED of an embodiment may include a compound represented by Formula D-1 below as the fourth compound:

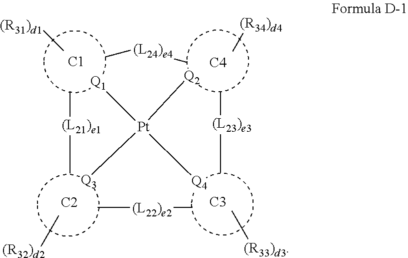

In Formula D-1, Q₁ to Q₄ may be each independently C or N.

In Formula D-1, C1 to C4 may be each independently a substituted or unsubstituted hydrocarbon ring having 5 to 30 ring-forming carbon atoms, or a substituted or unsubstituted heterocycle having 2 to 30 ring-forming carbon atoms.

In Formula D-1, L₂₁ to L₂₄ may be each independently a direct linkage,

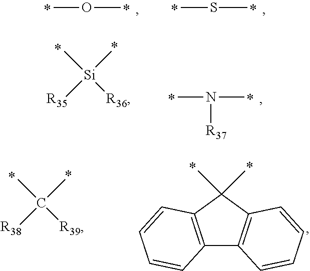

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₂₁ to L₂₄, —* means a part linked to C1 to C4.

In Formula D-1, e1 to e4 may be each independently 0 or 1. If e1 is 0, C1 and C2 may not be linked to each other. If e2 is 0, e2 and e3 may not be linked to each other. If e3 is 0, C3 and C4 may not be linked to each other. If e4 is 0, C1 and C4 may not be linked to each other.

In Formula D-1, R₃₁ to R₃₉ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. For example, R₃₁ to R₃₉ may be each independently a methyl group or a t-butyl group.

In Formula D-1, d1 to d4 may be each independently an integer of 0 to 4. In some embodiments, when each of d1 to d4 is an integer of 2 or more, a plurality of R₃₁'s to R₃₄'s may each be the same or at least one may be different.

In Formula D-1, C1 to C4 may be each independently a substituted or unsubstituted hydrocarbon ring or a substituted or unsubstituted heterocycle represented by any one selected from among C-1 to C-3 below:

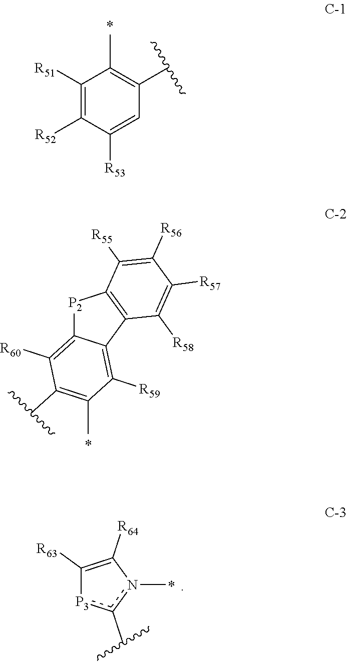

In C-1 to C-3, P₁ may be C—* or CR₅₄, P₂ may be N—* or NR₆₁, and P₃ may be N—* or NR₆₂. R₅₁ to R₆₄ may be each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 6 to 30 ring-forming carbon atoms, or may be bonded to an adjacent group to form a ring.

In addition, in C-1 to C-3, “

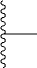

” corresponds to a part linked to Pt that is a central metal atom, and “—*” corresponds to a part linked to a neighboring cyclic group (C1 to C4) or a linker (L₂₁ to L₂₄).

The fourth compound represented by Formula D-1 as described above may be a phosphorescent dopant.

In an embodiment, the first compound may be a luminescent dopant which emits blue light, and the emission layer EML may emit light through fluorescence. For example, the emission layer EML may emit blue light through thermally activated delayed fluorescence.

In an embodiment, the fourth compound included in the emission layer EML may be a sensitizer. The fourth compound included in the emission layer EML in the light emitting element ED of an embodiment may serve as a sensitizer to deliver energy from the host to the first compound that is a light emitting dopant. In some embodiments, the fourth compound serving as an auxiliary dopant accelerates energy delivery to the first compound that is a light emitting dopant, thereby increasing the emission ratio of the first compound. Therefore, the emission layer EML of an embodiment may improve luminous efficiency. In addition, when the energy delivery to the first compound is increased, an exciton formed in the emission layer EML is not accumulated inside the emission layer EML and emits light rapidly, and thus deterioration of the element may be reduced. Therefore, the service life of the light emitting element ED of an embodiment may increase.

In an embodiment, the weight ratio of the second compound and the third compound in the light emitting element ED may be about 4:6 to about 7:3 or about 5:5 to about 7:3. For example, the weight ratio of the second compound the third compound may be 4:6, 5:5, 6:4, or 7:3. However, embodiments are not limited thereto. When the contents of the second compound and the third compound satisfy the above-described ratio, a charge balance characteristic in the emission layer EML are improved, and thus, the luminous efficiency and element service life may increase. When the contents of the second compound and the third compound deviate from the above-described ratio range, a charge balance in the emission layer EML is broken, and thus, the luminous efficiency may be reduced and the element may be easily deteriorated (e.g., damaged or degraded).

The light emitting element ED of an embodiment may include all of the first compound, the second compound, the third compound, and the fourth compound, and the emission layer EML may include the combination of two host materials and two dopant materials. In the light emitting element ED of an embodiment, the emission layer EML may concurrently (e.g., simultaneously) include two different hosts, the first compound that emits a delayed fluorescence, and the fourth compound including an organometallic complex, thereby exhibiting excellent luminous efficiency characteristics.

In an embodiment, the second compound represented by Formula HT above may be represented by any one selected from among the compounds represented by Compound Group 2 below. The emission layer EML may include at least one selected from among the compounds represented by Compound Group 2 as a hole transporting host material.

### Compound Group 2

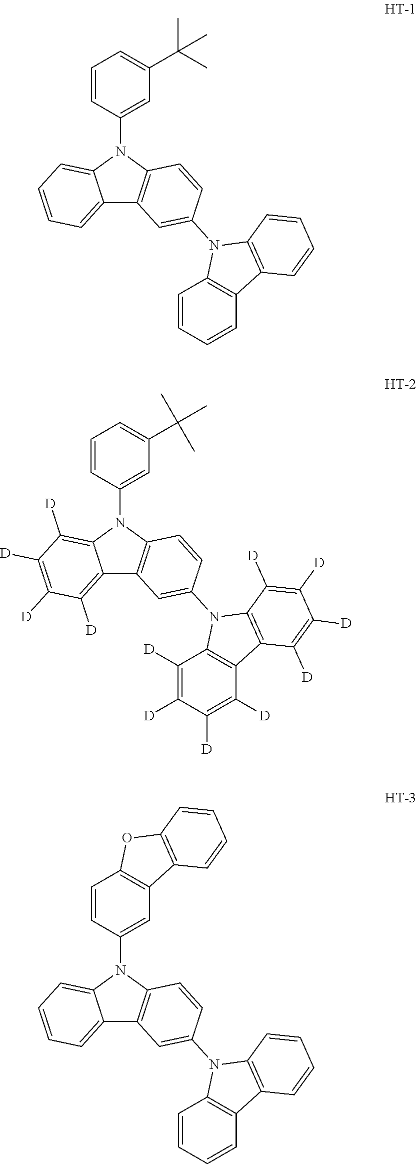 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

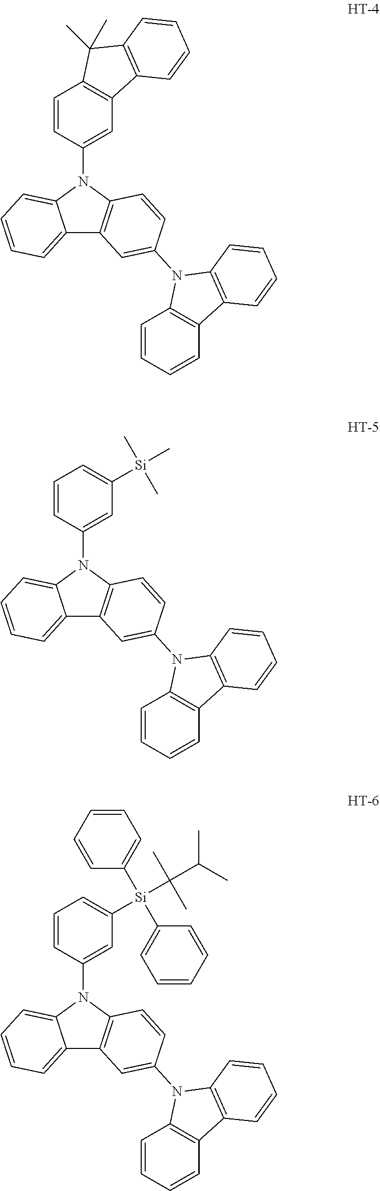 [SMILES: CC1(C)c2ccccc2-c2cc(-n3c4ccccc4c4cc(-n5c6ccccc6c6ccccc65)ccc43)ccc21 ; C[Si](C)(C)c1cccc(-n2c3ccccc3c3cc(-n4c5ccccc5c5ccccc54)ccc32)c1 ; CC(C)C(C)(C)[Si](c1ccccc1)(c1ccccc1)c1cccc(-n2c3ccccc3c3cc(-n4c5ccccc5c5ccccc54)ccc32)c1]

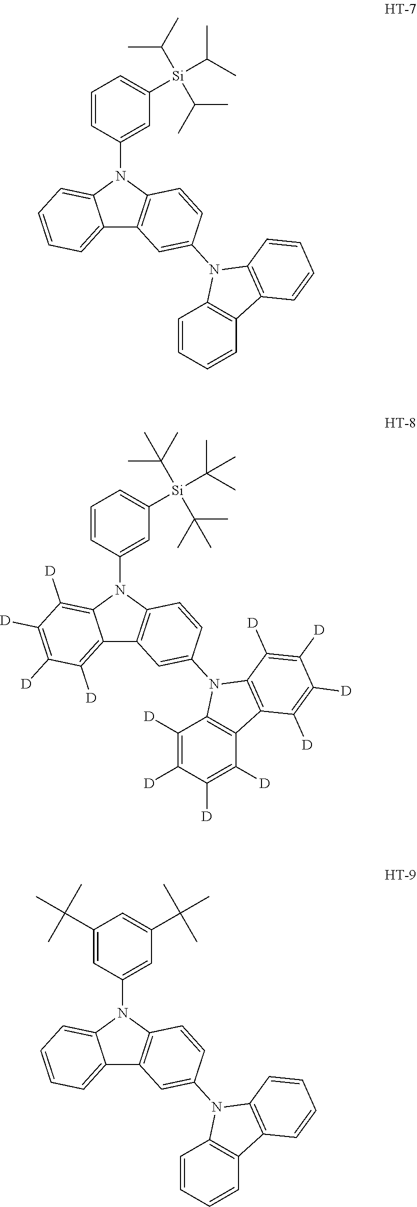 [SMILES: CC(C)[Si](c1cccc(-n2c3ccccc3c3cc(-n4c5ccccc5c5ccccc54)ccc32)c1)(C(C)C)C(C)C ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc([Si](C(C)(C)C)(C(C)(C)C)C(C)(C)C)c1 ; CC(C)(C)c1cc(-n2c3ccccc3c3cc(-n4c5ccccc5c5ccccc54)ccc32)cc(C(C)(C)C)c1]

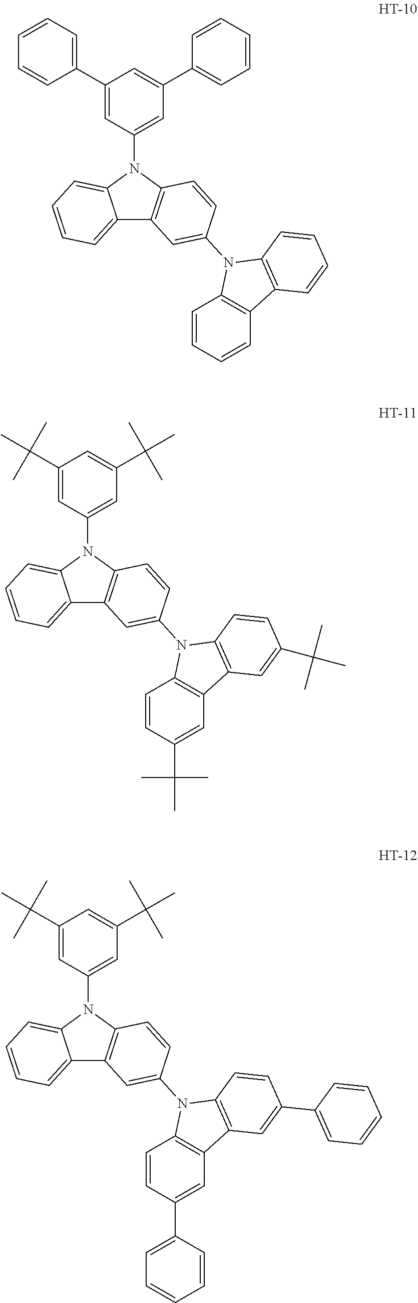

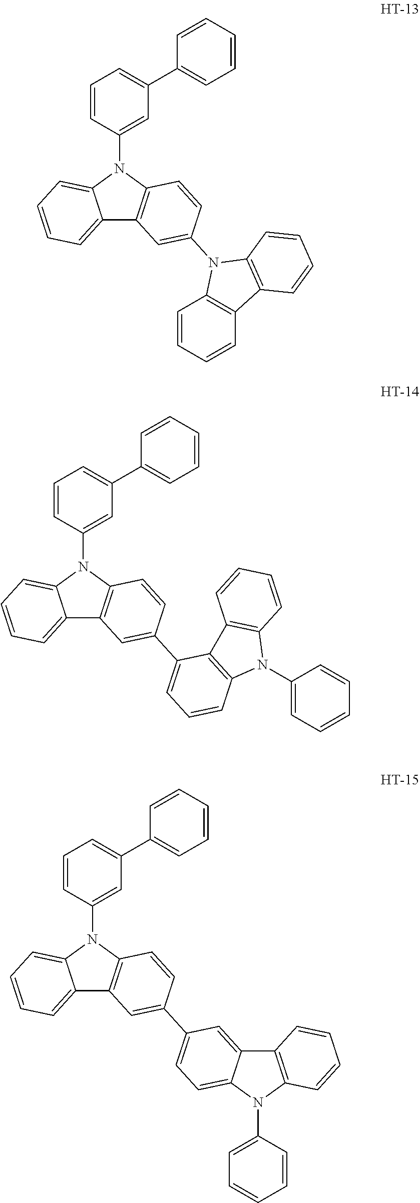 [SMILES: c1ccc(-c2cccc(-n3c4ccccc4c4cc(-n5c6ccccc6c6ccccc65)ccc43)c2)cc1 ; c1ccc(-c2cccc(-n3c4ccccc4c4cc(-c5cccc6c5c5ccccc5n6-c5ccccc5)ccc43)c2)cc1 ; c1ccc(-c2cccc(-n3c4ccccc4c4cc(-c5ccc6c(c5)c5ccccc5n6-c5ccccc5)ccc43)c2)cc1]

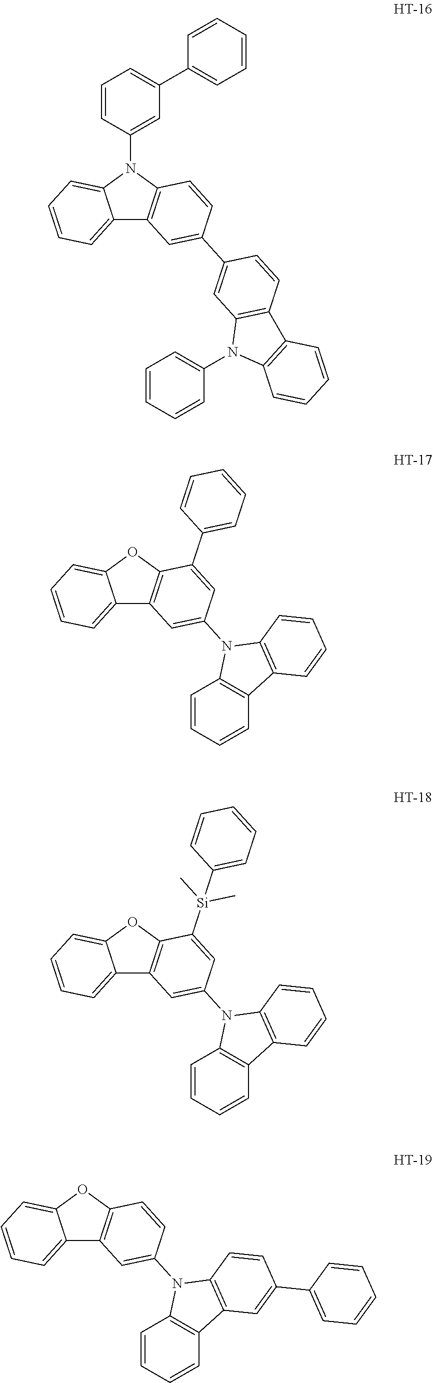 [SMILES: c1ccc(-c2cccc(-n3c4ccccc4c4cc(-c5ccc6c7ccccc7n(-c7ccccc7)c6c5)ccc43)c2)cc1 ; c1ccc(-c2cc(-n3c4ccccc4c4ccccc43)cc3c2oc2ccccc23)cc1 ; C[Si](C)(c1ccccc1)c1cc(-n2c3ccccc3c3ccccc32)cc2c1oc1ccccc12 ; c1ccc(-c2ccc3c(c2)c2ccccc2n3-c2ccc3oc4ccccc4c3c2)cc1]

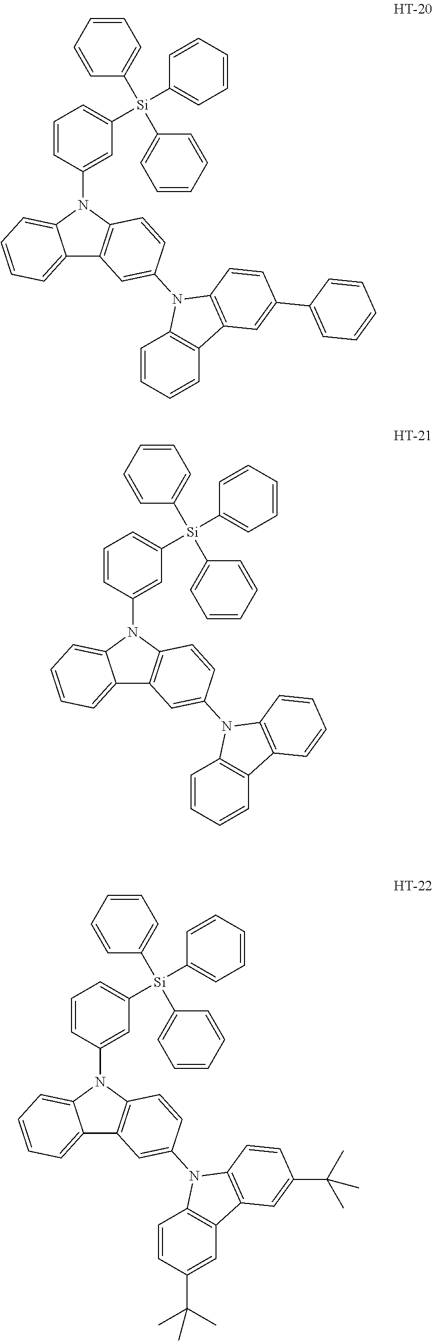 [SMILES: c1ccc(-c2ccc3c(c2)c2ccccc2n3-c2ccc3c(c2)c2ccccc2n3-c2cccc([Si](c3ccccc3)(c3ccccc3)c3ccccc3)c2)cc1 ; c1ccc([Si](c2ccccc2)(c2ccccc2)c2cccc(-n3c4ccccc4c4cc(-n5c6ccccc6c6ccccc65)ccc43)c2)cc1 ; CC(C)(C)c1ccc2c(c1)c1cc(C(C)(C)C)ccc1n2-c1ccc2c(c1)c1ccccc1n2-c1cccc([Si](c2ccccc2)(c2ccccc2)c2ccccc2)c1]

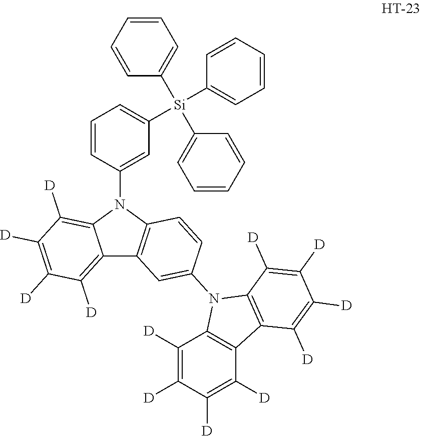 [SMILES: [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc([Si](c2ccccc2)(c2ccccc2)c2ccccc2)c1]

In an embodiment, the third compound represented by Formula ET may be represented by any one selected from among the compounds represented by Compound Group 3 below. The emission layer EML may include at least one selected from among the compounds represented by Compound Group 3 as an electron transporting host material.

### Compound Group 3

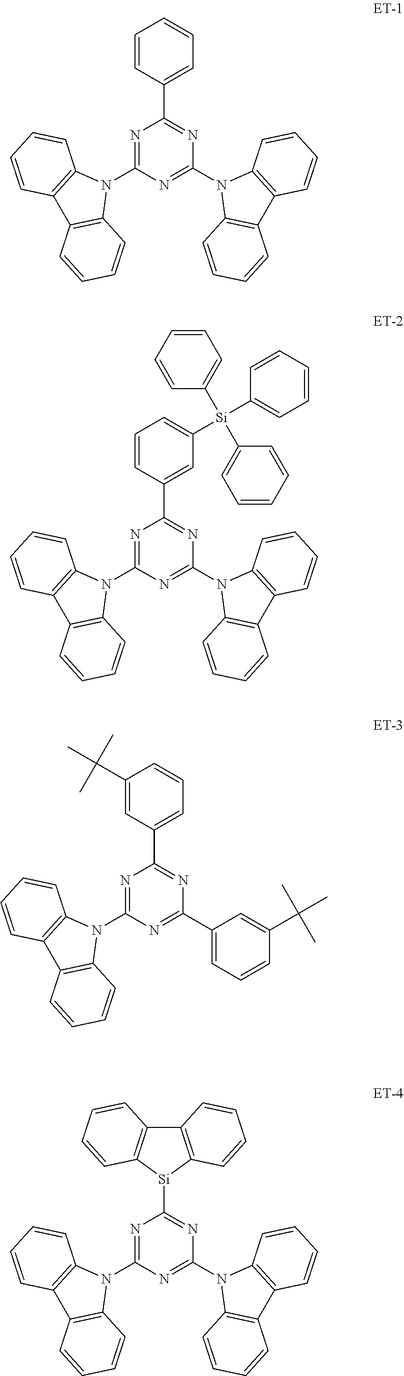

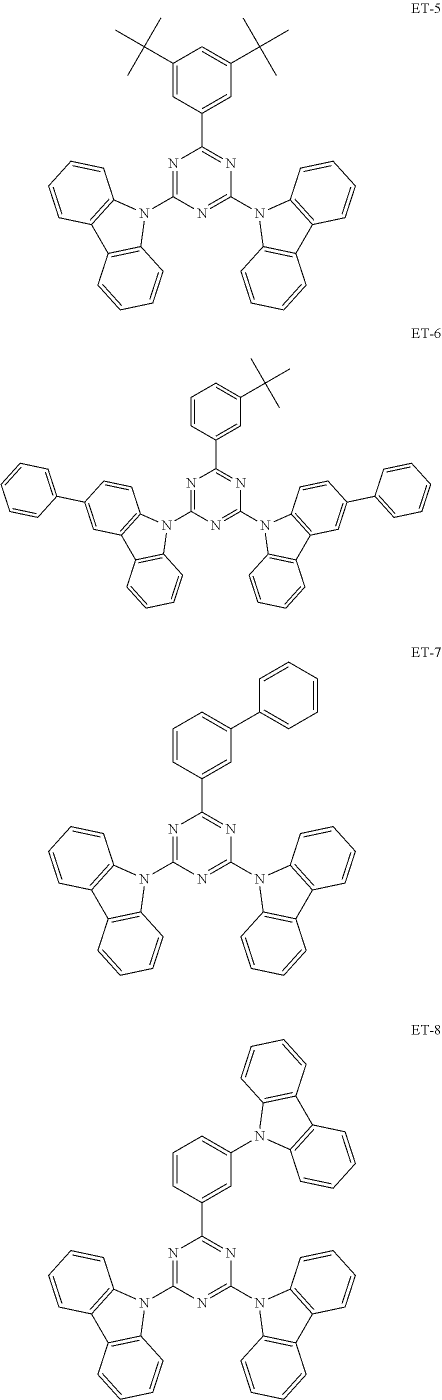 [SMILES: CC(C)(C)c1cc(-c2nc(-n3c4ccccc4c4ccccc43)nc(-n3c4ccccc4c4ccccc43)n2)cc(C(C)(C)C)c1 ; CC(C)(C)c1cccc(-c2nc(-n3c4ccccc4c4cc(-c5ccccc5)ccc43)nc(-n3c4ccccc4c4cc(-c5ccccc5)ccc43)n2)c1 ; c1ccc(-c2cccc(-c3nc(-n4c5ccccc5c5ccccc54)nc(-n4c5ccccc5c5ccccc54)n3)c2)cc1 ; c1cc(-c2nc(-n3c4ccccc4c4ccccc43)nc(-n3c4ccccc4c4ccccc43)n2)cc(-n2c3ccccc3c3ccccc32)c1]

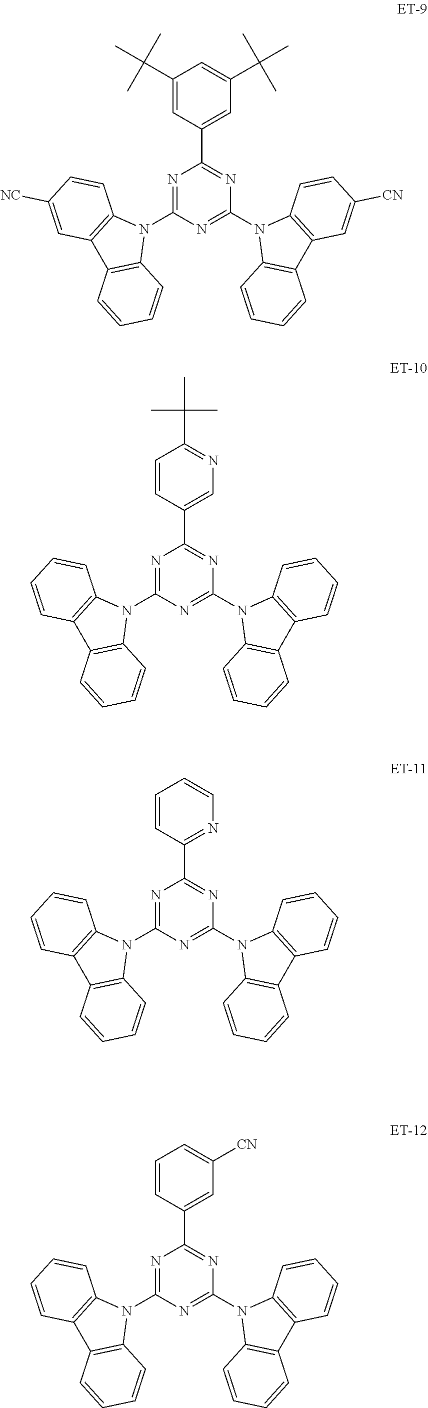 [SMILES: CC(C)(C)c1cc(-c2nc(-n3c4ccccc4c4cc(C#N)ccc43)nc(-n3c4ccccc4c4cc(C#N)ccc43)n2)cc(C(C)(C)C)c1 ; CC(C)(C)c1ccc(-c2nc(-n3c4ccccc4c4ccccc43)nc(-n3c4ccccc4c4ccccc43)n2)cn1 ; c1ccc(-c2nc(-n3c4ccccc4c4ccccc43)nc(-n3c4ccccc4c4ccccc43)n2)nc1 ; N#Cc1cccc(-c2nc(-n3c4ccccc4c4ccccc43)nc(-n3c4ccccc4c4ccccc43)n2)c1]

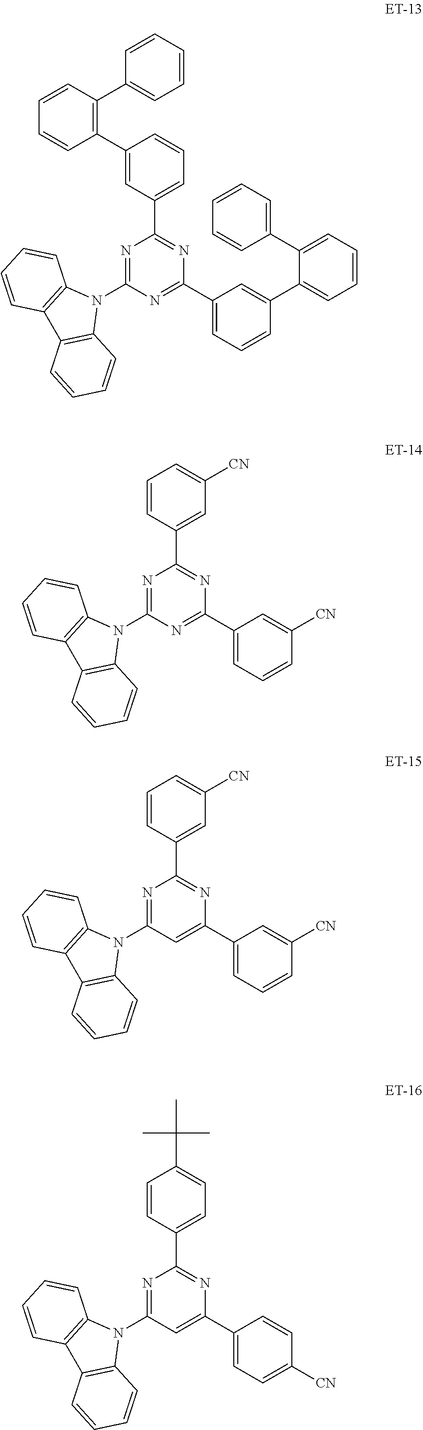 [SMILES: c1ccc(-c2ccccc2-c2cccc(-c3nc(-c4cccc(-c5ccccc5-c5ccccc5)c4)nc(-n4c5ccccc5c5ccccc54)n3)c2)cc1 ; N#Cc1cccc(-c2nc(-c3cccc(C#N)c3)nc(-n3c4ccccc4c4ccccc43)n2)c1 ; N#Cc1cccc(-c2cc(-n3c4ccccc4c4ccccc43)nc(-c3cccc(C#N)c3)n2)c1 ; CC(C)(C)c1ccc(-c2nc(-c3ccc(C#N)cc3)cc(-n3c4ccccc4c4ccccc43)n2)cc1]

In an embodiment, the fourth compound represented by Formula D-1 may include at least one selected from among the compounds represented by Compound Group 4 below. The emission layer EML may include at least one selected from among the compounds represented by Compound Group 4 as a sensitizer material.

### Compound Group 4

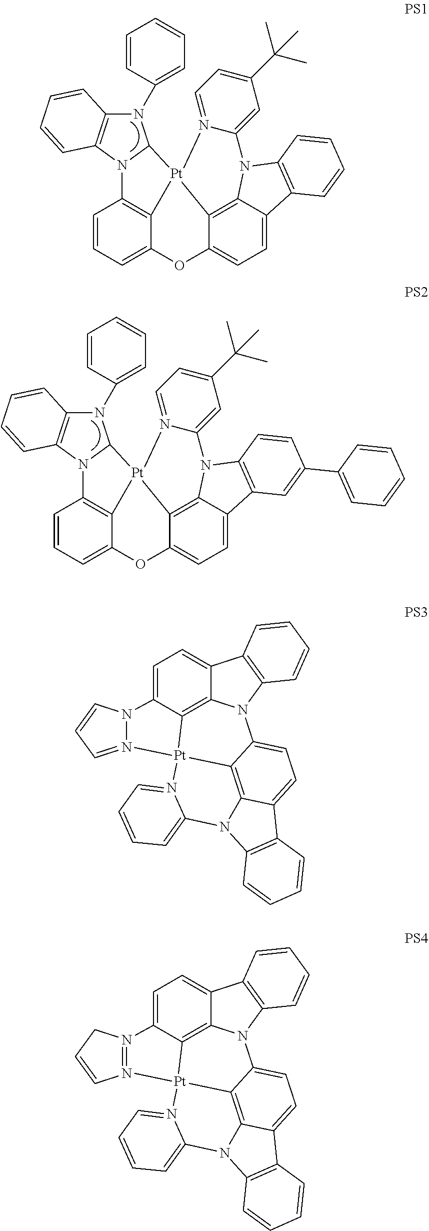

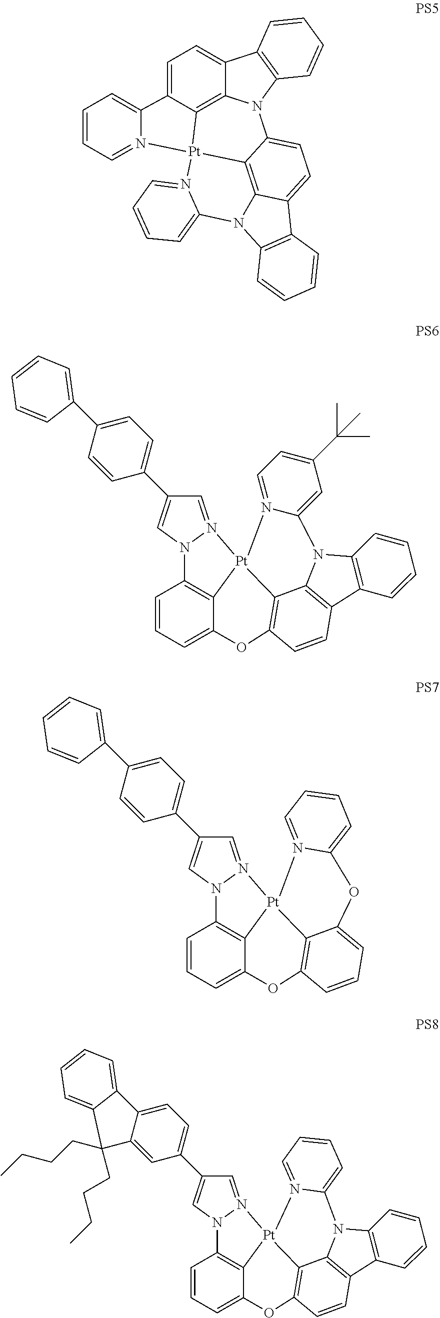

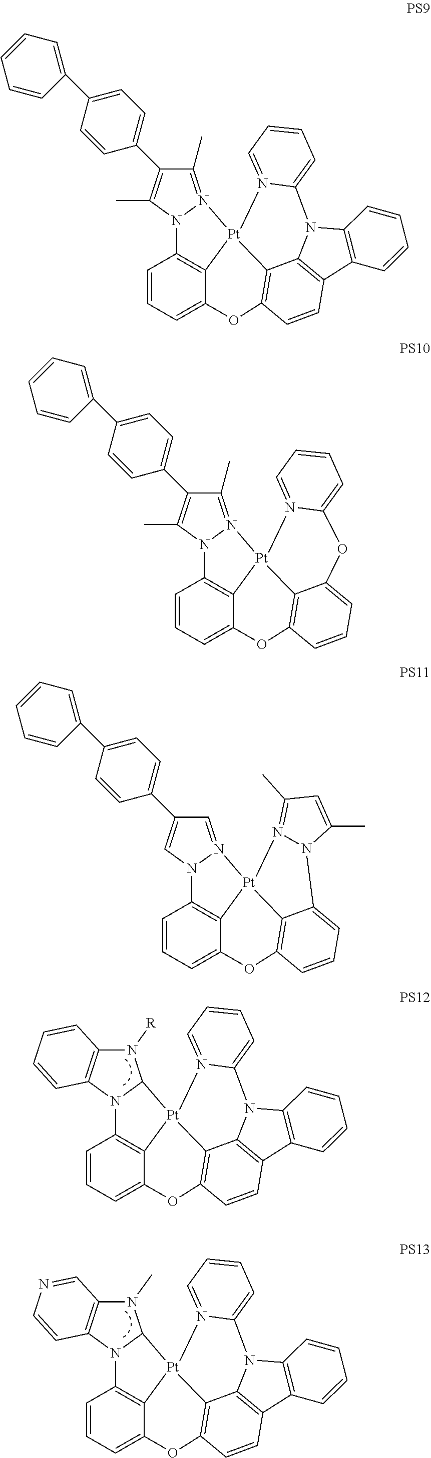

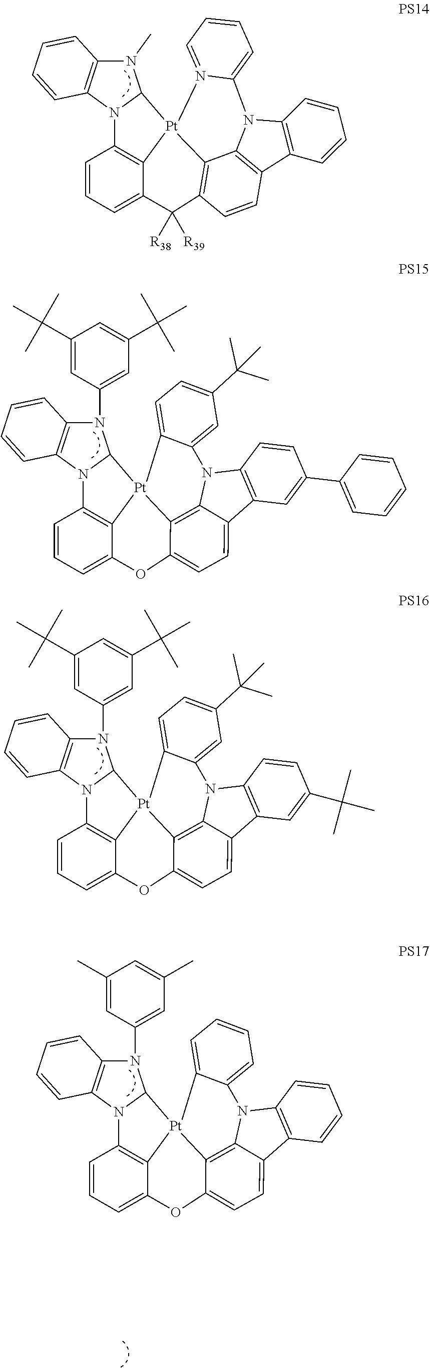

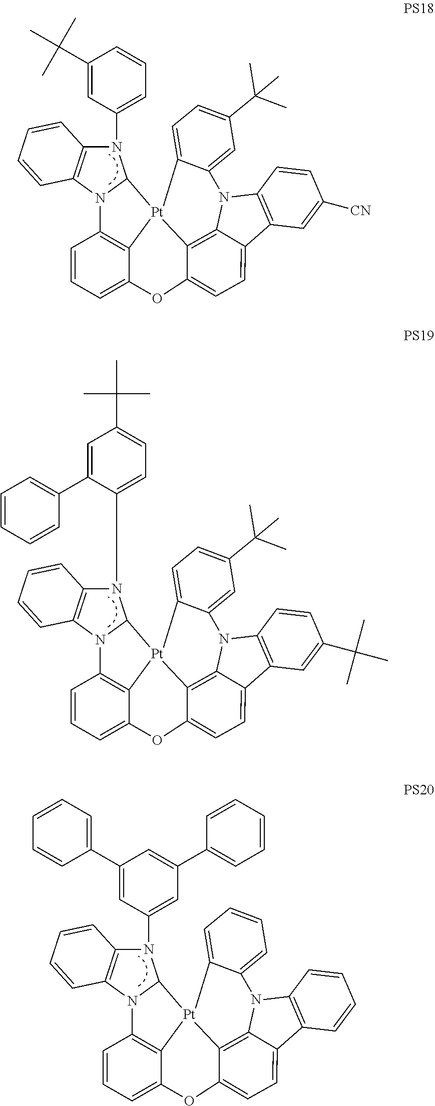

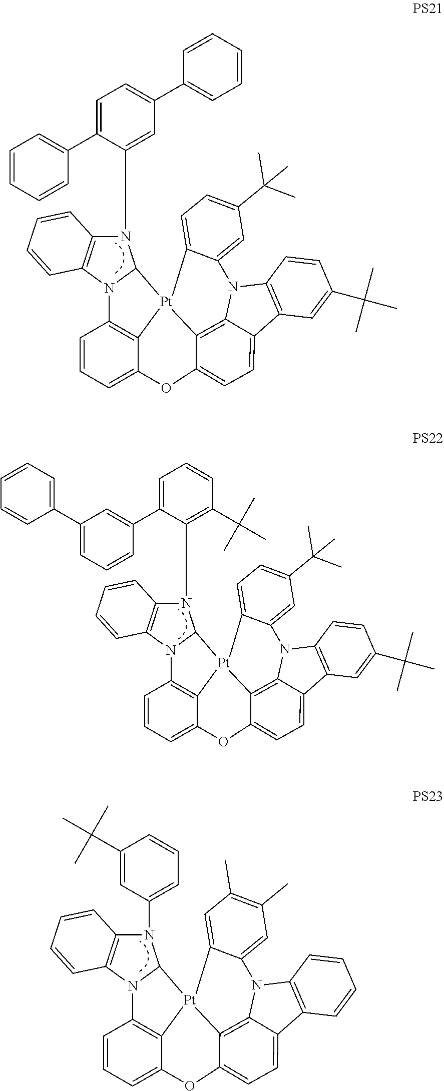

In the compounds included in Compound Group 4 above, R, R₃₈, and R₃₉ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In some embodiments, the light emitting element ED of an embodiment may include a plurality of emission layers. The plurality of emission layers may be sequentially stacked and provided, and for example, the light emitting element ED including the plurality of emission layers may emit white light. The light emitting element including the plurality of emission layers may be a light emitting element having a tandem structure. When the light emitting element ED includes the plurality of emission layers, at least one emission layer EML may include all of the first compound, the second compound, the third compound, and the fourth compound as described above.

In the light emitting element ED of an embodiment, the emission layer EML may further include an anthracene derivative, a pyrene derivative, a fluoranthene derivative, a chrysene derivative, a dehydrobenzanthracene derivative, and/or a triphenylene derivative. For example, the emission layer EML may include the anthracene derivative and/or the pyrene derivative.

In each light emitting element ED of embodiments illustrated in FIGS. 3 to 6, the emission layer EML may further include any suitable host and dopant generally used in the art besides the above-described host and dopant, and the emission layer EML may include a compound represented by Formula E-1 below. The compound represented by Formula E-1 below may be used as a fluorescent host material.

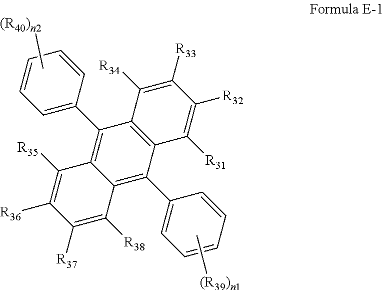

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, n1 and n2 may be each independently an integer of 0 to 5.

Formula E-1 may be represented by any one selected from among Compound E1 to Compound E20 below:

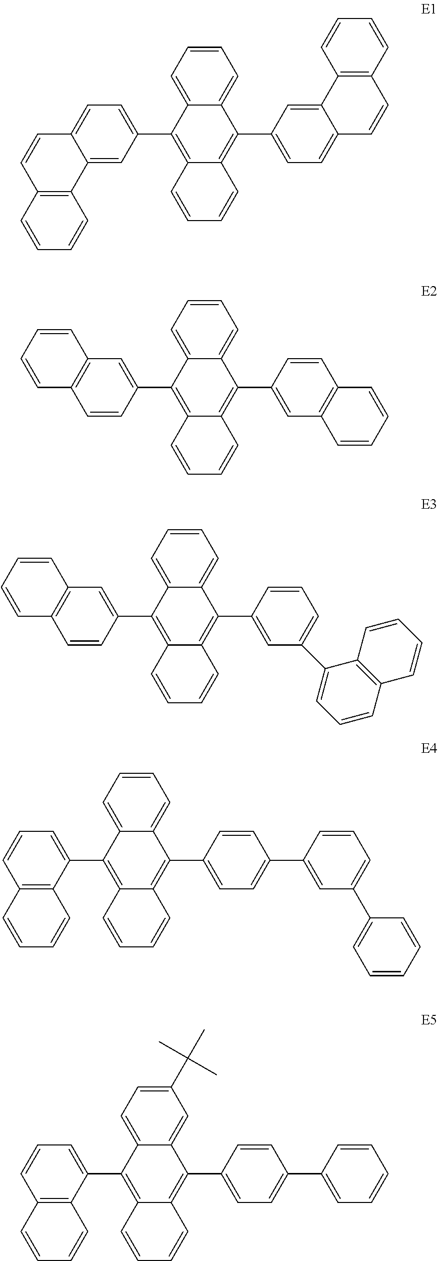

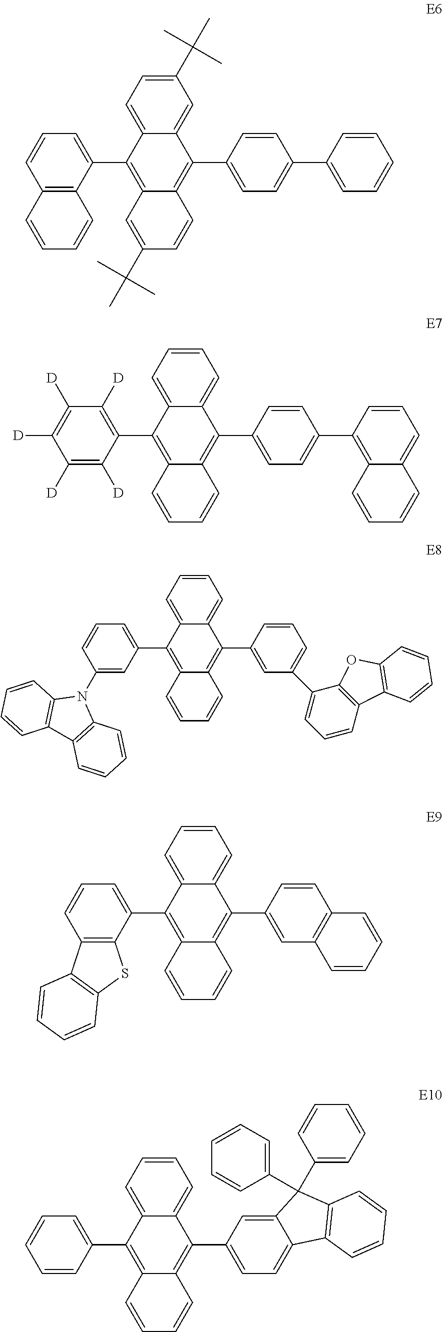

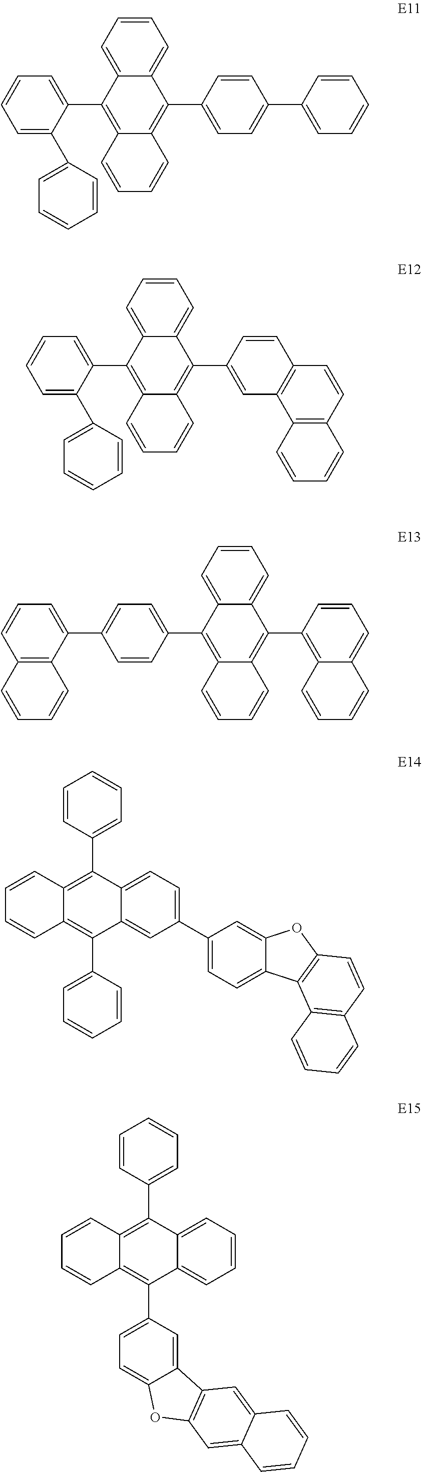

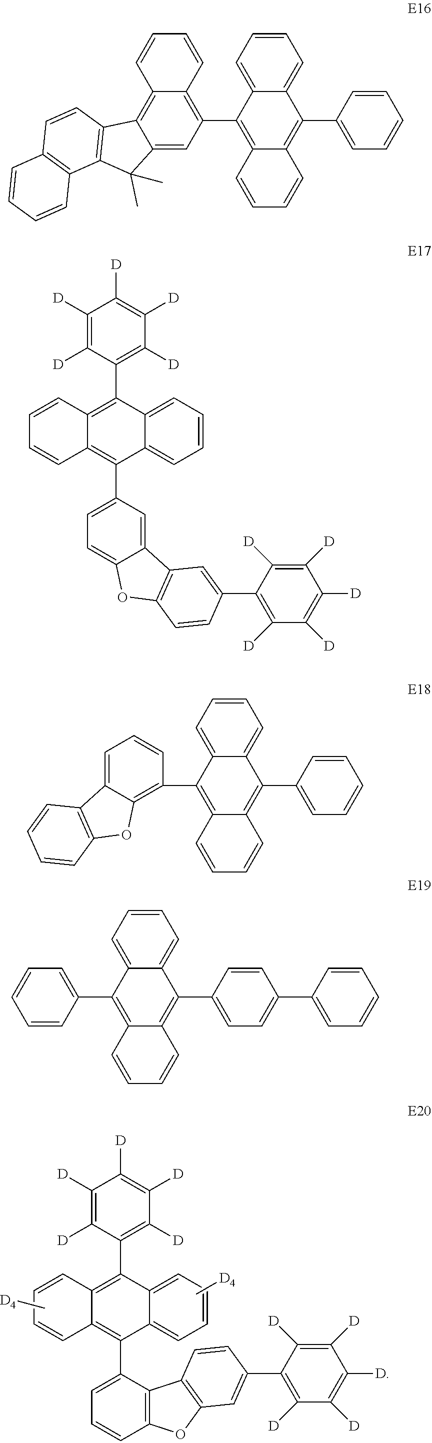

In an embodiment, the emission layer EML may further include a compound represented by Formula E-2a or Formula E-2b below. The compound represented by Formula E-2b below may be used as a phosphorescent host material.

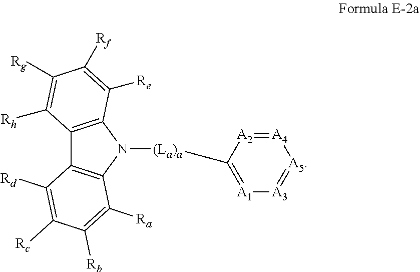

In Formula E-2a, a may be an integer selected from 0 to 10, Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or more, a plurality of Lₐs may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Rₐ to Rᵢ may be bonded to an adjacent group to form a hydrocarbon ring or a heterocycle containing N, O, S, etc. as a ring-forming atom.

In some embodiments, in Formula E-2a, two or three selected from among A₁ to A₅ may be N, and the rest may be CRᵢ.

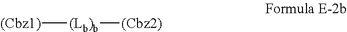

In Formula E-2b, Cbz1 and Cbz2 may be each independently an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}'s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2 below. However, the compounds listed in Compound Group E-2 below are examples, and the compound represented by Formula E-2a or Formula E-2b is not limited to those represented in Compound Group E-2 below.

### Compound Group E-2

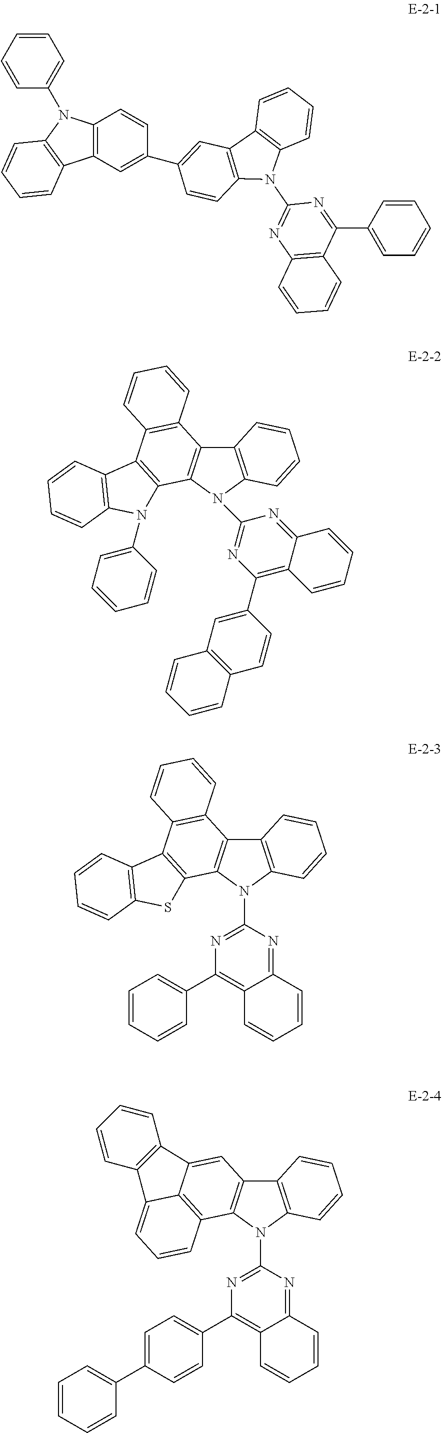

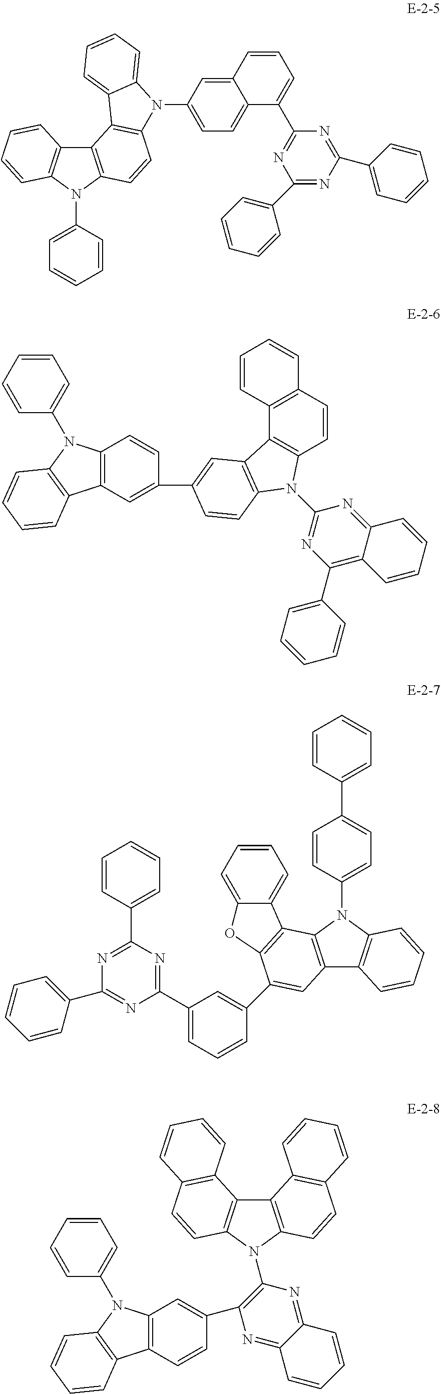 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

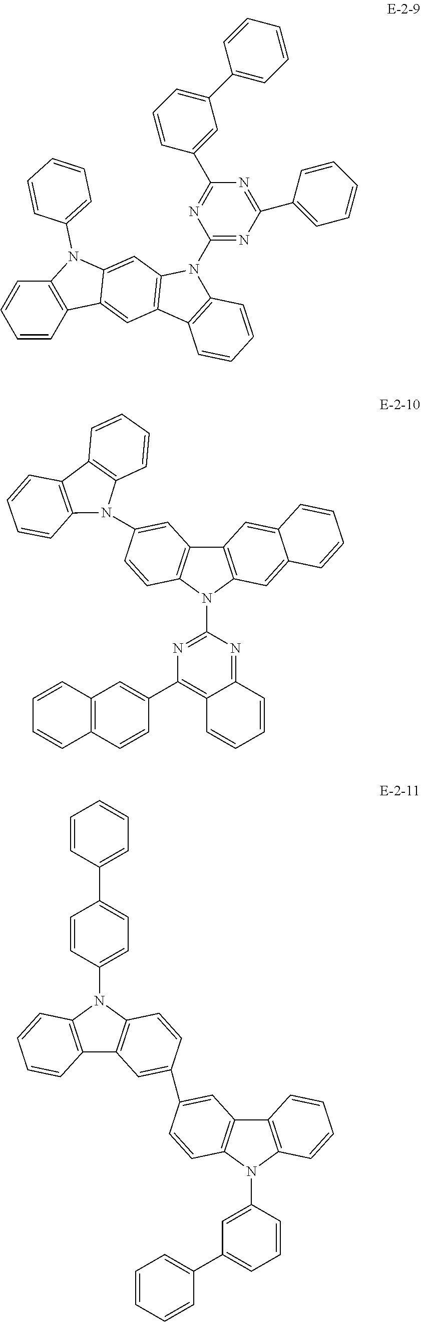 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

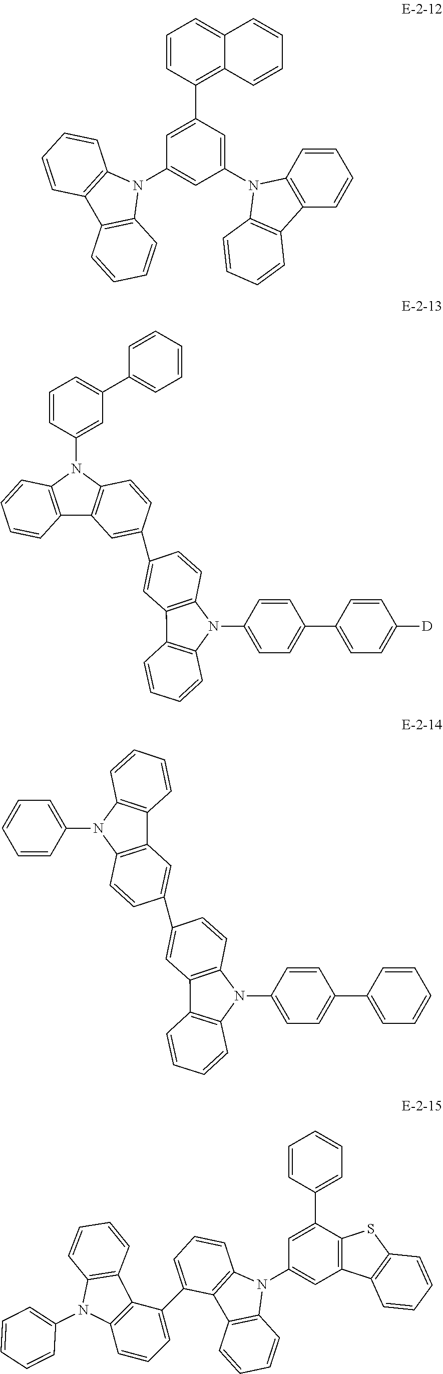 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

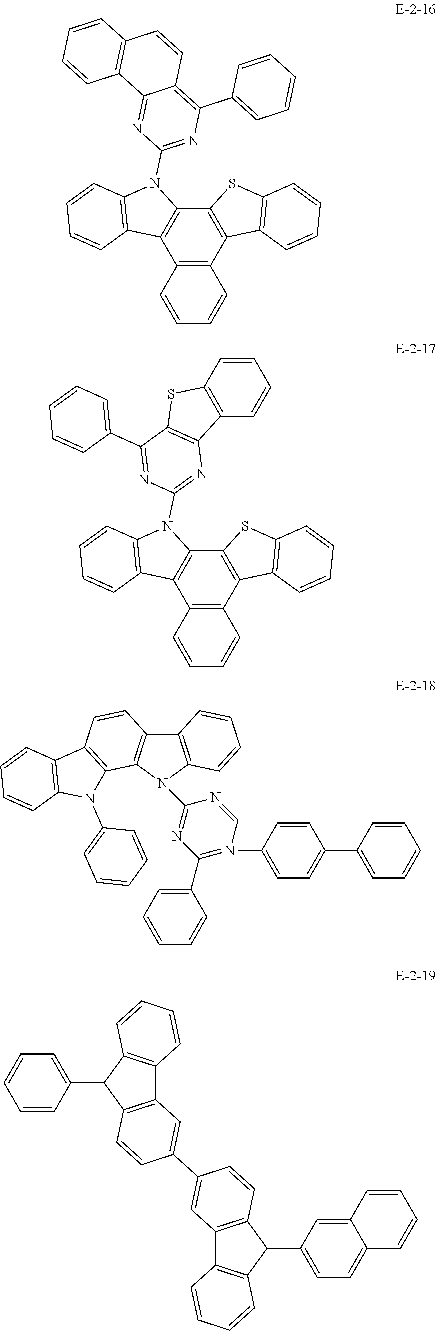

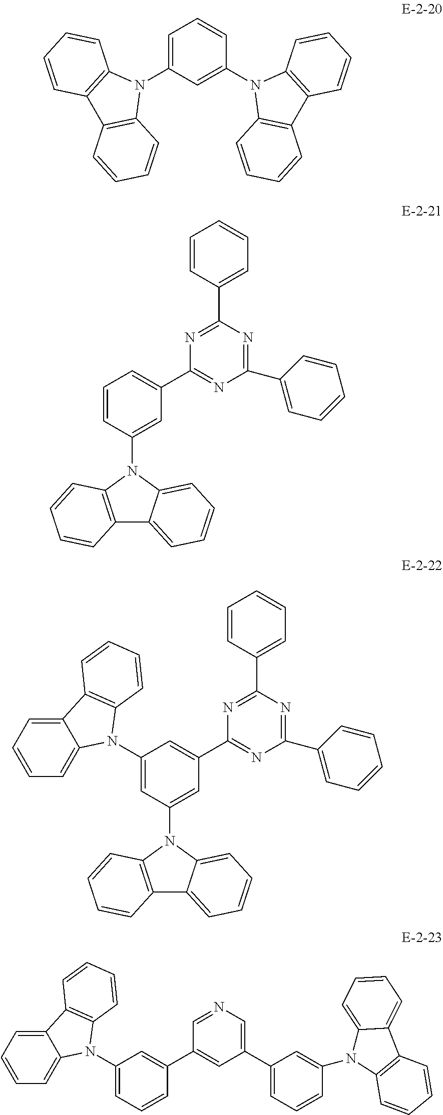 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

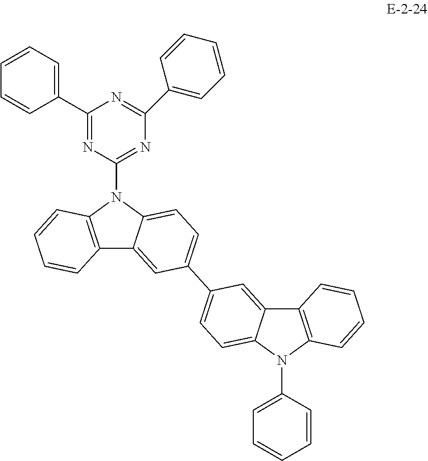 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include any suitable material generally used in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments of the present disclosure are not limited thereto, for example, tris(8-hydroxyquinolino)aluminum (Alq3), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include the compound represented by Formula M-a below. The compound represented by Formula M-a below may be used as a phosphorescent dopant material. In addition, the compound represented by Formula M-a in an embodiment may be used as an auxiliary dopant material.

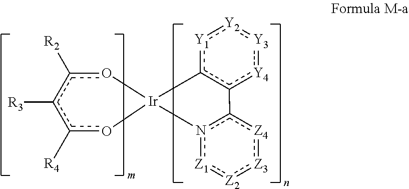

In Formula M-a above, Y₁ to Y₄ and Z₁ to Z₄ may be each independently CR₁ or N, R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be used as a phosphorescent dopant.

The compound represented by Formula M-a may be represented by any one selected from among Compound M-a1 to Compound M-a25 below. However, Compounds M-a1 to M-a25 below are examples, and the compound represented by Formula M-a is not limited to those represented by Compounds M-a1 to M-a25 below.

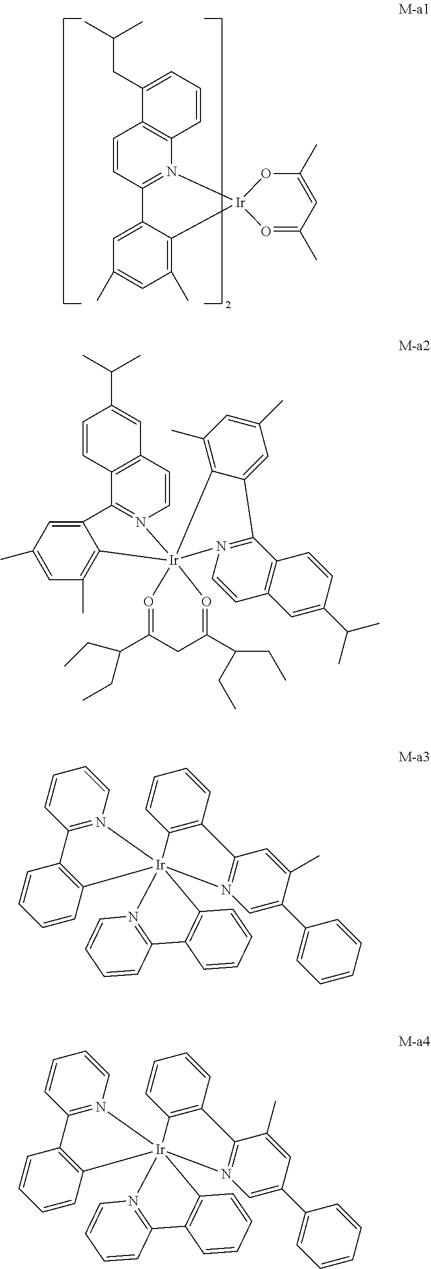

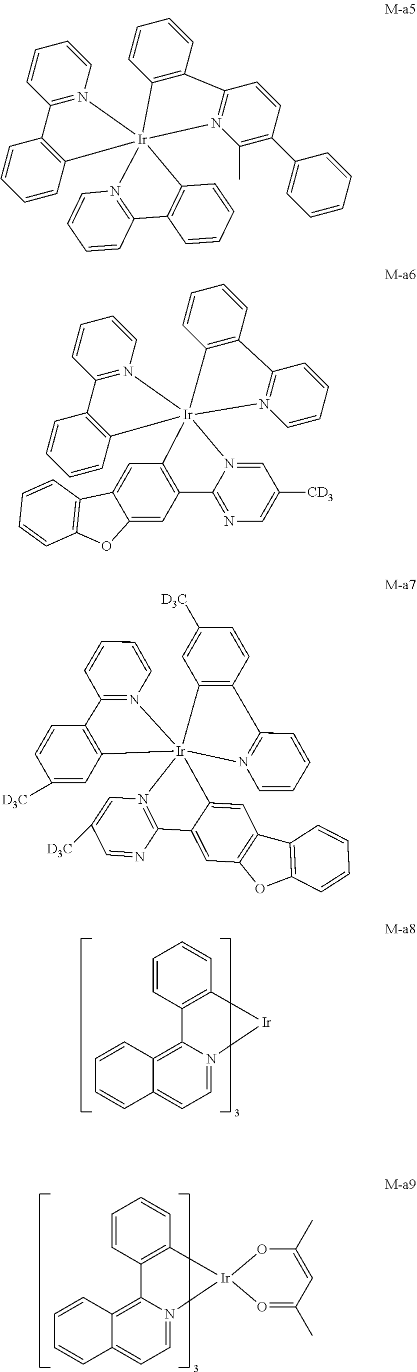

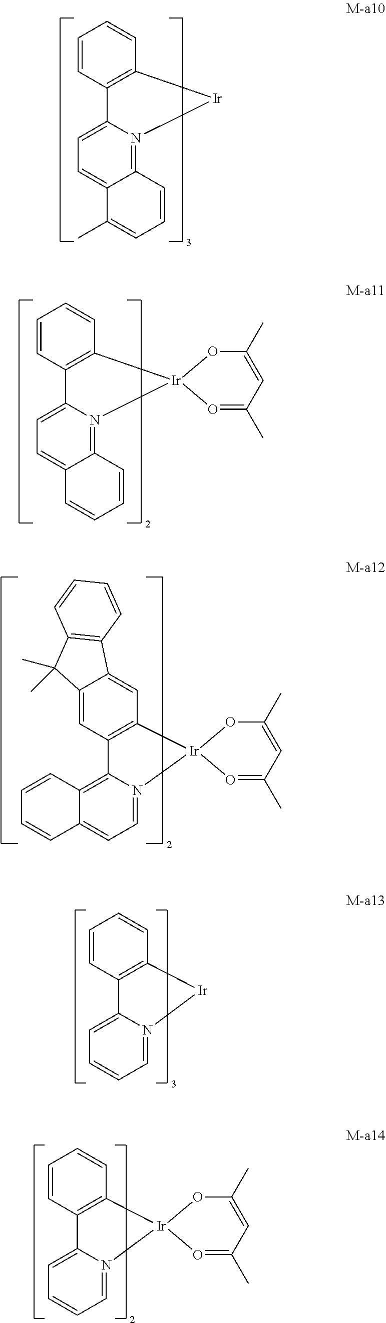

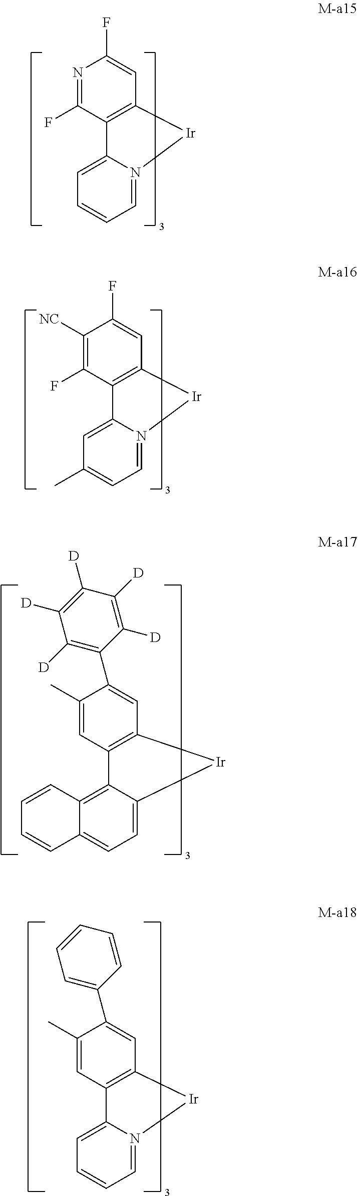

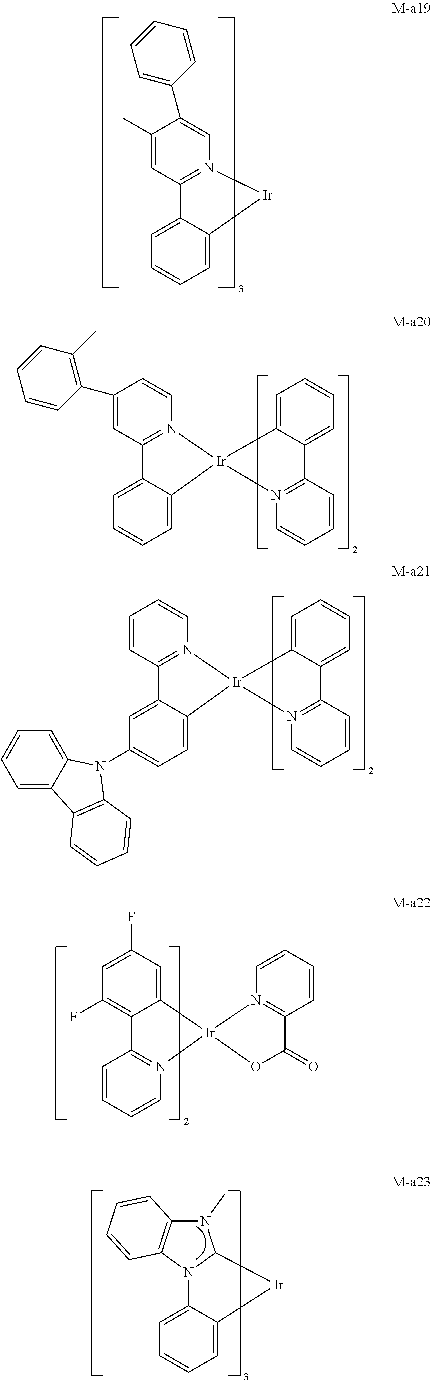

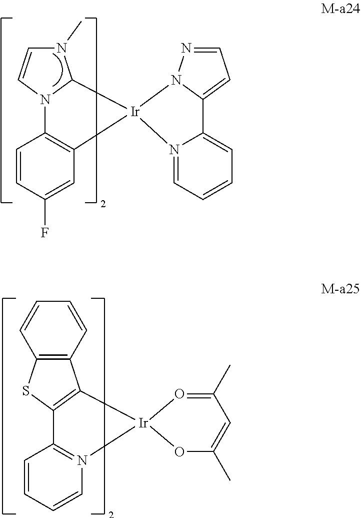

Compound M-a1 and Compound M-a2 may be used as a red dopant material, and Compound M-a3 to Compound M-a7 may be used as a green dopant material.

The emission layer EML may include a compound represented by any one selected from among Formula F-a to Formula F-c below. The compound represented by Formula F-a or Formula F-c below may be used as a fluorescence dopant material.

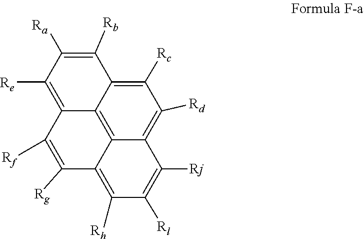

In Formula F-a above, two selected from among Rₐ to Rⱼ may each independently be substituted with *—NAr₁Ar₂. The others, which are not substituted with *—NAr₁Ar₂, selected from among Rₐ to R₁ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

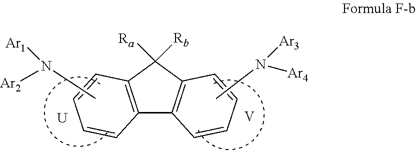

In Formula F-b above, Ra and Rb may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may be each independently a substituted or unsubstituted aryl group having 6 to 30 ring-forming carbon atoms, or a substituted or unsubstituted heteroaryl group having 2 to 30 ring-forming carbon atoms.

In Formula F-b, U and V may be each independently a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may be each independently 0 or 1. For example, in Formula F-b, it means that when the number of U or V is 1, one ring constitutes a fused ring at a portion indicated by U or V, and when the number of U or V is 0, a ring indicated by U or V does not exist (e.g., is not present). In some embodiments, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

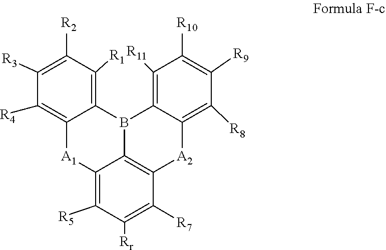

In Formula F-c, A₁ and A₂ may be each independently O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a condensed ring. For example, when A₁ and A₂ are each independently NRₘ, A₁ may be bonded to R₄ or R₅ to form a ring. In some embodiments, A₂ may be bonded to R₇ or R₈ to form a ring.

In an embodiment, the emission layer EML may further include any suitable dopant material. In some embodiments, the emission layer EML may include styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and/or the derivatives thereof (e.g., 2,5,8,11-tetra-t-butylperylene (TBP)), pyrene and/or the derivatives thereof (e.g., 1,1-dipyrene, 1,4-dipyrenylbenzene, 1,4-bis(N,N-diphenylamino)pyrene), etc.

The emission layer EML may further include any suitable phosphorescence dopant material generally used in the art. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. In some embodiments, iridium(III) bis(4,6-difluorophenylpyridinato-N,C2′) (Flrpic), bis(2,4-difluorophenylpyridinato)-tetrakis(1-pyrazolyl)borate iridium(III) (Fir6), and/or platinum octaethyl porphyrin (PtOEP) may be used as a phosphorescence dopant. However, embodiments of the present disclosure are not limited thereto.

The emission layer EML may include a quantum dot material. The core of the quantum dot may be selected from a Group II-VI compound, a Group III-VI compound, a Group I-III-IV compound, a Group III-V compound, a Group III-II-V compound, a Group IV-VI compound, a Group IV element, a Group IV compound, or a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, a binary compound, a ternary compound, or a quaternary compound may be present in a particle with a uniform (e.g., substantially uniform) concentration distribution, or may be present in the same particle with a partially different concentration distribution. In addition, a core/shell structure in which one quantum dot surrounds another quantum dot may also be possible. The core/shell structure may have a concentration gradient in which the concentration of elements presented in the shell decreases along a direction toward the core.

In some embodiments, the quantum dot may have the above-described core/shell structure including a core containing nanocrystals and a shell surrounding the core. The shell of the quantum dot may serve as a protection layer to prevent or reduce chemical deformation of the core to maintain semiconductor properties, and/or a charging layer to impart electrophoresis properties to the quantum dot. The shell may be a single layer or a multilayer. An example of the shell of the quantum dot may include a metal and/or non-metal oxide, a semiconductor compound, or a combination thereof.

For example, the metal and/or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAl₂O₄, CoFe₂O₄, NiFe₂O₄, and/or CoMn₂O₄, but embodiments of the present disclosure are not limited thereto.

Also, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have a full width of half maximum (FWHM) of a light emitting wavelength spectrum of about 45 nm or less, about 40 nm or less, or, for example, about 30 nm or less, and color purity and/or color reproducibility may be improved in the above range. In addition, light emitted through such a quantum dot is emitted in all directions, and thus, a wide viewing angle may be improved.

In addition, the form of a quantum dot is not particularly limited. For example, the quantum dot may have any suitable form generally used in the art. In some embodiments, a quantum dot in the form of spherical, pyramidal, multi-arm, and/or cubic nanoparticles, nanotubes, nanowires, nanofibers, nanoparticles, etc. may be used.

A quantum dot may control the color of emitted light according to the particle size thereof, and thus, the quantum dot may have various suitable light emission colors such as green, red, etc.

In each light emitting element ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In addition, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but embodiments of the present disclosure are not limited thereto. The electron transport region ETR may have a thickness, for example, from about 1,000 Å to about 1,500 Å.

The electron transport region ETR may be formed by using various suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-2 below:

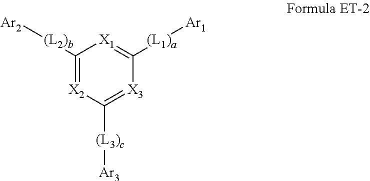

In Formula ET-2, at least one selected from among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may be each independently an integer of 0 to 10. In Formula ET-2, L₁ to L₃ may be each independently a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are an integer of 2 or more, L₁ to L₃ may be each independently a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments of the present disclosure are not limited thereto, and the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1-biphenyl-4-olato)aluminum (BAlq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

The electron transport region ETR may include at least one selected from among Compound ET1 to Compound ET36 below:

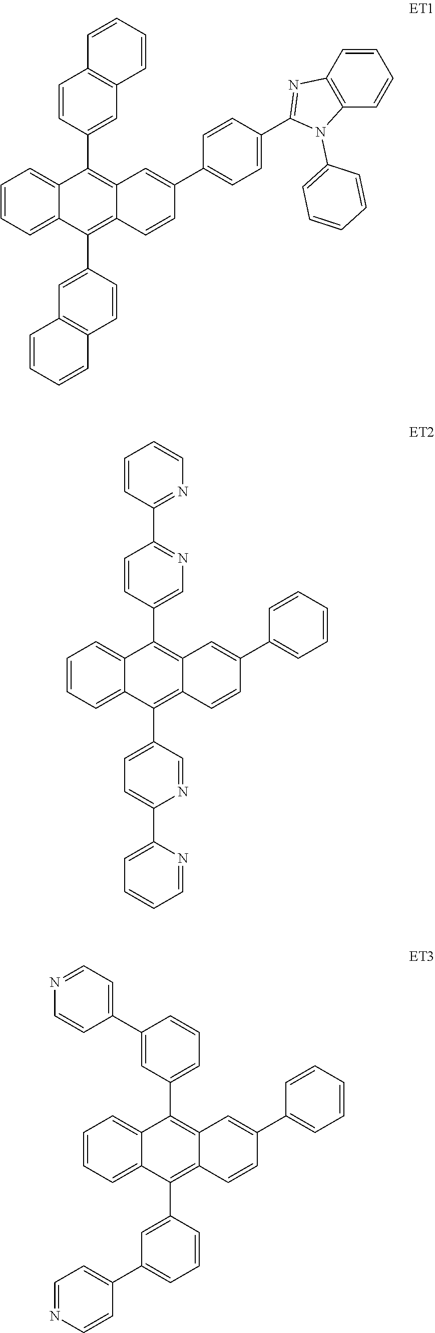 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

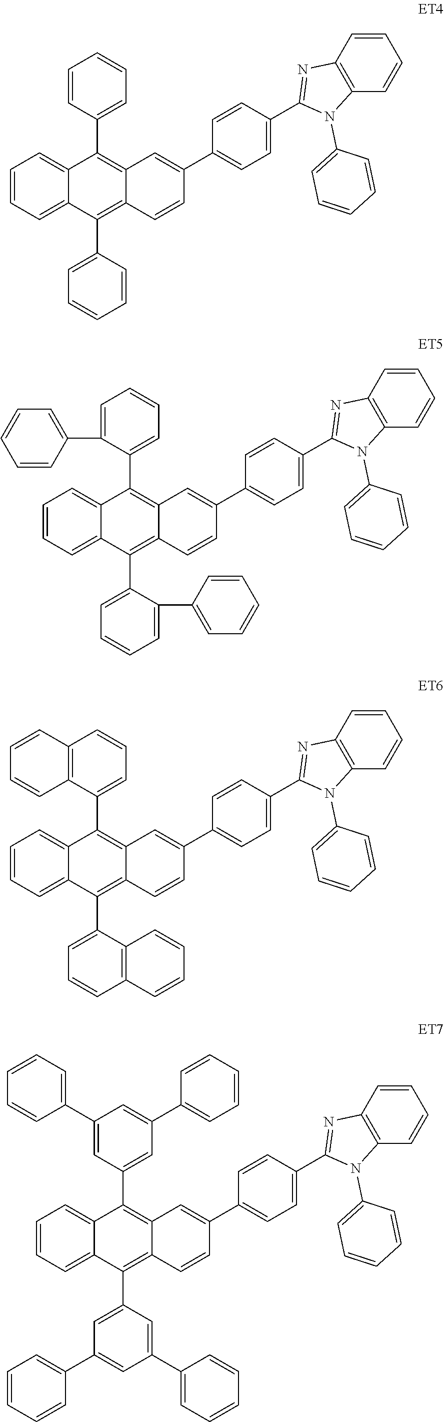 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

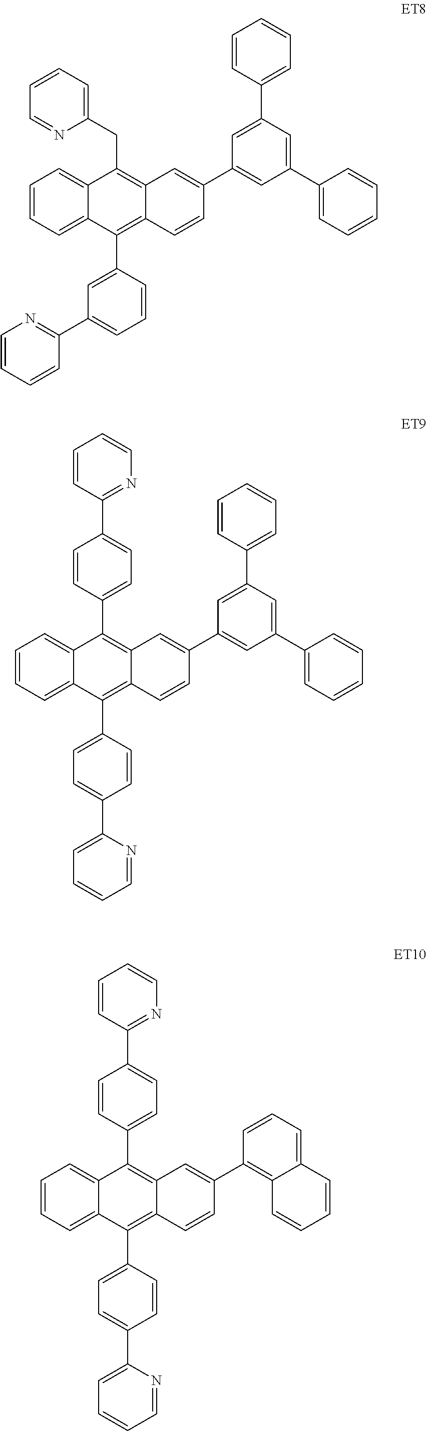 [SMILES: c1ccc(-c2cc(-c3ccccc3)cc(-c3ccc4c(-c5cccc(-c6ccccn6)c5)c5ccccc5c(Cc5ccccn5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

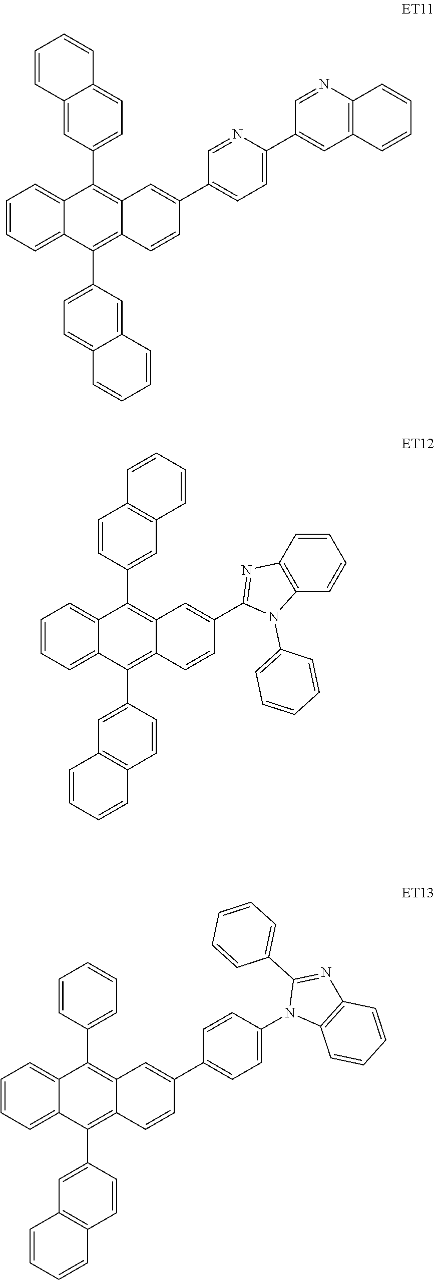 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

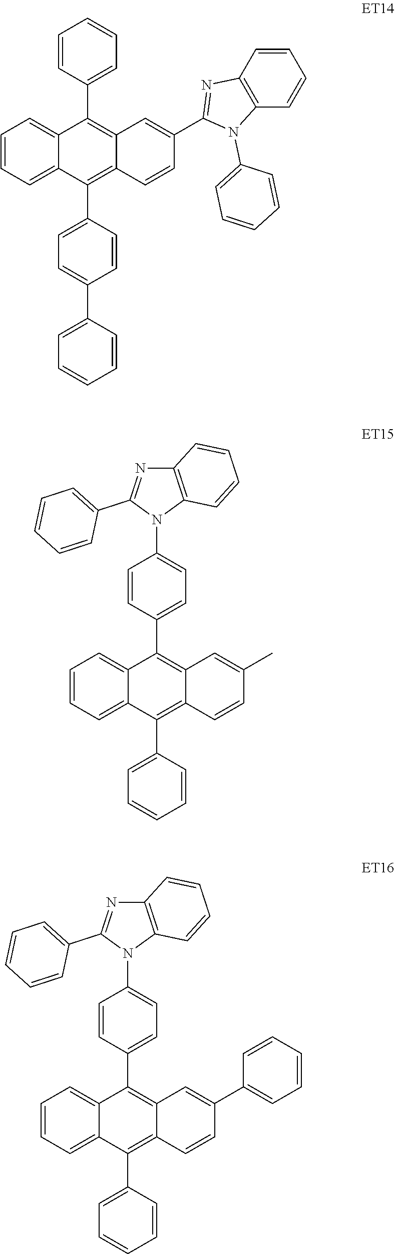 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

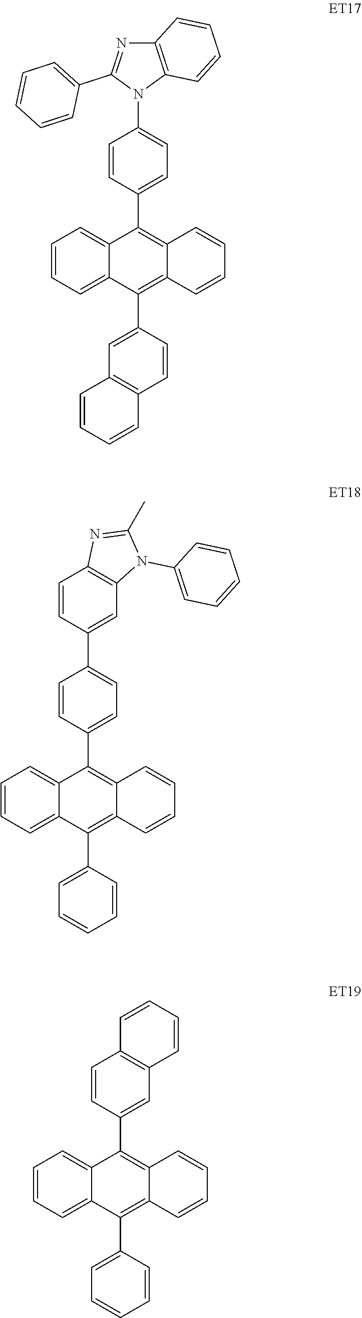

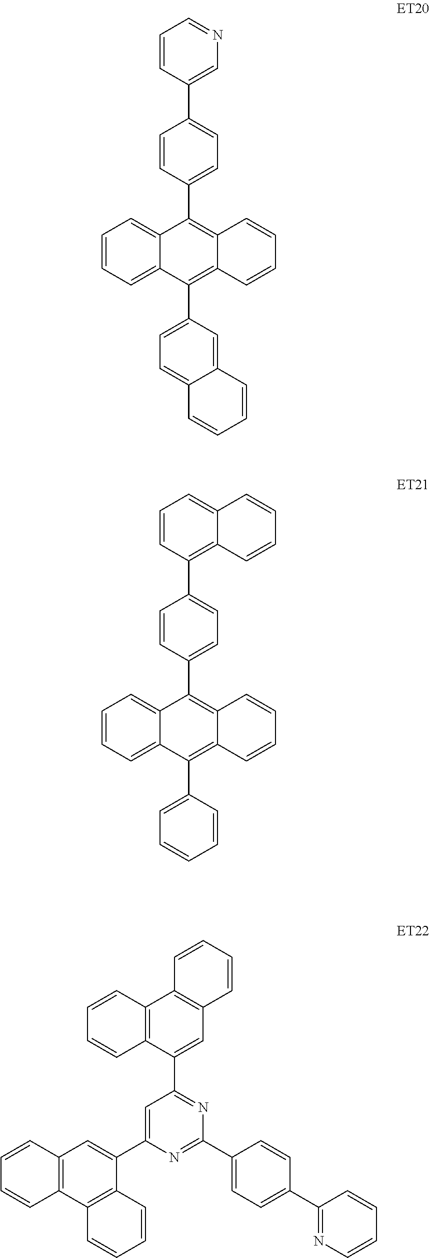

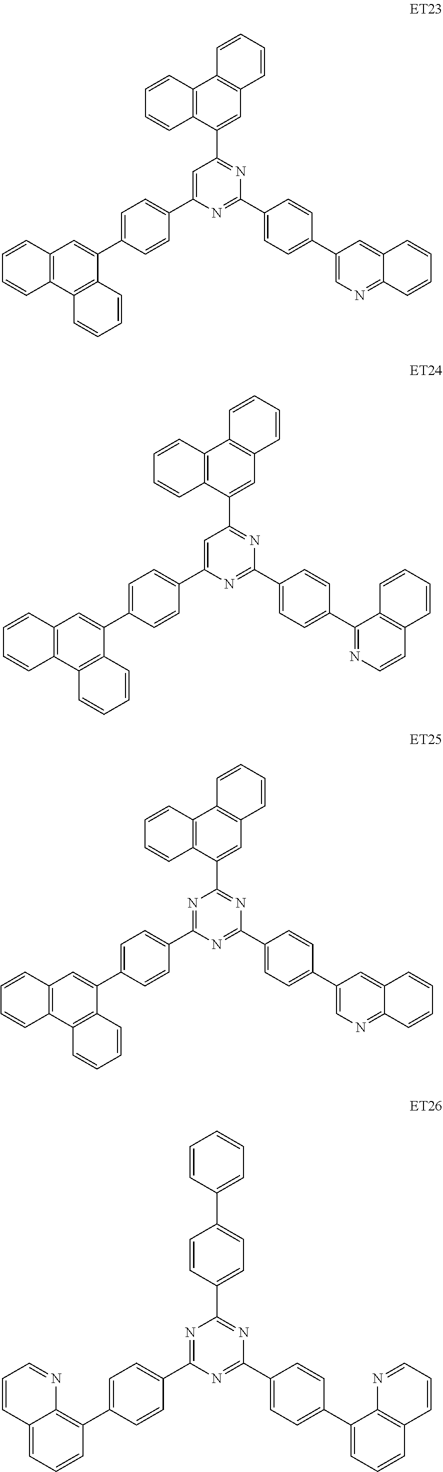 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5ccc(-c6cc7ccccc7c7ccccc67)cc5)cc(-c5cc6ccccc6c6ccccc56)n4)cc3)nccc2c1 ; c1ccc2ncc(-c3ccc(-c4nc(-c5ccc(-c6cc7ccccc7c7ccccc67)cc5)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

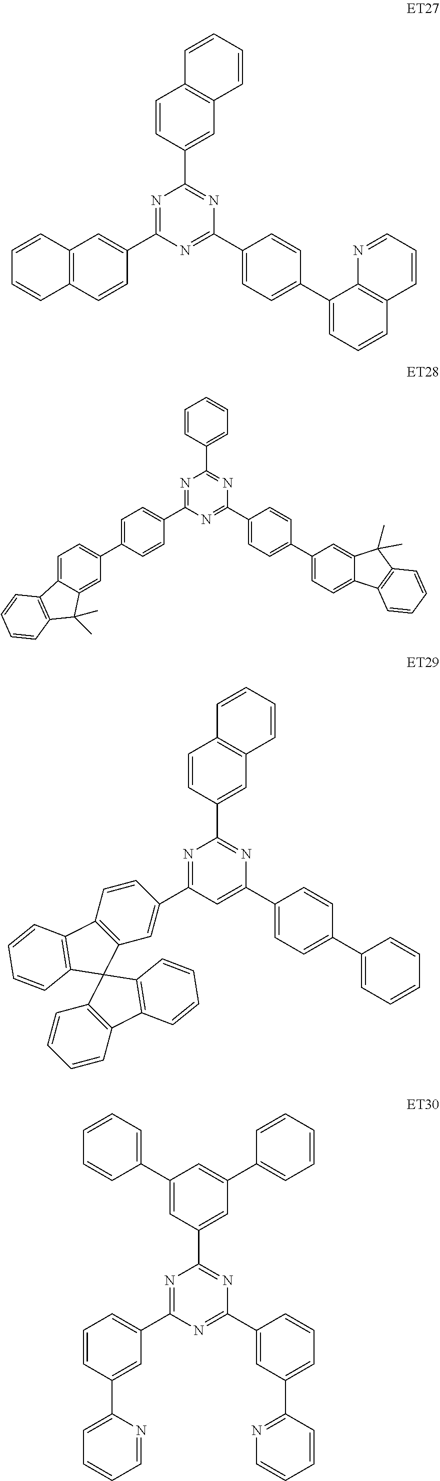 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

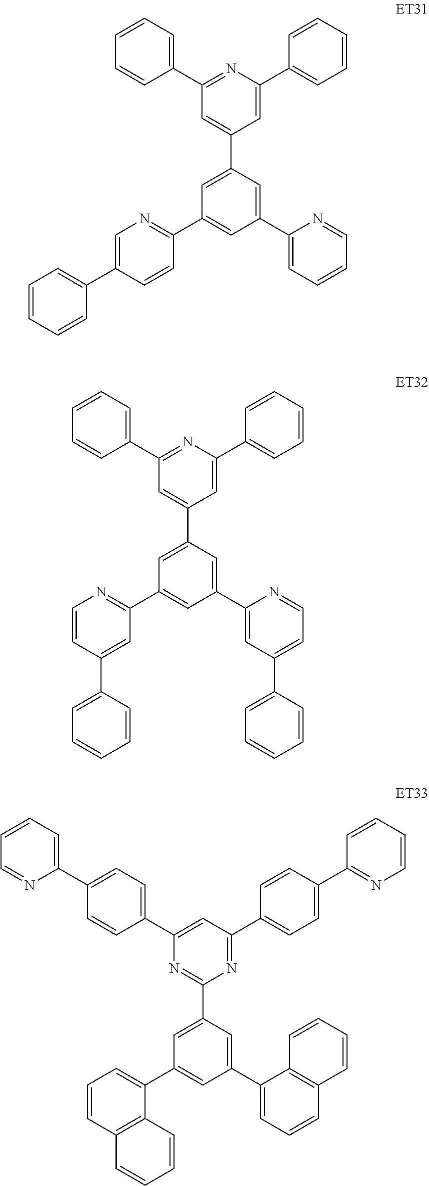 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

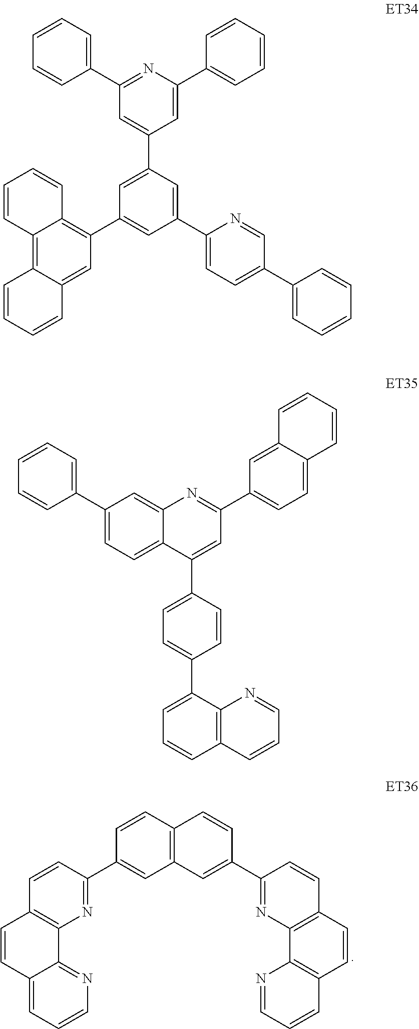 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In addition, the electron transport regions ETR may include a metal halide such as LiF, NaCl, CsF, RbCl, RbI, CuI, and/or KI, a lanthanide metal such as Yb, and/or a co-deposited material of the metal halide and the lanthanide metal. For example, the electron transport region ETR may include KI:Yb, RbI:Yb, LiF:Yb, etc. as a co-deposited material. In some embodiments, the electron transport region ETR may be formed using a metal oxide such as Li₂O and/or BaO, and/or 8-hydroxyl-lithium quinolate (Liq), etc., but embodiments of the present disclosure are not limited thereto. The electron transport region ETR may also be formed of a mixture material of an electron transport material and an insulating organometallic salt. The organometallic salt may be a material having an energy band gap of about 4 eV or more. For example, the organometallic salt may include, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments of the present disclosure are not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, suitable or satisfactory electron transport characteristics may be obtained without a substantial increase in a driving voltage. When the electron transport region ETR includes the electron injection layer EIL, the electron injection layer EIL may have a thickness of about 1 Å to about 100 Å, for example, about 3 Å to about 90 Å. If the thickness of the electron injection layer EIL satisfies the above-described range, suitable or satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second electrode EL2 may be a cathode, and when the first electrode EL1 is a cathode, the second electrode EL2 may be an anode. The second electrode may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, Yb, W, and/or a compound or mixture including these (e.g., AgMg, AgYb, or MgYb). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, and/or the like.

In some embodiments, the second electrode EL2 may be connected with an auxiliary electrode. If the second electrode EL2 is connected with the auxiliary electrode, the resistance of the second electrode EL2 may be decreased.

In some embodiments, a capping layer CPL may further be on the second electrode EL2 of the light emitting element ED of an embodiment. The capping layer CPL may include a multilayer or a single layer.

In an embodiment, the capping layer CPL may be an organic layer and/or an inorganic layer. For example, when the capping layer CPL contains an inorganic material, the inorganic material may include an alkaline metal compound (for example, LiF), an alkaline earth metal compound (for example, MgF₂), SiON, SiNₓ, SiO_{y}, etc.

For example, when the capping layer CPL contains an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol sol-9-yl)triphenylamine (TCTA), etc., and/or may include an epoxy resin, and/or an acrylate such as a methacrylate. However, embodiments of the present disclosure are not limited thereto, and the capping layer CPL may include at least one selected from among Compounds P1 to P5 below:

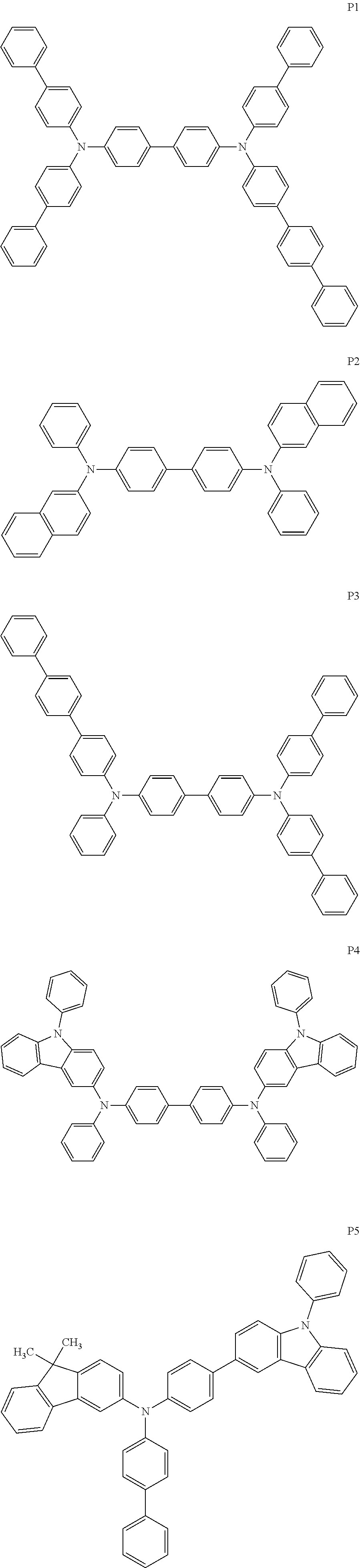 [SMILES: c1ccc(-c2ccc(-c3ccc(N(c4ccc(-c5ccccc5)cc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be about 1.6 or more with respect to light in a wavelength range of about 550 nm to about 660 nm.

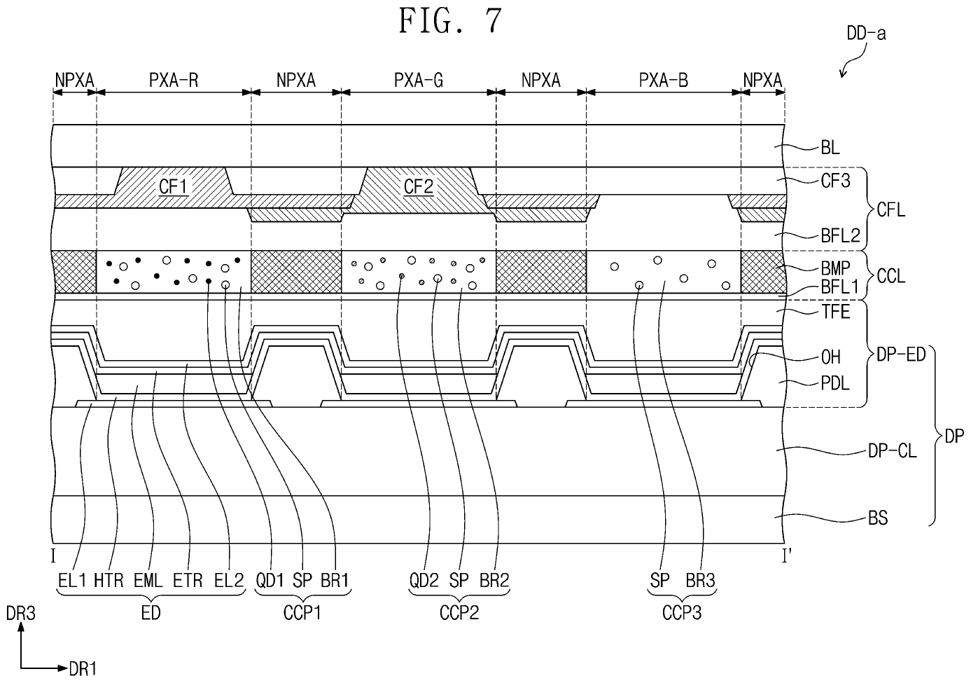

Each of FIGS. 7 to 10 is a cross-sectional view of a display device according to an embodiment of the present disclosure. Hereinafter, in describing the display devices of embodiments with reference to FIGS. 7 to 10, the duplicated features which have been described in FIGS. 1 to 6 are not described again, but their differences will be mainly described.

Referring to FIG. 7, the display device DD-a according to an embodiment may include a display panel DP including a display element layer DP-ED, a light control layer CCL on the display panel DP, and a color filter layer CFL.

In an embodiment illustrated in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR on the first electrode EL1, an emission layer EML on the hole transport region HTR, an electron transport region ETR on the emission layer EML, and a second electrode EL2 on the electron transport region ETR. In some embodiments, the structures of the light emitting elements of FIGS. 3 to 6 as described above may be equally applied to the structure of the light emitting element ED illustrated in FIG. 7.

The emission layer EML of the light emitting element ED included in the display device DD-a according to an embodiment may include the first compound and at least one of the second compound, the third compound, or the fourth compound of an embodiment as described above.

Referring to FIG. 7, the emission layer EML may be in an opening OH defined in a pixel defining film PDL. For example, the emission layer EML which is divided by the pixel defining film PDL and provided corresponding to each light emitting regions PXA-R, PXA-G, and PXA-B may emit light in the same (e.g., substantially the same) wavelength range. In the display device DD-a of an embodiment, the emission layer EML may emit blue light. Unlike the configuration illustrated, in an embodiment, the emission layer EML may be provided as a common layer in the entire light emitting regions PXA-R, PXA-G, and PXA-B.

The light control layer CCL may be on the display panel DP. The light control layer CCL may include a light conversion body. The light conversion body may be a quantum dot, a phosphor, and/or the like. The light conversion body may emit provided light by converting the wavelength thereof. In some embodiments, the light control layer CCL may include a layer containing the quantum dot and/or a layer containing the phosphor.

The light control layer CCL may include a plurality of light control parts CCP1, CCP2, and CCP3. The light control parts CCP1, CCP2, and CCP3 may be spaced apart from each other.

Referring to FIG. 7, divided patterns BMP may be between the light control parts CCP1, CCP2, and CCP3 which are spaced apart from each other, but embodiments of the present disclosure are not limited thereto. FIG. 7 illustrates that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 which converts a first color light provided from the light emitting element ED into a second color light, a second light control part CCP2 containing a second quantum dot QD2 which converts the first color light into a third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The same as described above may be applied with respect to the quantum dots QD1 and QD2.

In addition, the light control layer CCL may further include a scatterer SP (e.g., a light scatterer SP). The first light control part CCP1 may include the first quantum dot QD1 and the scatterer SP, the second light control part CCP2 may include the second quantum dot QD2 and the scatterer SP, and the third light control part CCP3 may not include any suitable quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of various suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce penetration of moisture and/or oxygen (hereinafter, referred to as ‘moisture/oxygen’). The barrier layer BFL1 may be on the light control parts CCP1, CCP2, and CCP3 to block or reduce exposure of the light control parts CCP1, CCP2, and CCP3 to moisture/oxygen. In some embodiments, the barrier layer BFL1 may cover the light control parts CCP1, CCP2, and CCP3. In addition, the barrier layer BFL2 may be provided between the light control parts CCP1, CCP2, and CCP3 and the color filter layer CFL.

The barrier layers BFL1 and BFL2 may include at least one inorganic layer. In some embodiments, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, and/or a metal thin film which secures a transmittance, etc. In some embodiments, the barrier layers BFL1 and BFL2 may further include an organic film. The barrier layers BFL1 and BFL2 may be formed of a single layer or a plurality of layers.

In the display device DD-a of an embodiment, the color filter layer CFL may be on the light control layer CCL. For example, the color filter layer CFL may be directly on the light control layer CCL. In this case, the barrier layer BFL2 may be omitted.

The color filter layer CFL may include filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye. Embodiments of the present disclosure are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but be provided as one filter. The first to third filters CF1, CF2, and CF3 may correspond to the red light emitting region PXA-R, the green light emitting region PXA-G, and the blue light emitting region PXA-B, respectively.

In some embodiments, the color filter layer CFL may include a light shielding part. The color filter layer CFL may include a light shielding part that overlaps at the boundaries of neighboring filters CF1, CF2, and CF3. The light shielding part may be a black matrix. The light shielding part BM may include an organic light shielding material and/or an inorganic light shielding material containing a black pigment and/or dye. The light shielding part may separate boundaries between the adjacent filters CF1, CF2, and CF3. In addition, in an embodiment, the light shielding part may be formed of a blue filter.

A base substrate BL may be on the color filter layer CFL. The base substrate BL may be a member which provides a base surface in which the color filter layer CFL, the light control layer CCL, and the like are located. The base substrate BL may be a glass substrate, a metal substrate, a plastic substrate, etc. However, embodiments of the present disclosure are not limited thereto, and the base substrate BL may be an inorganic layer, an organic layer, or a composite material layer. In addition, unlike the configuration illustrated, in an embodiment, the base substrate BL may be omitted.

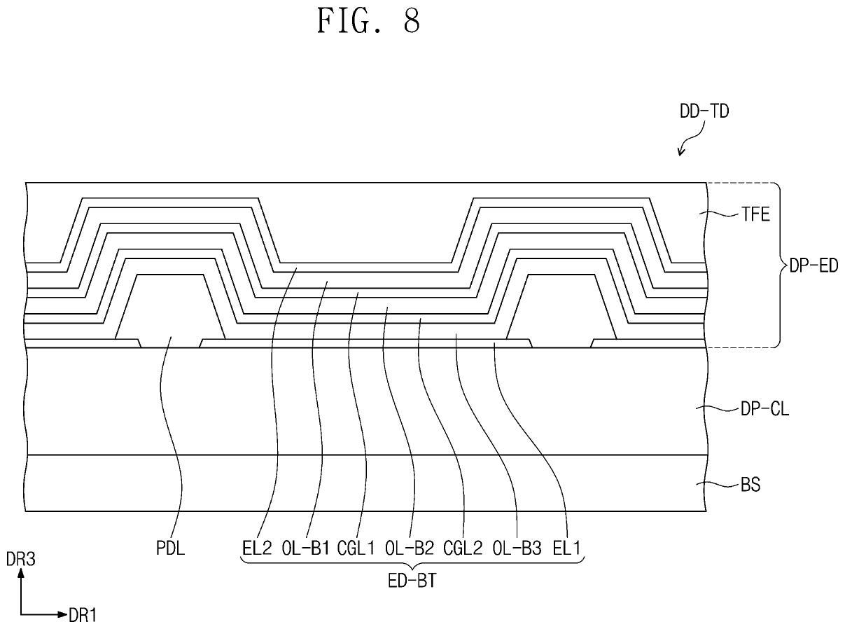

FIG. 8 is a cross-sectional view illustrating a portion of a display device according to an embodiment of the present disclosure. FIG. 8 illustrates a cross-sectional view of another embodiment of a part corresponding to the display panel DP of FIG. 7. In the display device DD-TD of an embodiment, the light emitting element ED-BT may include a plurality of light emitting structures OL-B1, OL-B2, and OL-B3. The light emitting element ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR together with the emission layer EML (FIG. 7) located therebetween.

In some embodiments, the light emitting element ED-BT included in the display device DD-TD of an embodiment may be a light emitting element having a tandem structure and including a plurality of emission layers.

In an embodiment illustrated in FIG. 8, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from each other. For example, the light emitting element ED-BT including the plurality of light emitting structures OL-B1, OL-B2, and OL-B3 which emit light beams having wavelength ranges different from each other may emit white light.

Charge generation layers CGL1 and CGL2 may be respectively between two of the neighboring light emitting structures OL-B1, OL-B2, and OL-B3. The charge generation layers CGL1 and CGL2 may include a p-type charge generation layer and/or an n-type charge generation layer.

At least one selected from among the light emitting structures OL-B1, OL-B2, and OL-B3 included in the display device DD-TD of an embodiment may include the first compound and at least one of the second compound, the third compound, or the fourth compound of an embodiment as described above.

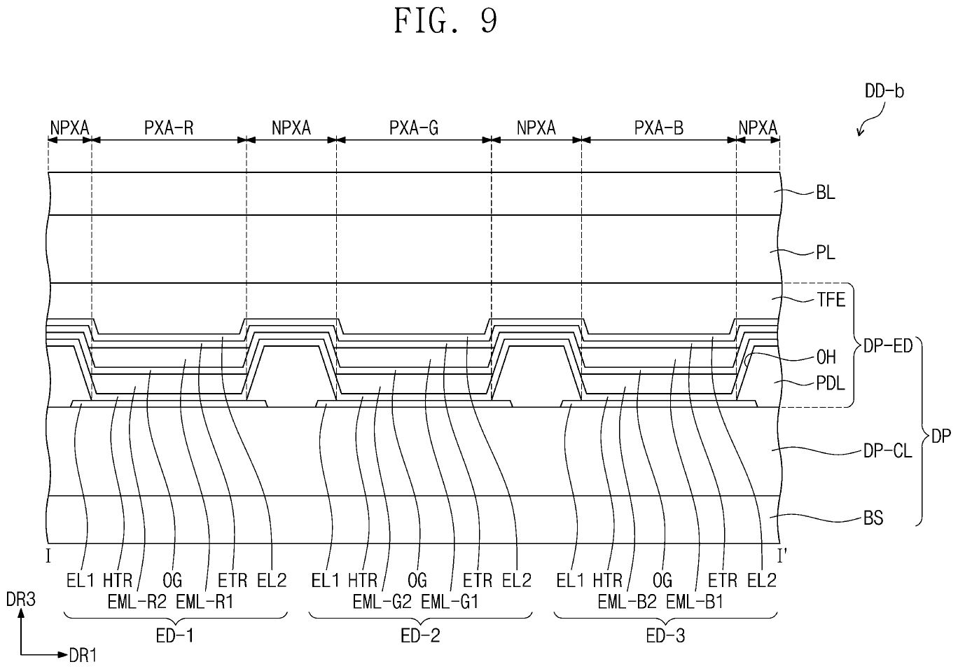

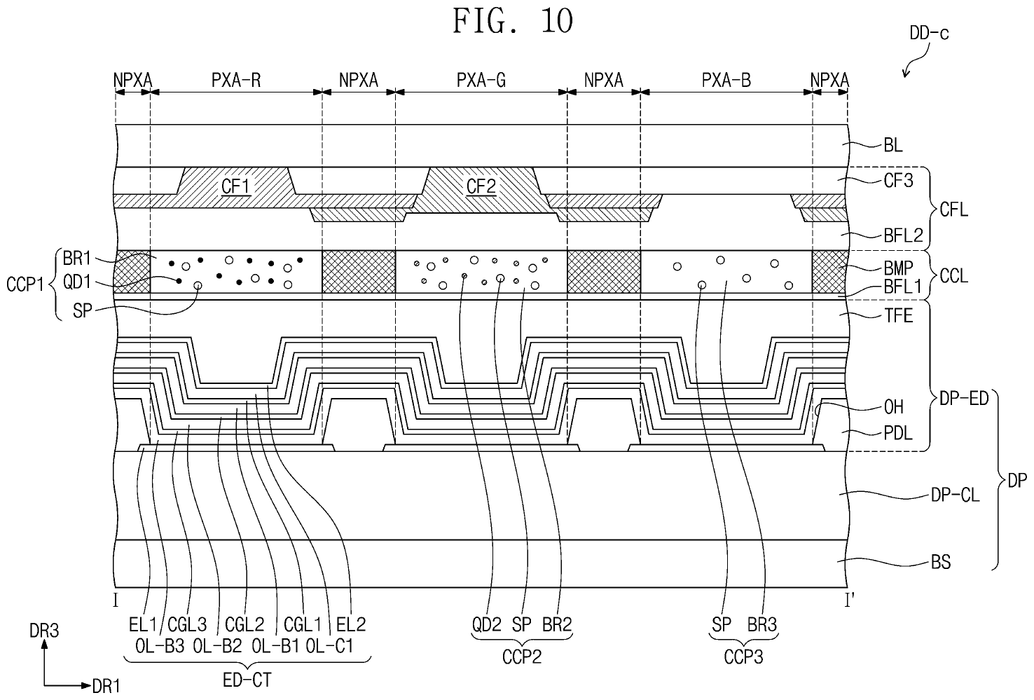

Referring to FIG. 9, the display device DD-b according to an embodiment may include light emitting elements ED-1, ED-2, and ED-3 in which two emission layers are stacked. Compared with the display device DD of an embodiment illustrated in FIG. 2, an embodiment illustrated in FIG. 10 has a difference in that the first to third light emitting elements ED-1, ED-2, and ED-3 each include two emission layers stacked in the thickness direction. In each of the first to third light emitting elements ED-1, ED-2, and ED-3, the two emission layers may emit light in the same (e.g., substantially the same) wavelength region.

The first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light emitting elements ED-1, ED-2, and ED-3. However, embodiments of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be between the electron transport region ETR and the emission auxiliary part OG. The second red emission layer EML-R2, the second green emission layer EML-G2, and the second blue emission layer EML-B2 may be between the emission auxiliary part OG and the hole transport region HTR.

That is, the first light emitting element ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting element ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting element ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be on the display element layer DP-ED. The optical auxiliary layer PL may include a polarizing layer. The optical auxiliary layer PL may be on the display panel DP and control reflected light in the display panel DP due to external light. Unlike the configuration illustrated, the optical auxiliary layer PL in the display device according to an embodiment may be omitted.

Unlike FIGS. 8 and 9, FIG. 10 illustrates that a display device DD-c includes four light emitting structures OL-B1, OL-B2, OL-B3, and OL-C1. A light emitting element ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, embodiments of the present disclosure are not limited thereto, and the first to fourth light emitting structures OL-B1, OL-B2, OL-B3, and OL-C1 may emit light beams in different wavelength regions.

The charge generation layers CGL1, CGL2, and CGL3 between adjacent light emitting structures OL-B1, OL-B2, OL-B3, and OL-C1 may include a p-type charge generation layer and/or an n-type charge generation layer.

At least one selected from among the light emitting structures OL-B1, OL-B2, OL-B3, and OL-C1 included in the display device DD-c of an embodiment may include the first compound and at least one of the second compound, the third compound, or the fourth compound of an embodiment as described above.

The light emitting element ED according to an embodiment of the present disclosure may include the above-described first compound of an embodiment in at least one of the hole transport region HTR between the first electrode EL1 and the second electrode EL2, the emission layer EML, or the electron transport region ETR, and/or in a capping layer CPL.

For example, the first compound according to an embodiment may be included in the emission layer EML of the light emitting element ED of an embodiment, and the light emitting element of an embodiment may exhibit high efficiency and long service life characteristics.

The above-described first compound of an embodiment has an electron donor substituent at the para-position of a boron atom, which may increase the photoluminescence quantum yield (PLQY) and oscillator strength (f). Accordingly, the first compound of an embodiment according to the present disclosure may have stronger binding stability, thereby keeping excellent PLQY and oscillator strength and improving the element service life.

Hereinafter, with reference to Examples and Comparative Examples, a polycyclic compound used as the first compound according to an embodiment of the present disclosure and a light emitting element of an embodiment of the present disclosure will be described in more detail. In addition, Examples described below are only illustrations to assist the understanding of the subject matter of the present disclosure, and the scope of the present disclosure is not limited thereto.

### Examples

### 1. Synthesis of Polycyclic Compound of Example

First, a synthetic method of a polycyclic compound according to the current embodiment will be described in more detail by illustrating synthetic methods of Compounds A-20, B-15, C-10, D-20, E-2 and E-4. In addition, in the following descriptions, the synthetic methods of the polycyclic compounds are provided as examples, but the synthetic method according to an embodiment of the present disclosure is not limited to Examples below.

### (1) Synthesis of Compound A-20

Polycyclic Compound A-20 according to an example may be synthesized by, for example, the steps shown in Reaction Scheme 1 below:

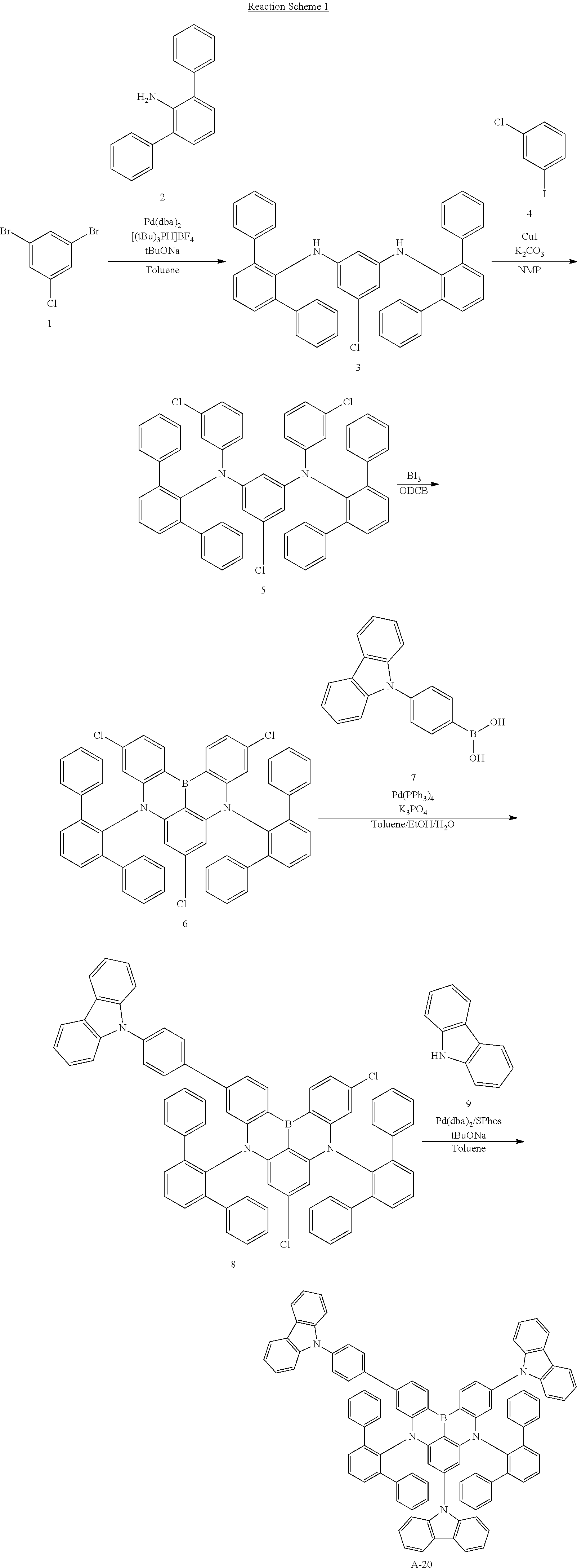

1) In a three-necked flask, Compound 1-b (150 mmol), Compound 2 (300 mmol), tBuONa (450 mmol), Pd(dba)₂ (15 mmol), and [(tBu)₃PH]BF₄ (30 mmol) were added, purging with Ar was performed, then 1,000 mL of toluene was added thereto, and the resulting mixture was stirred at about 60° C. for about 3 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (129 mmol, yield 86%). By fast atom bombardment-mass spectrometry (FAB-MS) measurement of the obtained purified product, it was identified that the molecular weight was 599, thereby identifying Compound 3.

2) Then, in a three-necked flask, Compound 3 (129 mmol), Compound 4 (1290 mmol), K₂CO₃ (645 mmol), and CuI (141 mmol) were added, purging with Ar was performed, 50 mL of N-methyl-2-pyrrolidone (NMP) was added thereto to dissolve the resulting mixture, and then the resulting mixture was stirred at about 190° C. for about 50 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (92 mmol, yield 71%). By FAB-MS measurement of the obtained purified product, it was identified that the molecular weight was 820, thereby identifying Compound 5.

3) In a three-necked flask, Compound 5 (92 mmol) was added, purging with Ar was performed, 200 mL of orthodichlorobenzene (ODCB) was added, BI₃ (366 mmol) was added thereto to dissolve the resulting mixture, and then the resulting mixture was stirred at about 180° C. for about 6 hours. The reaction solution was subjected to dispersion washing with a large number of acetonitrile, and then solids were recovered by filtration. The resulting crude product was purified by silica gel column chromatography (a mixed solvent of hexane/dichloromethane=2/1) and recrystallization (a mixed solvent of ethanol/toluene=5/1) to obtain yellow solids (17 mmol, yield 19%). By FAB-MS measurement of the obtained purified product, it was identified that the molecular weight was 828, thereby identifying Compound 6.

4) In a three-necked flask, Compound 6 (17 mmol), Compound 7 (17 mmol), K₃PO₄ (32 mmol), and Pd(PPh₃)₄ (2 mmol) were added, purging with Ar was performed, 100 mL of toluene, 10 mL of EtOH, and 10 mL of H₂O were added thereto, and the resulting mixture was stirred at about 80° C. for about 2 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain yellow solids (7 mmol, yield 33%). By FAB-MS measurement of the obtained purified product, it was identified that the molecular weight was 1034, thereby identifying Compound 8.

5) In a three-necked flask, Compound 8 (7 mmol), Compound 9 (14 mmol), tBuONa (28 mmol), Pd(dba)₂ (3 mmol), and SPhos (6 mmol) were added, purging with Ar was performed, then 60 mL of toluene was added thereto, and the resulting mixture was stirred at about 100° C. for about 8 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain yellow solids (6 mmol, yield 86%). By FAB-MS measurement of the obtained purified product, it was identified that the molecular weight was 1296, thereby identifying Compound A-20.

### (2) Synthesis of Compound B-15

Polycyclic Compound B-15 according to an example may be synthesized by, for example, the steps shown in Reaction Scheme 2 below:

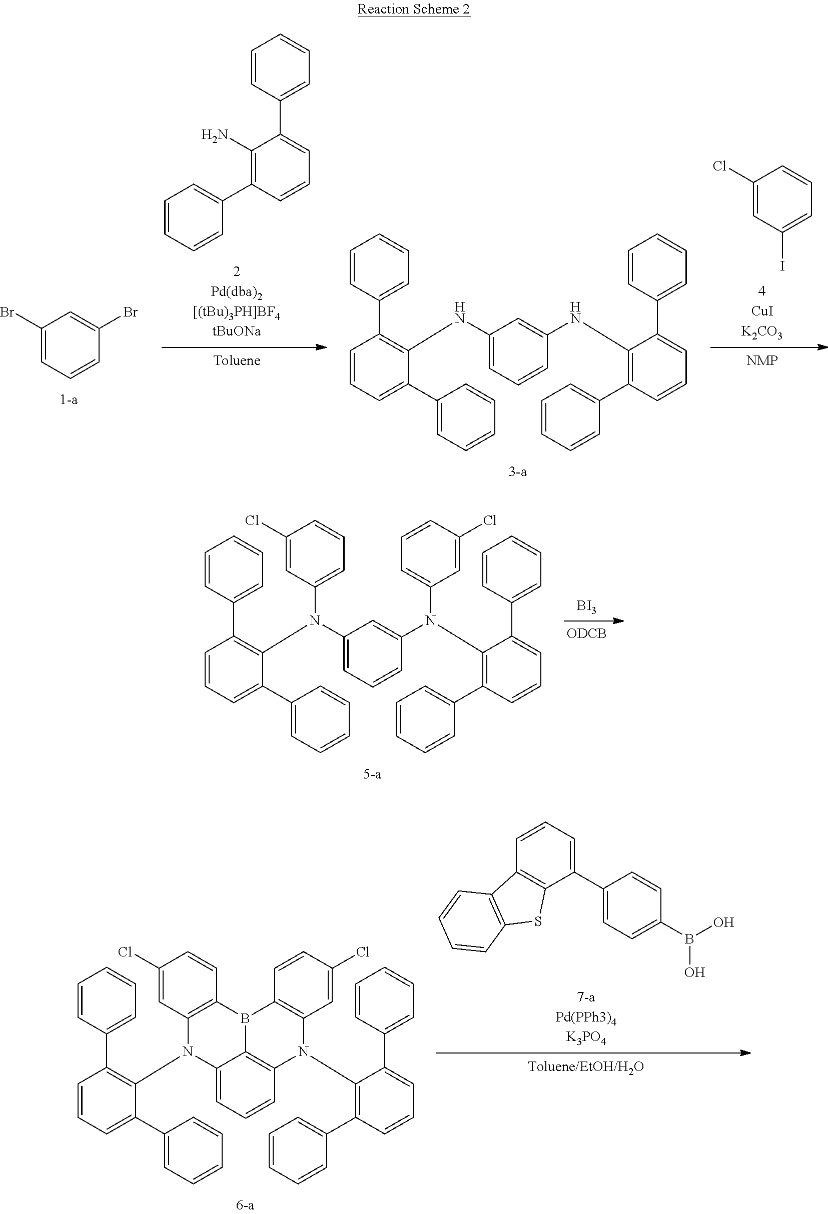

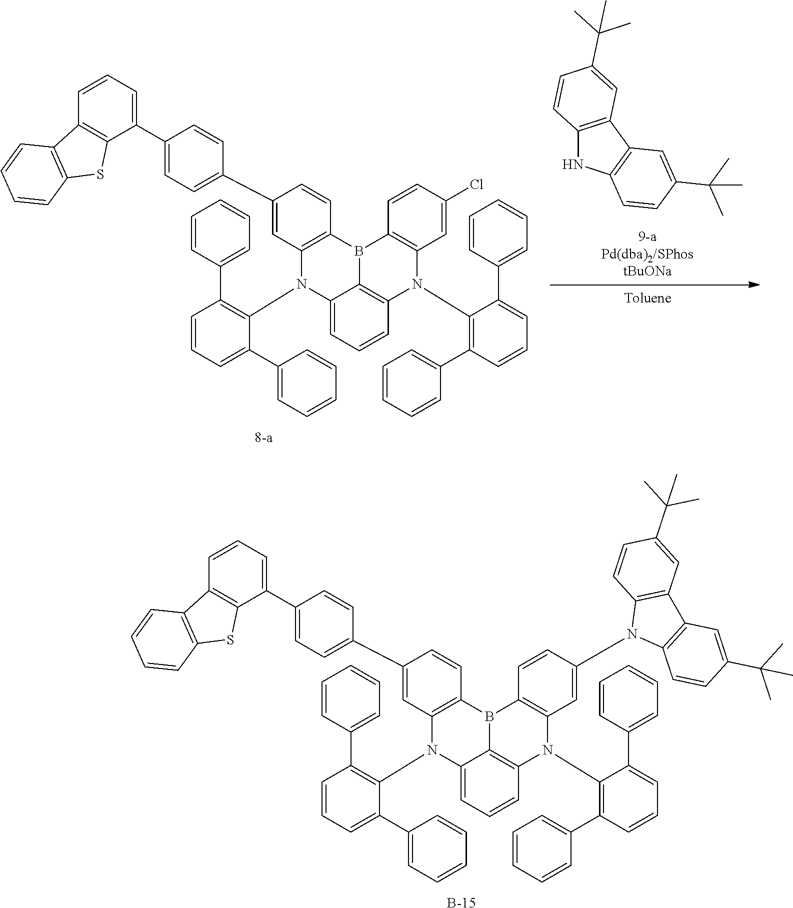

1) In a three-necked flask, Compound 1-a (150 mmol), Compound 2 (300 mmol), tBuONa (450 mmol), Pd(dba)₂ (15 mmol), and [(tBu)₃PH]BF₄ (30 mmol) were added, purging with Ar was performed, then 1,000 mL of toluene was added thereto, and the resulting mixture was stirred at about 100° C. for about 1 hour. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (143 mmol, yield 95%). By FAB-MS measurement of the obtained purified product, it was identified that the molecular weight was 564, thereby identifying Compound 3-a.

2) Then, in a three-necked flask, Compound 3-a (143 mmol), Compound 4 (1430 mmol), K₂CO₃ (715 mmol), and CuI (143 mmol) were added, purging with Ar was performed, 100 mL of NMP was added thereto to dissolve the resulting mixture, and then the resulting mixture was stirred at about 190° C. for about 28 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (112 mmol, yield 78%). By FAB-MS measurement of the obtained purified product, it was identified that the molecular weight was 786, thereby identifying Compound 5-a.

3) In a three-necked flask, Compound 5-a (112 mmol) was added, purging with Ar was performed, 200 mL of ODCB was added thereto to dissolve the resulting mixture, then BI₃ (448 mmol) was added thereto, and the resulting mixture was stirred at about 180° C. for about 3 hours. The reaction solution was subjected to dispersion washing with a large number of acetonitrile, and then solids were recovered by filtration. The resulting crude product was purified by silica gel column chromatography (a mixed solvent of hexane/toluene=2/1) and recrystallization (a mixed solvent of ethanol/toluene=5/1) to obtain yellow solids (41 mmol, yield 37%). By FAB-MS measurement of the obtained purified product, it was identified that the molecular weight was 793, thereby identifying Compound 6-a.

4) In a three-necked flask, Compound 6-a (41 mmol), Compound 7-a (41 mmol), K₃PO₄ (62 mmol), and Pd(PPh₃)₄ (4 mmol) were added, purging with Ar was performed, 100 mL of toluene, 10 mL of EtOH, and 10 mL of H₂O were added thereto, and the resulting mixture was stirred at about 100° C. for about 2 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain yellow solids (21 mmol, yield 52%). By FAB-MS measurement of the obtained purified product, it was identified that the molecular weight was 1017, thereby identifying Compound 8-a.

5) In a three-necked flask, Compound 8-a (21 mmol), Compound 9-a (42 mmol), tBuONa (84 mmol), Pd(dba)₂ (2 mmol), and SPhos (4 mmol) were added, purging with Ar was performed, then 100 mL of toluene was added thereto, and the resulting mixture was stirred at about 100° C. for about 4 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain yellow solids (16 mmol, yield 76%). By FAB-MS measurement of the obtained purified product, it was identified that the molecular weight was 1260, thereby identifying Compound B-15.

### (3) Synthesis of Compound C-10

Polycyclic Compound C-10 according to an example may be synthesized by, for example, the steps shown in Reaction Scheme 3 below:

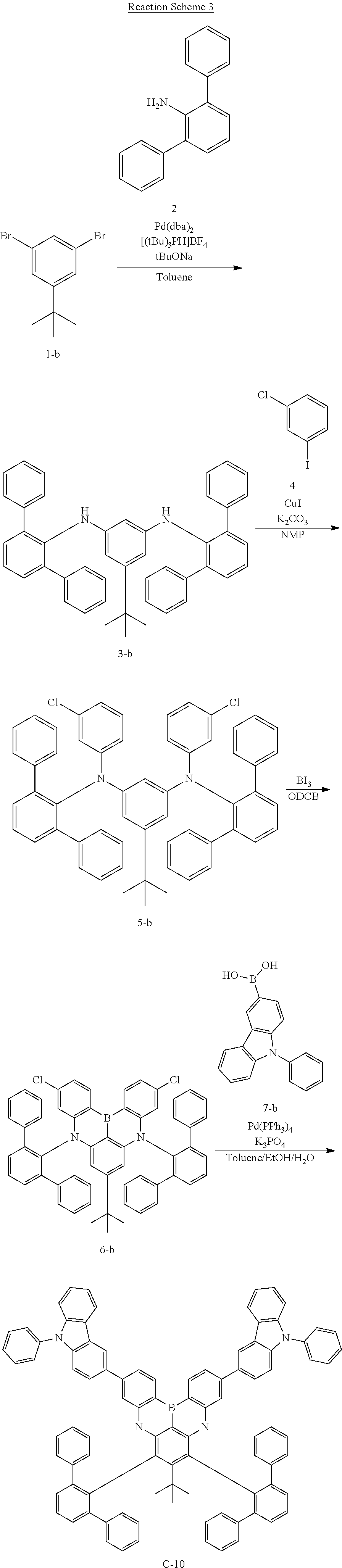

1) In a three-necked flask, Compound 1-b (150 mmol), Compound 2 (300 mmol), tBuONa (450 mmol), Pd(dba)₂ (15 mmol), and [(tBu)₃PH]BF₄ (30 mmol) were added, purging with Ar was performed, then 1,000 mL of toluene was added thereto, and the resulting mixture was stirred at about 90° C. for about 3 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (136 mmol, yield 91%). By FAB-MS measurement of the obtained purified product, it was identified that the molecular weight was 621, thereby identifying Compound 3-b.

2) Then, in a three-necked flask, Compound 3-b (136 mmol), Compound 4-b (1360 mmol), K₂CO₃ (680 mmol), and CuI (136 mmol) were added, purging with Ar was performed, 100 mL of NMP was added thereto to dissolve the resulting mixture, and then the resulting mixture was stirred at about 190° C. for about 24 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (72 mmol, yield 53%). By FAB-MS measurement of the obtained purified product, it was identified that the molecular weight was 842, thereby identifying Compound 5-b.

3) In a three-necked flask, Compound 5-b (72 mmol) was added, purging with Ar was performed, 100 mL of ODCB was added thereto to dissolve the resulting mixture, then BI₃ (288 mmol) was added thereto, and the resulting mixture was stirred at about 180° C. for about 2 hours. The reaction solution was subjected to dispersion washing with a large number of acetonitrile, and then solids were recovered by filtration. The resulting crude product was purified by silica gel column chromatography (a mixed solvent of hexane/toluene=2/1) and recrystallization (a mixed solvent of ethanol/toluene=5/1) to obtain yellow solids (9 mmol, yield 12%). By FAB-MS measurement of the obtained purified product, it was identified that the molecular weight was 850, thereby identifying Compound 6-b.

4) In a three-necked flask, Compound 6-b (9 mmol), Compound 7-b (18 mmol), K₃PO₄ (36 mmol), and Pd(PPh₃)₄ (2 mmol) were added, purging with Ar was performed, 50 mL of toluene, 5 mL of EtOH, and 5 mL of H₂O were added thereto, and the resulting mixture was stirred at about 100° C. for about 6 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain yellow solids (8 mmol, yield 94%). By FAB-MS measurement of the obtained purified product, it was identified that the molecular weight was 1263, thereby identifying Compound C-10.

### (4) Synthesis of Compound D-20

Polycyclic Compound D-20 according to an example may be synthesized by, for example, the steps shown in Reaction Scheme 4 below:

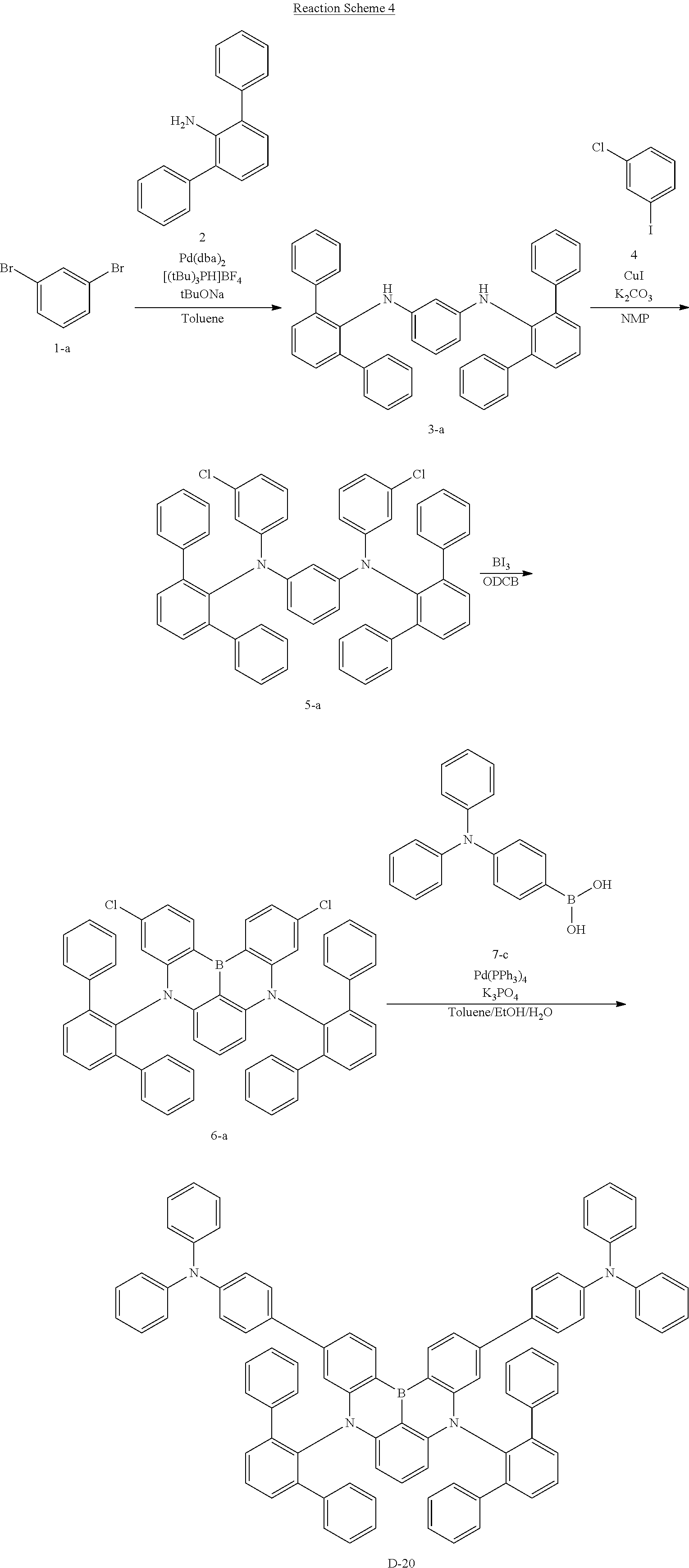

1) In a three-necked flask, Compound 1-a (150 mmol), Compound 2 (300 mmol), tBuONa (450 mmol), Pd(dba)₂ (15 mmol), and [(tBu)₃PH]BF₄ (30 mmol) were added, purging with Ar was performed, then 1,000 mL of toluene was added thereto, and the resulting mixture was stirred at about 100° C. for about 1 hour. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (143 mmol, yield 95%). By FAB-MS measurement of the obtained purified product, it was identified that the molecular weight was 564, thereby identifying Compound 3-a.

2) Then, in a three-necked flask, Compound 3-a (143 mmol), Compound 4 (1430 mmol), K₂CO₃ (715 mmol), and CuI (143 mmol) were added, purging with Ar was performed, 100 mL of NMP was added thereto to dissolve the resulting mixture, and then the resulting mixture was stirred at about 190° C. for about 28 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (112 mmol, yield 78%). By FAB-MS measurement of the obtained purified product, it was identified that the molecular weight was 786, thereby identifying Compound 5-a.

3) In a three-necked flask, Compound 5-a (112 mmol) was added, purging with Ar was performed, 200 mL of ODCB was added thereto to dissolve the resulting mixture, then BI₃ (448 mmol) was added thereto, and the resulting mixture was stirred at about 180° C. for about 3 hours. The reaction solution was subjected to dispersion washing with a large number of acetonitrile, and then solids were recovered by filtration. The resulting crude product was purified by silica gel column chromatography (a mixed solvent of hexane/toluene=2/1) and recrystallization (a mixed solvent of ethanol/toluene=5/1) to obtain yellow solids (41 mmol, yield 37%). By FAB-MS measurement of the obtained purified product, it was identified that the molecular weight was 793, thereby identifying Compound 6-a.

4) In a three-necked flask, Compound 6-a (41 mmol), Compound 7-c (41 mmol), K₃PO₄ (62 mmol), and Pd(PPh₃)₄ (4 mmol) were added, purging with Ar was performed, 100 mL of toluene, 10 mL of EtOH, and 10 mL of H₂O were added thereto, and the resulting mixture was stirred at about 100° C. for about 2 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain yellow solids (27 mmol, yield 65%). By FAB-MS measurement of the obtained purified product, it was identified that the molecular weight was 1211, thereby identifying Compound D-20.

### (5) Synthesis of Compound E-2

Polycyclic Compound E-2 according to an example may be synthesized by, for example, the steps shown in Reaction Scheme 5 below:

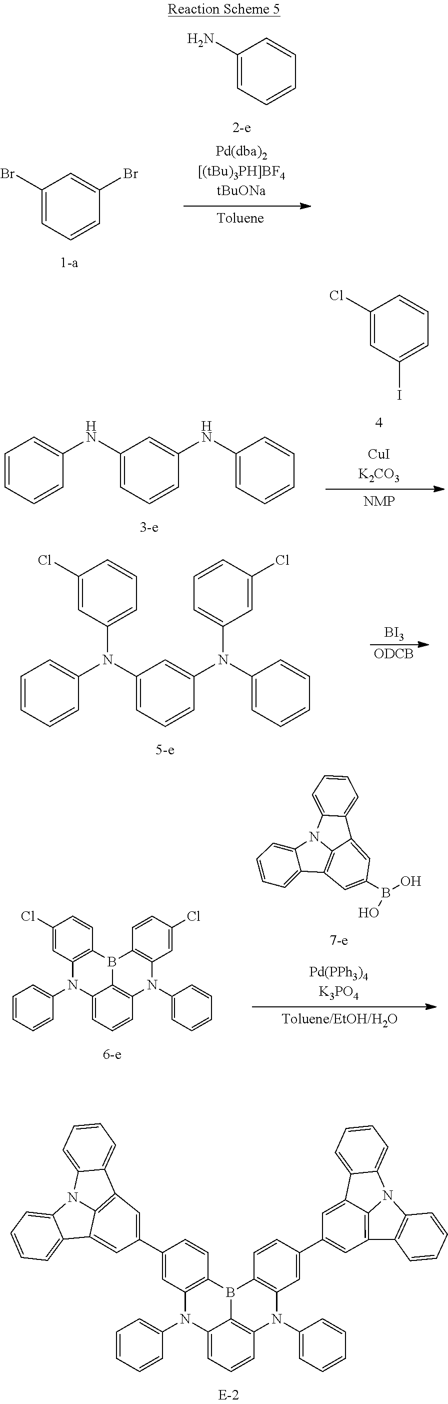

1) In a three-necked flask, Compound 1-a (150 mmol), Compound 2-e (300 mmol), tBuONa (450 mmol), Pd(dba)₂ (15 mmol), and [(tBu)₃PH]BF₄ (30 mmol) were added, purging with Ar was performed, then 1,000 mL of toluene was added thereto, and the resulting mixture was stirred at about 100° C. for about 1 hour. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (146 mmol, yield 97%). By FAB-MS measurement of the obtained purified product, it was identified that the molecular weight was 260, thereby identifying Compound 3-e.

2) Then, in a three-necked flask, Compound 3-e (146 mmol), Compound 4 (1460 mmol), K₂CO₃ (715 mmol), and CuI (143 mmol) were added, purging with Ar was performed, 100 mL of NMP was added thereto to dissolve the resulting mixture, and then the resulting mixture was stirred at about 190° C. for about 12 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (125 mmol, yield 86%). By FAB-MS measurement of the obtained purified product, it was identified that the molecular weight was 481, thereby identifying Compound 5-e.

3) In a three-necked flask, Compound 5-e (125 mmol) was added, purging with Ar was performed, 200 mL of ODCB was added thereto to dissolve the resulting mixture, then BI₃ (250 mmol) was added thereto, and the resulting mixture was stirred at about 180° C. for about 1 hour. The reaction solution was subjected to dispersion washing with a large number of acetonitrile, and then solids were recovered by filtration. The resulting crude product was purified by silica gel column chromatography (a mixed solvent of hexane/toluene=2/1) and recrystallization (a mixed solvent of ethanol/toluene=5/1) to obtain yellow solids (56 mmol, yield 45%). By FAB-MS measurement of the obtained purified product, it was identified that the molecular weight was 489, thereby identifying Compound 6-e.

4) In a three-necked flask, Compound 6-e (28 mmol), Compound 7-e (56 mmol), K₃PO₄ (62 mmol), and Pd(PPh₃)₄ (4 mmol) were added, purging with Ar was performed, 100 mL of toluene, 10 mL of EtOH, and 10 mL of H₂O were added thereto, and the resulting mixture was stirred at about 120° C. for about 5 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain yellow solids (20 mmol, yield 71%). By FAB-MS measurement of the obtained purified product, it was identified that the molecular weight was 899, thereby identifying Compound E-2.

### (6) Synthesis of Compound E-4

Polycyclic Compound E-4 according to an example may be synthesized by, for example, the steps shown in Reaction Scheme 6 below:

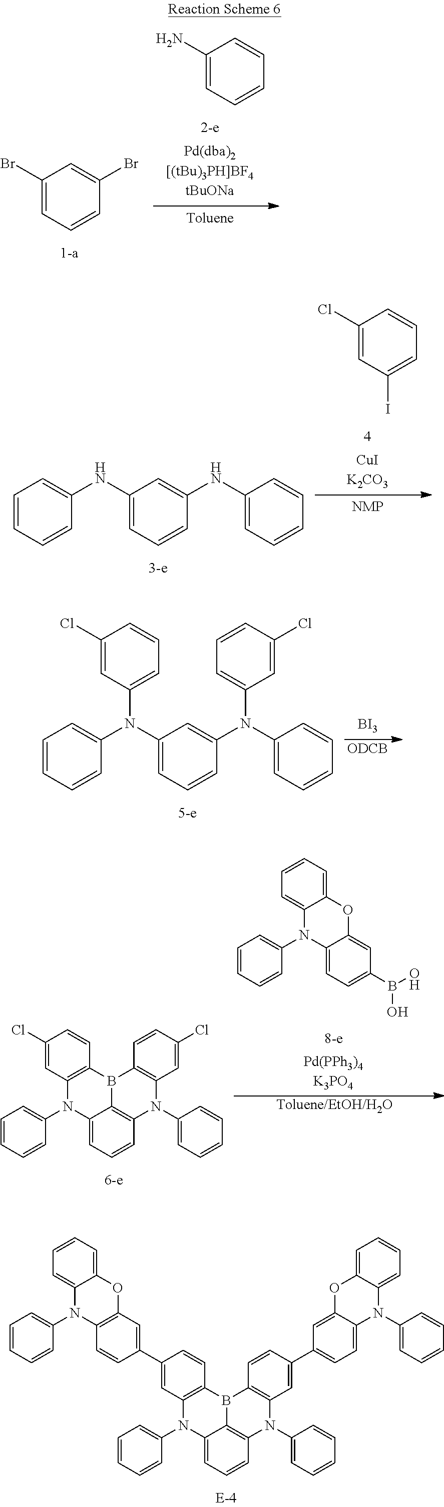

1) In a three-necked flask, Compound 1-a (150 mmol), Compound 2-e (300 mmol), tBuONa (450 mmol), Pd(dba)₂ (15 mmol), and [(tBu)₃PH]BF₄ (30 mmol) were added, purging with Ar was performed, then 1,000 mL of toluene was added thereto, and the resulting mixture was stirred at about 100° C. for about 1 hour. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (146 mmol, yield 97%). By FAB-MS measurement of the obtained purified product, it was identified that the molecular weight was 260, thereby identifying Compound 3-e.

2) Then, in a three-necked flask, Compound 3-e (146 mmol), Compound 4 (1460 mmol), K₂CO₃ (715 mmol), and CuI (143 mmol) were added, purging with Ar was performed, 100 mL of NMP was added thereto to dissolve the resulting mixture, and then the resulting mixture was stirred at about 190° C. for about 12 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain white solids (125 mmol, yield 86%). By FAB-MS measurement of the obtained purified product, it was identified that the molecular weight was 481, thereby identifying Compound 5-e.

3) In a three-necked flask, Compound 5-e (125 mmol) was added, purging with Ar was performed, 200 mL of ODCB was added thereto to dissolve the resulting mixture, then BI₃ (250 mmol) was added thereto, and the resulting mixture was stirred at about 180° C. for about 1 hour. The reaction solution was subjected to dispersion washing with a large number of acetonitrile, and then solids were recovered by filtration. The resulting crude product was purified by silica gel column chromatography (a mixed solvent of hexane/toluene=2/1) and recrystallization (a mixed solvent of ethanol/toluene=5/1) to obtain yellow solids (56 mmol, yield 45%). By FAB-MS measurement of the obtained purified product, it was identified that the molecular weight was 489, thereby identifying Compound 6-e.

4) In a three-necked flask, Compound 6-e (28 mmol), Compound 8-e (56 mmol), K₃PO₄ (62 mmol), and Pd(PPh₃)₄ (4 mmol) were added, purging with Ar was performed, 100 mL of toluene, 10 mL of EtOH, and 10 mL of H₂O were added thereto, and the resulting mixture was stirred at about 100° C. for about 2 hours. Water was added to the reaction system, an organic layer was extracted by using toluene, and then was dried over magnesium sulfate to distill the solvent off. The resulting crude product was purified by silica gel column chromatography (a mixed solvent of hexane/toluene=2/1) and recrystallization (a mixed solvent of ethanol/toluene=5/1) to obtain yellow solids (24 mmol, yield 86%). By FAB-MS measurement of the obtained purified product, it was identified that the molecular weight was 935, thereby identifying Compound E-4.

### 2. Manufacture of Light Emitting Elements and Evaluation of Polycyclic Compounds

### (1) Evaluation of Fluorescence Emission Properties of Polycyclic Compounds

In the evaluation of emission properties, a 20 wt % dope film was formed on a quartz glass by depositing PPF below as a matrix, and the fluorescence emission spectrum was measured using a JASCO V-670 spectrometer. The fluorescence quantum yield was measured using JASCOILF-835 integrating sphere system.

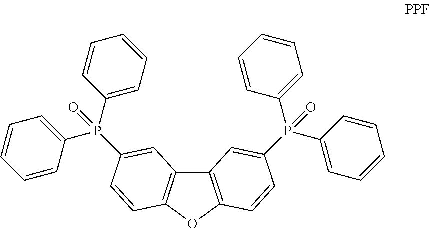 [SMILES: O=P(c1ccccc1)(c1ccccc1)c1ccc2oc3ccc(P(=O)(c4ccccc4)c4ccccc4)cc3c2c1]

TABLE 1

| | | Fluorescence |
|---|---|---|
| | | quantum |
| Compound | λmax/nm | yield/% |
| Example Compound A-20 | 459 | 92 |
| Example Compound B-15 | 460 | 93 |
| Example Compound C-10 | 468 | 98 |
| Example Compound D-20 | 463 | 91 |
| Example Compound E-2 | 468 | 95 |
| Example Compound E-4 | 460 | 97 |
| Comparative Example | 469 | 89 |
| Compound X1 | | |
| Comparative Example | 458 | 84 |
| Compound X2 | | |
| Comparative Example | 456 | 90 |
| Compound X3 | | |
| Comparative Example | 452 | 80 |
| Compound X4 | | |

Referring to the results of Table 1, Example Compounds A-20, B-15, C-10, D-20, E-2, and E-4, and Comparative Example Compounds X1 to X4 emit light in a wavelength region of about 450 nm to about 470 nm. The fluorescence quantum yield is measured as values of about 80% to about 98%.

### (2) Manufacture of Light Emitting Elements

The light emitting elements were manufactured using Example Compounds and Comparative Example Compounds as a dopant material for the emission layer.

Specifically, a 1500 Å-thick ITO was patterned on a glass substrate, washed with ultrapure water, and treated with UV and ozone for about 10 minutes. Then, HAT-CN was used to form a 100 Å-thick hole injection layer, and α-NPB was used to form a 400 Å-thick hole transport layer.

Next, mCBP was used to form a 50 Å-thick electron blocking layer, and Example Compound or Comparative Example and mCBP were mixed in a ratio of about 20:80 to form an emission layer. The emission layer was formed to have a thickness of about 200 Å. On the emission layer, TPBi was used to form a 300 Å-thick electron transport layer, and Liq was used to form a 5 Å-thick electron injection layer. Next, aluminum (Al) was used to form a 1,000 Å-thick second electrode. Here, the hole injection layer, the hole transport layer, the emission layer, the electron transport layer, the electron injection layer, and the second electrode were formed by using a vacuum deposition apparatus.

### Example Compounds

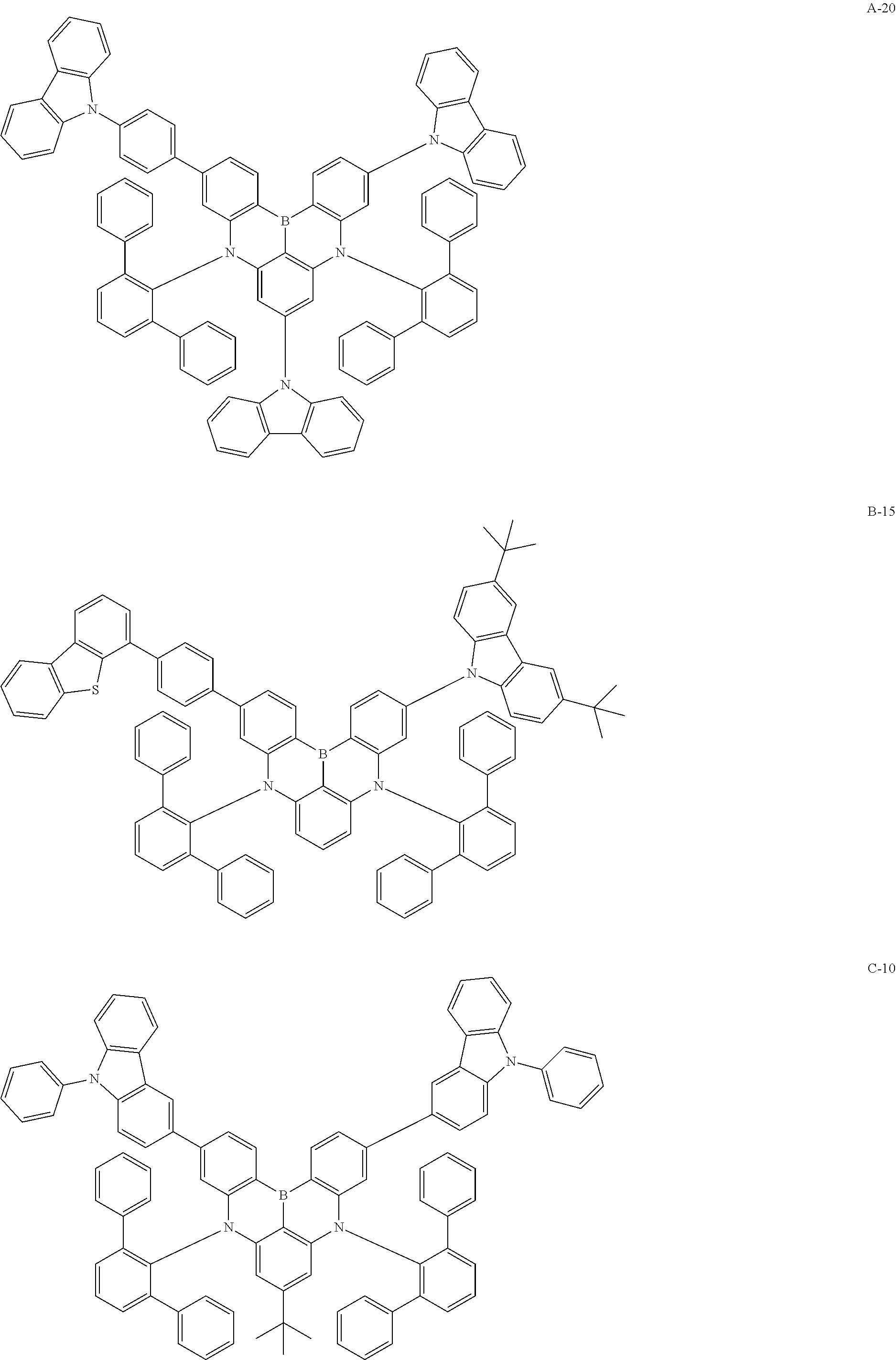

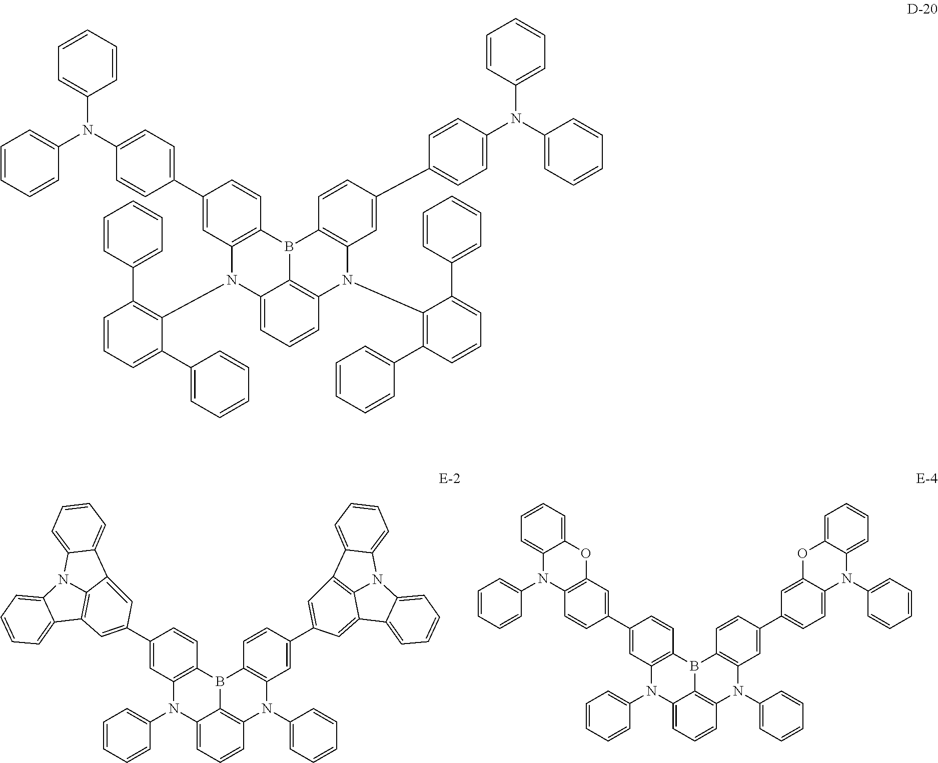 [SMILES: c1ccc(-c2cccc(-c3ccccc3)c2N2c3cc(-c4ccc(N(c5ccccc5)c5ccccc5)cc4)ccc3B3c4ccc(-c5ccc(N(c6ccccc6)c6ccccc6)cc5)cc4N(c4c(-c5ccccc5)cccc4-c4ccccc4)c4cccc2c43)cc1 ; c1ccc(N2c3cc(-c4cc5c6ccccc6n6c7ccccc7c(c4)c56)ccc3B3c4ccc(-c5cc6c7ccccc7n7c8ccccc8c(c5)c67)cc4N(c4ccccc4)c4cccc2c43)cc1 ; c1ccc(N2c3ccccc3Oc3cc(-c4ccc5c(c4)N(c4ccccc4)c4cccc6c4B5c4ccc(-c5ccc7c(c5)Oc5ccccc5N7c5ccccc5)cc4N6c4ccccc4)ccc32)cc1]

### Comparative Example Compounds

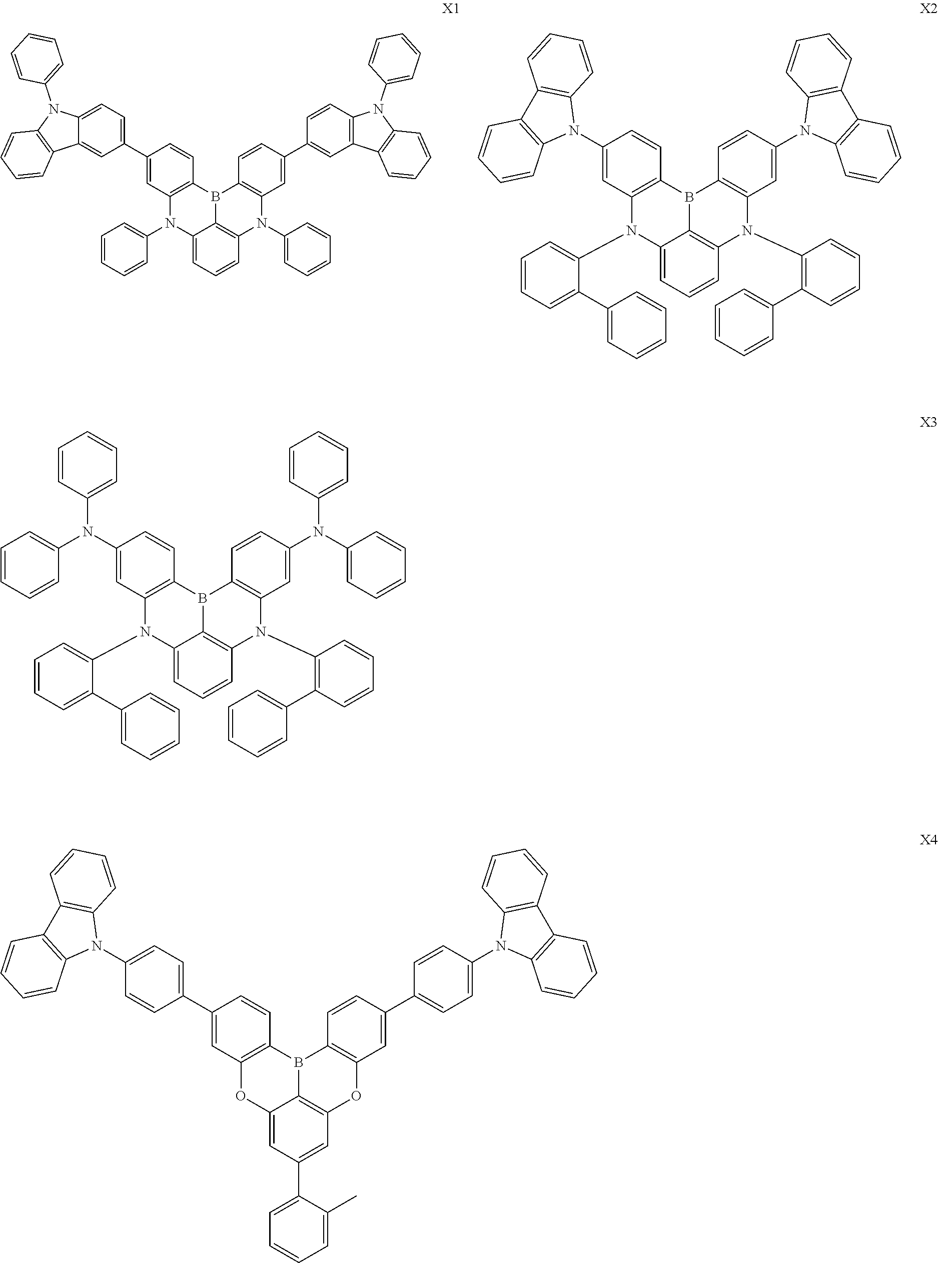 [SMILES: c1ccc(N2c3cc(-c4ccc5c(c4)c4ccccc4n5-c4ccccc4)ccc3B3c4ccc(-c5ccc6c(c5)c5ccccc5n6-c5ccccc5)cc4N(c4ccccc4)c4cccc2c43)cc1 ; c1ccc(-c2ccccc2N2c3cc(-n4c5ccccc5c5ccccc54)ccc3B3c4ccc(-n5c6ccccc6c6ccccc65)cc4N(c4ccccc4-c4ccccc4)c4cccc2c43)cc1 ; c1ccc(-c2ccccc2N2c3cc(N(c4ccccc4)c4ccccc4)ccc3B3c4ccc(N(c5ccccc5)c5ccccc5)cc4N(c4ccccc4-c4ccccc4)c4cccc2c43)cc1 ; Cc1ccccc1-c1cc2c3c(c1)Oc1cc(-c4ccc(-n5c6ccccc6c6ccccc65)cc4)ccc1B3c1ccc(-c3ccc(-n4c5ccccc5c5ccccc54)cc3)cc1O2]

The compounds below used to manufacture the light emitting elements are known materials, and commercial products were subjected to sublimation purification and used to manufacture the elements:

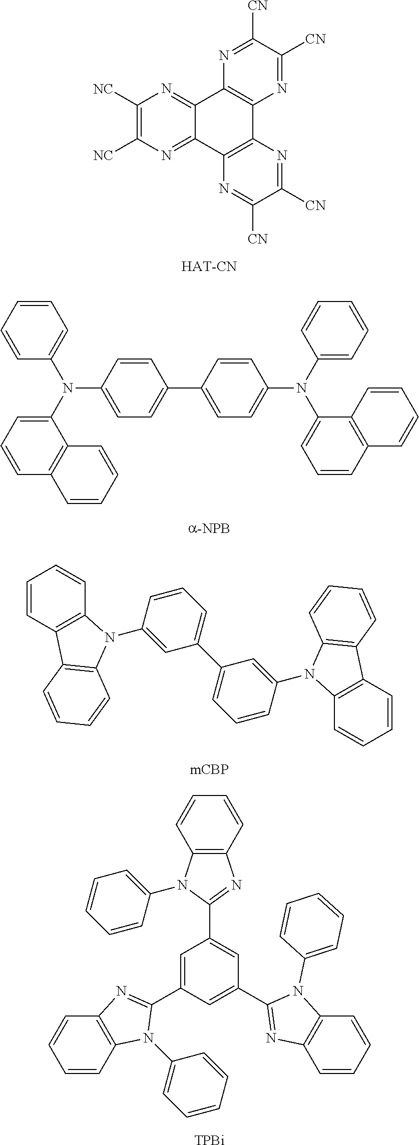

### Experimental Example

The dopant compound, the maximum emission wavelength (λₘₐₓ), the maximum value of external quantum efficiency (EQEₘₐₓ), and a half service life (LT₅₀) were evaluated and listed in Table 2.

In Table 2, the voltages and current densities of the light emitting elements were measured by using SourceMeter (Keithley Instruments, Inc., 2400 series), and the brightness and maximum quantum efficiency were measured by using an external quantum efficiency measurement apparatus, C9920-2-12 manufactured by Hamamatsu Photonics, co., Japan.

In Table 2, the half service life (LT₅₀) was measured on the basis of the time taken for the brightness to deteriorate to 50% from an initial value when each of the light emitting elements of Examples and Comparative Examples was continuously operated at a current density of 10 mA/cm². The half service life (LT₅₀) was evaluated as a relative ratio, assuming the half service life value of Comparative Example 1 as 100%.

TABLE 2

| Examples of | | | | |
|---|---|---|---|---|
| manufactured | | λmax | EQEₘₐₓ | LT₅₀ |
| elements | Dopant compound | (nm) | (%) | (%) |
| Example 1 | Example Compound A-20 | 460 | 21 | 244 |
| Example 2 | Example Compound B-15 | 461 | 23 | 256 |
| Example 3 | Example Compound C-10 | 469 | 22 | 339 |
| Example 4 | Example Compound D-20 | 464 | 21 | 215 |
| Example 5 | Example Compound E-2 | 470 | 24 | 284 |
| Example 6 | Example Compound E-4 | 463 | 22 | 267 |
| Comparative | Comparative Example | 470 | 13 | 100 |
| Example 1 | Compound X1 | | | |
| Comparative | Comparative Example | 459 | 17 | 120 |
| Example 2 | Compound X2 | | | |
| Comparative | Comparative Example | 457 | 19 | 54 |
| Example 3 | Compound X3 | | | |
| Comparative | Comparative Example | 459 | 5 | 6 |
| Example 4 | Compound X4 | | | |

Referring to the results of Table 2, it can be seen that the light emitting elements including the polycyclic compound of an embodiment of Examples 1 to 6 have excellent half service life and improved luminous efficiency compared with the light emitting elements of Comparative Examples 1 to 4. Specifically, the light emitting elements of Examples 1 to 6 emit light in a blue wavelength region of about 450 nm to about 470 nm, and exhibit an EQEₘₐₓ value of about 21% or more, and LT50 of about 210% or more.

In contrast, the light emitting elements of Comparative Examples 1 to 4 emit light in a blue wavelength region of about 450 nm to about 470 nm, but exhibit an EQEₘₐₓ value of about 19% or less, and LT₅₀ of about 100%, 120%, 54%, and 6%, respectively.

The polycyclic compound of embodiments of the present disclosure has an electron donor substituent at the para-position of a boron atom, which may increase the photoluminescence quantum yield (PLQY) and oscillator strength (f). Accordingly, the polycyclic compound of embodiments of the present disclosure may have stronger molecular stability, thereby keeping excellent PLQY and oscillator strength.

The light emitting element of embodiments of the present disclosure includes the polycyclic compound in the emission layer, thereby improving element service life and exhibiting improved luminous efficiency.

The light emitting element of an embodiment may include the polycyclic compound of an embodiment, thereby exhibiting high efficiency and improving a service life characteristic.

The polycyclic compound of an embodiment may be used as a luminescent material for achieving improved characteristics of the light emitting element having high efficiency and a long service life.

Although the subject matter of the present disclosure has been described with reference to example embodiments of the present disclosure, it will be understood that the subject matter of the present disclosure should not be limited to described embodiments but various changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims, and equivalents thereof.

What is claimed is:

1. A light emitting element comprising:
a first electrode;
a second electrode on the first electrode; and
an emission layer between the first electrode and the second electrode,
wherein the emission layer comprises:
a first compound represented by Formula 1 below; and
at least one of a second compound represented by Formula HT below, a third compound represented by Formula ET below, or a fourth compound represented by Formula D-1 below: 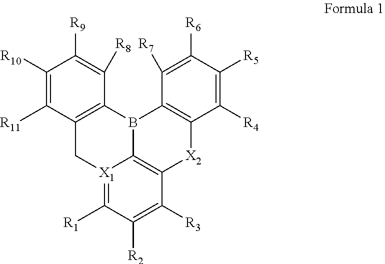
wherein, in Formula 1 above,
X₁ and X₂ are each independently O, S, Se, or NRₐ, and at least one of X₁ or X₂ is S, Se, or NRₐ,
Rₐ is a substituted or unsubstituted phenyl group,
R₁ to R₄, R₆ to R₉, and R₁₁ are each independently a hydrogen atom, a deuterium atom, a halogen atom, a cyano group, a nitro group, a substituted or unsubstituted boryl group, a substituted or unsubstituted amino group, a substituted or unsubstituted alkyl group having 1 to 20 carbon atoms, a substituted or unsubstituted cycloalkyl group having 6 to 30 ring-forming carbon atoms, a substituted or unsubstituted aryl group having 6 to 30 ring-forming carbon atoms, or a substituted or unsubstituted heteroaryl group having 3 to 30 ring-forming carbon atoms,
R₅ and R₁₀ are each independently represented by Formula 2 or Formula 3 below,
when each of R₅ and R₁₀ is represented by Formula 2, at least one L₁ is a substituted or unsubstituted arylene group having 6 to 30 ring-forming carbon atoms, and
when each of R₅ and R₁₀ is represented by Formula 3, the case where at least one L₂ is a direct linkage and N among heteroatoms contained in Ar₃ is directly linked to a benzene ring in Formula 1 above is excluded: 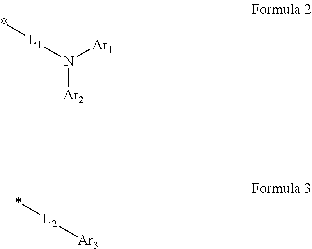
wherein, in Formula 2 and Formula 3 above,
L₁ and L₂ are each independently a direct linkage, or a substituted or unsubstituted arylene group having 6 to 30 ring-forming carbon atoms,
Ar₁ and Ar₂ are each independently a substituted or unsubstituted aryl group having 6 to 30 ring-forming carbon atoms, or a substituted or unsubstituted heteroaryl group having 3 to 30 ring-forming carbon atoms, and
Ar₃ is a substituted or unsubstituted heteroaryl group having 3 to 30 ring-forming carbon atoms, 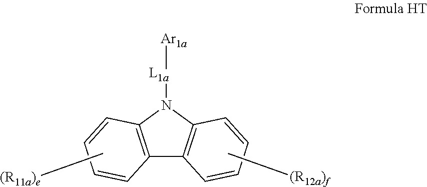
wherein, in Formula HT above,
L₁ₐ is a direct linkage, a substituted or unsubstituted arylene group having 6 to 30 ring-forming carbon atoms, or a substituted or unsubstituted heteroarylene group having 2 to 30 ring-forming carbon atoms,
Ar₁ₐ is a substituted or unsubstituted aryl group having 6 to 30 ring-forming carbon atoms, or a substituted or unsubstituted heteroaryl group having 2 to 30 ring-forming carbon atoms,
R₁₁ₐ and R₁₂ₐ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
e and f are each independently an integer of 0 to 4: 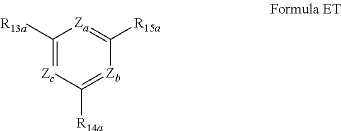
wherein, in Formula ET above,
at least one selected from among Zₐ to Z_{c} is N, and the rest are CR₁₆ₐ, and
R₁₃ₐ to R₁₆ₐ are each independently a hydrogen atom, a deuterium atom, a cyano group, a substituted or unsubstituted silyl atoms, a substituted or unsubstituted aryl group having 6 to 30 ring-forming carbon atoms, or a substituted or unsubstituted heteroaryl group having 2 to 30 ring-forming carbon atoms, and 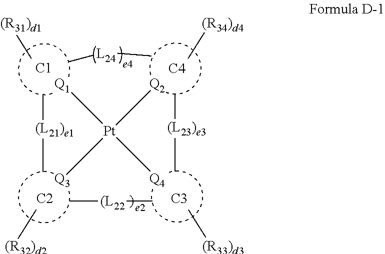
wherein, in Formula D-1 above,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₂₁ to L₂₄ are each independently a direct linkage, 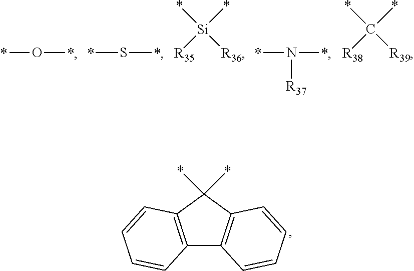
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
e1 to e4 are each independently 0 or 1,
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and
d1 to d4 are each independently an integer of 0 to 4.

2. The light emitting element of claim 1, wherein Rₐ above is represented by Formula 4 below:
Formula 4 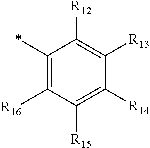
wherein, in Formula 4 above, R₁₂ to R₁₆ are each independently a hydrogen atom, a deuterium atom, a halogen atom, a cyano group, a nitro group, a substituted or unsubstituted boryl group, a substituted or unsubstituted amino group, a substituted or unsubstituted alkyl group having 1 to 20 carbon atoms, a substituted or unsubstituted cycloalkyl group having 6 to 30 ring-forming carbon atoms, a substituted or unsubstituted aryl group having 6 to 30 ring-forming carbon atoms, or a substituted or unsubstituted heteroaryl group having 3 to 30 ring-forming carbon atoms, and
“*—” is a position linked to N.

3. The light emitting element of claim 2, wherein R₁₂ to R₁₆ are each independently a hydrogen atom, a deuterium atom, a substituted or unsubstituted propyl group, a substituted or unsubstituted phenyl group, or a substituted or unsubstituted cyclohexyl group.

4. The light emitting element of claim 1, wherein R₁ and R₃ above are each independently a hydrogen atom or a deuterium atom, and
R₂ above is a hydrogen atom, a deuterium atom, a substituted or unsubstituted i-propyl group, a substituted or unsubstituted t-butyl group, a substituted or unsubstituted cyclohexyl group, a substituted or unsubstituted phenyl group, or a substituted or unsubstituted carbazole group.

5. The light emitting element of claim 1, wherein Formula 1 above is represented by any one selected from among Formula 1-1 to Formula 1-3 below: 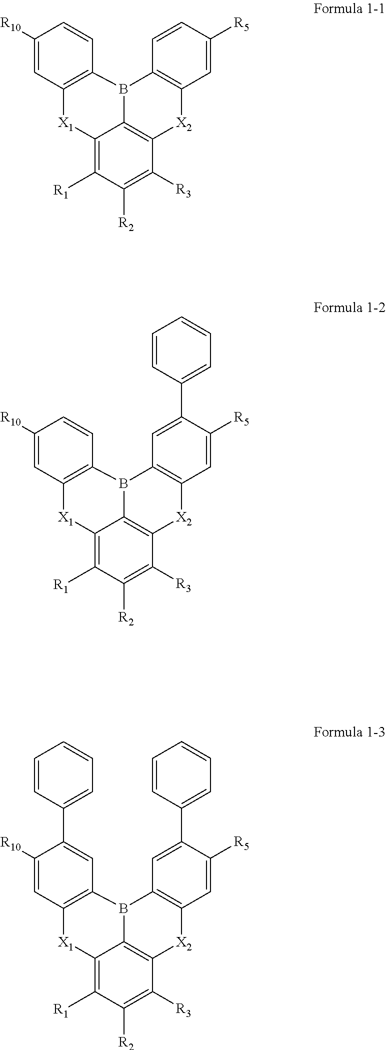
wherein, in Formula 1-1 to Formula 1-3 above,
each hydrogen atom is unsubstituted or substituted with a deuterium atom, and
X₁, X₂, R₁ to R₃, R₅, and R₁₀ are the same as defined with respect to Formula 1 above.

6. The light emitting element of claim 1, wherein Ara above is a substituted or unsubstituted heteroaryl group having 3 to 30 ring-forming carbon atoms and containing a heteroatom such as O, S, or N as a ring-forming atom, and
the case where Ar₃ is a pyridine group, a pyrazine group, a pyrimidine group, or a quinazoline group, or contains at least three Ns as a ring-forming atom is excluded.

7. The light emitting element of claim 1, wherein, when any one selected from among R₅ and R₁₀ above is represented by Formula 2, and the other is represented by Formula 3,
the case where L₁ is a direct linkage or L₂ is a direct linkage, and N among heteroatoms contained in Ar₃ is directly linked to the benzene ring in Formula 1 above is excluded.

8. The light emitting element of claim 1, wherein any one selected from among X₁ and X₂ is NRₐ, and the other is O or NRₐ.

9. The light emitting element of claim 1, wherein, when R₅ and R₁₀ above are represented by Formula 3 above, any one L₂ selected from among R₅ and R₁₀ above is a direct linkage, Ar₃ above is a substituted or unsubstituted heteroaryl group having 3 to 30 ring-forming carbon atoms and having N as a ring-forming atom, and N constituting Ar₃ above is linked to the benzene ring in Formula 1 above, and the other is a dibenzofuran group, a dibenzothiophene group, or 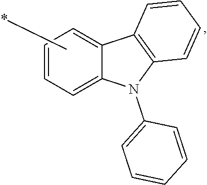
at least one of Rₐ's above is a substituted phenyl group.

10. The light emitting element of claim 9, wherein Rₐ, the substituted phenyl group is represented by any one selected from among Formula 4-1 or Formula 4-2 below: 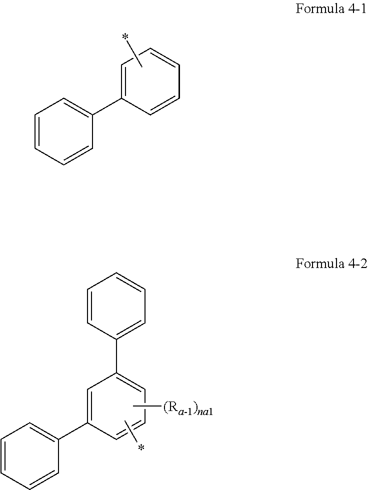
wherein, in Formula 4-2 above,
Rₐ₋₁ is a hydrogen atom, a deuterium atom, or a substituted or unsubstituted aryl group having 6 to 15 carbon atoms, and
nₐ₁ is an integer of 0 to 3.

11. The light emitting element of claim 1, wherein Formula 2 above is represented by Formula 2-1 below: 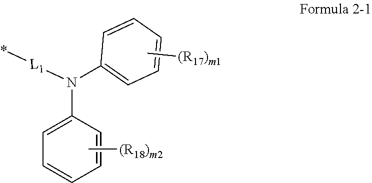
wherein, in Formula 2-1 above,
R₁₇ and R₁₈ are each independently a hydrogen atom, a deuterium atom, a substituted or unsubstituted alkyl group having 1 to 10 carbon atoms, a substituted or unsubstituted cycloalkyl group having 6 to 15 ring-forming carbon atoms, or a substituted or unsubstituted aryl group having 6 to 15 ring-forming carbon atoms,
m1 and m2 are each independently an integer of 0 to 5, and
L₁ is the same as defined with respect to Formula 2 above.

12. The light emitting element of claim 1, wherein Formula 3 above is represented by any one selected from among Formula 3-1 to Formula 3-3 below: 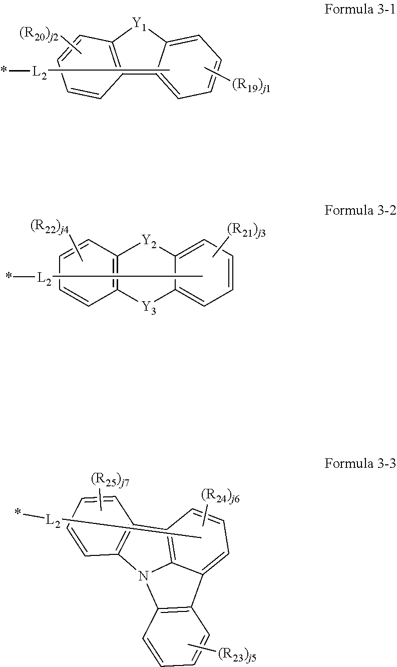
wherein, in Formula 3-1 and Formula 3-2 above,
Y₁ and Y₂ are each independently O, S, or NR₂₆, and
Y₃ is O, S, NR₂₇, or CR₂₈R₂₉, and
wherein, in Formula 3-1 to Formula 3-3 above,
R₁₉ to R₂₅ are each independently a hydrogen atom, a deuterium atom, a halogen atom, a cyano group, a nitro group, a substituted or unsubstituted boryl group, a substituted or unsubstituted amino group, a substituted or unsubstituted alkyl group having 1 to 20 carbon atoms, a substituted or unsubstituted aryl group having 6 to 30 ring-forming carbon atoms, or a substituted or unsubstituted heteroaryl group having 3 to 30 ring-forming carbon atoms,
R₂₆ is a hydrogen atom or a substituted or unsubstituted phenyl group,
R₂₇ is a substituted or unsubstituted phenyl group,
R₂₈ and R₂₉ are each independently a substituted or unsubstituted alkyl group having 1 to 4 carbon atoms, or a substituted or unsubstituted phenyl group,
j1 to j5 and j7 are each independently an integer of 0 to 4,
j6 is an integer of 0 to 3, and
L₂ is the same as defined with respect to Formula 3 above.

13. The light emitting element of claim 1, wherein the emission layer emits delayed fluorescence.

14. The light emitting element of claim 1, wherein the emission layer comprises the first compound and the second compound.

15. The light emitting element of claim 14, wherein the emission layer further comprises at least one of the third compound or the fourth compound.

16. The light emitting element of claim 1, wherein Formula 1 above is represented by any one selected from among Compound Group 1 below:
Compound Group 1

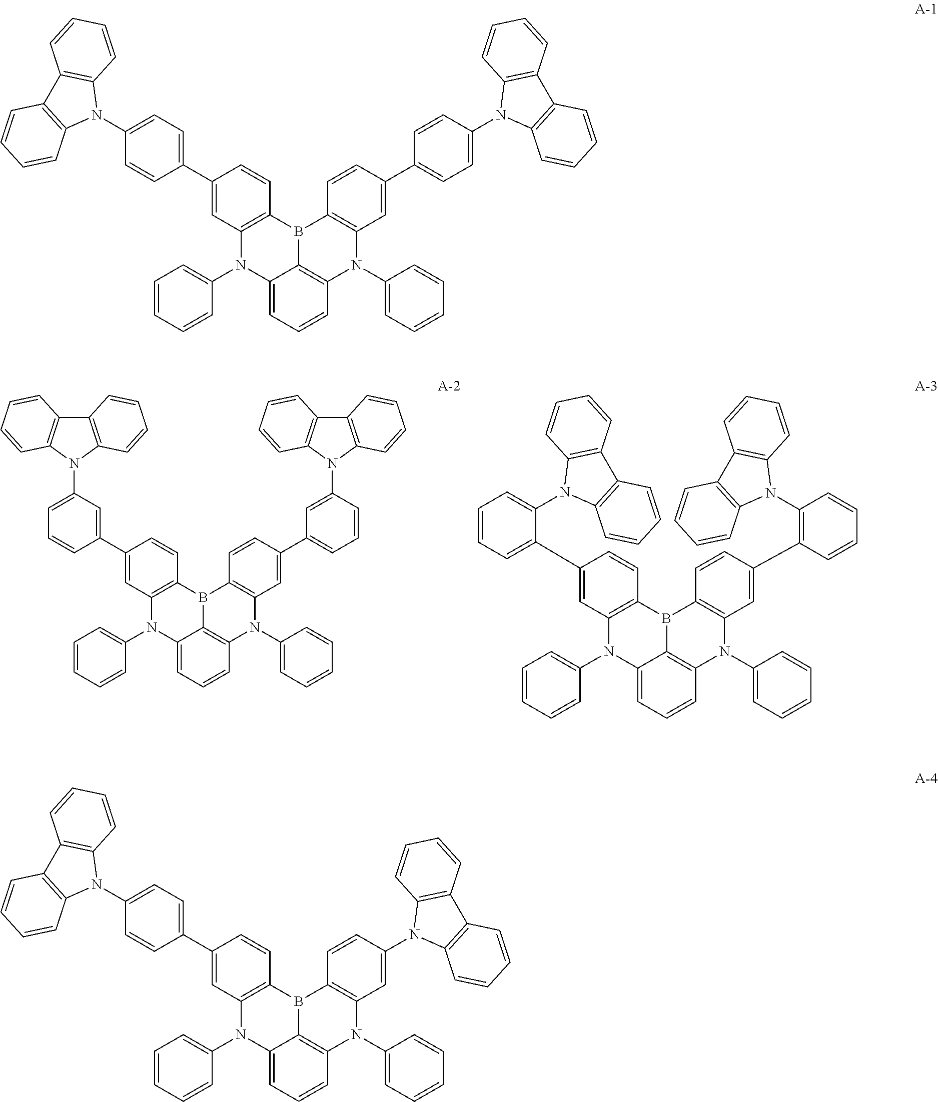 [SMILES: c1ccc(N2c3cc(-c4ccc(-n5c6ccccc6c6ccccc65)cc4)ccc3B3c4ccc(-c5ccc(-n6c7ccccc7c7ccccc76)cc5)cc4N(c4ccccc4)c4cccc2c43)cc1 ; c1ccc(N2c3cc(-c4cccc(-n5c6ccccc6c6ccccc65)c4)ccc3B3c4ccc(-c5cccc(-n6c7ccccc7c7ccccc76)c5)cc4N(c4ccccc4)c4cccc2c43)cc1 ; c1ccc(N2c3cc(-c4ccccc4-n4c5ccccc5c5ccccc54)ccc3B3c4ccc(-c5ccccc5-n5c6ccccc6c6ccccc65)cc4N(c4ccccc4)c4cccc2c43)cc1 ; c1ccc(N2c3cc(-c4ccc(-n5c6ccccc6c6ccccc65)cc4)ccc3B3c4ccc(-n5c6ccccc6c6ccccc65)cc4N(c4ccccc4)c4cccc2c43)cc1]

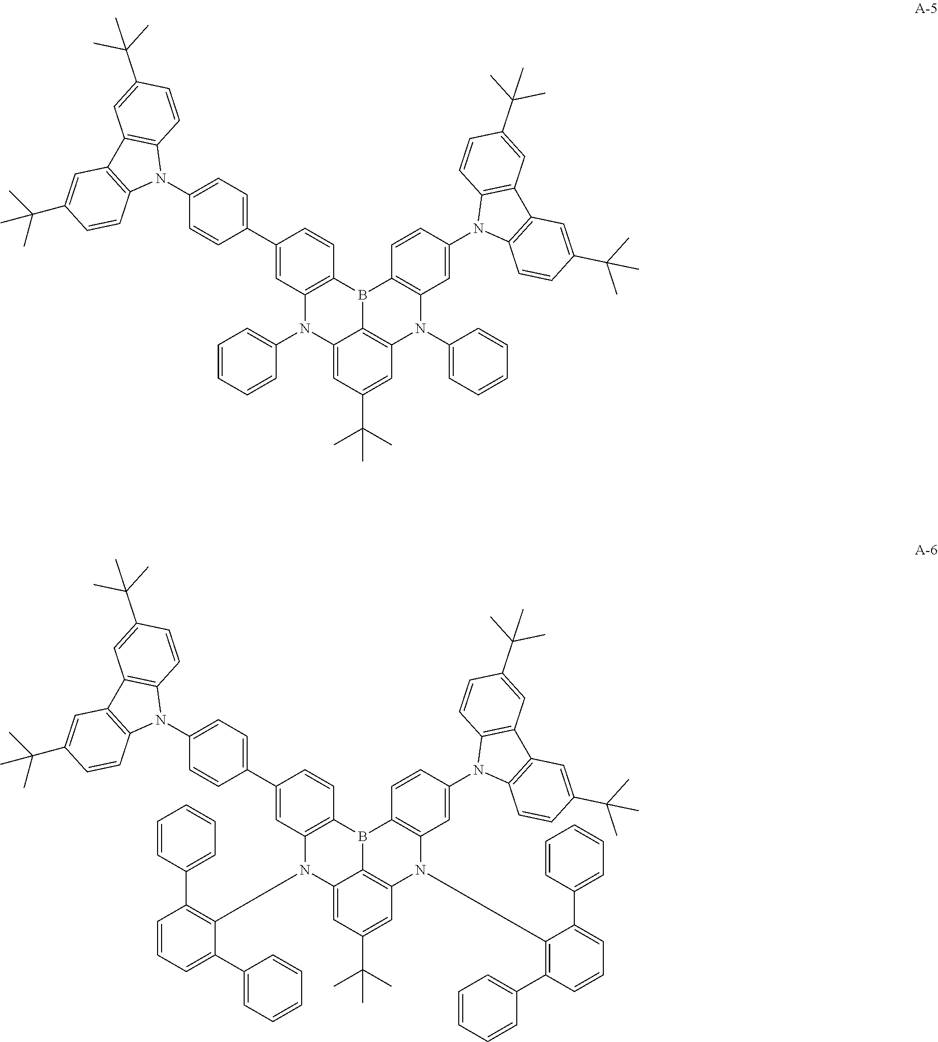

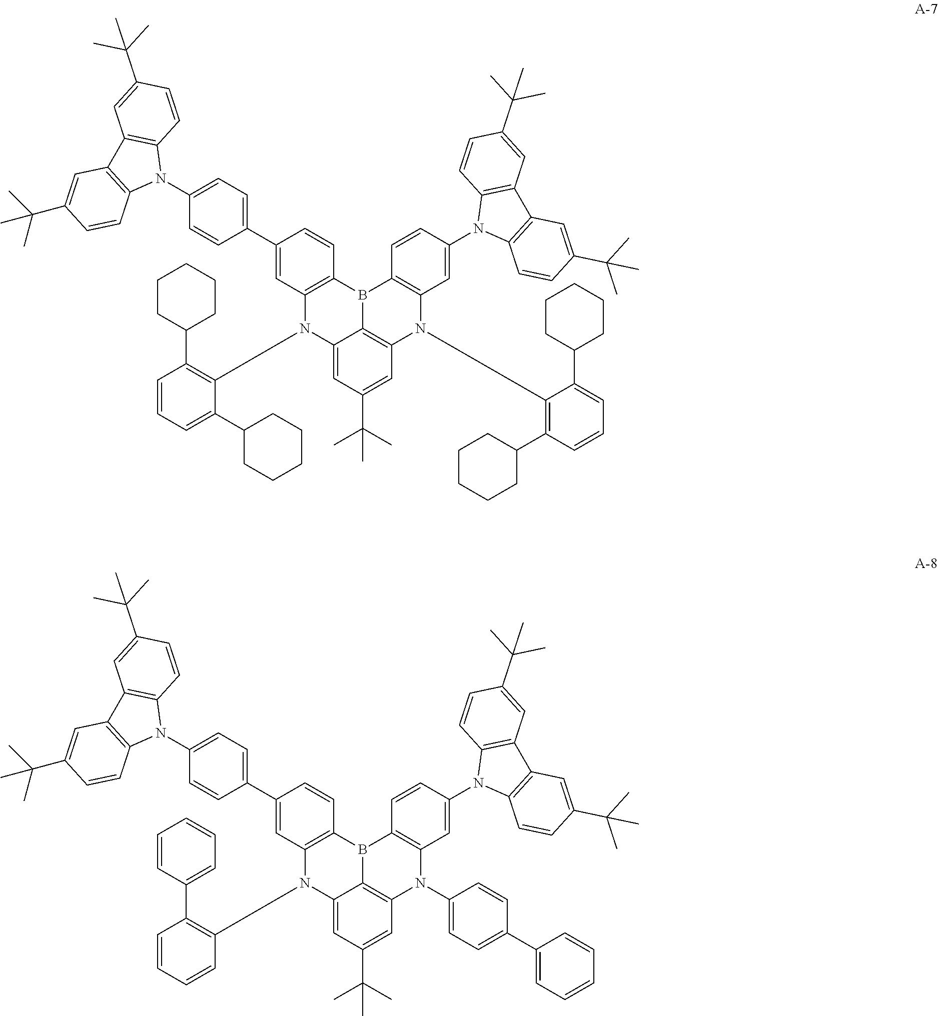

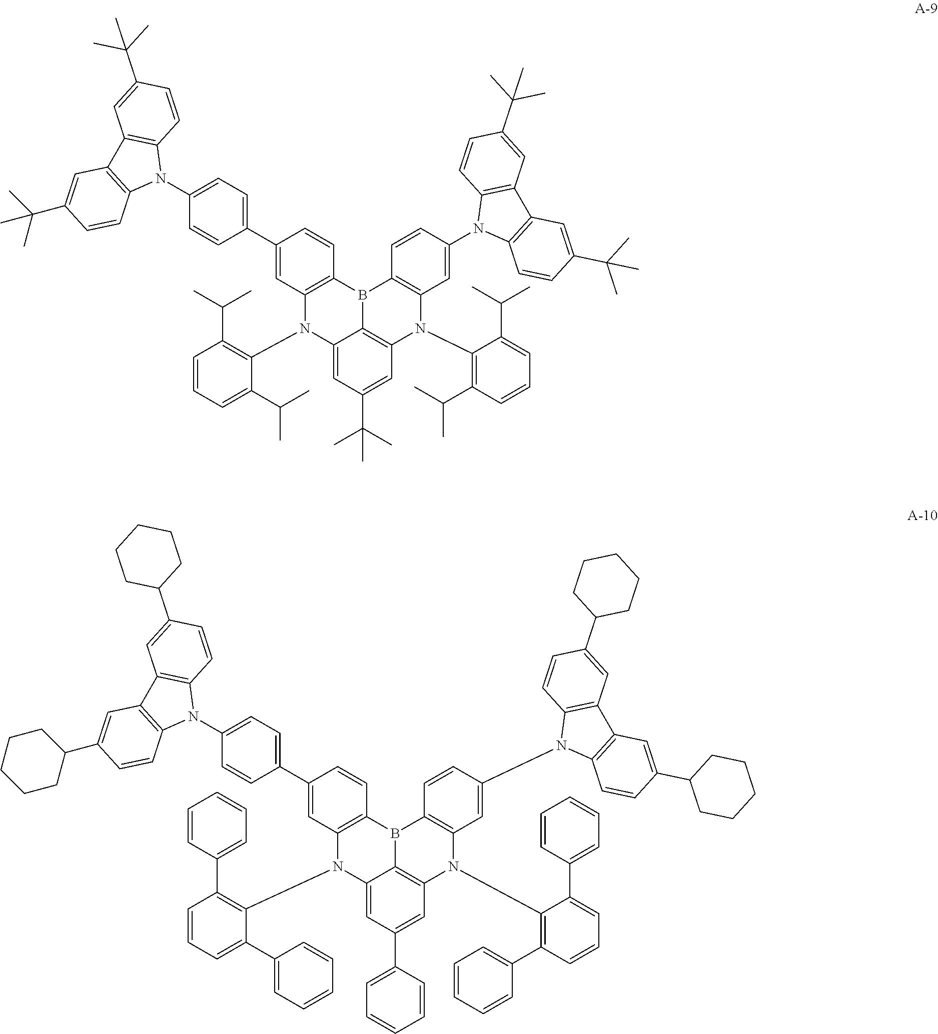 [SMILES: CC(C)c1cccc(C(C)C)c1N1c2cc(-c3ccc(-n4c5ccc(C(C)(C)C)cc5c5cc(C(C)(C)C)ccc54)cc3)ccc2B2c3ccc(-n4c5ccc(C(C)(C)C)cc5c5cc(C(C)(C)C)ccc54)cc3N(c3c(C(C)C)cccc3C(C)C)c3cc(C(C)(C)C)cc1c32 ; c1ccc(-c2cc3c4c(c2)N(c2c(-c5ccccc5)cccc2-c2ccccc2)c2cc(-n5c6ccc(C7CCCCC7)cc6c6cc(C7CCCCC7)ccc65)ccc2B4c2ccc(-c4ccc(-n5c6ccc(C7CCCCC7)cc6c6cc(C7CCCCC7)ccc65)cc4)cc2N3c2c(-c3ccccc3)cccc2-c2ccccc2)cc1]

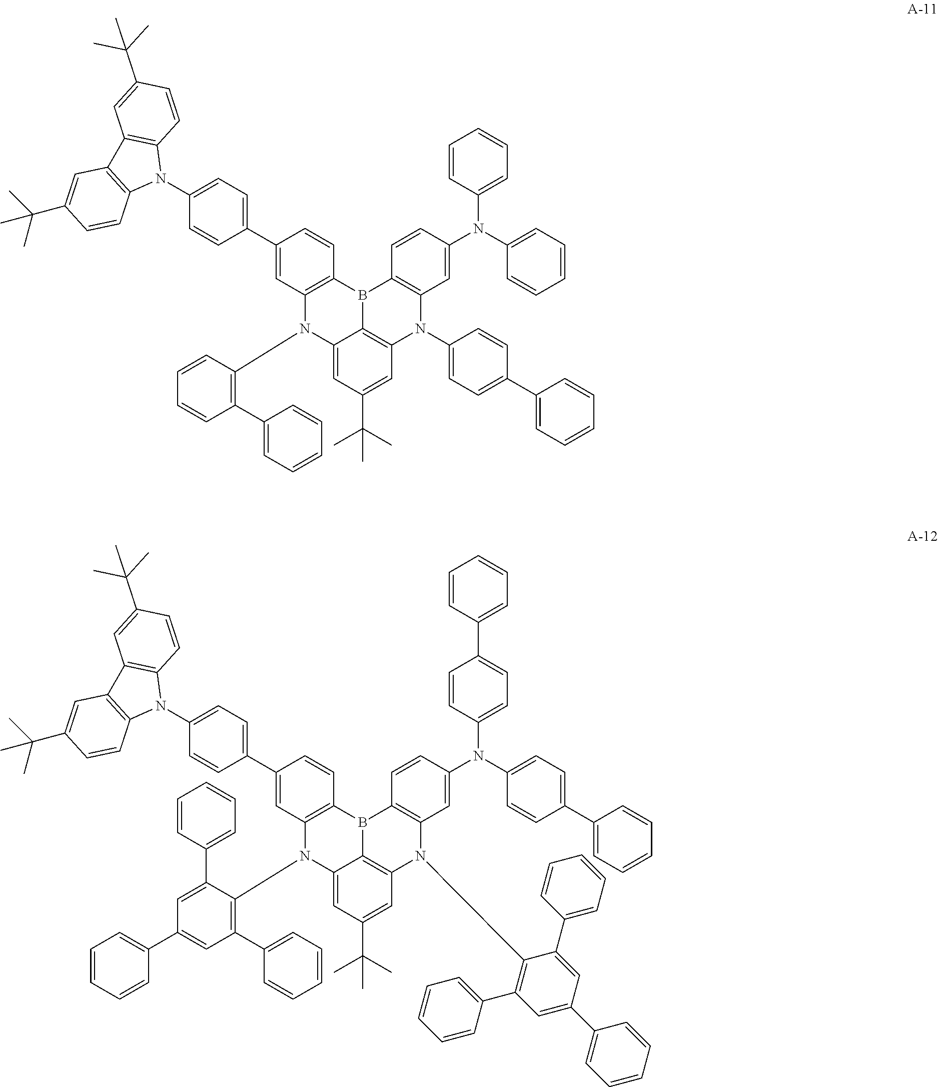 [SMILES: CC(C)(C)c1cc2c3c(c1)N(c1ccccc1-c1ccccc1)c1cc(-c4ccc(-n5c6ccc(C(C)(C)C)cc6c6cc(C(C)(C)C)ccc65)cc4)ccc1B3c1ccc(N(c3ccccc3)c3ccccc3)cc1N2c1ccc(-c2ccccc2)cc1 ; CC(C)(C)c1cc2c3c(c1)N(c1c(-c4ccccc4)cc(-c4ccccc4)cc1-c1ccccc1)c1cc(N(c4ccc(-c5ccccc5)cc4)c4ccc(-c5ccccc5)cc4)ccc1B3c1ccc(-c3ccc(-n4c5ccc(C(C)(C)C)cc5c5cc(C(C)(C)C)ccc54)cc3)cc1N2c1c(-c2ccccc2)cc(-c2ccccc2)cc1-c1ccccc1]

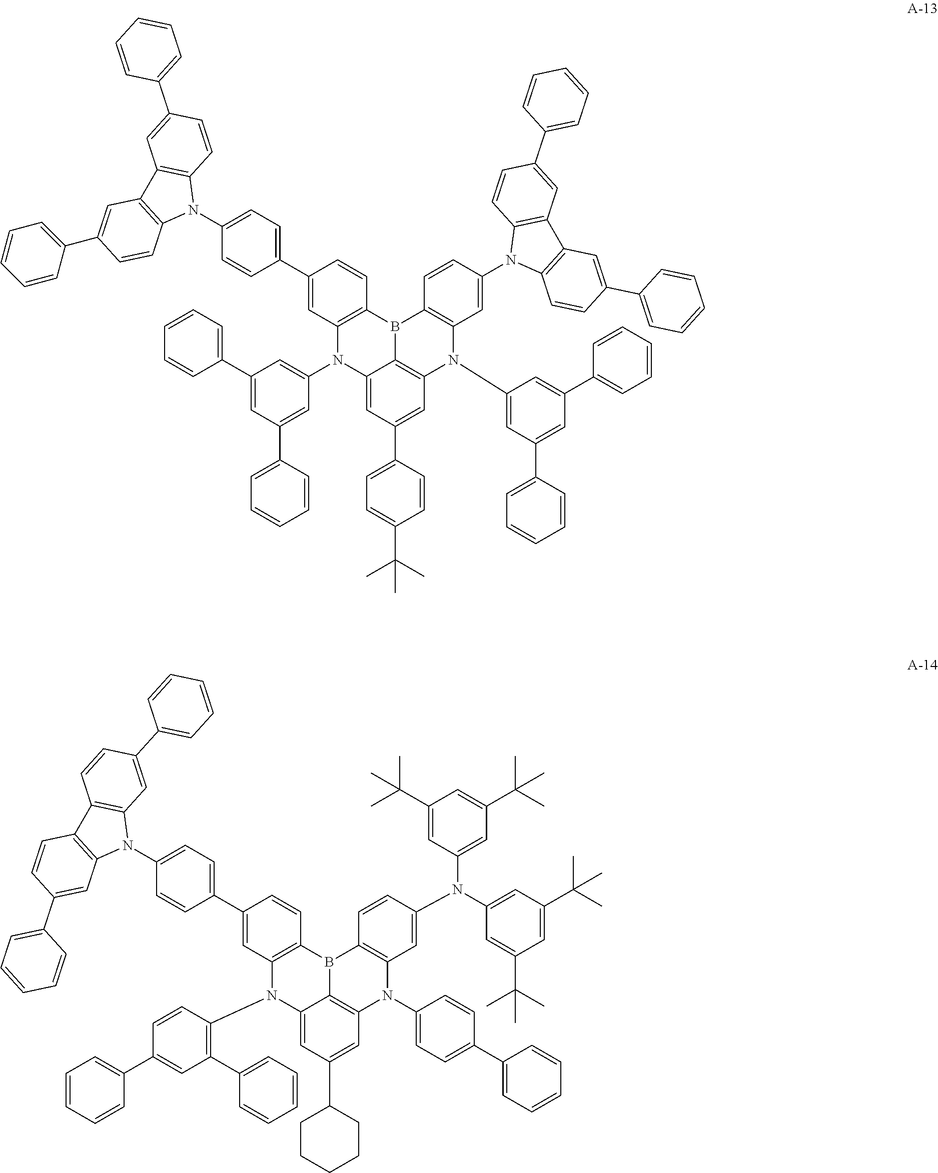 [SMILES: CC(C)(C)c1ccc(-c2cc3c4c(c2)N(c2cc(-c5ccccc5)cc(-c5ccccc5)c2)c2cc(-n5c6ccc(-c7ccccc7)cc6c6cc(-c7ccccc7)ccc65)ccc2B4c2ccc(-c4ccc(-n5c6ccc(-c7ccccc7)cc6c6cc(-c7ccccc7)ccc65)cc4)cc2N3c2cc(-c3ccccc3)cc(-c3ccccc3)c2)cc1 ; CC(C)(C)c1cc(N(c2cc(C(C)(C)C)cc(C(C)(C)C)c2)c2ccc3c(c2)N(c2ccc(-c4ccccc4)cc2)c2cc(C4CCCCC4)cc4c2B3c2ccc(-c3ccc(-n5c6cc(-c7ccccc7)ccc6c6ccc(-c7ccccc7)cc65)cc3)cc2N4c2ccc(-c3ccccc3)cc2-c2ccccc2)cc(C(C)(C)C)c1]

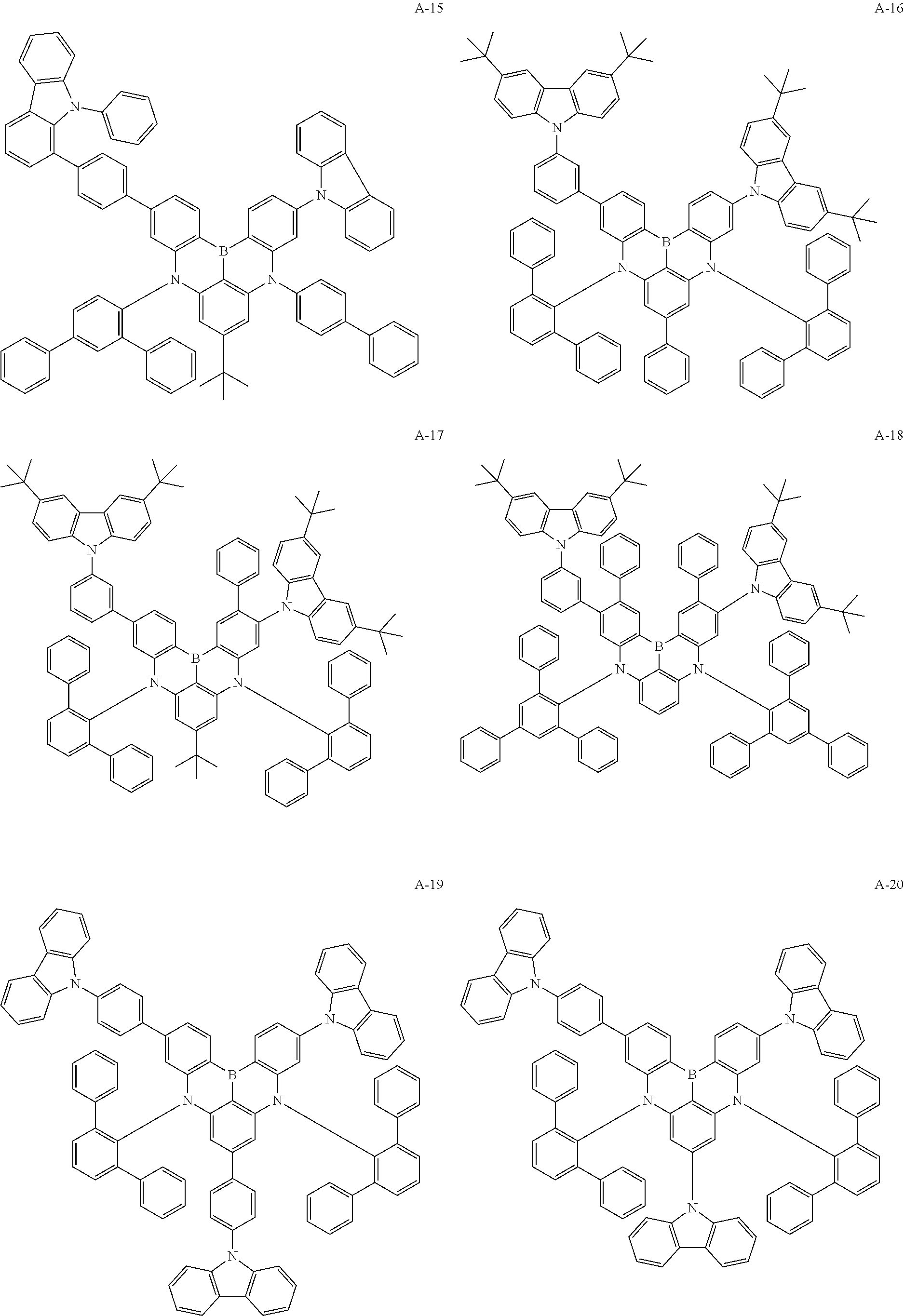

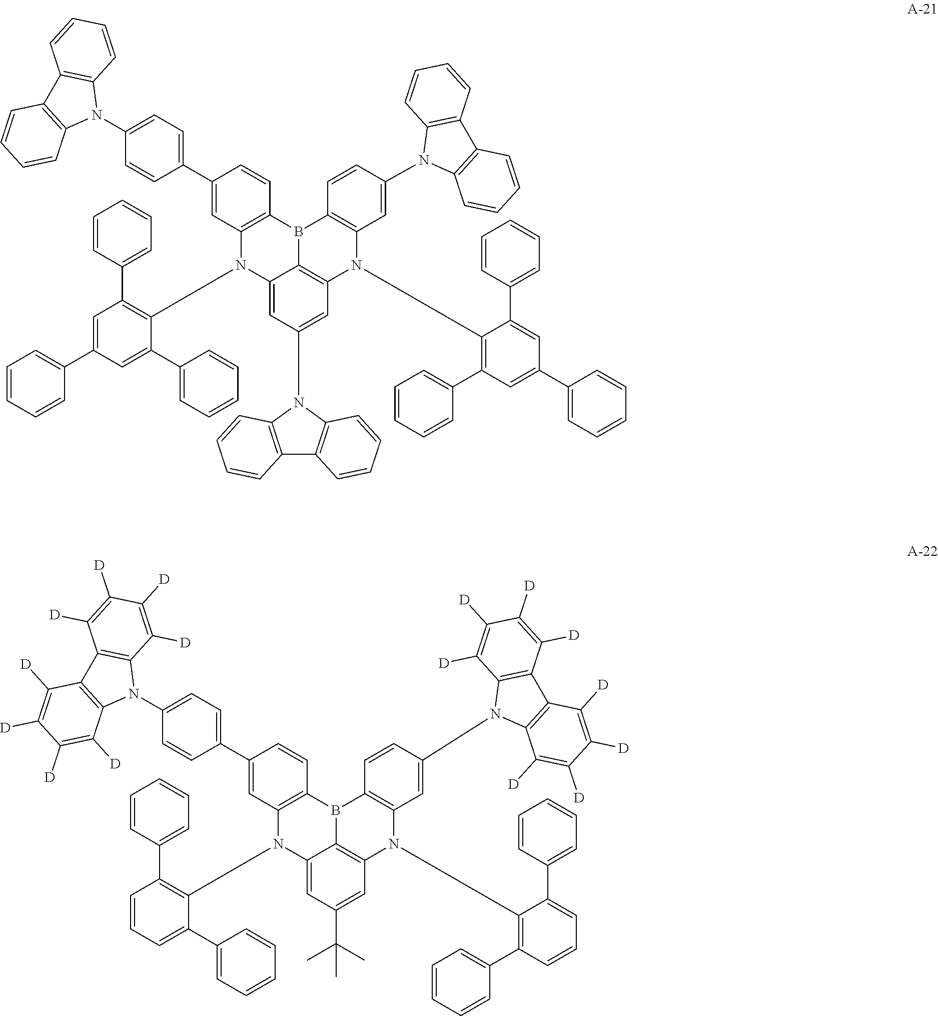 [SMILES: c1ccc(-c2cc(-c3ccccc3)c(N3c4cc(-c5ccc(-n6c7ccccc7c7ccccc76)cc5)ccc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; [2H]c1c([2H])c([2H])c2c(c1[2H])c1c([2H])c([2H])c([2H])c([2H])c1n2-c1ccc(-c2ccc3c(c2)N(c2c(-c4ccccc4)cccc2-c2ccccc2)c2cc(C(C)(C)C)cc4c2B3c2ccc(-n3c5c([2H])c([2H])c([2H])c([2H])c5c5c([2H])c([2H])c([2H])c([2H])c53)cc2N4c2c(-c3ccccc3)cccc2-c2ccccc2)cc1]

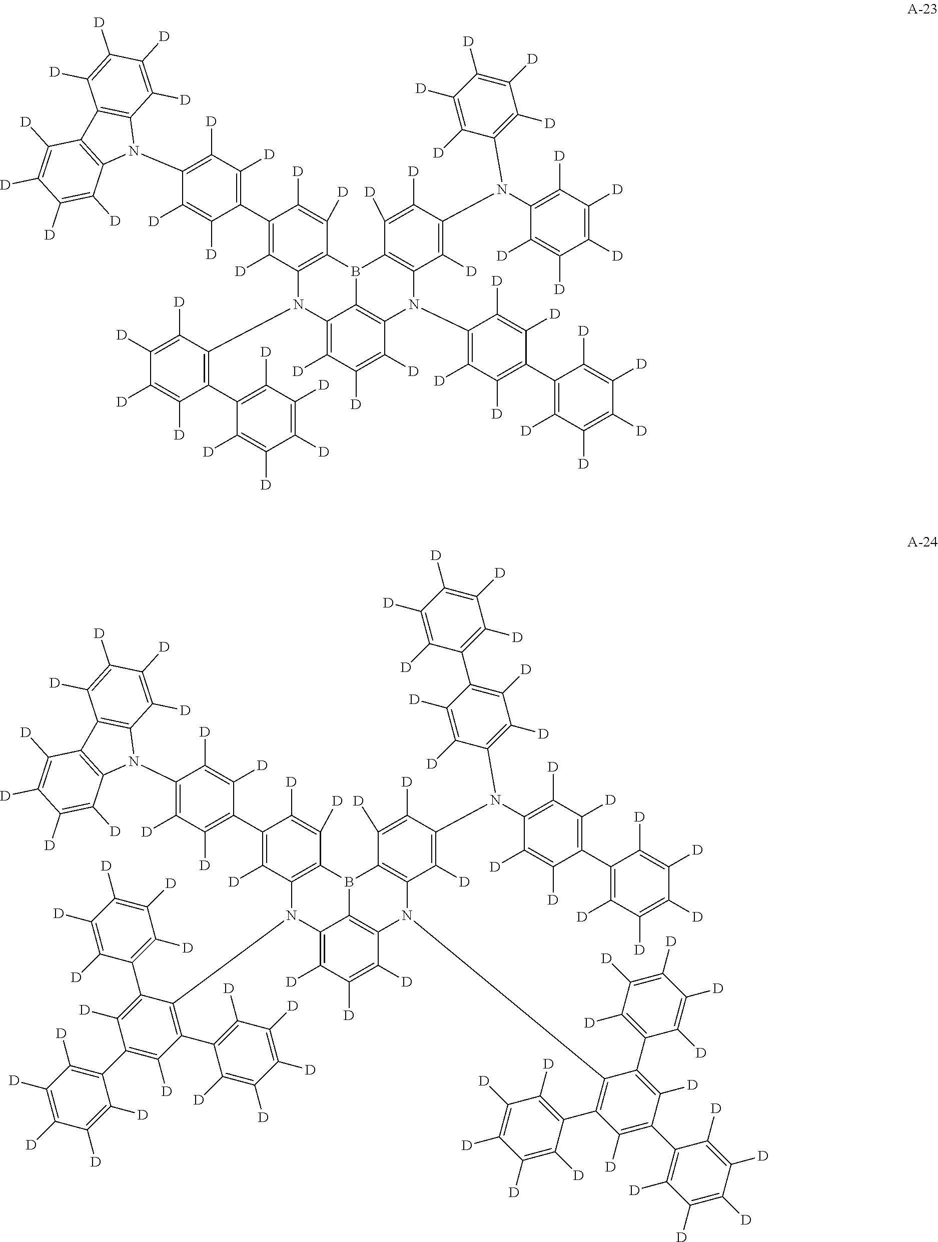

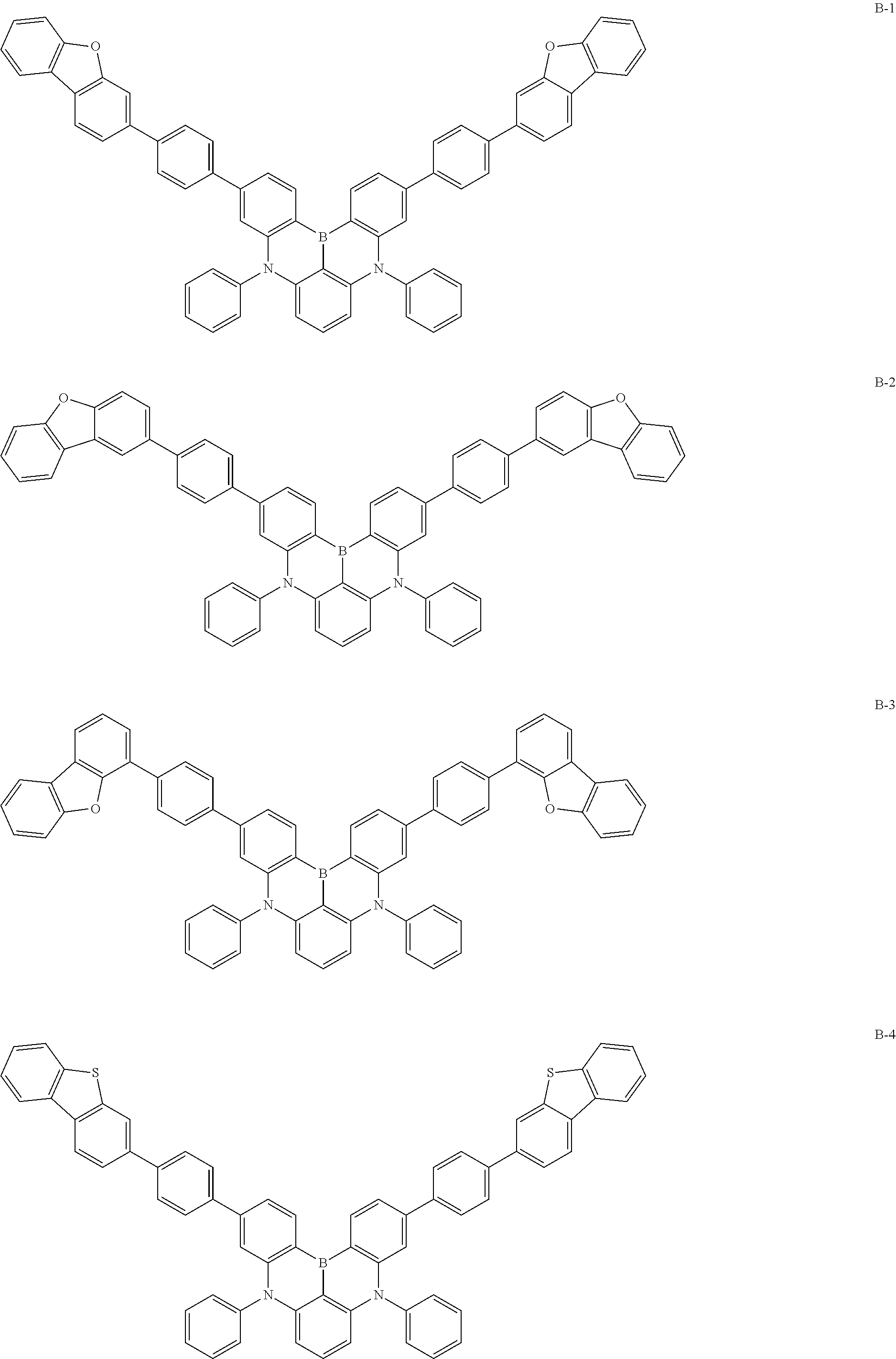 [SMILES: c1ccc(N2c3cc(-c4ccc(-c5ccc6c(c5)oc5ccccc56)cc4)ccc3B3c4ccc(-c5ccc(-c6ccc7c(c6)oc6ccccc67)cc5)cc4N(c4ccccc4)c4cccc2c43)cc1 ; c1ccc(N2c3cc(-c4ccc(-c5ccc6oc7ccccc7c6c5)cc4)ccc3B3c4ccc(-c5ccc(-c6ccc7oc8ccccc8c7c6)cc5)cc4N(c4ccccc4)c4cccc2c43)cc1 ; c1ccc(N2c3cc(-c4ccc(-c5cccc6c5oc5ccccc56)cc4)ccc3B3c4ccc(-c5ccc(-c6cccc7c6oc6ccccc67)cc5)cc4N(c4ccccc4)c4cccc2c43)cc1 ; c1ccc(N2c3cc(-c4ccc(-c5ccc6c(c5)sc5ccccc56)cc4)ccc3B3c4ccc(-c5ccc(-c6ccc7c(c6)sc6ccccc67)cc5)cc4N(c4ccccc4)c4cccc2c43)cc1]

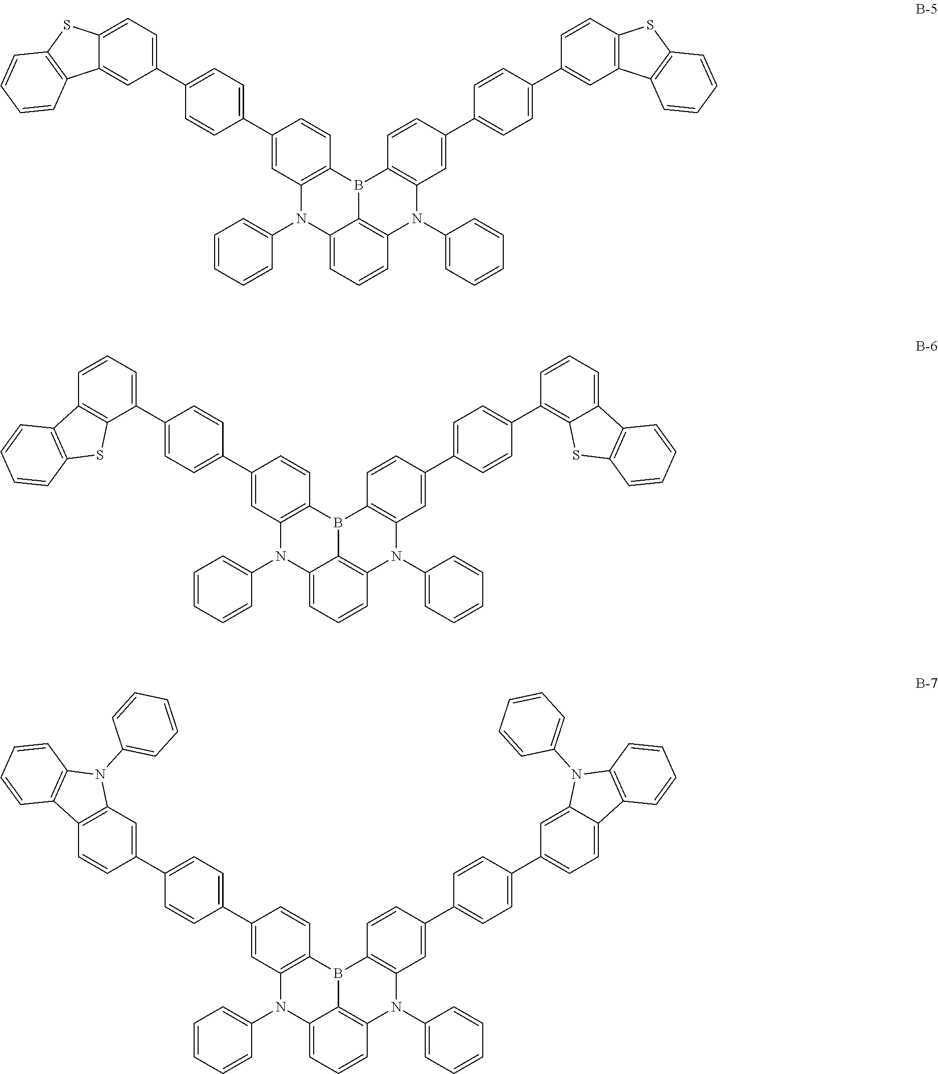 [SMILES: c1ccc(N2c3cc(-c4ccc(-c5ccc6sc7ccccc7c6c5)cc4)ccc3B3c4ccc(-c5ccc(-c6ccc7sc8ccccc8c7c6)cc5)cc4N(c4ccccc4)c4cccc2c43)cc1 ; c1ccc(N2c3cc(-c4ccc(-c5cccc6c5sc5ccccc56)cc4)ccc3B3c4ccc(-c5ccc(-c6cccc7c6sc6ccccc67)cc5)cc4N(c4ccccc4)c4cccc2c43)cc1 ; c1ccc(N2c3cc(-c4ccc(-c5ccc6c7ccccc7n(-c7ccccc7)c6c5)cc4)ccc3B3c4ccc(-c5ccc(-c6ccc7c8ccccc8n(-c8ccccc8)c7c6)cc5)cc4N(c4ccccc4)c4cccc2c43)cc1]

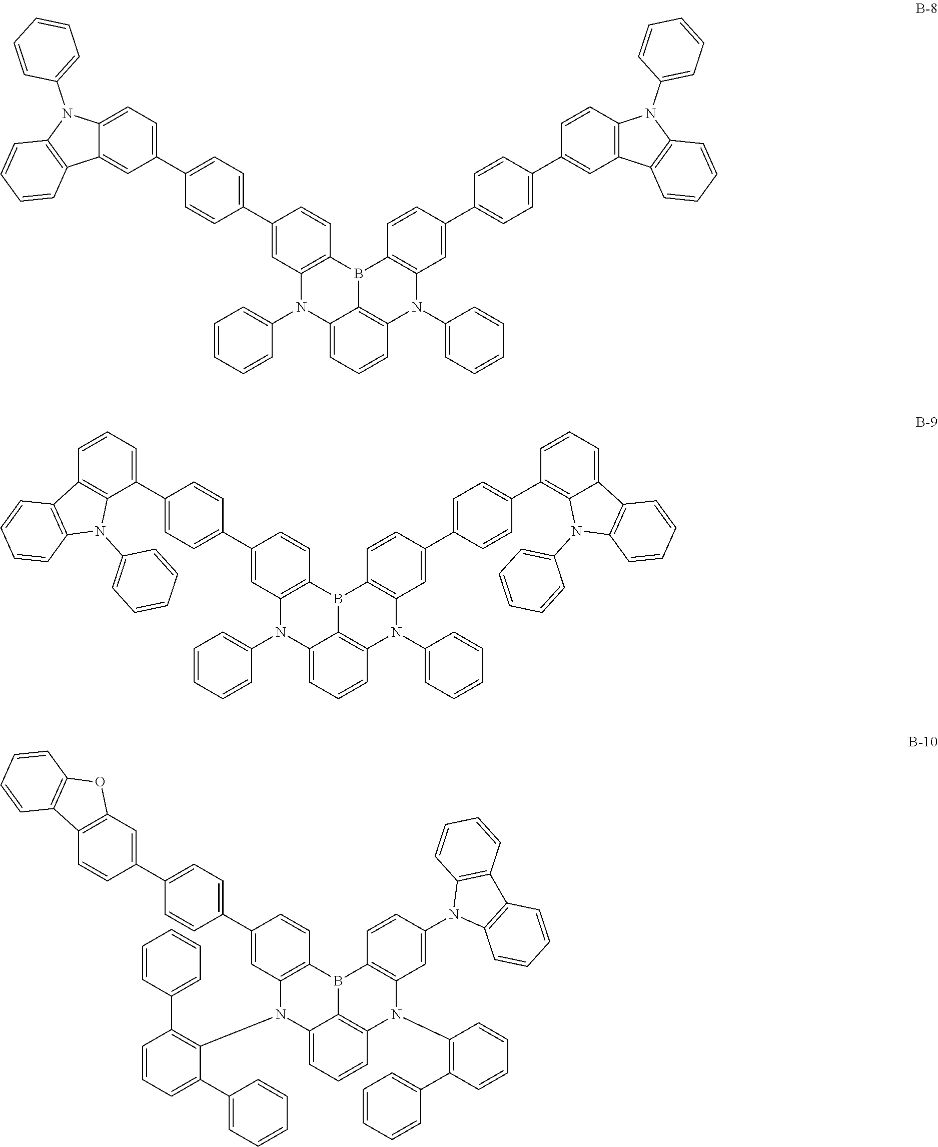 [SMILES: c1ccc(N2c3cc(-c4ccc(-c5ccc6c(c5)c5ccccc5n6-c5ccccc5)cc4)ccc3B3c4ccc(-c5ccc(-c6ccc7c(c6)c6ccccc6n7-c6ccccc6)cc5)cc4N(c4ccccc4)c4cccc2c43)cc1 ; c1ccc(N2c3cc(-c4ccc(-c5cccc6c7ccccc7n(-c7ccccc7)c56)cc4)ccc3B3c4ccc(-c5ccc(-c6cccc7c8ccccc8n(-c8ccccc8)c67)cc5)cc4N(c4ccccc4)c4cccc2c43)cc1 ; c1ccc(-c2ccccc2N2c3cc(-n4c5ccccc5c5ccccc54)ccc3B3c4ccc(-c5ccc(-c6ccc7c(c6)oc6ccccc67)cc5)cc4N(c4c(-c5ccccc5)cccc4-c4ccccc4)c4cccc2c43)cc1]

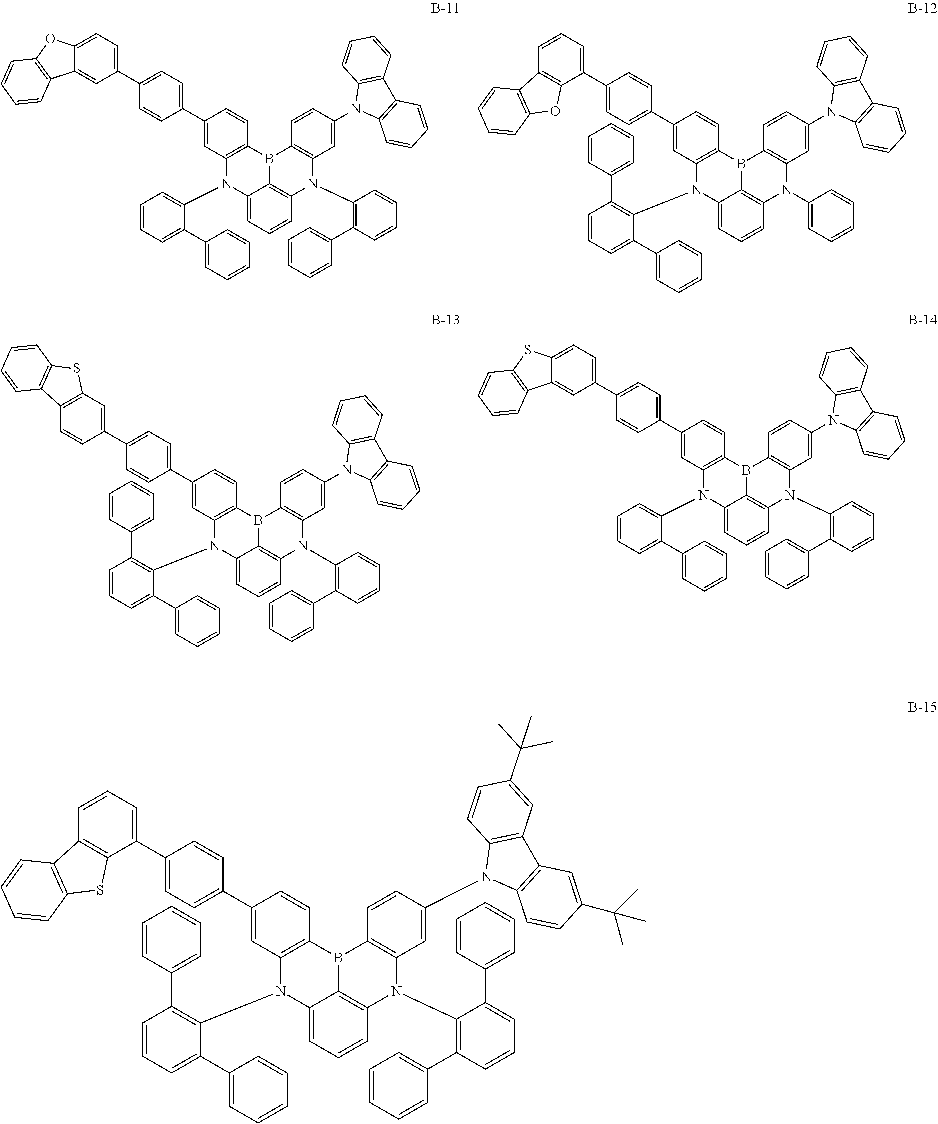

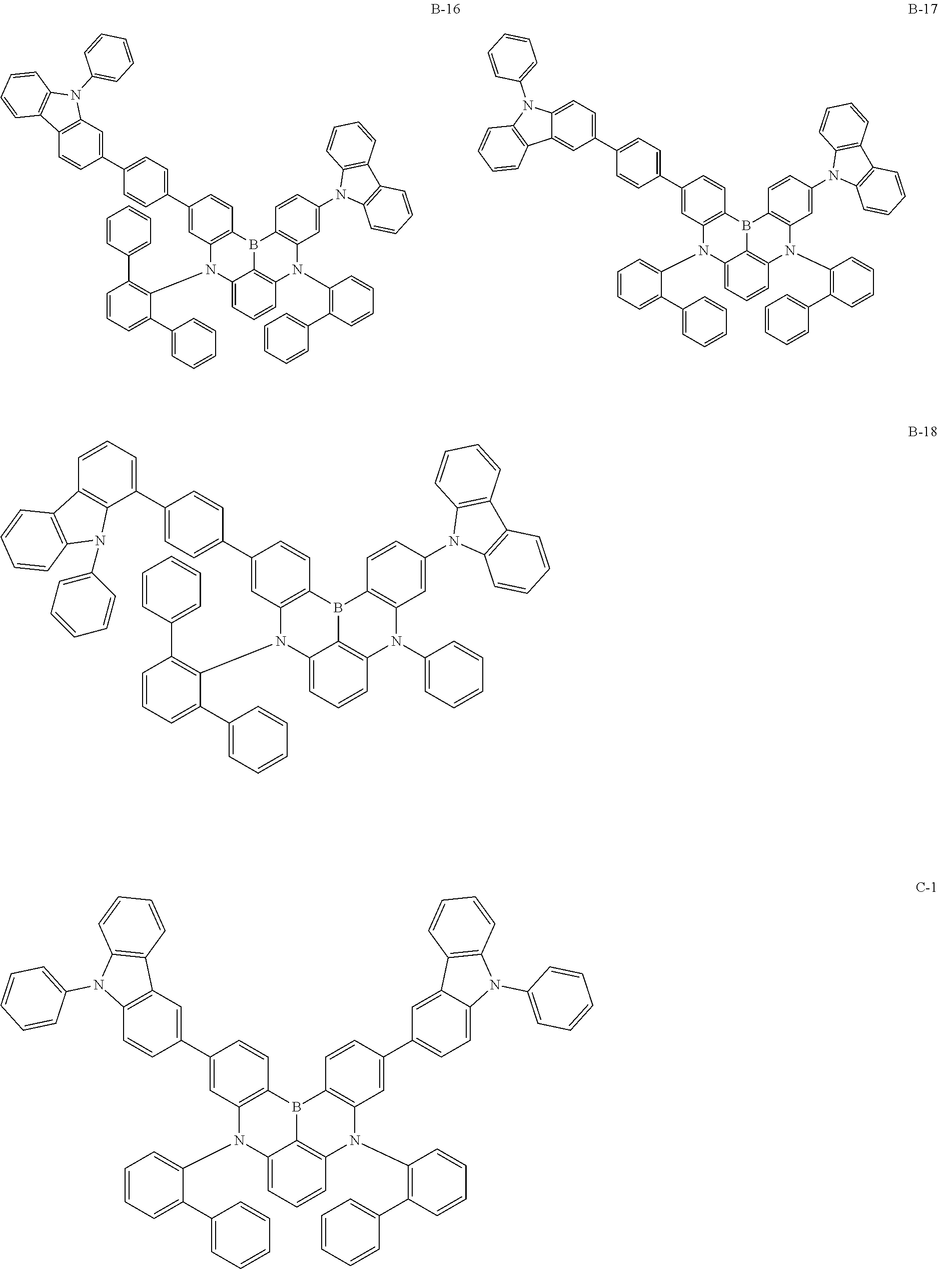

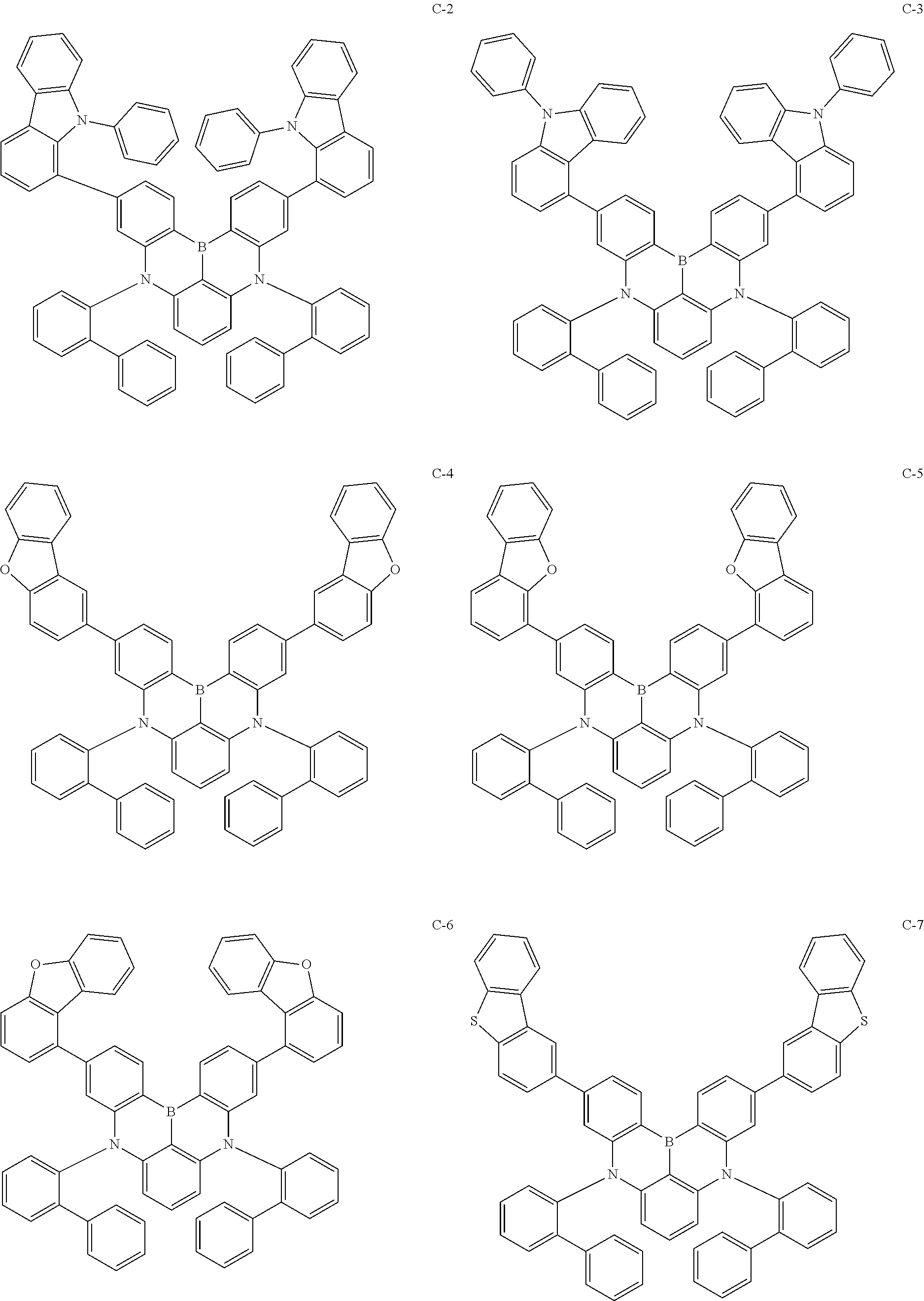

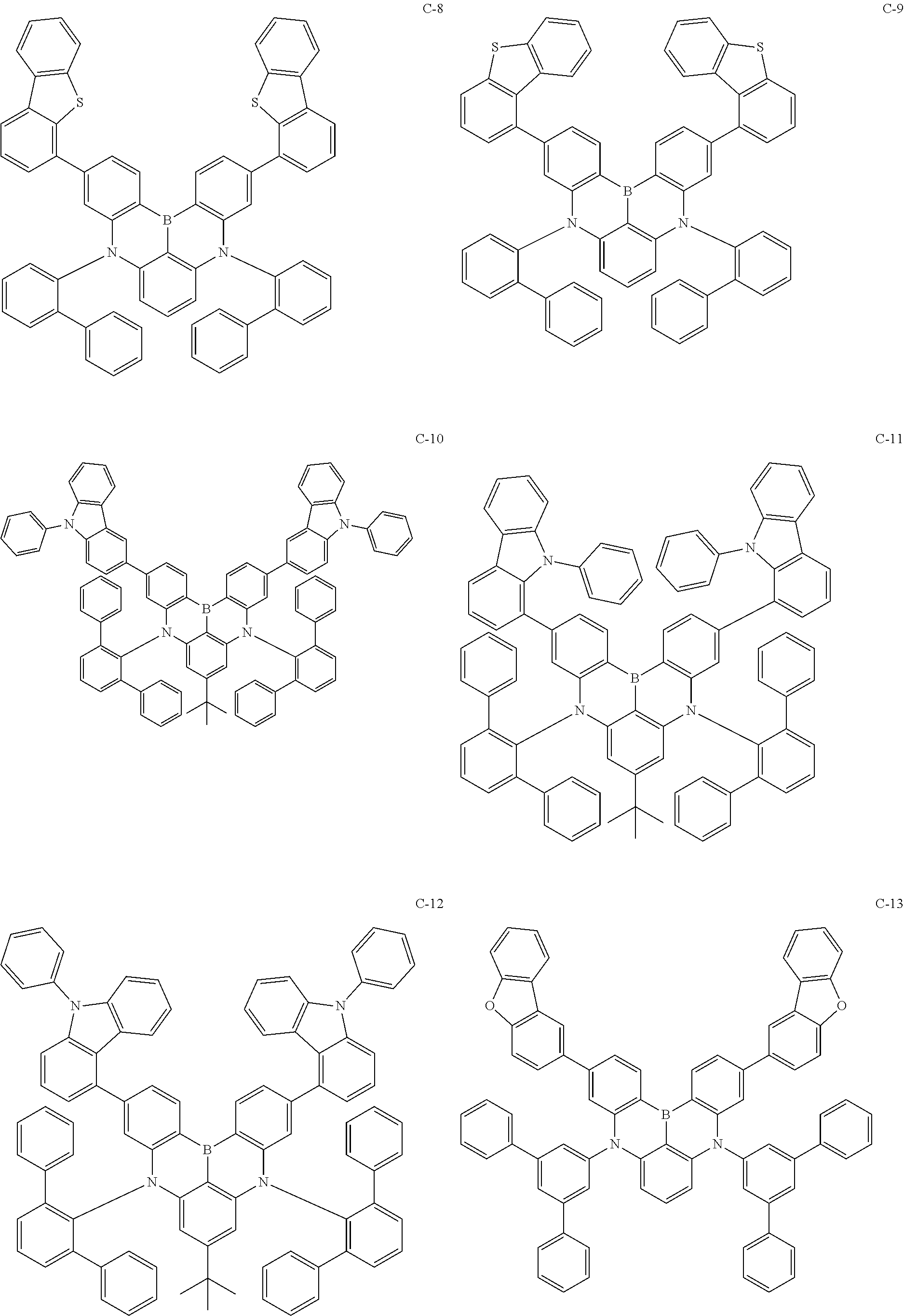

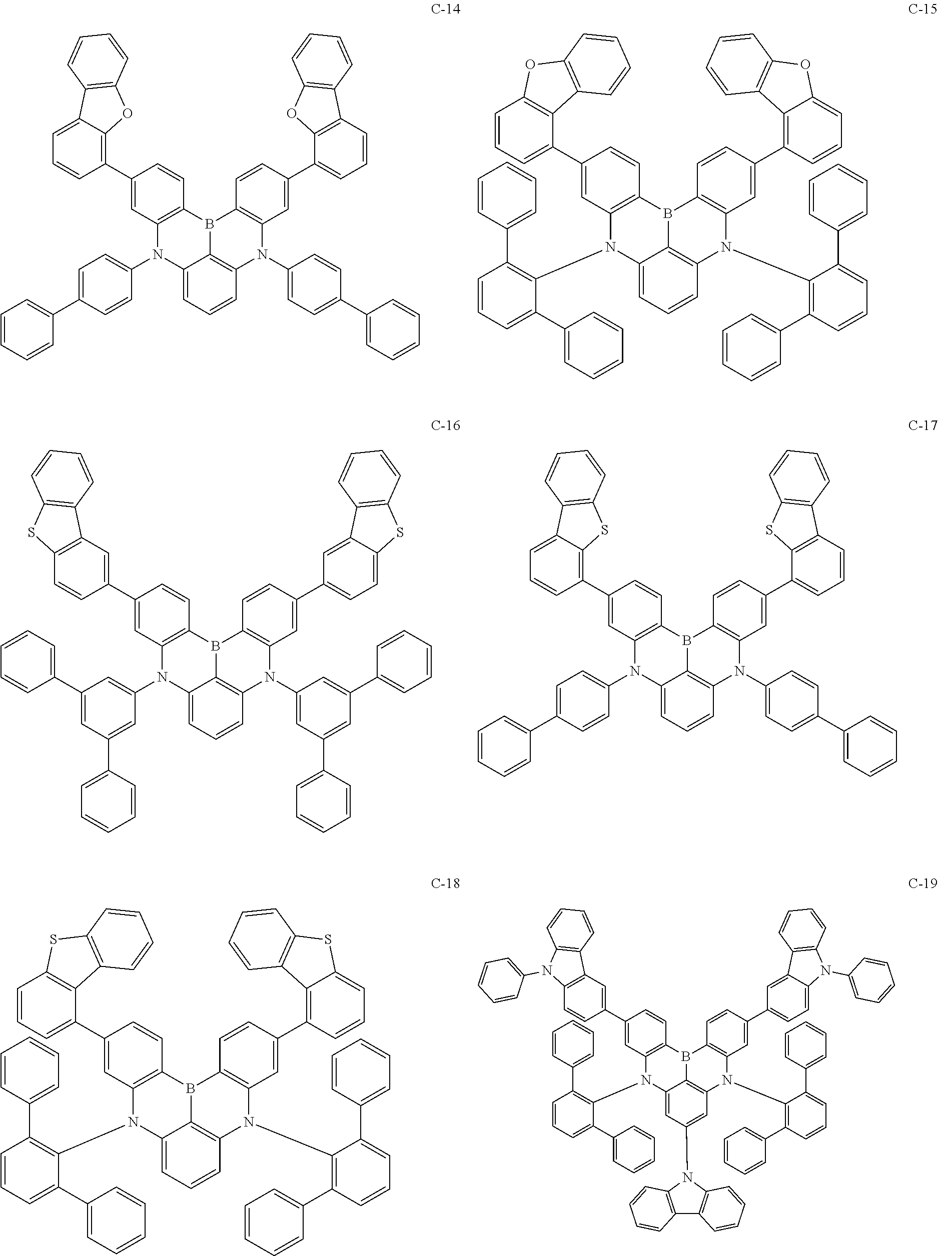

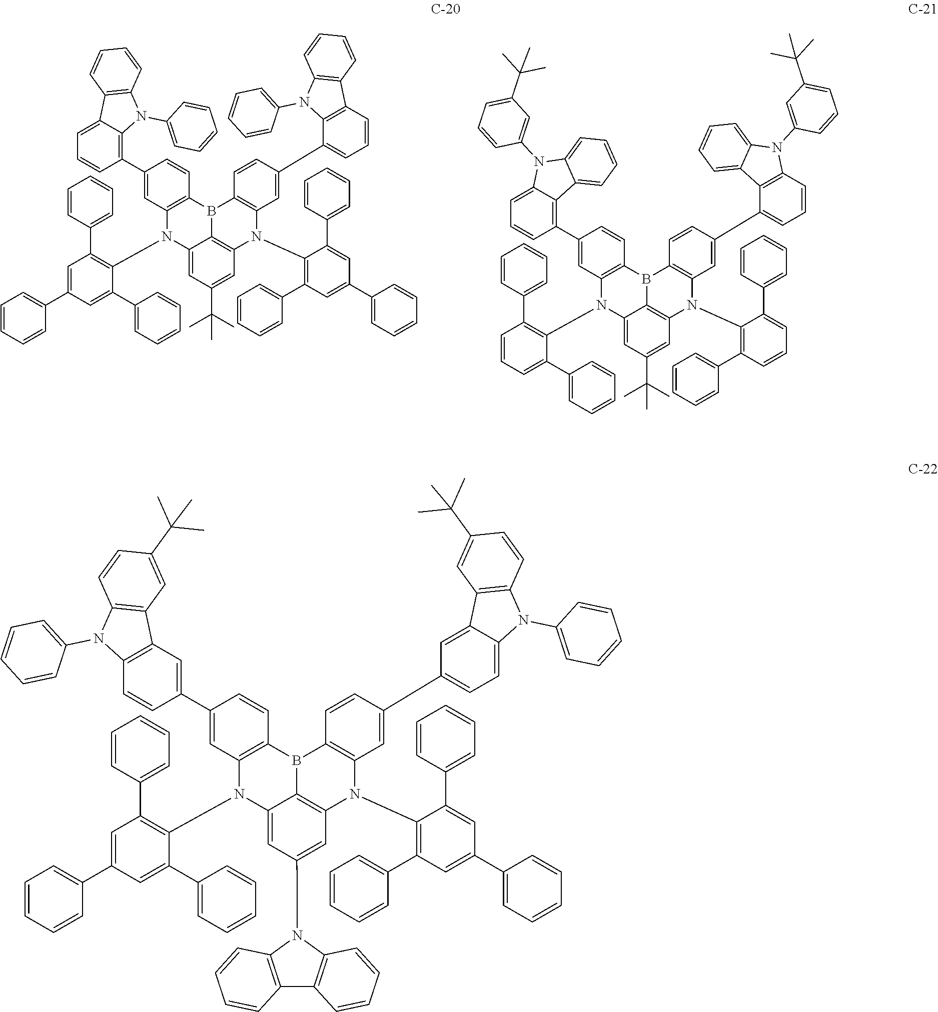

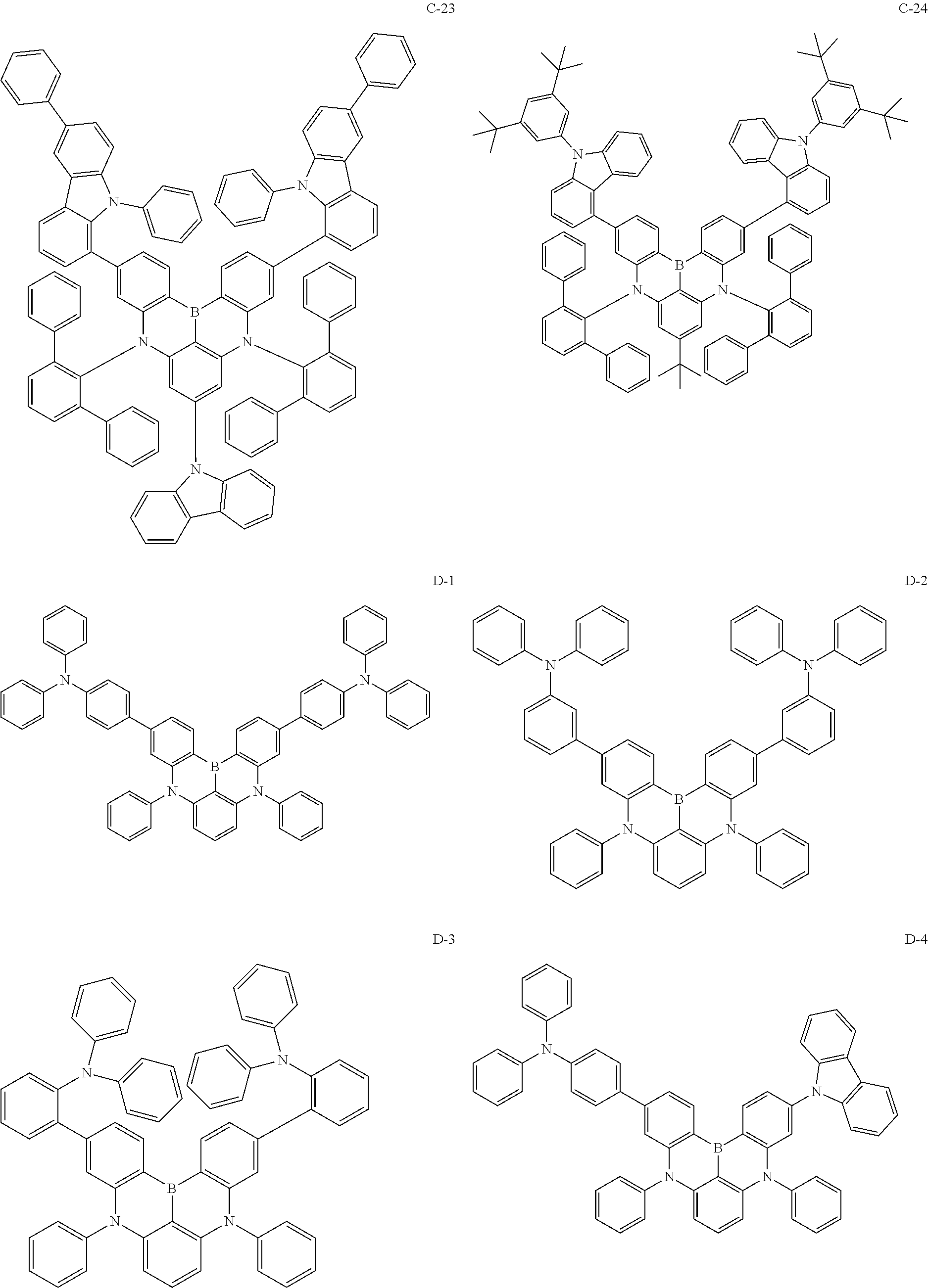

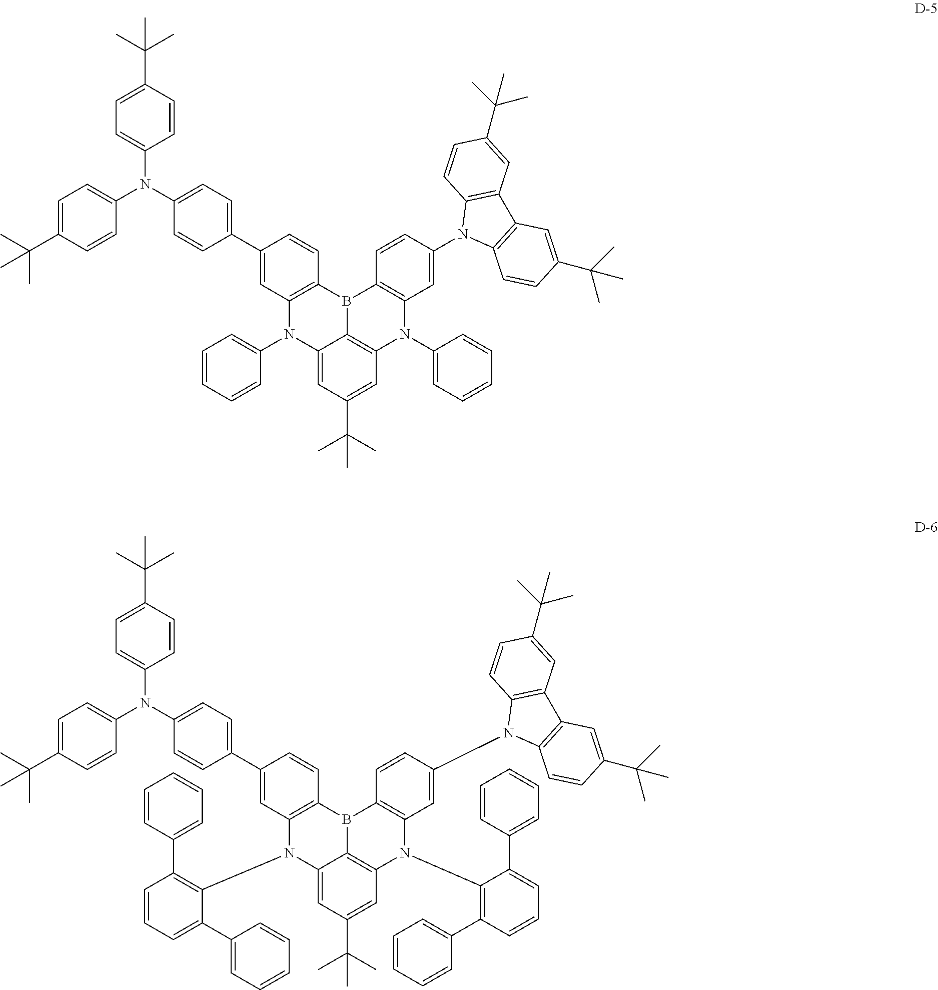

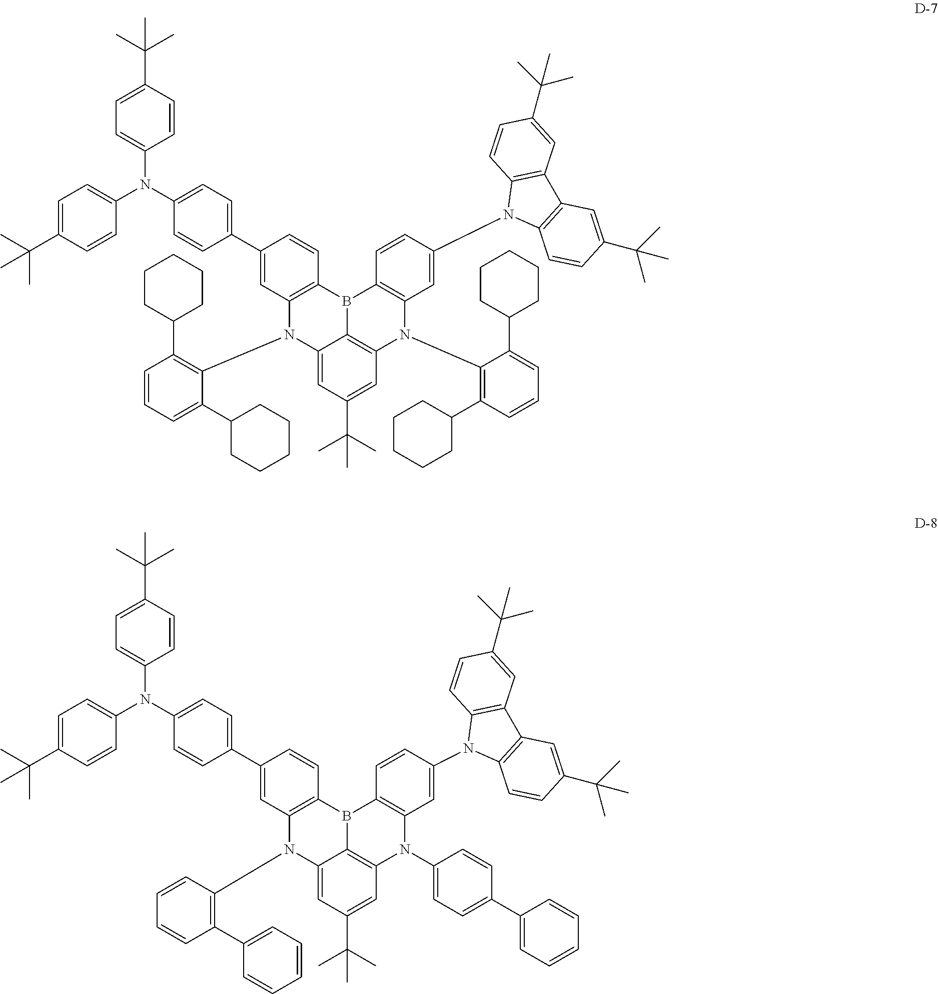

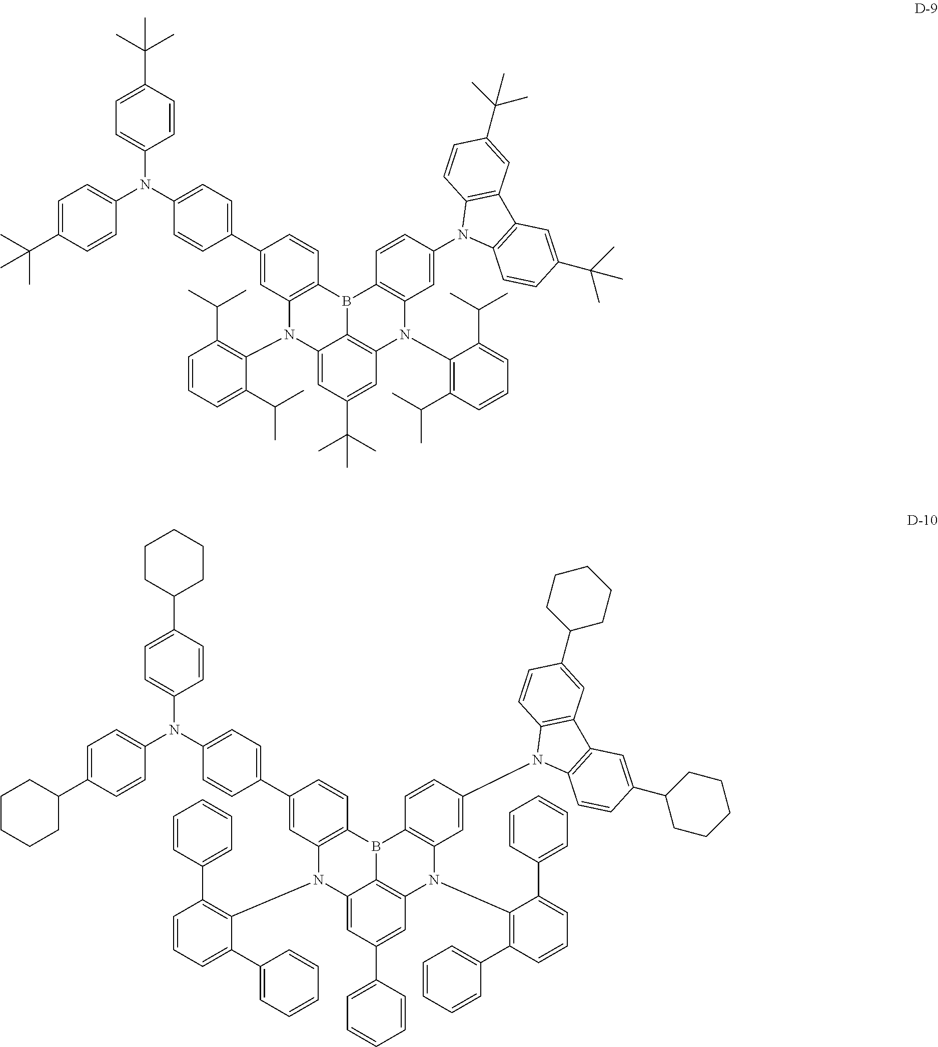 [SMILES: CC(C)c1cccc(C(C)C)c1N1c2cc(-c3ccc(N(c4ccc(C(C)(C)C)cc4)c4ccc(C(C)(C)C)cc4)cc3)ccc2B2c3ccc(-n4c5ccc(C(C)(C)C)cc5c5cc(C(C)(C)C)ccc54)cc3N(c3c(C(C)C)cccc3C(C)C)c3cc(C(C)(C)C)cc1c32 ; c1ccc(-c2cc3c4c(c2)N(c2c(-c5ccccc5)cccc2-c2ccccc2)c2cc(-n5c6ccc(C7CCCCC7)cc6c6cc(C7CCCCC7)ccc65)ccc2B4c2ccc(-c4ccc(N(c5ccc(C6CCCCC6)cc5)c5ccc(C6CCCCC6)cc5)cc4)cc2N3c2c(-c3ccccc3)cccc2-c2ccccc2)cc1]

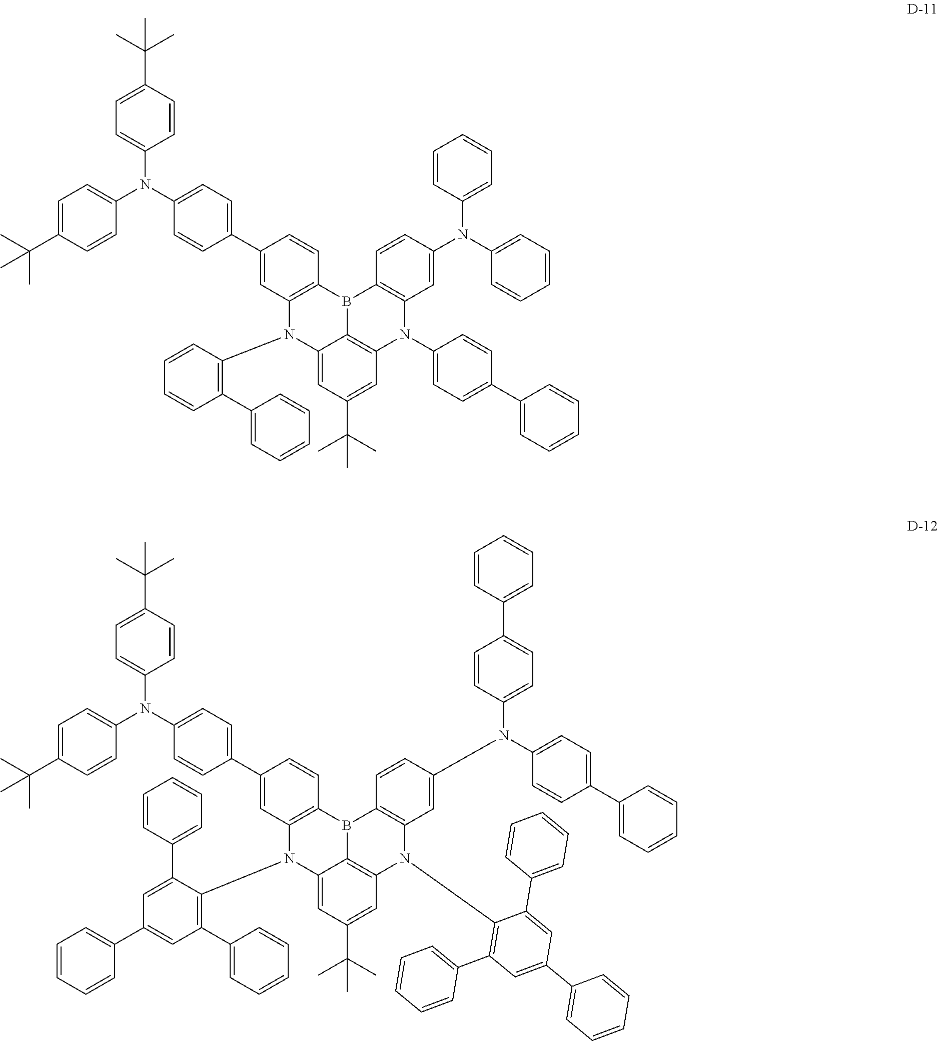 [SMILES: CC(C)(C)c1ccc(N(c2ccc(-c3ccc4c(c3)N(c3ccccc3-c3ccccc3)c3cc(C(C)(C)C)cc5c3B4c3ccc(N(c4ccccc4)c4ccccc4)cc3N5c3ccc(-c4ccccc4)cc3)cc2)c2ccc(C(C)(C)C)cc2)cc1 ; CC(C)(C)c1ccc(N(c2ccc(-c3ccc4c(c3)N(c3c(-c5ccccc5)cc(-c5ccccc5)cc3-c3ccccc3)c3cc(C(C)(C)C)cc5c3B4c3ccc(N(c4ccc(-c6ccccc6)cc4)c4ccc(-c6ccccc6)cc4)cc3N5c3c(-c4ccccc4)cc(-c4ccccc4)cc3-c3ccccc3)cc2)c2ccc(C(C)(C)C)cc2)cc1]

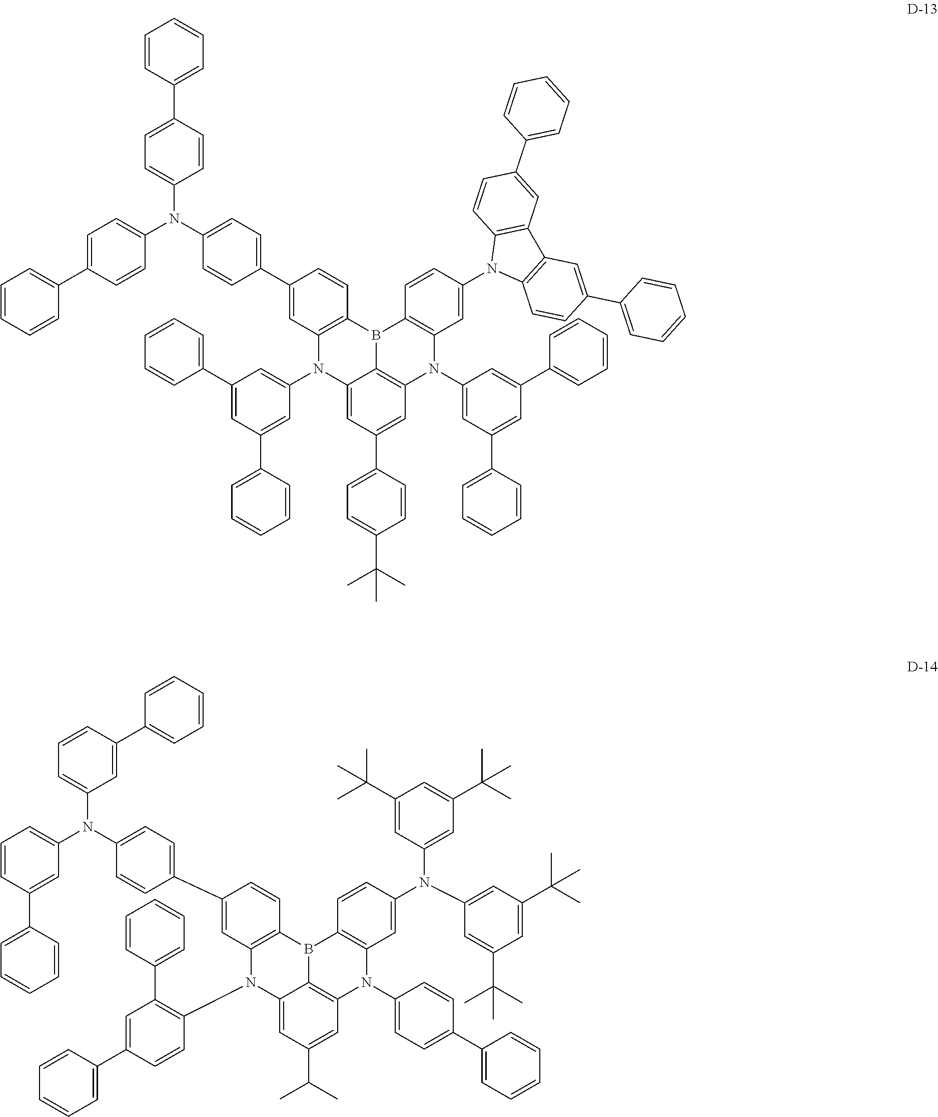 [SMILES: CC(C)(C)c1ccc(-c2cc3c4c(c2)N(c2cc(-c5ccccc5)cc(-c5ccccc5)c2)c2cc(-n5c6ccc(-c7ccccc7)cc6c6cc(-c7ccccc7)ccc65)ccc2B4c2ccc(-c4ccc(N(c5ccc(-c6ccccc6)cc5)c5ccc(-c6ccccc6)cc5)cc4)cc2N3c2cc(-c3ccccc3)cc(-c3ccccc3)c2)cc1 ; CC(C)c1cc2c3c(c1)N(c1ccc(-c4ccccc4)cc1-c1ccccc1)c1cc(-c4ccc(N(c5cccc(-c6ccccc6)c5)c5cccc(-c6ccccc6)c5)cc4)ccc1B3c1ccc(N(c3cc(C(C)(C)C)cc(C(C)(C)C)c3)c3cc(C(C)(C)C)cc(C(C)(C)C)c3)cc1N2c1ccc(-c2ccccc2)cc1]

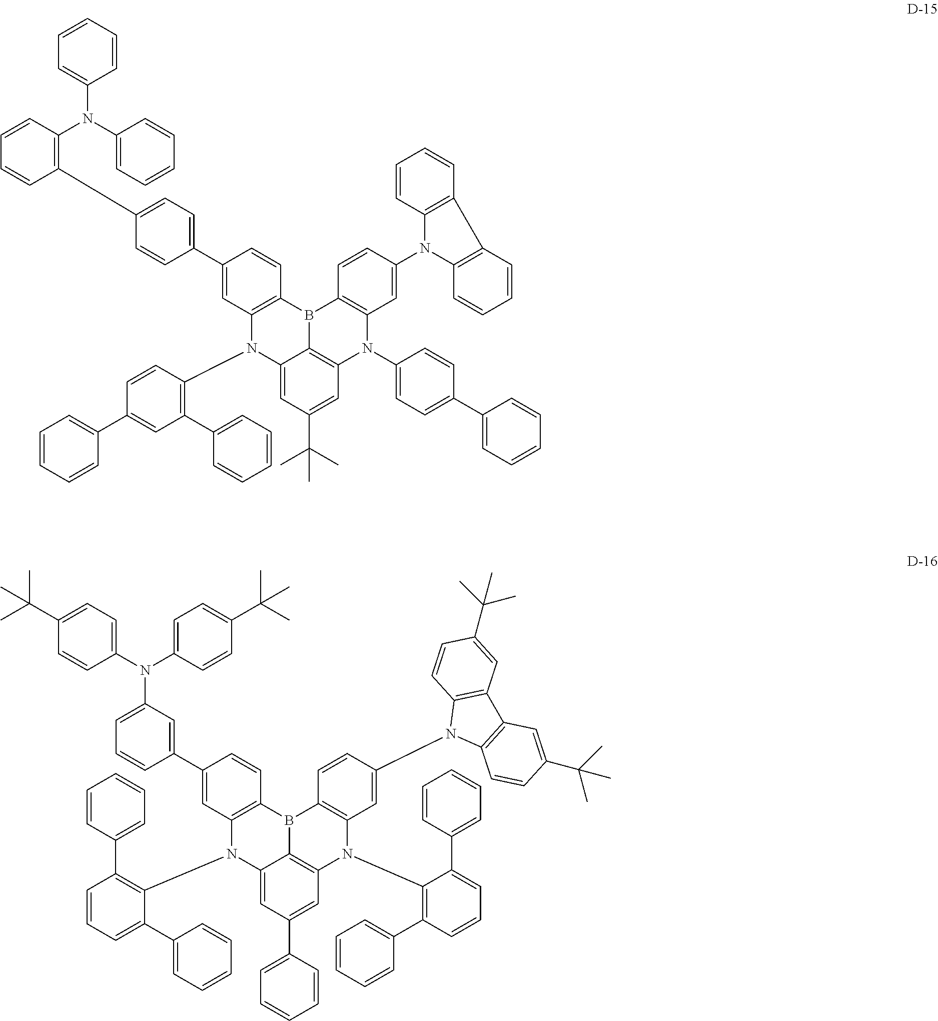 [SMILES: CC(C)(C)c1cc2c3c(c1)N(c1ccc(-c4ccccc4)cc1-c1ccccc1)c1cc(-c4ccc(-c5ccccc5N(c5ccccc5)c5ccccc5)cc4)ccc1B3c1ccc(-n3c4ccccc4c4ccccc43)cc1N2c1ccc(-c2ccccc2)cc1 ; CC(C)(C)c1ccc(N(c2ccc(C(C)(C)C)cc2)c2cccc(-c3ccc4c(c3)N(c3c(-c5ccccc5)cccc3-c3ccccc3)c3cc(-c5ccccc5)cc5c3B4c3ccc(-n4c6ccc(C(C)(C)C)cc6c6cc(C(C)(C)C)ccc64)cc3N5c3c(-c4ccccc4)cccc3-c3ccccc3)c2)cc1]

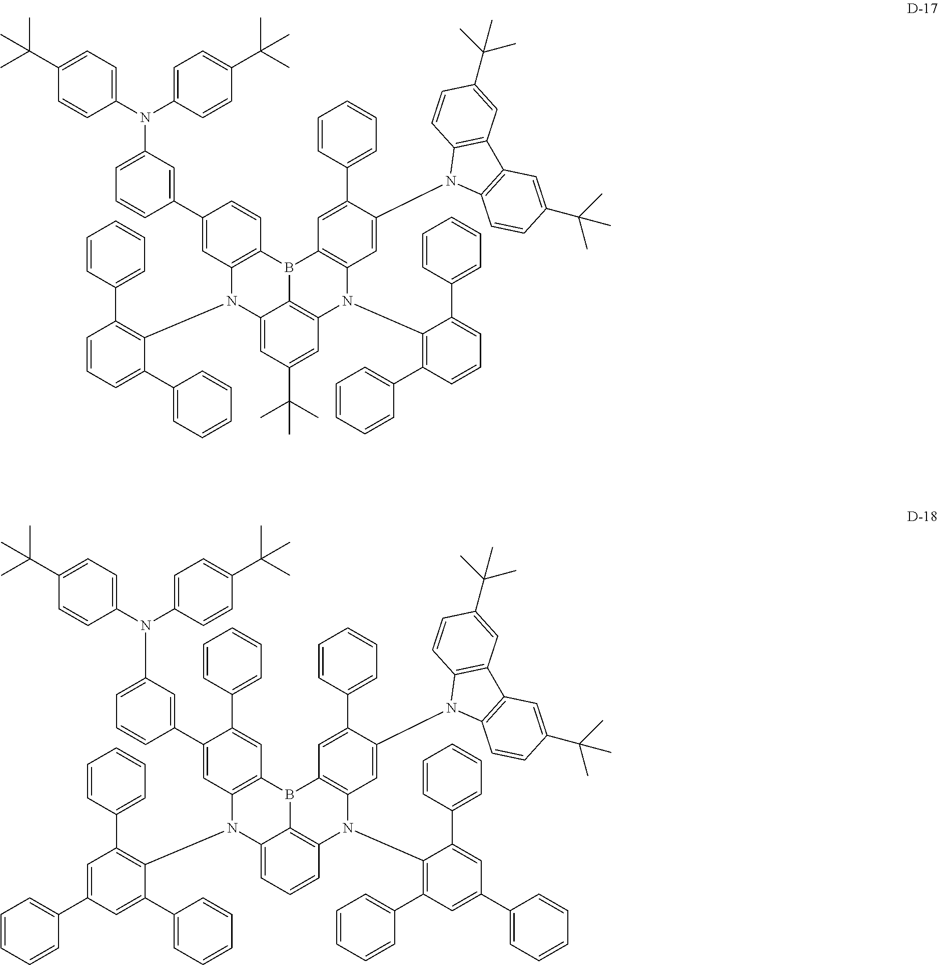 [SMILES: CC(C)(C)c1ccc(N(c2ccc(C(C)(C)C)cc2)c2cccc(-c3ccc4c(c3)N(c3c(-c5ccccc5)cccc3-c3ccccc3)c3cc(C(C)(C)C)cc5c3B4c3cc(-c4ccccc4)c(-n4c6ccc(C(C)(C)C)cc6c6cc(C(C)(C)C)ccc64)cc3N5c3c(-c4ccccc4)cccc3-c3ccccc3)c2)cc1 ; CC(C)(C)c1ccc(N(c2ccc(C(C)(C)C)cc2)c2cccc(-c3cc4c(cc3-c3ccccc3)B3c5cc(-c6ccccc6)c(-n6c7ccc(C(C)(C)C)cc7c7cc(C(C)(C)C)ccc76)cc5N(c5c(-c6ccccc6)cc(-c6ccccc6)cc5-c5ccccc5)c5cccc(c53)N4c3c(-c4ccccc4)cc(-c4ccccc4)cc3-c3ccccc3)c2)cc1]

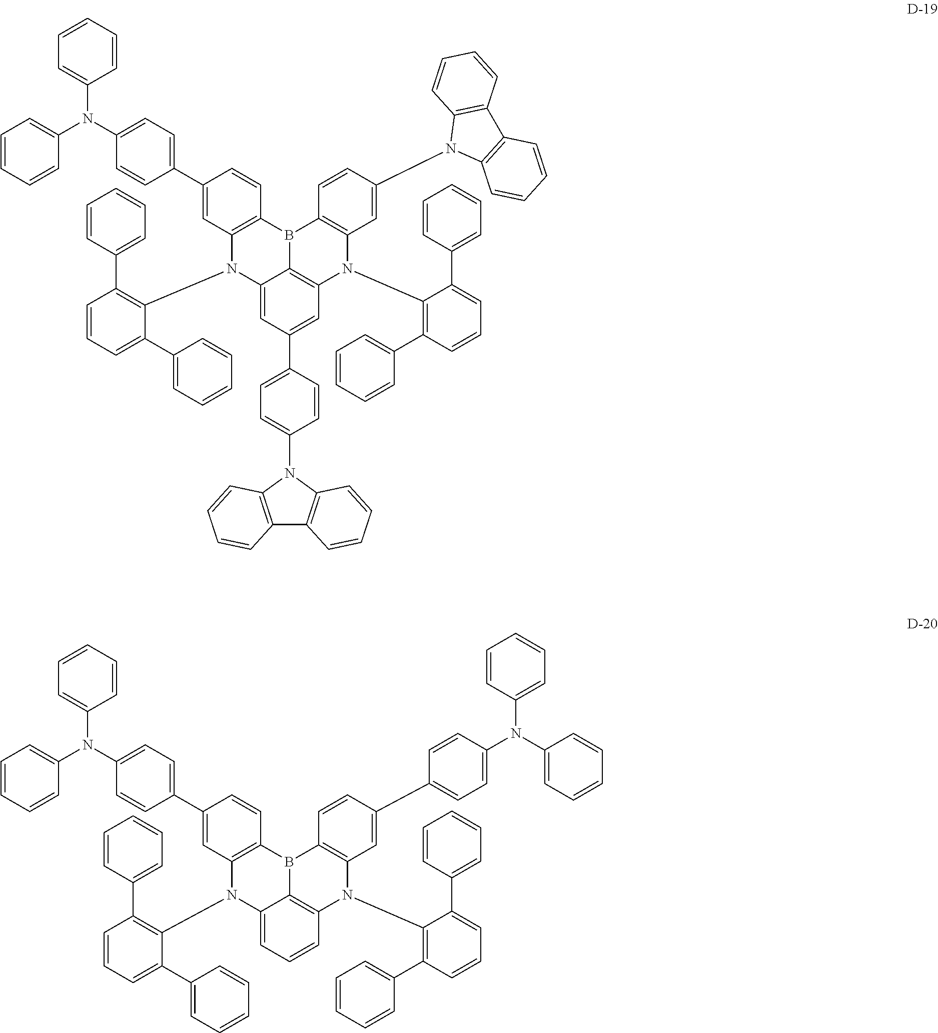 [SMILES: c1ccc(-c2cccc(-c3ccccc3)c2N2c3cc(-c4ccc(N(c5ccccc5)c5ccccc5)cc4)ccc3B3c4ccc(-n5c6ccccc6c6ccccc65)cc4N(c4c(-c5ccccc5)cccc4-c4ccccc4)c4cc(-c5ccc(-n6c7ccccc7c7ccccc76)cc5)cc2c43)cc1 ; c1ccc(-c2cccc(-c3ccccc3)c2N2c3cc(-c4ccc(N(c5ccccc5)c5ccccc5)cc4)ccc3B3c4ccc(-c5ccc(N(c6ccccc6)c6ccccc6)cc5)cc4N(c4c(-c5ccccc5)cccc4-c4ccccc4)c4cccc2c43)cc1]

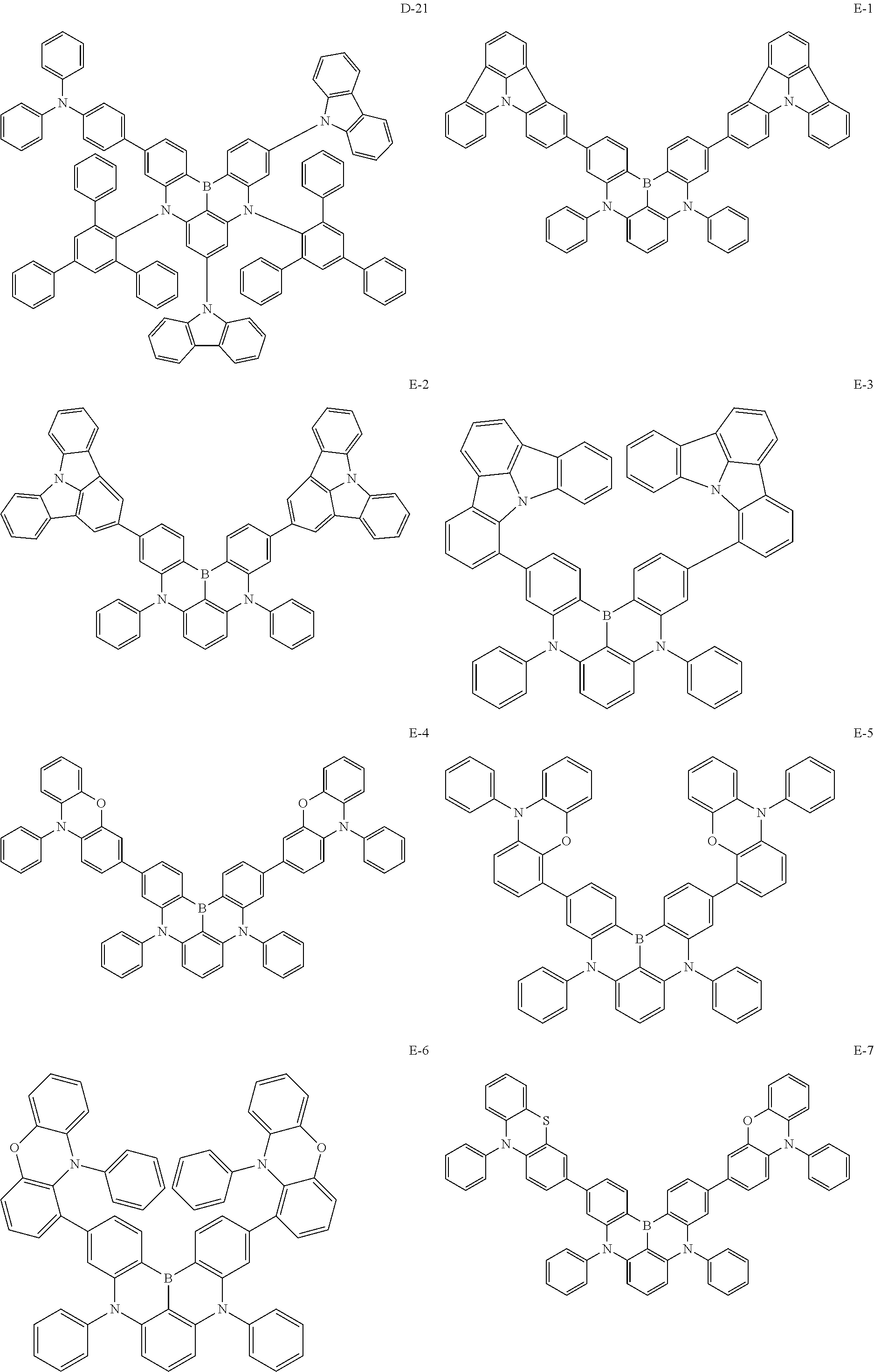

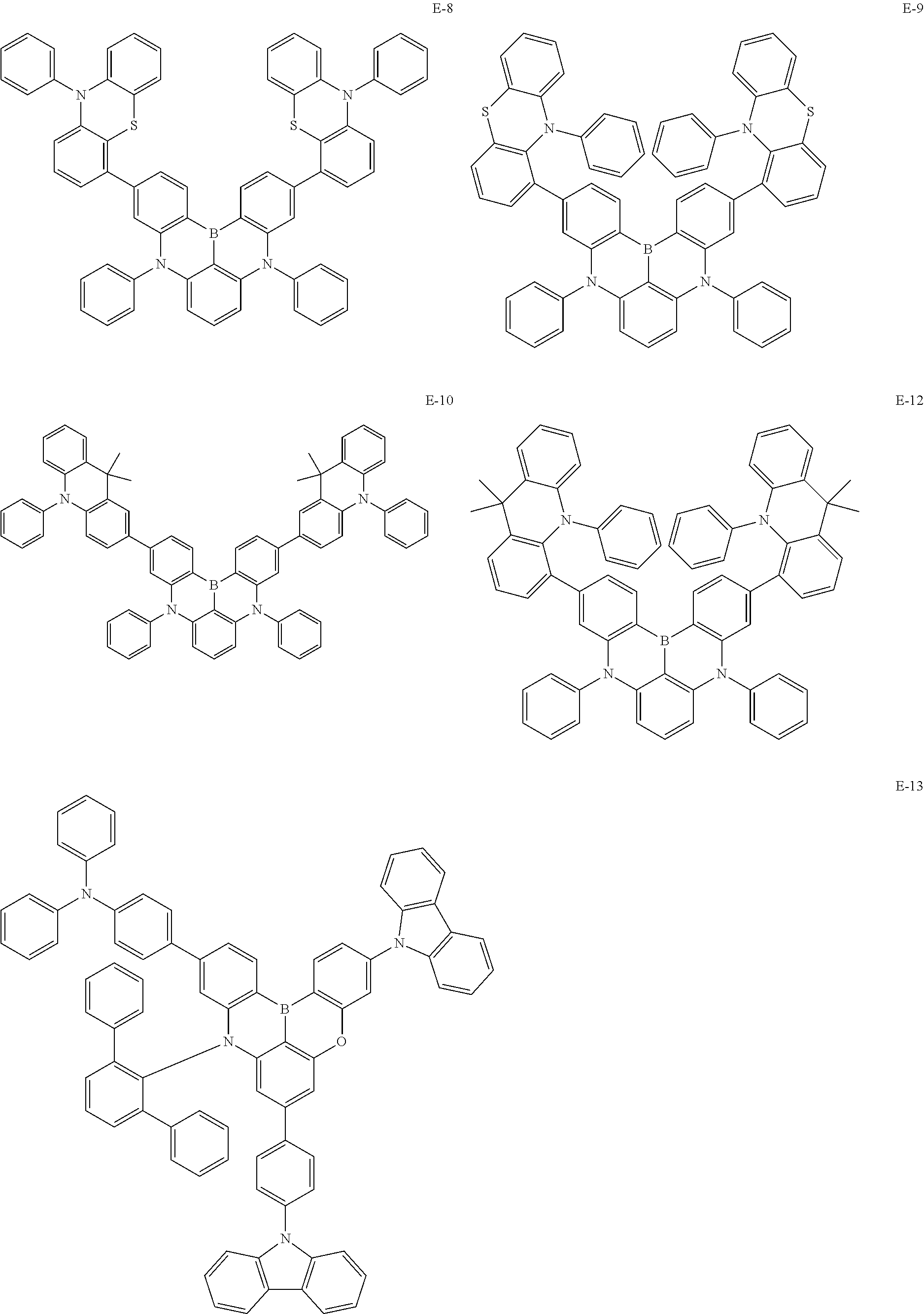

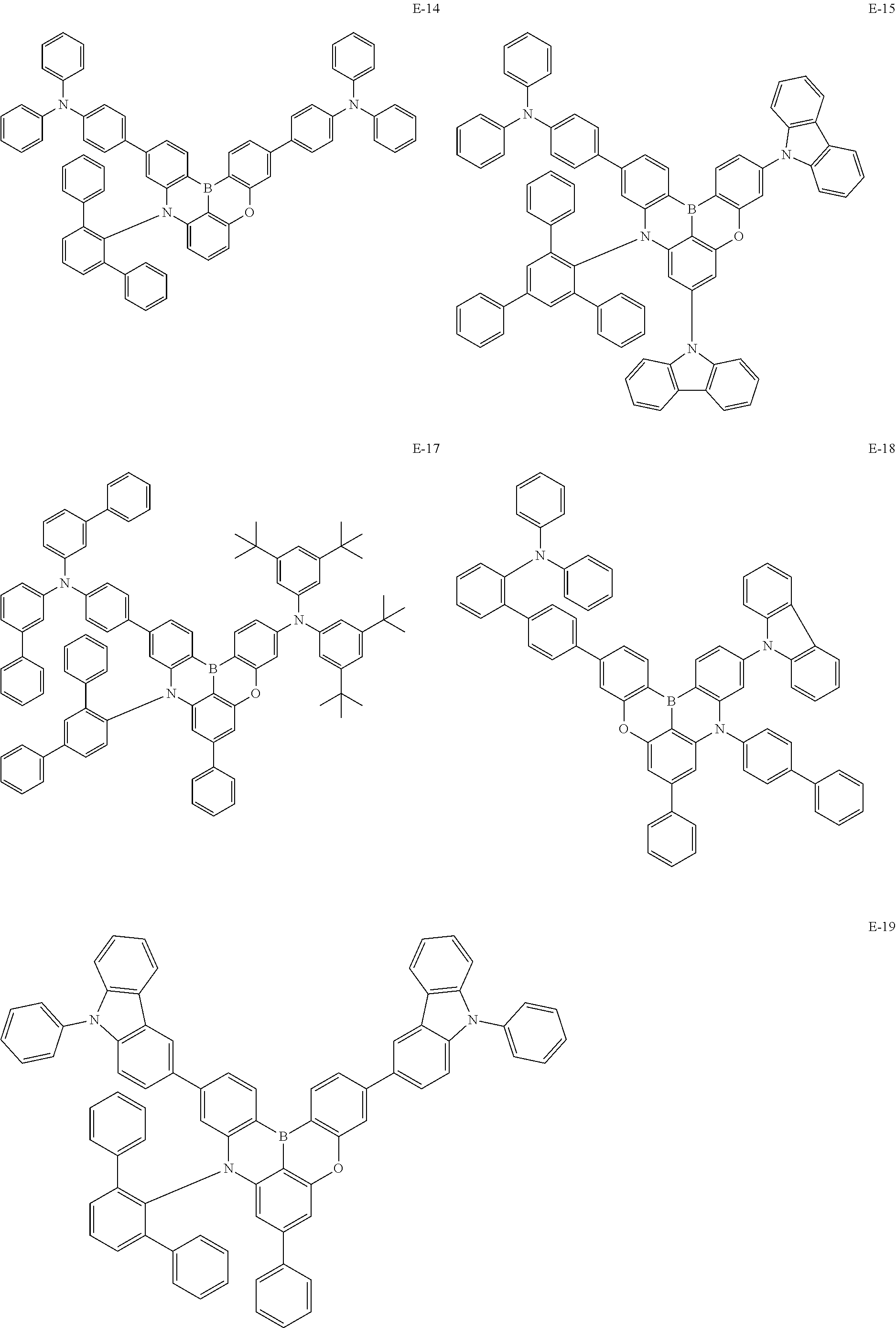

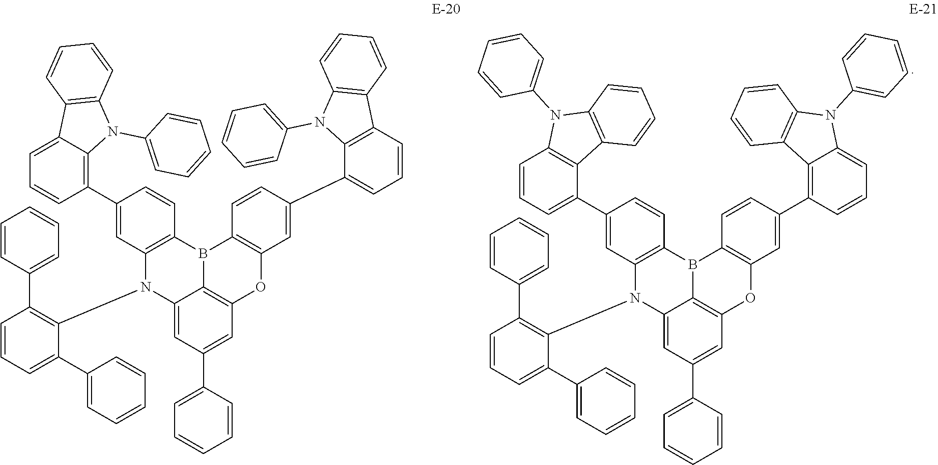 [SMILES: c1ccc(-c2cc3c4c(c2)N(c2c(-c5ccccc5)cccc2-c2ccccc2)c2cc(-c5cccc6c7ccccc7n(-c7ccccc7)c56)ccc2B4c2ccc(-c4cccc5c6ccccc6n(-c6ccccc6)c45)cc2O3)cc1 ; c1ccc(-c2cc3c4c(c2)N(c2c(-c5ccccc5)cccc2-c2ccccc2)c2cc(-c5cccc6c5c5ccccc5n6-c5ccccc5)ccc2B4c2ccc(-c4cccc5c4c4ccccc4n5-c4ccccc4)cc2O3)cc1]

17. A polycyclic compound represented by Formula 1 below:
Formula 1 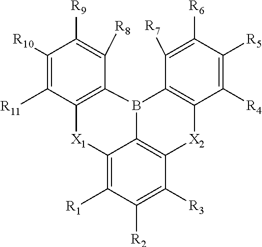
wherein, in Formula 1 above,
X₁ and X₂ are each independently O, S, Se, or NRₐ, and at least one of X₁ or X₂ is S, Se, or NRₐ,
Rₐ is a substituted or unsubstituted phenyl group,
R₁ to R₄, R₆ to R_{9,} and R₁₁ are each independently a hydrogen atom, a deuterium atom, a halogen atom, a cyano group, a nitro group, a substituted or unsubstituted boryl group, a substituted or unsubstituted amino group, a substituted or unsubstituted alkyl group having 1 to 20 carbon atoms, a substituted or unsubstituted cycloalkyl group having 6 to 30 ring-forming carbon atoms, a substituted or unsubstituted aryl group having 6 to 30 ring-forming carbon atoms, or a substituted or unsubstituted heteroaryl group having 3 to 30 ring-forming carbon atoms,
R₅ and R₁₀ are each independently represented by Formula 2 or Formula 3 below,
when each of R₅ and R₁₀ is represented by Formula 2, at least one L₁ is a substituted or unsubstituted arylene group having 6 to 30 ring-forming carbon atoms, and
when each of R₅ and R₁₀ is represented by Formula 3, the case where at least one L₂ is a direct linkage and N among heteroatoms contained in Ar₃ is directly linked to a benzene ring in Formula 1 above is excluded: 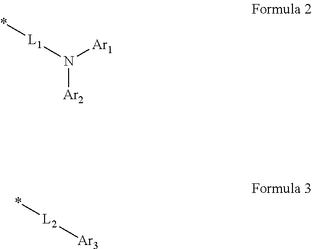
wherein, in Formula 2 and Formula 3 above,
L₁ and L₂ are each independently a direct linkage, or a substituted or unsubstituted arylene group having 6 to 30 ring-forming carbon atoms,
Ar₁ and Ar₂ are each independently a substituted or unsubstituted aryl group having 6 to 30 ring-forming carbon atoms, or a substituted or unsubstituted heteroaryl group having 3 to 30 ring-forming carbon atoms, and
Ar₃ is a substituted or unsubstituted heteroaryl group having 3 to 30 ring-forming carbon atoms.

18. The polycyclic compound of claim 17, wherein Rₐ above is represented by Formula 4 below: 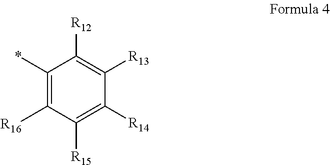
wherein, in Formula 4 above,
R₁₂ to R₁₆ are each independently a hydrogen atom, a deuterium atom, a halogen atom, a cyano group, a nitro group, a substituted or unsubstituted boryl group, a substituted or unsubstituted amino group, a substituted or unsubstituted alkyl group having 1 to 20 carbon atoms, a substituted or unsubstituted cycloalkyl group having 6 to 30 ring-forming carbon atoms, a substituted or unsubstituted aryl group having 6 to 30 ring-forming carbon atoms, or a substituted or unsubstituted heteroaryl group having 3 to 30 ring-forming carbon atoms.

19. The polycyclic compound of claim 17, wherein Formula 1 above is represented by any one selected from among Formula 1-1 to Formula 1-3 below: 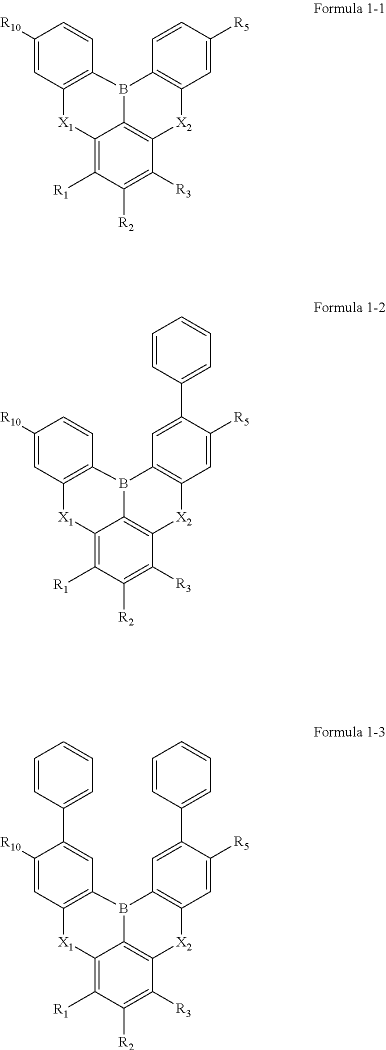
wherein, in Formula 1-1 to Formula 1-3 above,
each hydrogen atom is unsubstituted or substituted with a deuterium atom, and
X₁, X₂, R₁ to R₃, R₅, and R₁₀ are the same as defined with respect to Formula 1 above.

20. The polycyclic compound of claim 17, wherein Formula 1 above is represented by any one selected from among Compound Group 1 below:
Compound Group 1 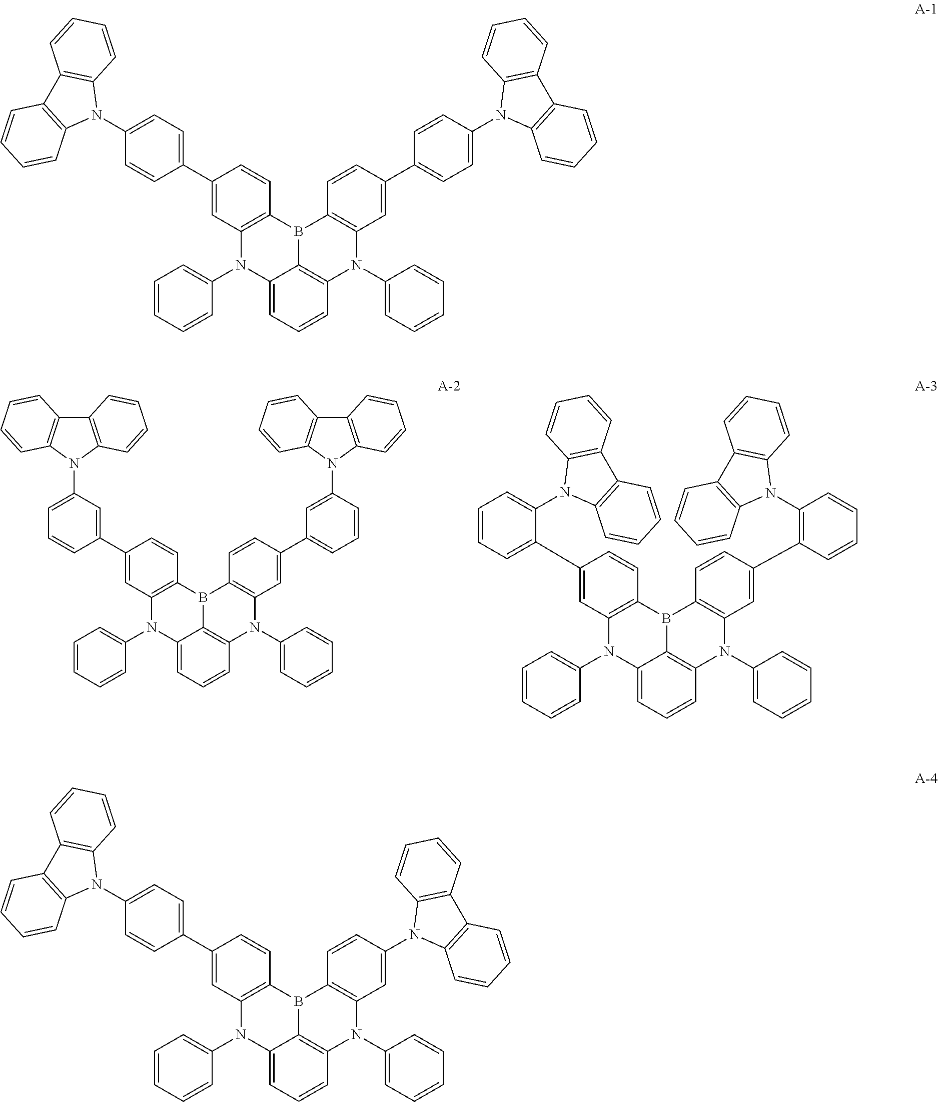 [SMILES: c1ccc(N2c3cc(-c4ccc(-n5c6ccccc6c6ccccc65)cc4)ccc3B3c4ccc(-c5ccc(-n6c7ccccc7c7ccccc76)cc5)cc4N(c4ccccc4)c4cccc2c43)cc1 ; c1ccc(N2c3cc(-c4cccc(-n5c6ccccc6c6ccccc65)c4)ccc3B3c4ccc(-c5cccc(-n6c7ccccc7c7ccccc76)c5)cc4N(c4ccccc4)c4cccc2c43)cc1 ; c1ccc(N2c3cc(-c4ccccc4-n4c5ccccc5c5ccccc54)ccc3B3c4ccc(-c5ccccc5-n5c6ccccc6c6ccccc65)cc4N(c4ccccc4)c4cccc2c43)cc1 ; c1ccc(N2c3cc(-c4ccc(-n5c6ccccc6c6ccccc65)cc4)ccc3B3c4ccc(-n5c6ccccc6c6ccccc65)cc4N(c4ccccc4)c4cccc2c43)cc1] 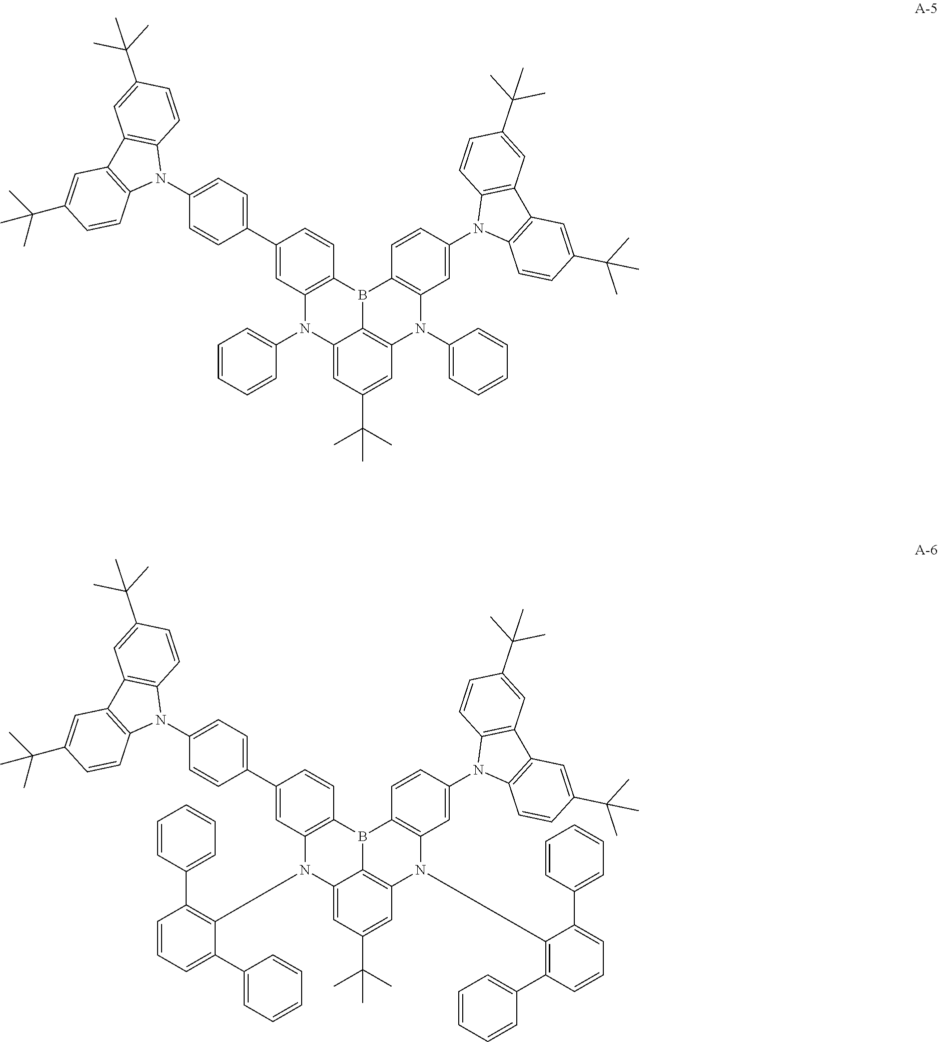 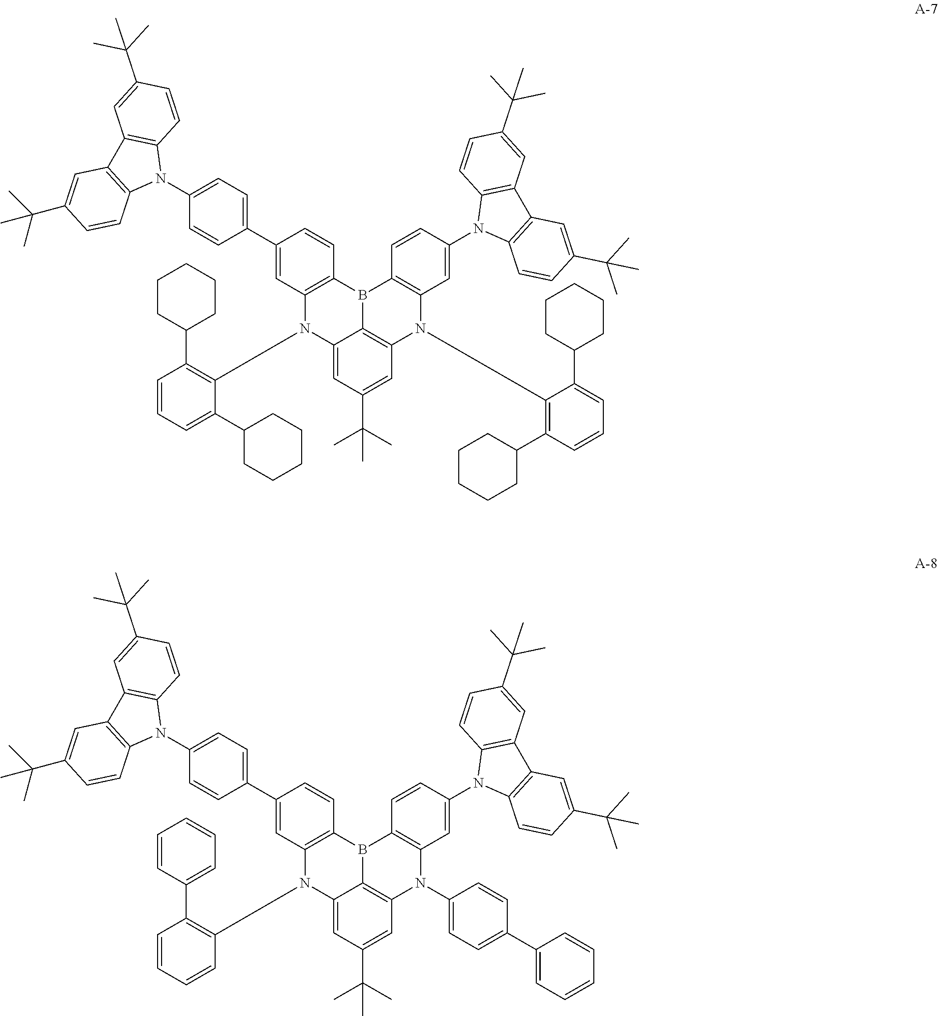 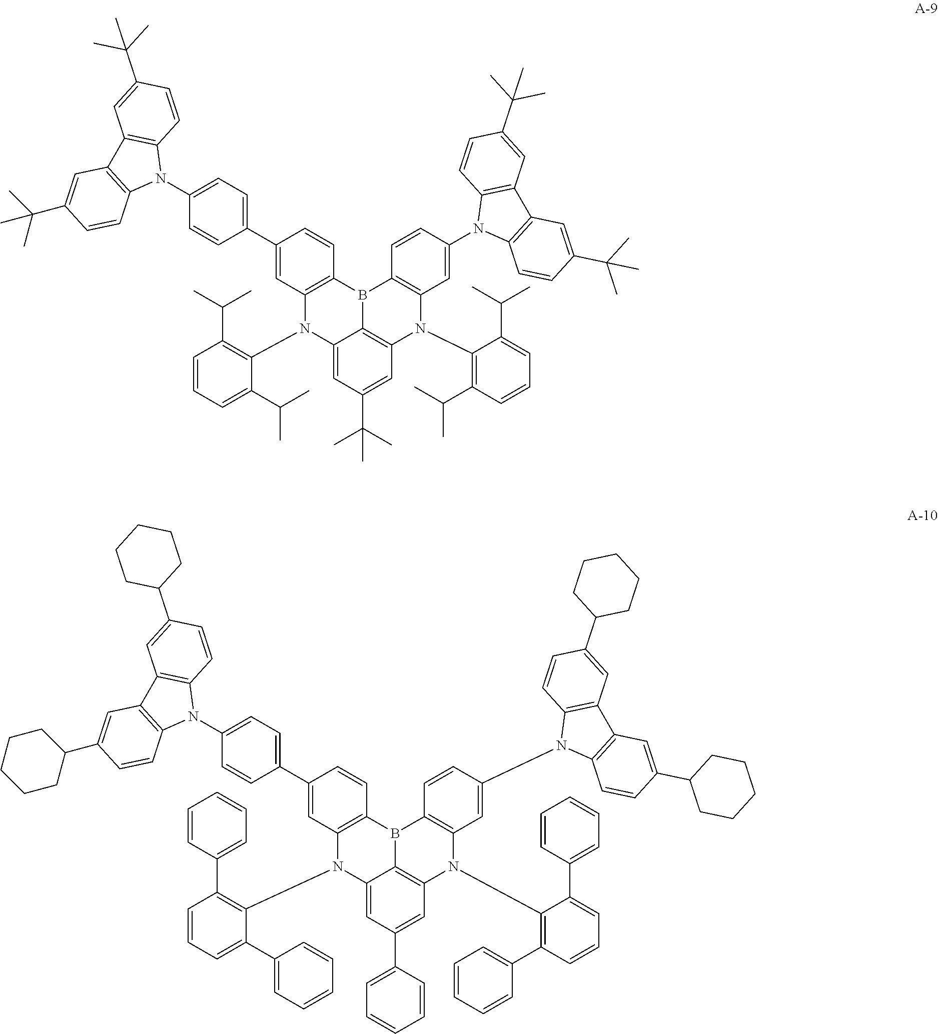 [SMILES: CC(C)c1cccc(C(C)C)c1N1c2cc(-c3ccc(-n4c5ccc(C(C)(C)C)cc5c5cc(C(C)(C)C)ccc54)cc3)ccc2B2c3ccc(-n4c5ccc(C(C)(C)C)cc5c5cc(C(C)(C)C)ccc54)cc3N(c3c(C(C)C)cccc3C(C)C)c3cc(C(C)(C)C)cc1c32 ; c1ccc(-c2cc3c4c(c2)N(c2c(-c5ccccc5)cccc2-c2ccccc2)c2cc(-n5c6ccc(C7CCCCC7)cc6c6cc(C7CCCCC7)ccc65)ccc2B4c2ccc(-c4ccc(-n5c6ccc(C7CCCCC7)cc6c6cc(C7CCCCC7)ccc65)cc4)cc2N3c2c(-c3ccccc3)cccc2-c2ccccc2)cc1] 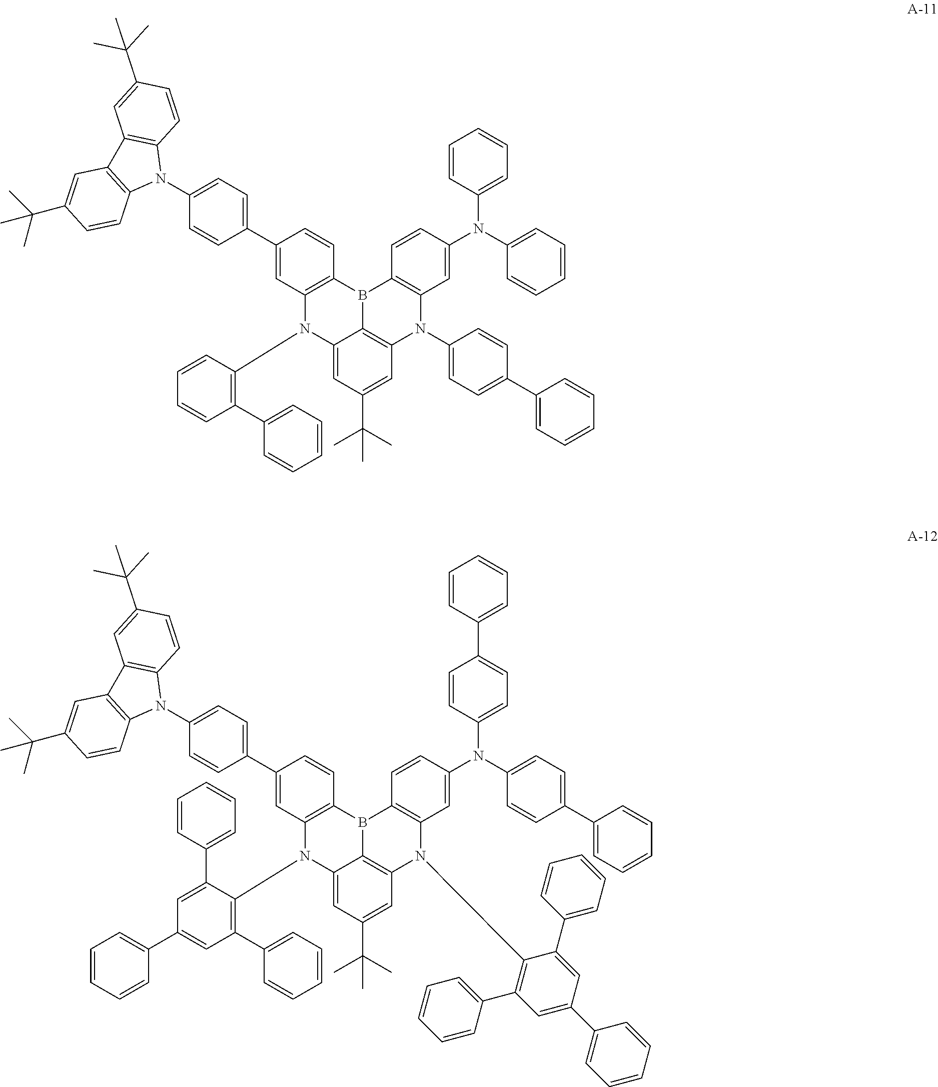 [SMILES: CC(C)(C)c1cc2c3c(c1)N(c1ccccc1-c1ccccc1)c1cc(-c4ccc(-n5c6ccc(C(C)(C)C)cc6c6cc(C(C)(C)C)ccc65)cc4)ccc1B3c1ccc(N(c3ccccc3)c3ccccc3)cc1N2c1ccc(-c2ccccc2)cc1 ; CC(C)(C)c1cc2c3c(c1)N(c1c(-c4ccccc4)cc(-c4ccccc4)cc1-c1ccccc1)c1cc(N(c4ccc(-c5ccccc5)cc4)c4ccc(-c5ccccc5)cc4)ccc1B3c1ccc(-c3ccc(-n4c5ccc(C(C)(C)C)cc5c5cc(C(C)(C)C)ccc54)cc3)cc1N2c1c(-c2ccccc2)cc(-c2ccccc2)cc1-c1ccccc1] 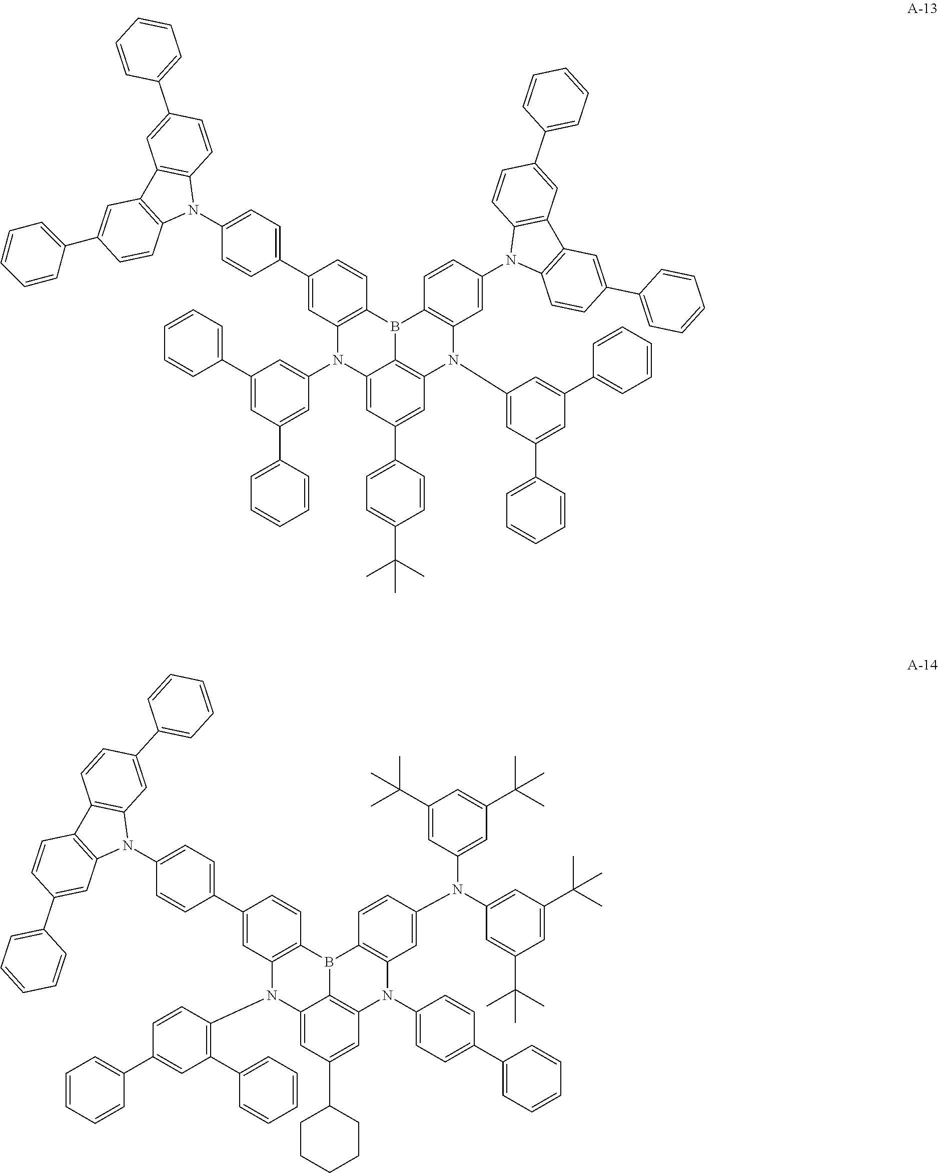 [SMILES: CC(C)(C)c1ccc(-c2cc3c4c(c2)N(c2cc(-c5ccccc5)cc(-c5ccccc5)c2)c2cc(-n5c6ccc(-c7ccccc7)cc6c6cc(-c7ccccc7)ccc65)ccc2B4c2ccc(-c4ccc(-n5c6ccc(-c7ccccc7)cc6c6cc(-c7ccccc7)ccc65)cc4)cc2N3c2cc(-c3ccccc3)cc(-c3ccccc3)c2)cc1 ; CC(C)(C)c1cc(N(c2cc(C(C)(C)C)cc(C(C)(C)C)c2)c2ccc3c(c2)N(c2ccc(-c4ccccc4)cc2)c2cc(C4CCCCC4)cc4c2B3c2ccc(-c3ccc(-n5c6cc(-c7ccccc7)ccc6c6ccc(-c7ccccc7)cc65)cc3)cc2N4c2ccc(-c3ccccc3)cc2-c2ccccc2)cc(C(C)(C)C)c1] 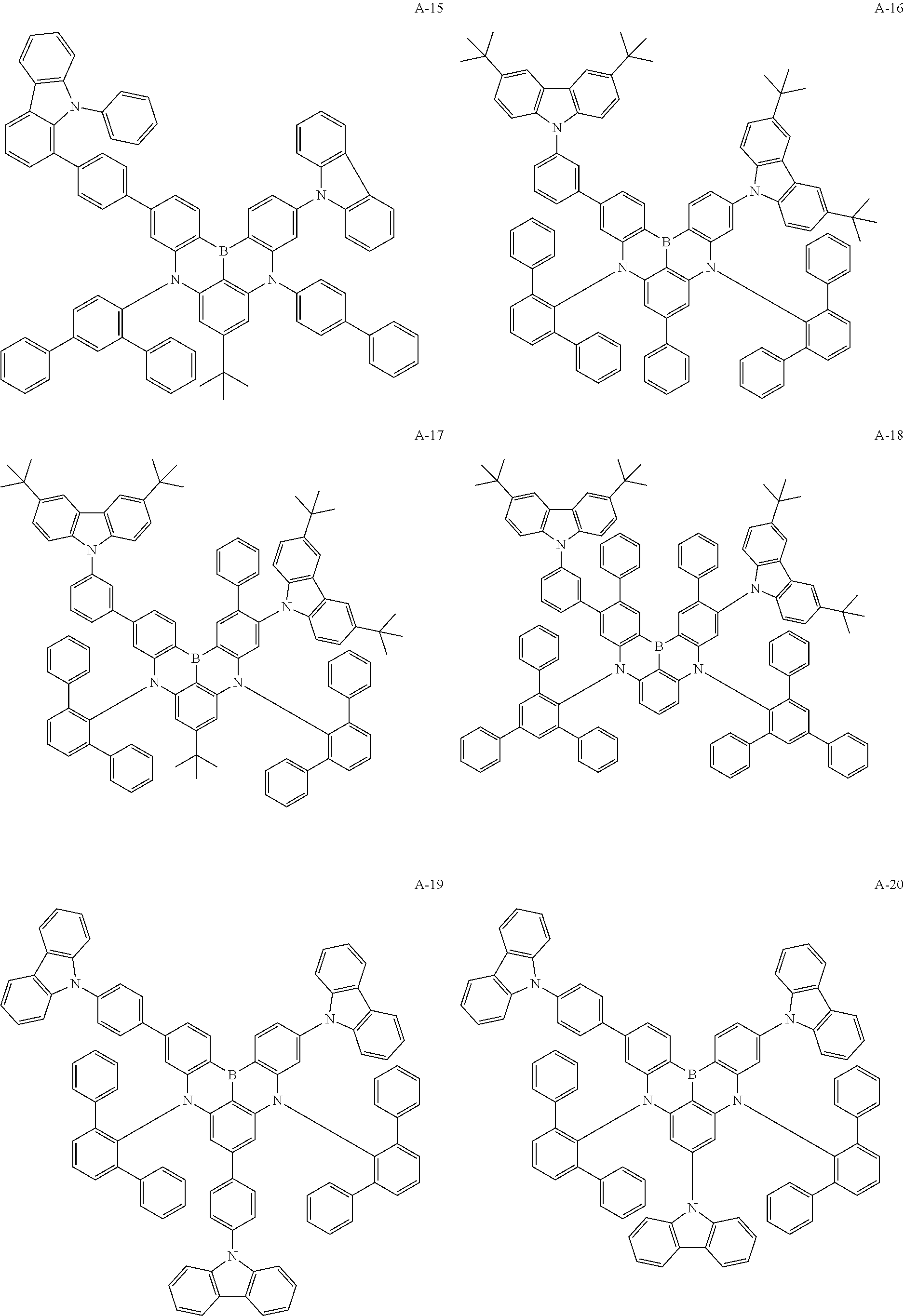 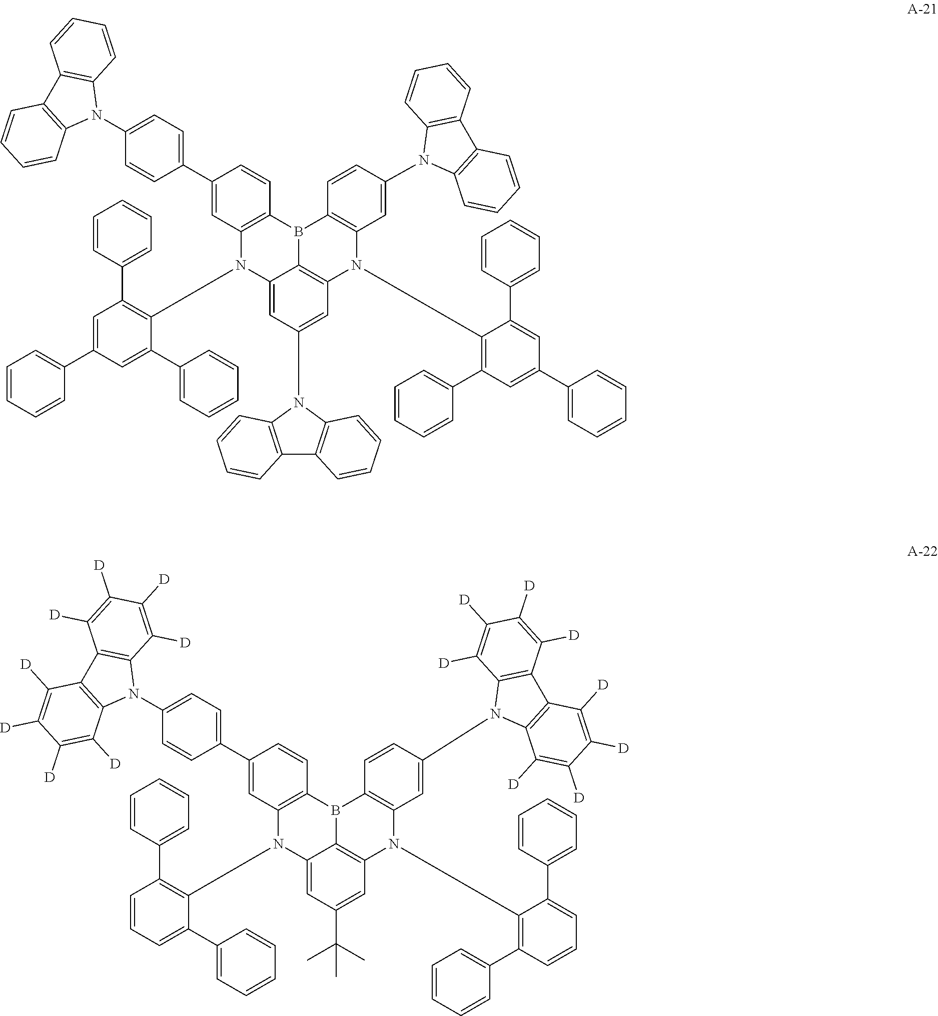 [SMILES: c1ccc(-c2cc(-c3ccccc3)c(N3c4cc(-c5ccc(-n6c7ccccc7c7ccccc76)cc5)ccc4B4c5ccc(-n6c7ccccc7c7ccccc76)cc5N(c5c(-c6ccccc6)cc(-c6ccccc6)cc5-c5ccccc5)c5cc(-n6c7ccccc7c7ccccc76)cc3c54)c(-c3ccccc3)c2)cc1 ; [2H]c1c([2H])c([2H])c2c(c1[2H])c1c([2H])c([2H])c([2H])c([2H])c1n2-c1ccc(-c2ccc3c(c2)N(c2c(-c4ccccc4)cccc2-c2ccccc2)c2cc(C(C)(C)C)cc4c2B3c2ccc(-n3c5c([2H])c([2H])c([2H])c([2H])c5c5c([2H])c([2H])c([2H])c([2H])c53)cc2N4c2c(-c3ccccc3)cccc2-c2ccccc2)cc1] 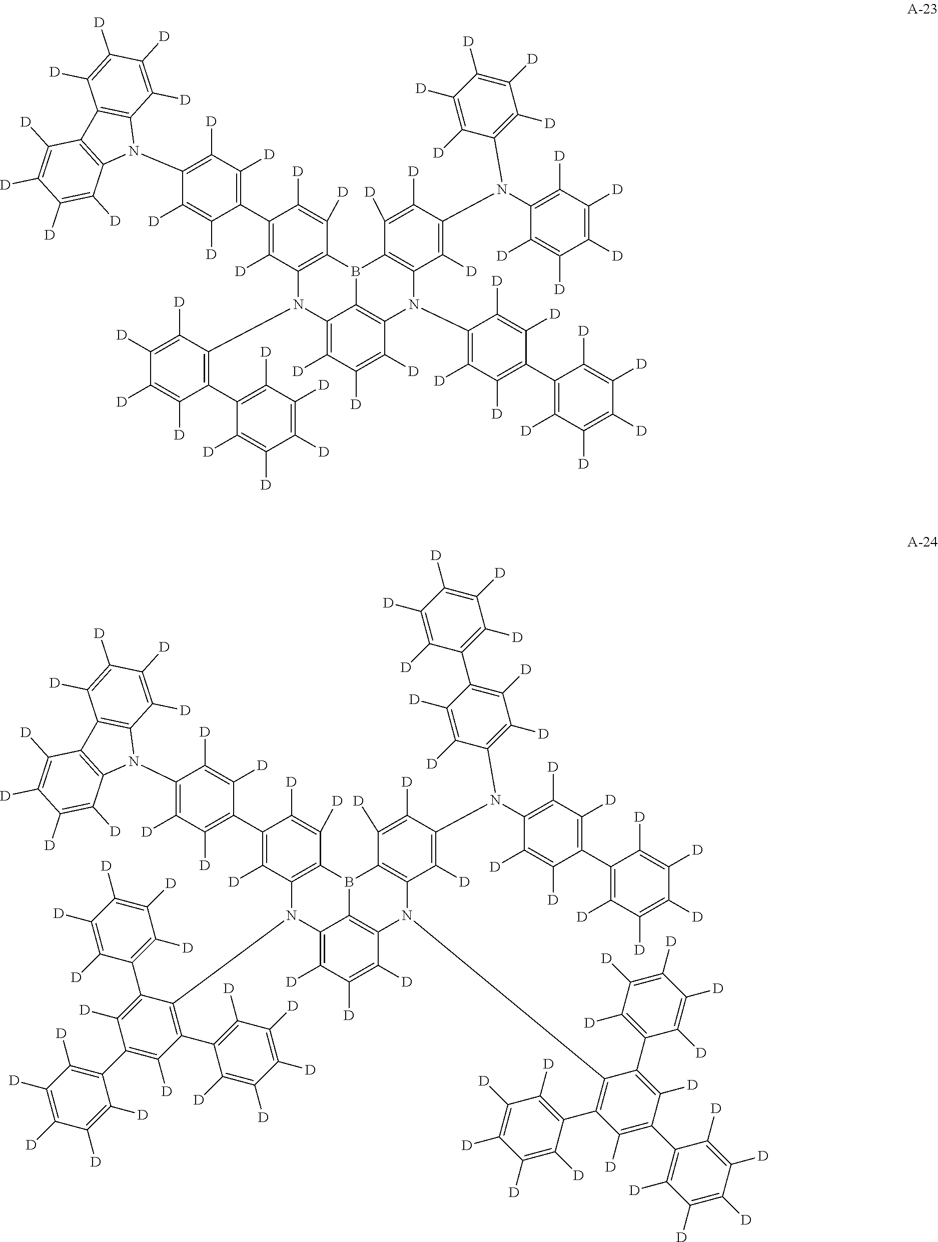 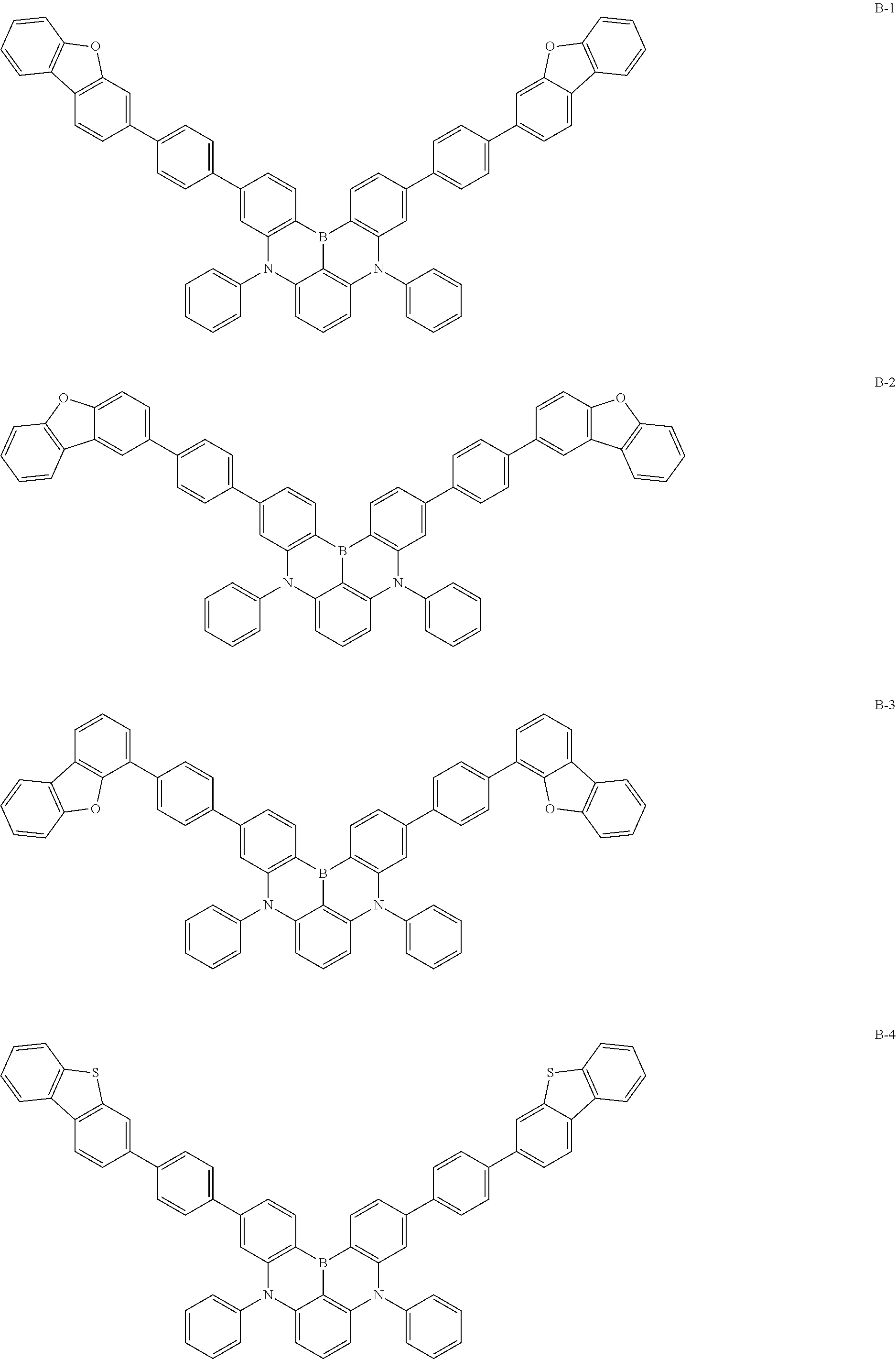 [SMILES: c1ccc(N2c3cc(-c4ccc(-c5ccc6c(c5)oc5ccccc56)cc4)ccc3B3c4ccc(-c5ccc(-c6ccc7c(c6)oc6ccccc67)cc5)cc4N(c4ccccc4)c4cccc2c43)cc1 ; c1ccc(N2c3cc(-c4ccc(-c5ccc6oc7ccccc7c6c5)cc4)ccc3B3c4ccc(-c5ccc(-c6ccc7oc8ccccc8c7c6)cc5)cc4N(c4ccccc4)c4cccc2c43)cc1 ; c1ccc(N2c3cc(-c4ccc(-c5cccc6c5oc5ccccc56)cc4)ccc3B3c4ccc(-c5ccc(-c6cccc7c6oc6ccccc67)cc5)cc4N(c4ccccc4)c4cccc2c43)cc1 ; c1ccc(N2c3cc(-c4ccc(-c5ccc6c(c5)sc5ccccc56)cc4)ccc3B3c4ccc(-c5ccc(-c6ccc7c(c6)sc6ccccc67)cc5)cc4N(c4ccccc4)c4cccc2c43)cc1] 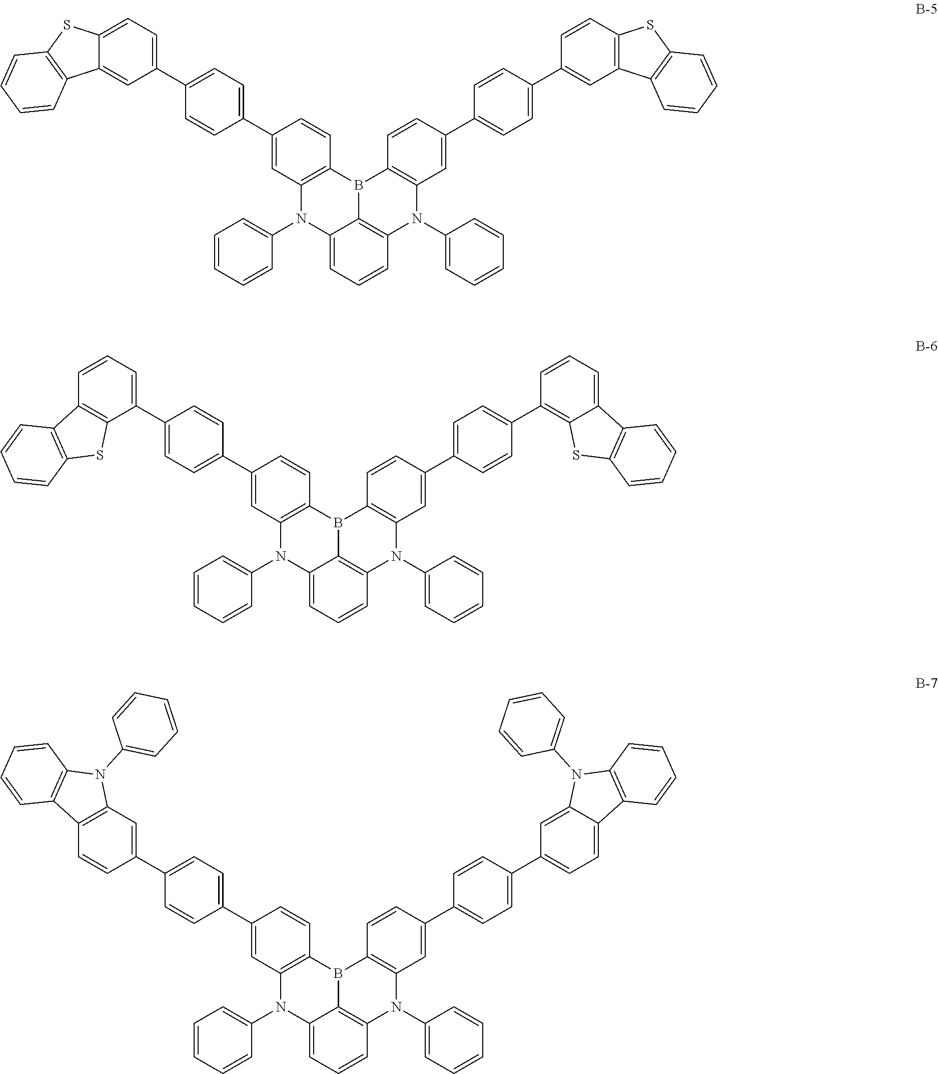 [SMILES: c1ccc(N2c3cc(-c4ccc(-c5ccc6sc7ccccc7c6c5)cc4)ccc3B3c4ccc(-c5ccc(-c6ccc7sc8ccccc8c7c6)cc5)cc4N(c4ccccc4)c4cccc2c43)cc1 ; c1ccc(N2c3cc(-c4ccc(-c5cccc6c5sc5ccccc56)cc4)ccc3B3c4ccc(-c5ccc(-c6cccc7c6sc6ccccc67)cc5)cc4N(c4ccccc4)c4cccc2c43)cc1 ; c1ccc(N2c3cc(-c4ccc(-c5ccc6c7ccccc7n(-c7ccccc7)c6c5)cc4)ccc3B3c4ccc(-c5ccc(-c6ccc7c8ccccc8n(-c8ccccc8)c7c6)cc5)cc4N(c4ccccc4)c4cccc2c43)cc1] 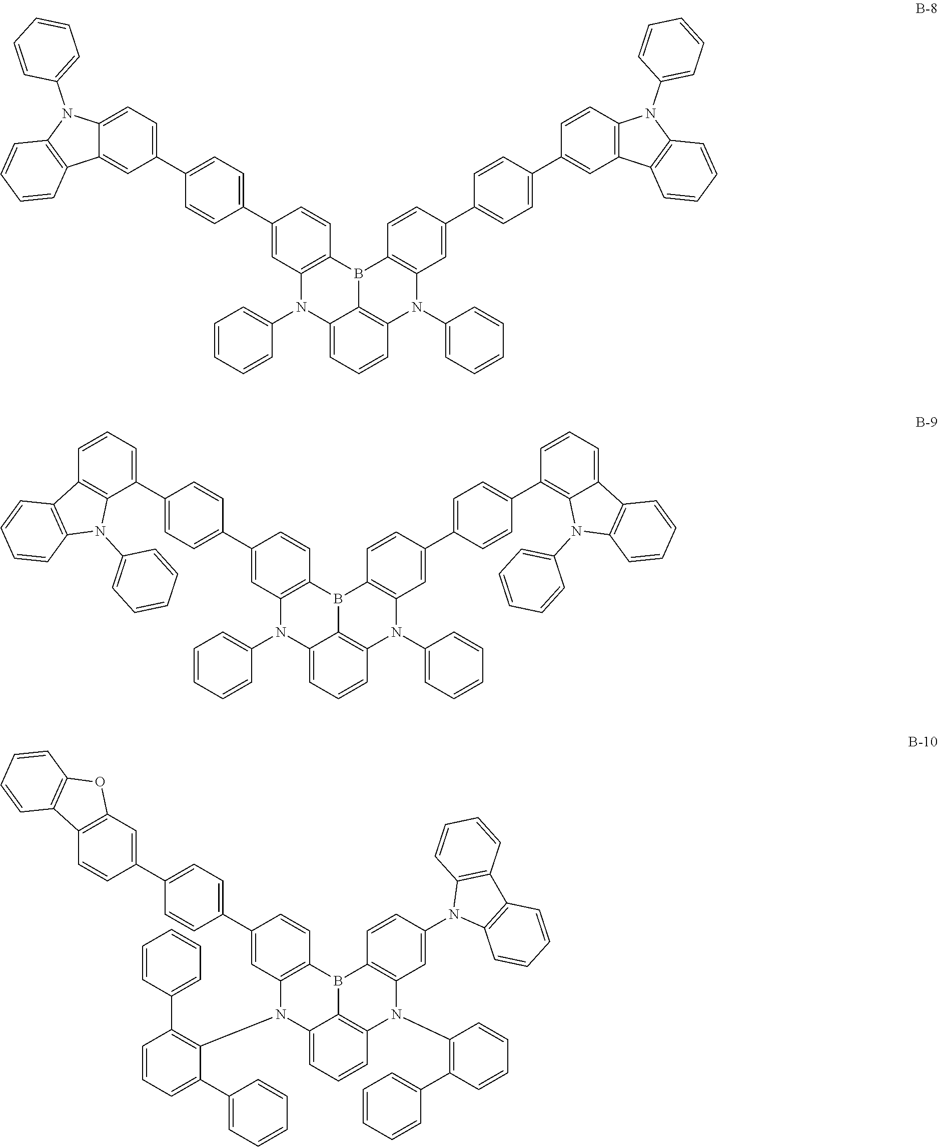 [SMILES: c1ccc(N2c3cc(-c4ccc(-c5ccc6c(c5)c5ccccc5n6-c5ccccc5)cc4)ccc3B3c4ccc(-c5ccc(-c6ccc7c(c6)c6ccccc6n7-c6ccccc6)cc5)cc4N(c4ccccc4)c4cccc2c43)cc1 ; c1ccc(N2c3cc(-c4ccc(-c5cccc6c7ccccc7n(-c7ccccc7)c56)cc4)ccc3B3c4ccc(-c5ccc(-c6cccc7c8ccccc8n(-c8ccccc8)c67)cc5)cc4N(c4ccccc4)c4cccc2c43)cc1 ; c1ccc(-c2ccccc2N2c3cc(-n4c5ccccc5c5ccccc54)ccc3B3c4ccc(-c5ccc(-c6ccc7c(c6)oc6ccccc67)cc5)cc4N(c4c(-c5ccccc5)cccc4-c4ccccc4)c4cccc2c43)cc1] 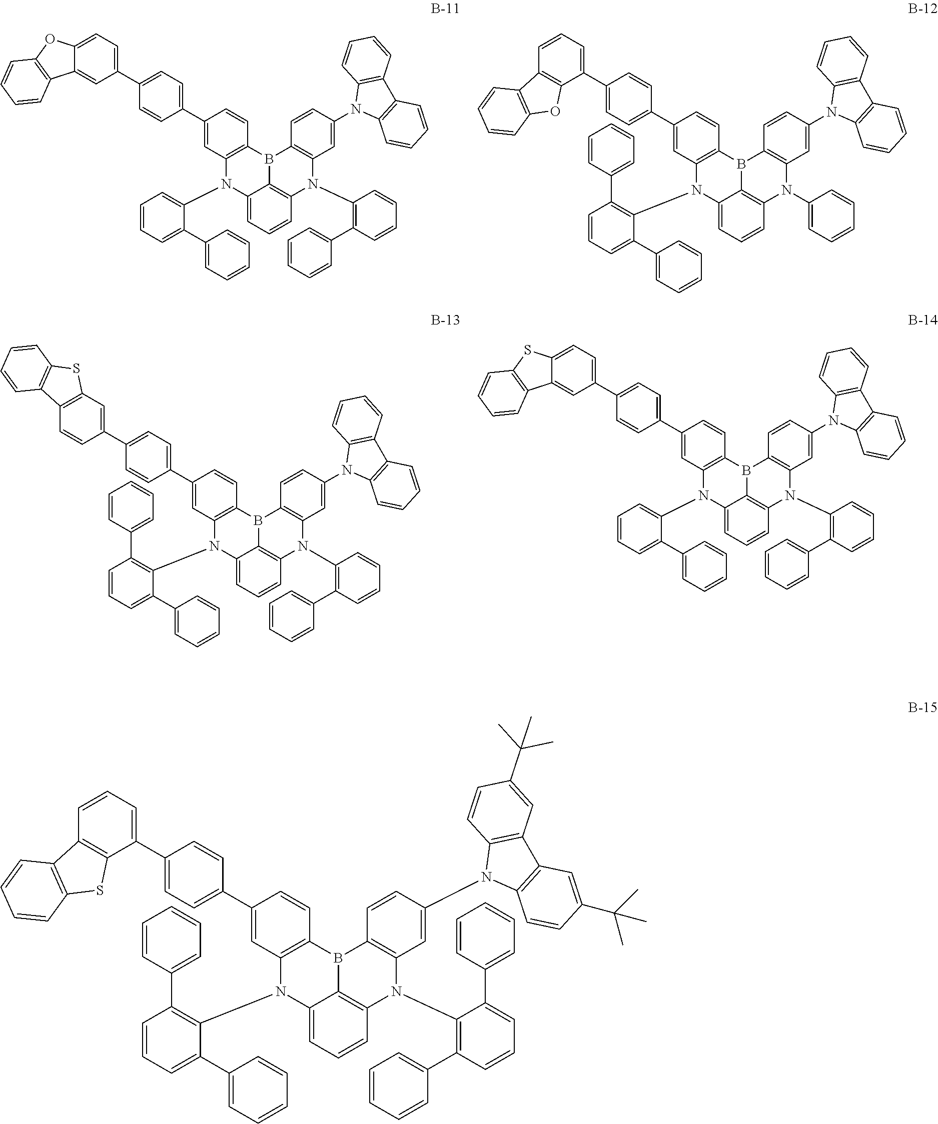 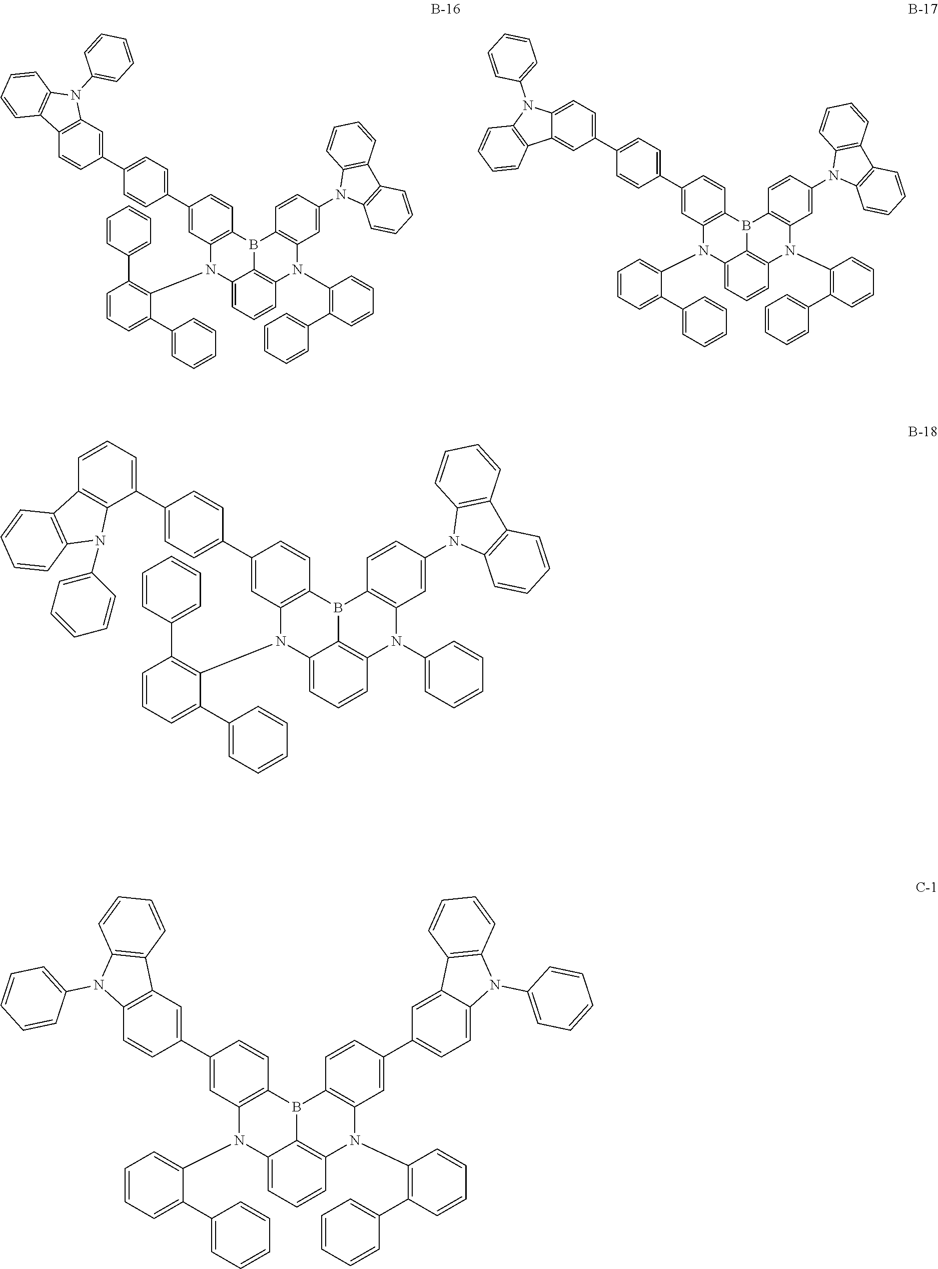 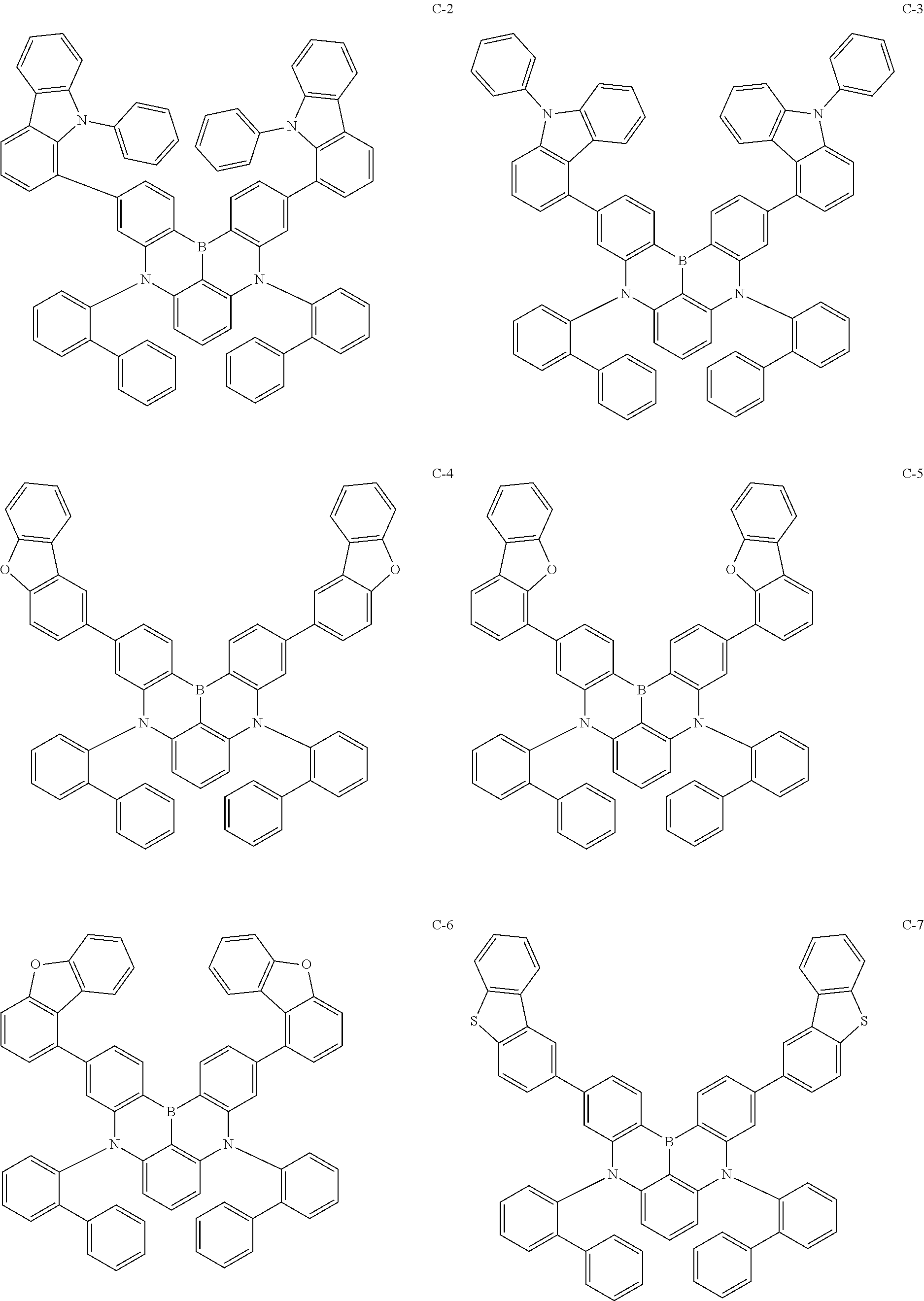 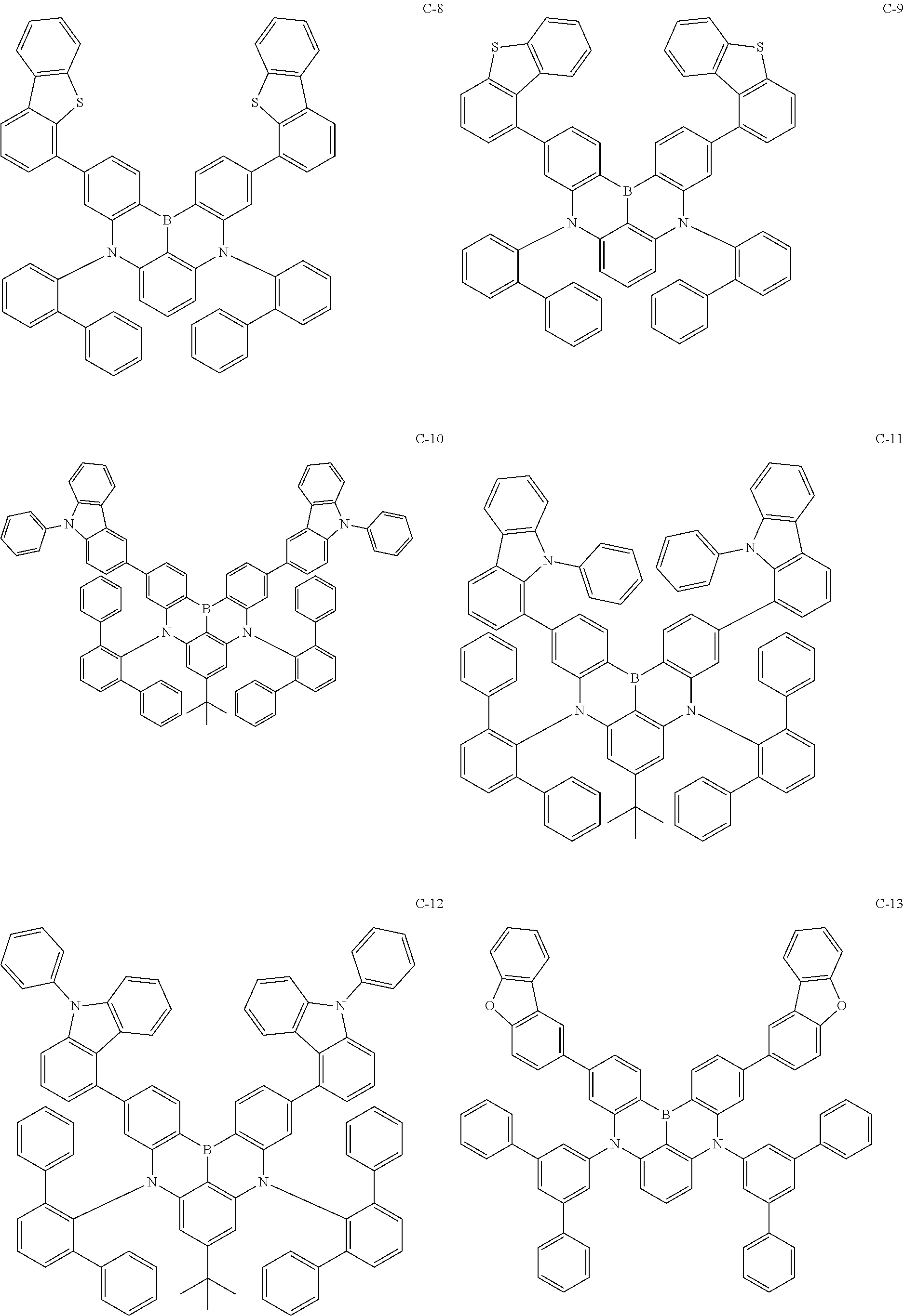 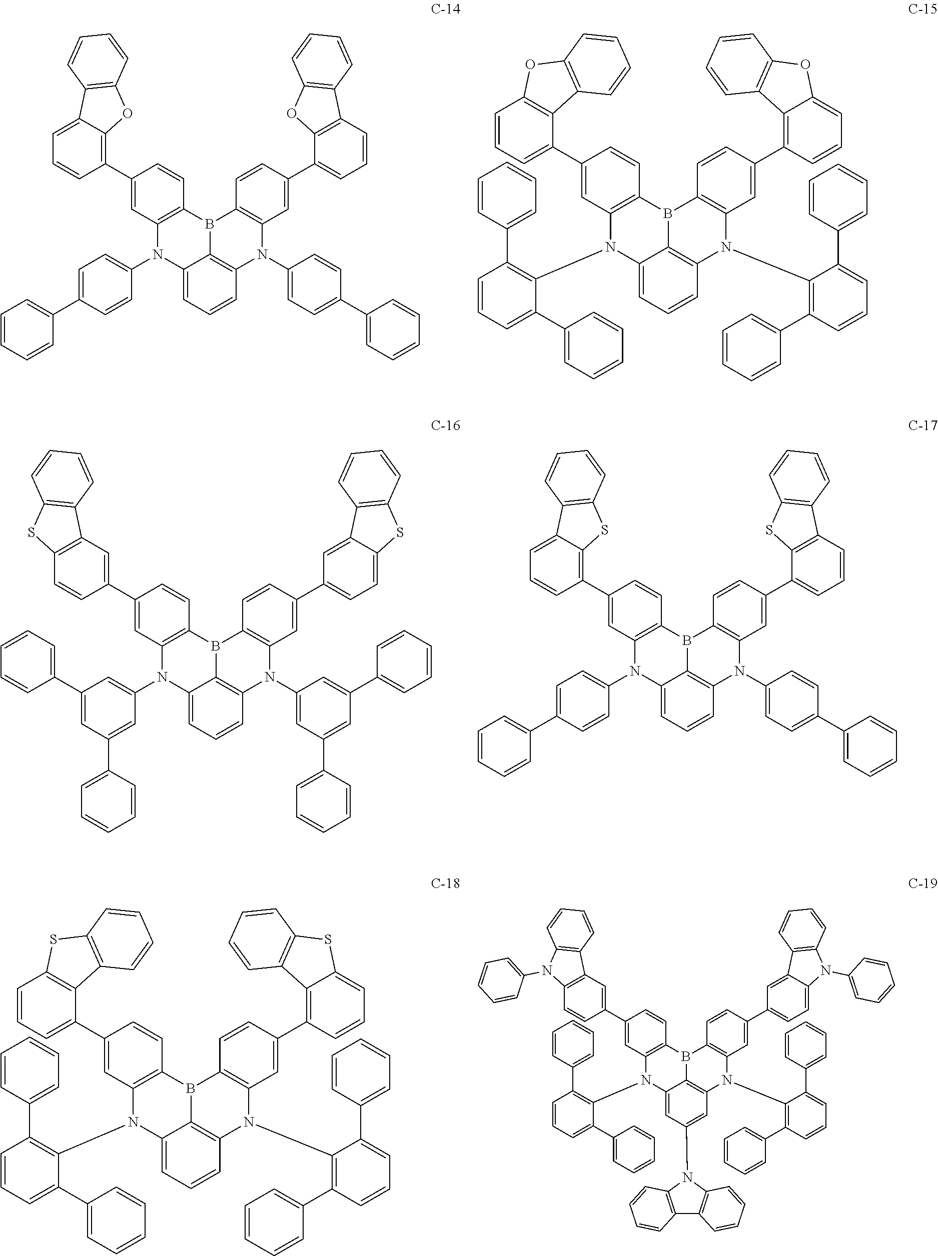 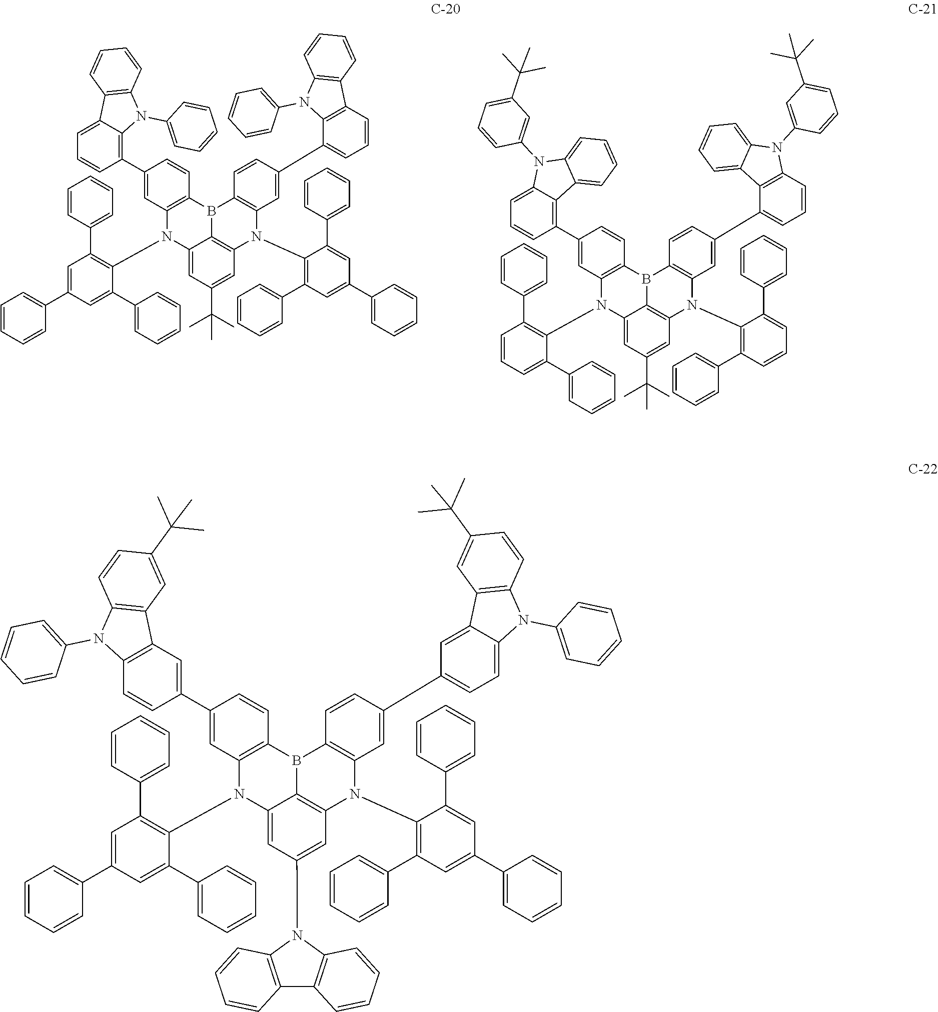 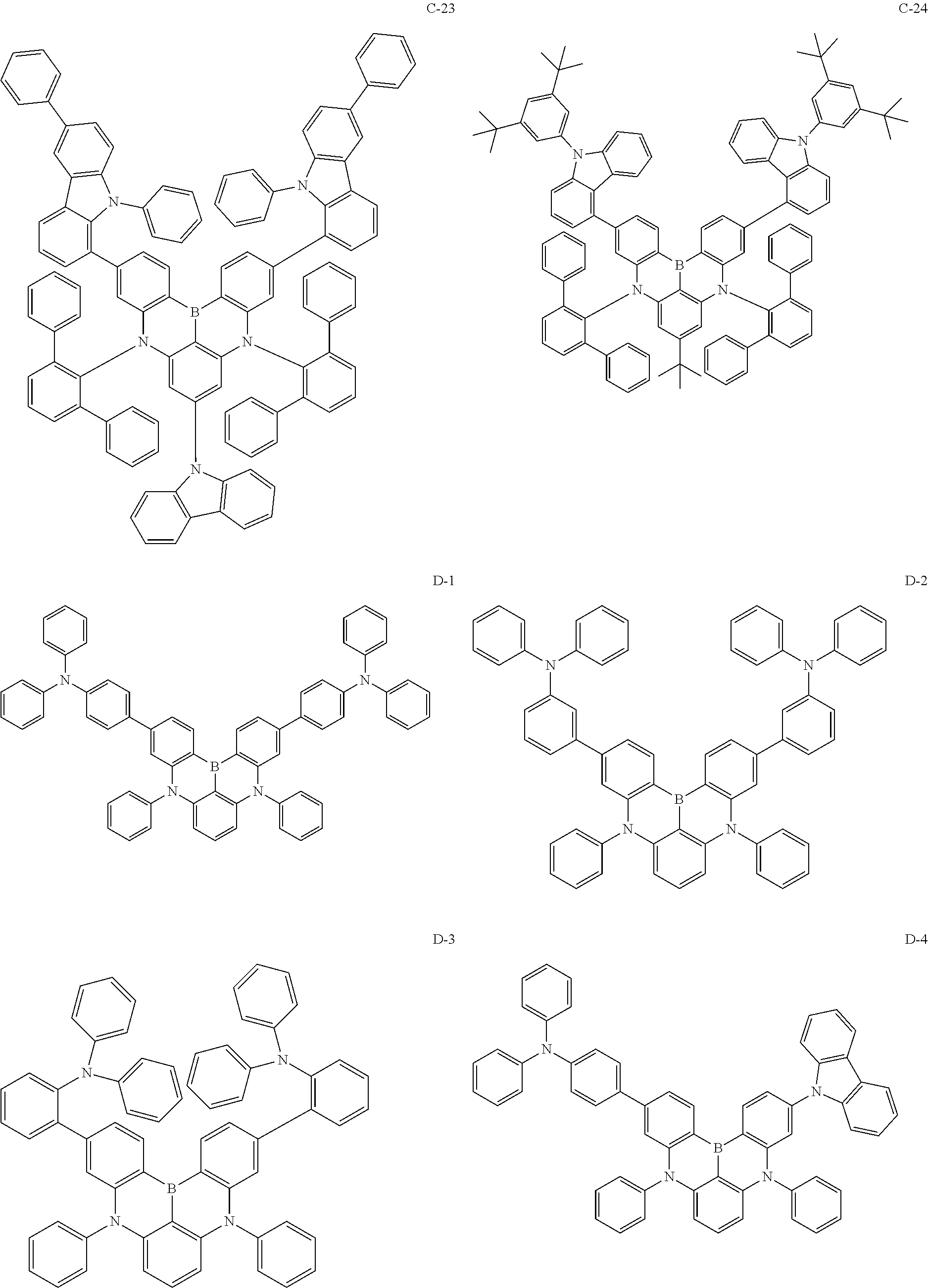 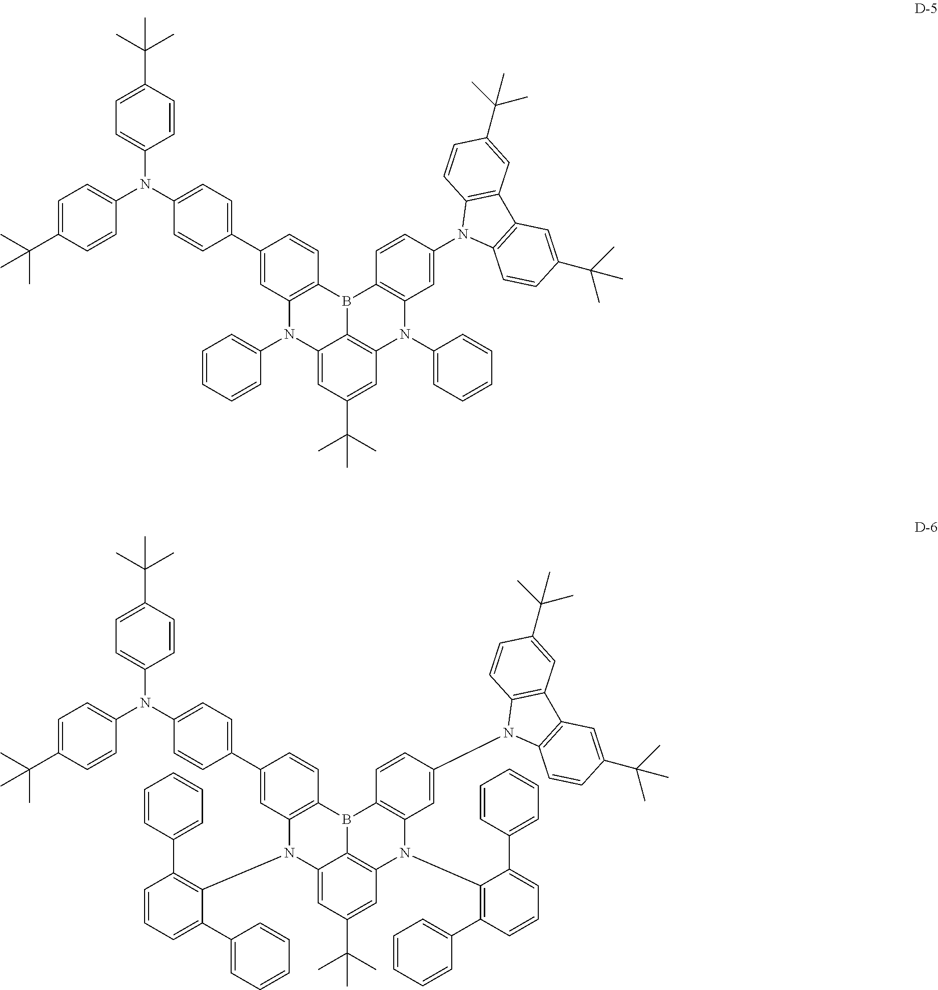 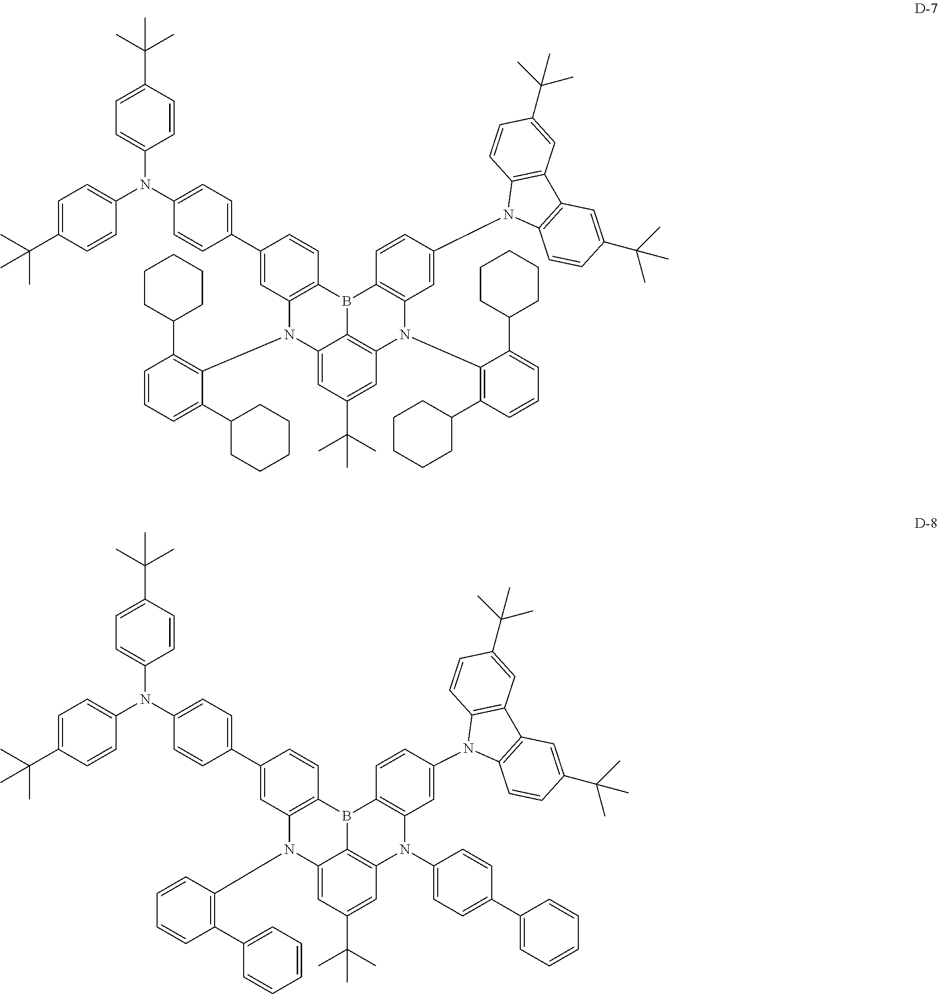 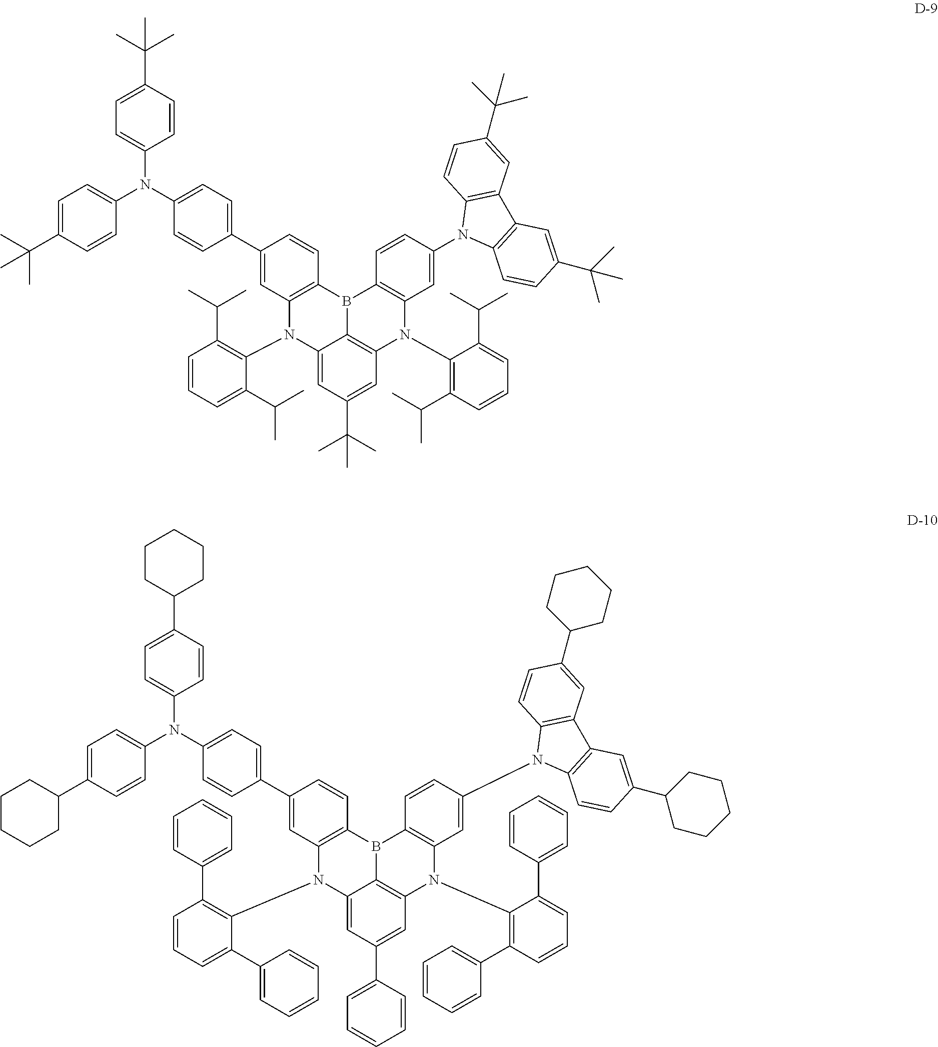 [SMILES: CC(C)c1cccc(C(C)C)c1N1c2cc(-c3ccc(N(c4ccc(C(C)(C)C)cc4)c4ccc(C(C)(C)C)cc4)cc3)ccc2B2c3ccc(-n4c5ccc(C(C)(C)C)cc5c5cc(C(C)(C)C)ccc54)cc3N(c3c(C(C)C)cccc3C(C)C)c3cc(C(C)(C)C)cc1c32 ; c1ccc(-c2cc3c4c(c2)N(c2c(-c5ccccc5)cccc2-c2ccccc2)c2cc(-n5c6ccc(C7CCCCC7)cc6c6cc(C7CCCCC7)ccc65)ccc2B4c2ccc(-c4ccc(N(c5ccc(C6CCCCC6)cc5)c5ccc(C6CCCCC6)cc5)cc4)cc2N3c2c(-c3ccccc3)cccc2-c2ccccc2)cc1] 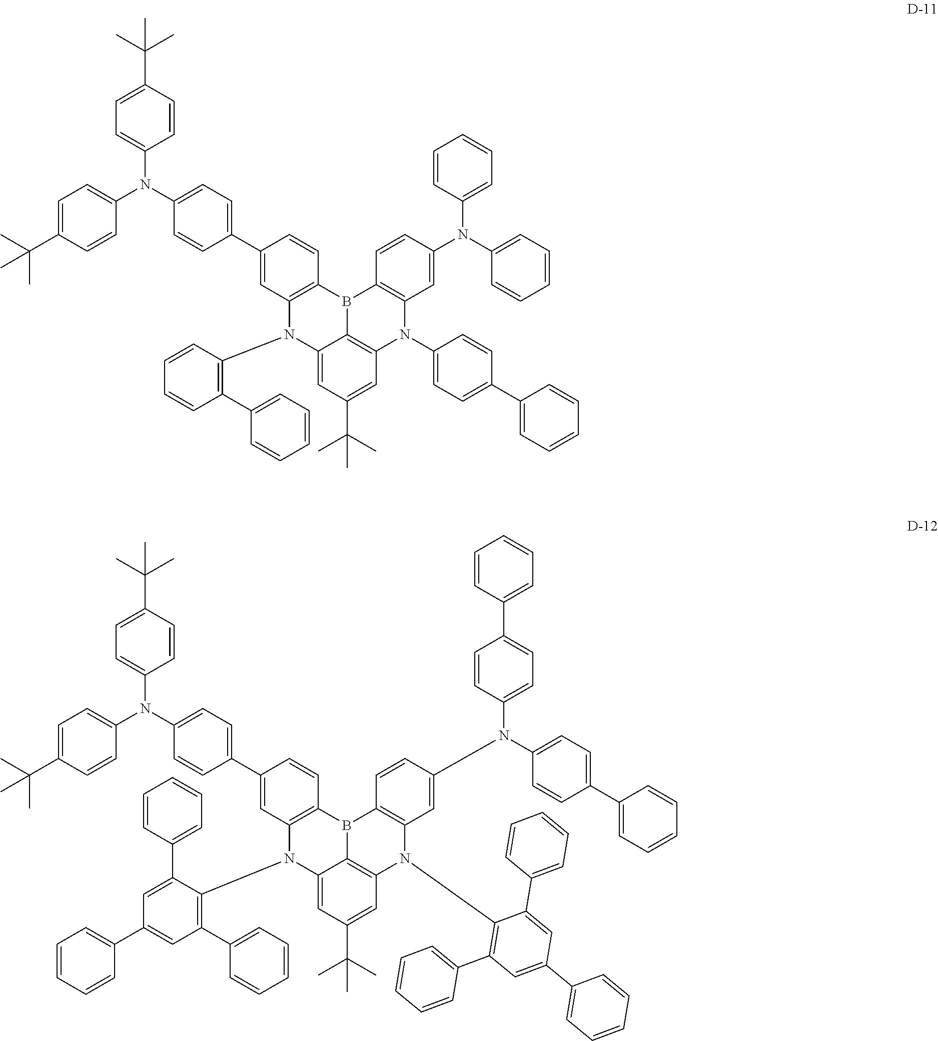 [SMILES: CC(C)(C)c1ccc(N(c2ccc(-c3ccc4c(c3)N(c3ccccc3-c3ccccc3)c3cc(C(C)(C)C)cc5c3B4c3ccc(N(c4ccccc4)c4ccccc4)cc3N5c3ccc(-c4ccccc4)cc3)cc2)c2ccc(C(C)(C)C)cc2)cc1 ; CC(C)(C)c1ccc(N(c2ccc(-c3ccc4c(c3)N(c3c(-c5ccccc5)cc(-c5ccccc5)cc3-c3ccccc3)c3cc(C(C)(C)C)cc5c3B4c3ccc(N(c4ccc(-c6ccccc6)cc4)c4ccc(-c6ccccc6)cc4)cc3N5c3c(-c4ccccc4)cc(-c4ccccc4)cc3-c3ccccc3)cc2)c2ccc(C(C)(C)C)cc2)cc1] 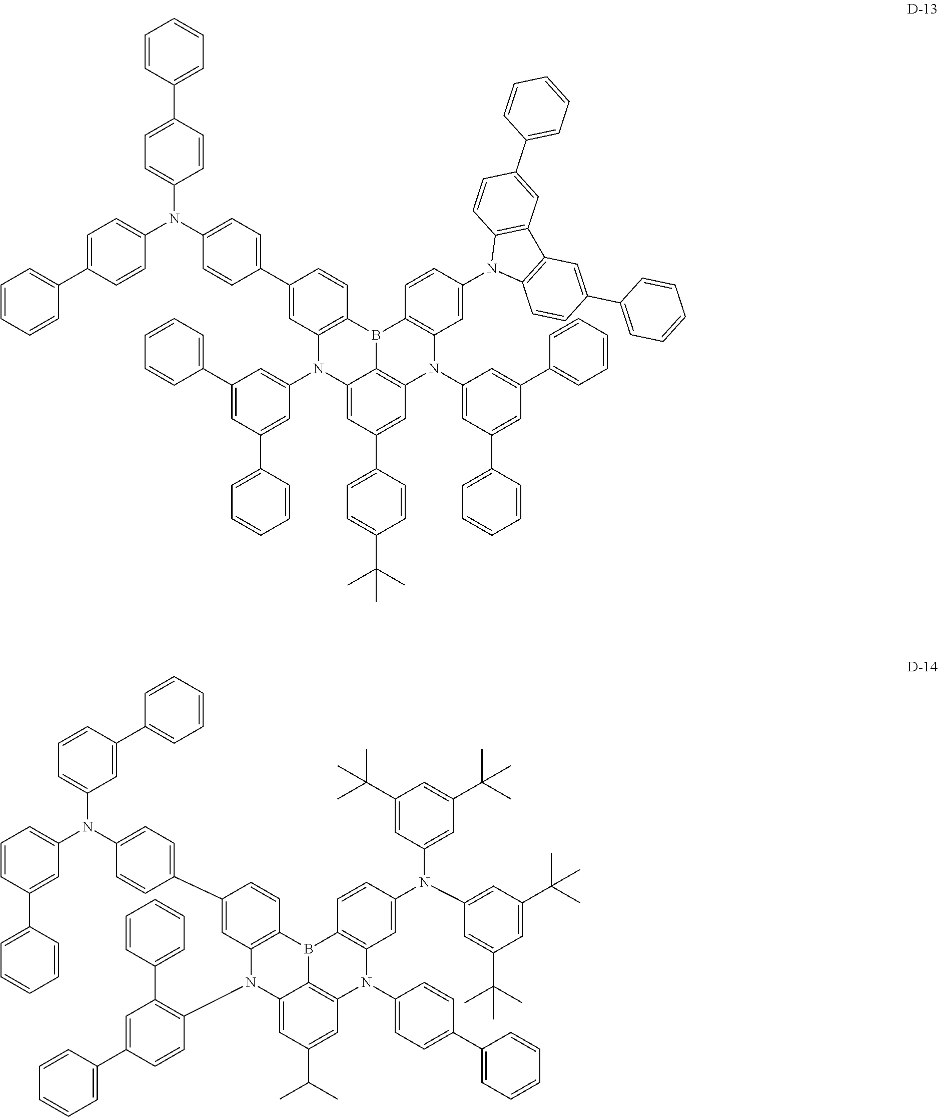 [SMILES: CC(C)(C)c1ccc(-c2cc3c4c(c2)N(c2cc(-c5ccccc5)cc(-c5ccccc5)c2)c2cc(-n5c6ccc(-c7ccccc7)cc6c6cc(-c7ccccc7)ccc65)ccc2B4c2ccc(-c4ccc(N(c5ccc(-c6ccccc6)cc5)c5ccc(-c6ccccc6)cc5)cc4)cc2N3c2cc(-c3ccccc3)cc(-c3ccccc3)c2)cc1 ; CC(C)c1cc2c3c(c1)N(c1ccc(-c4ccccc4)cc1-c1ccccc1)c1cc(-c4ccc(N(c5cccc(-c6ccccc6)c5)c5cccc(-c6ccccc6)c5)cc4)ccc1B3c1ccc(N(c3cc(C(C)(C)C)cc(C(C)(C)C)c3)c3cc(C(C)(C)C)cc(C(C)(C)C)c3)cc1N2c1ccc(-c2ccccc2)cc1] 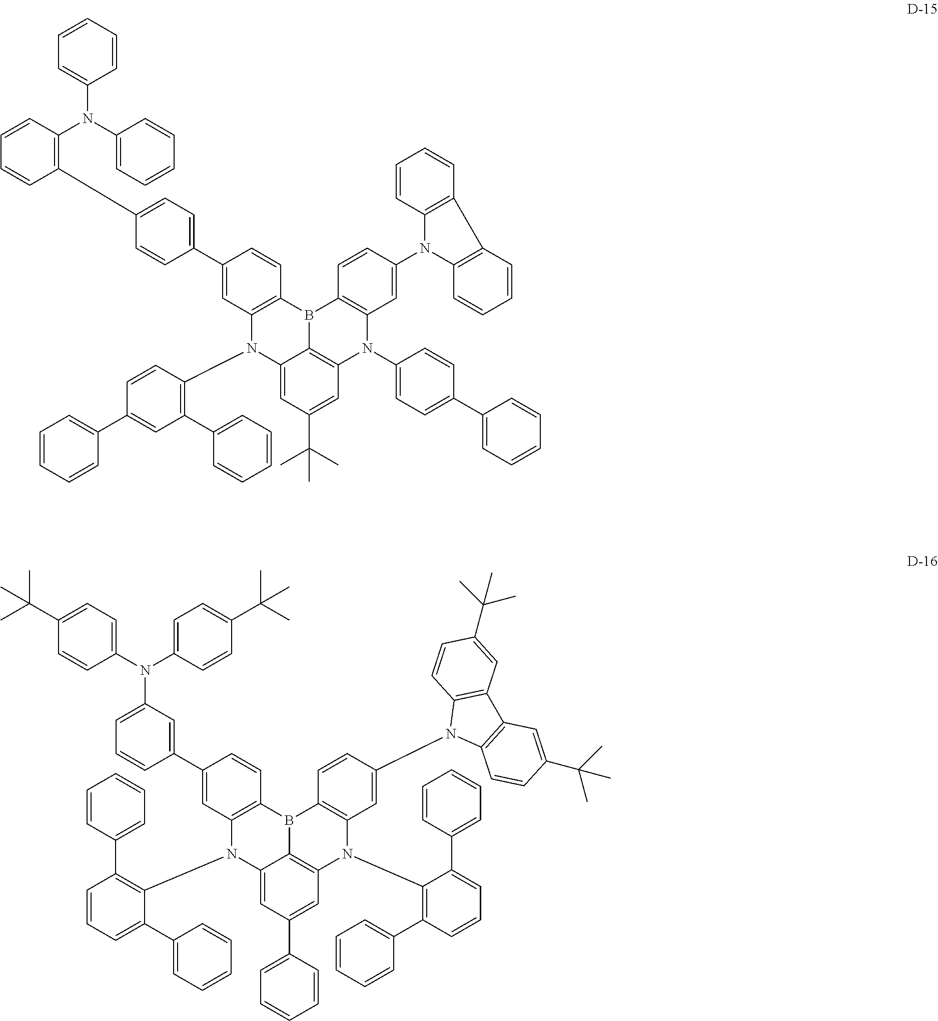 [SMILES: CC(C)(C)c1cc2c3c(c1)N(c1ccc(-c4ccccc4)cc1-c1ccccc1)c1cc(-c4ccc(-c5ccccc5N(c5ccccc5)c5ccccc5)cc4)ccc1B3c1ccc(-n3c4ccccc4c4ccccc43)cc1N2c1ccc(-c2ccccc2)cc1 ; CC(C)(C)c1ccc(N(c2ccc(C(C)(C)C)cc2)c2cccc(-c3ccc4c(c3)N(c3c(-c5ccccc5)cccc3-c3ccccc3)c3cc(-c5ccccc5)cc5c3B4c3ccc(-n4c6ccc(C(C)(C)C)cc6c6cc(C(C)(C)C)ccc64)cc3N5c3c(-c4ccccc4)cccc3-c3ccccc3)c2)cc1] 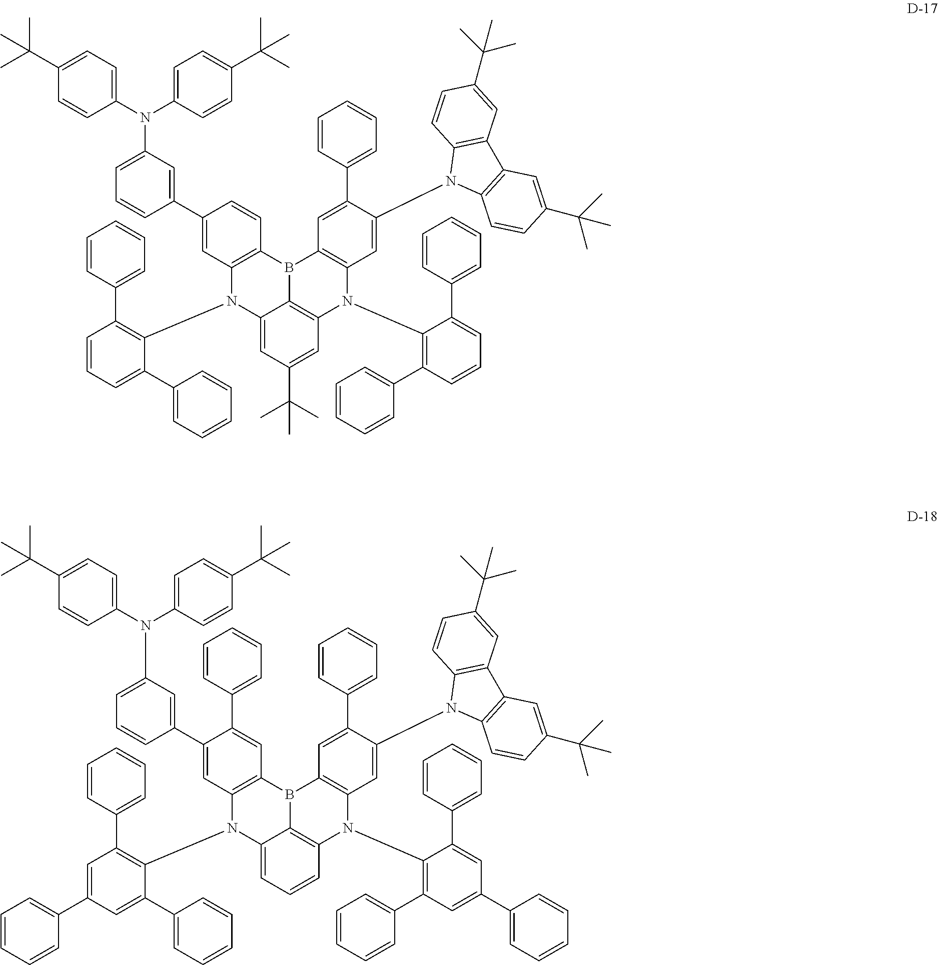 [SMILES: CC(C)(C)c1ccc(N(c2ccc(C(C)(C)C)cc2)c2cccc(-c3ccc4c(c3)N(c3c(-c5ccccc5)cccc3-c3ccccc3)c3cc(C(C)(C)C)cc5c3B4c3cc(-c4ccccc4)c(-n4c6ccc(C(C)(C)C)cc6c6cc(C(C)(C)C)ccc64)cc3N5c3c(-c4ccccc4)cccc3-c3ccccc3)c2)cc1 ; CC(C)(C)c1ccc(N(c2ccc(C(C)(C)C)cc2)c2cccc(-c3cc4c(cc3-c3ccccc3)B3c5cc(-c6ccccc6)c(-n6c7ccc(C(C)(C)C)cc7c7cc(C(C)(C)C)ccc76)cc5N(c5c(-c6ccccc6)cc(-c6ccccc6)cc5-c5ccccc5)c5cccc(c53)N4c3c(-c4ccccc4)cc(-c4ccccc4)cc3-c3ccccc3)c2)cc1] 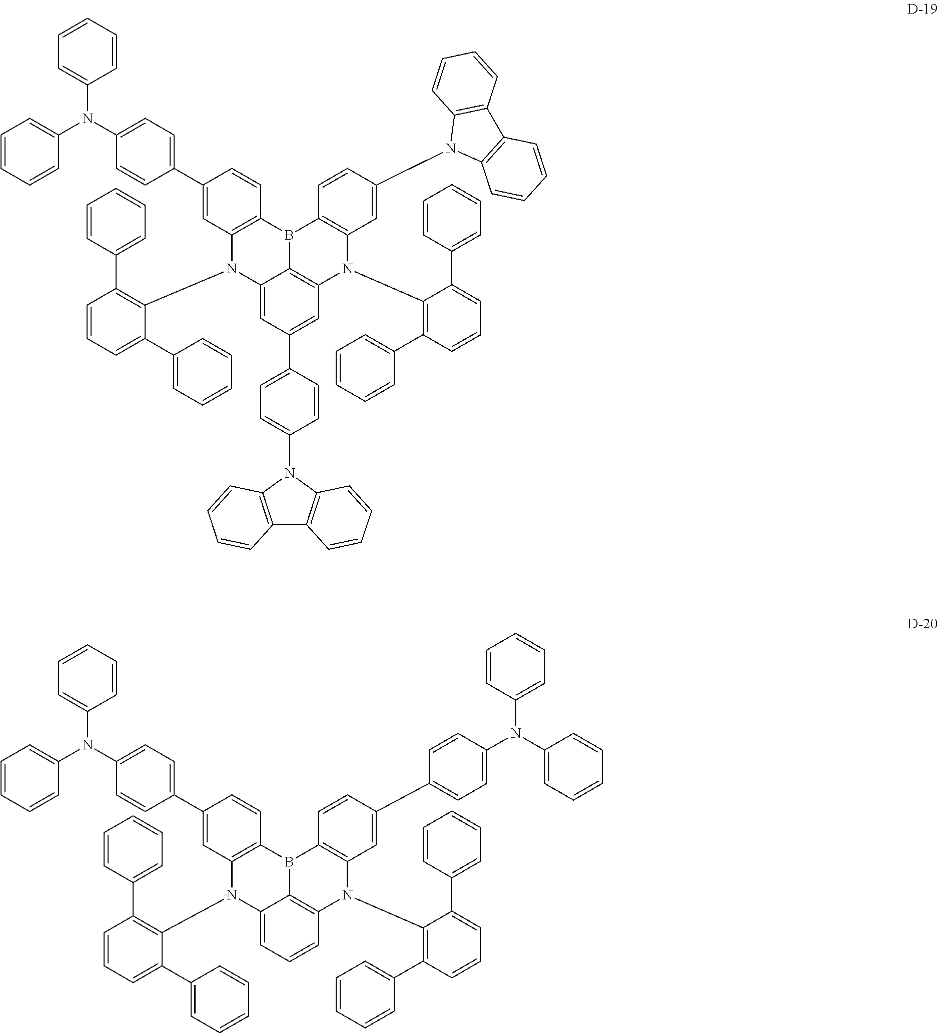 [SMILES: c1ccc(-c2cccc(-c3ccccc3)c2N2c3cc(-c4ccc(N(c5ccccc5)c5ccccc5)cc4)ccc3B3c4ccc(-n5c6ccccc6c6ccccc65)cc4N(c4c(-c5ccccc5)cccc4-c4ccccc4)c4cc(-c5ccc(-n6c7ccccc7c7ccccc76)cc5)cc2c43)cc1 ; c1ccc(-c2cccc(-c3ccccc3)c2N2c3cc(-c4ccc(N(c5ccccc5)c5ccccc5)cc4)ccc3B3c4ccc(-c5ccc(N(c6ccccc6)c6ccccc6)cc5)cc4N(c4c(-c5ccccc5)cccc4-c4ccccc4)c4cccc2c43)cc1] 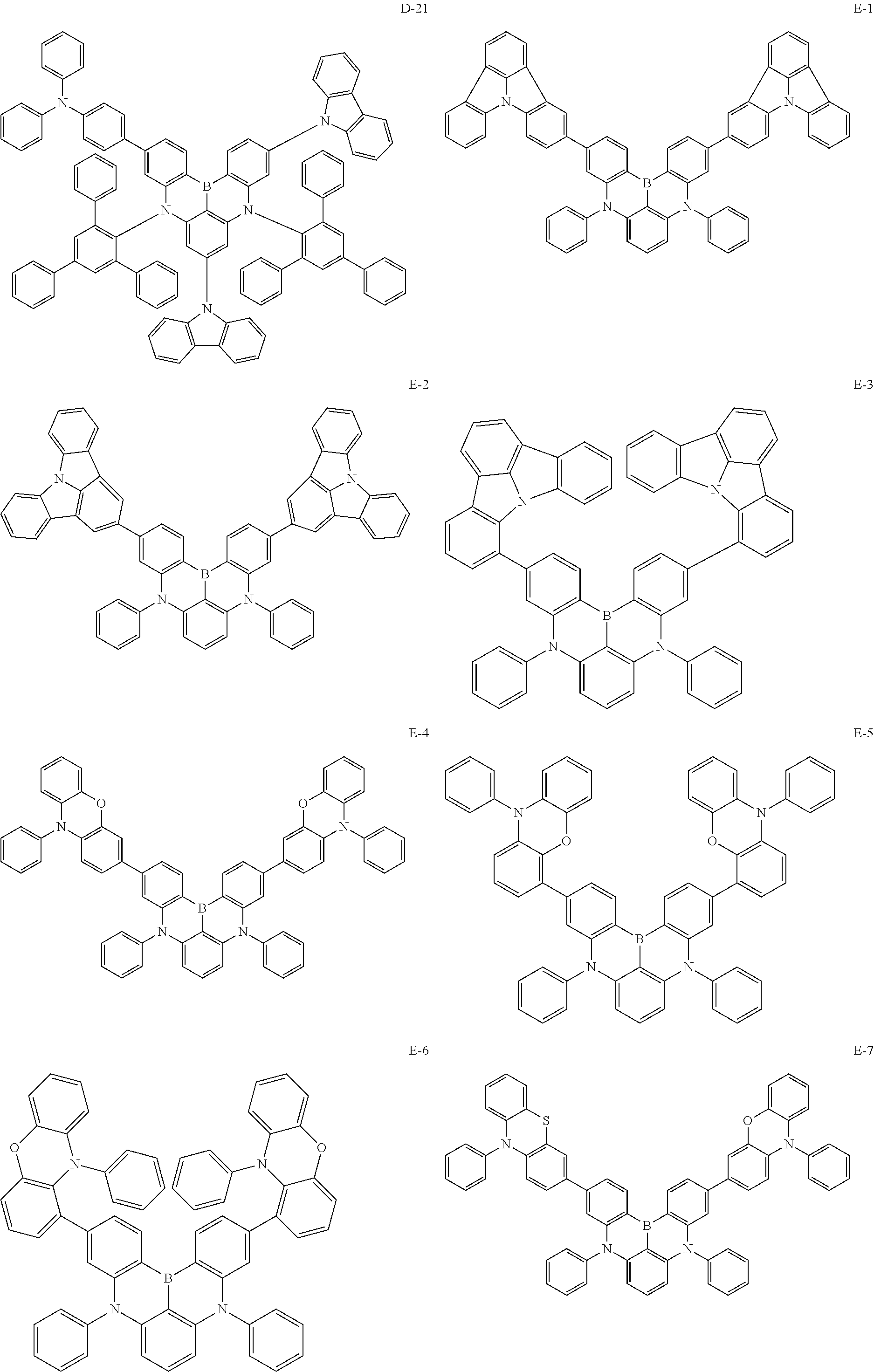 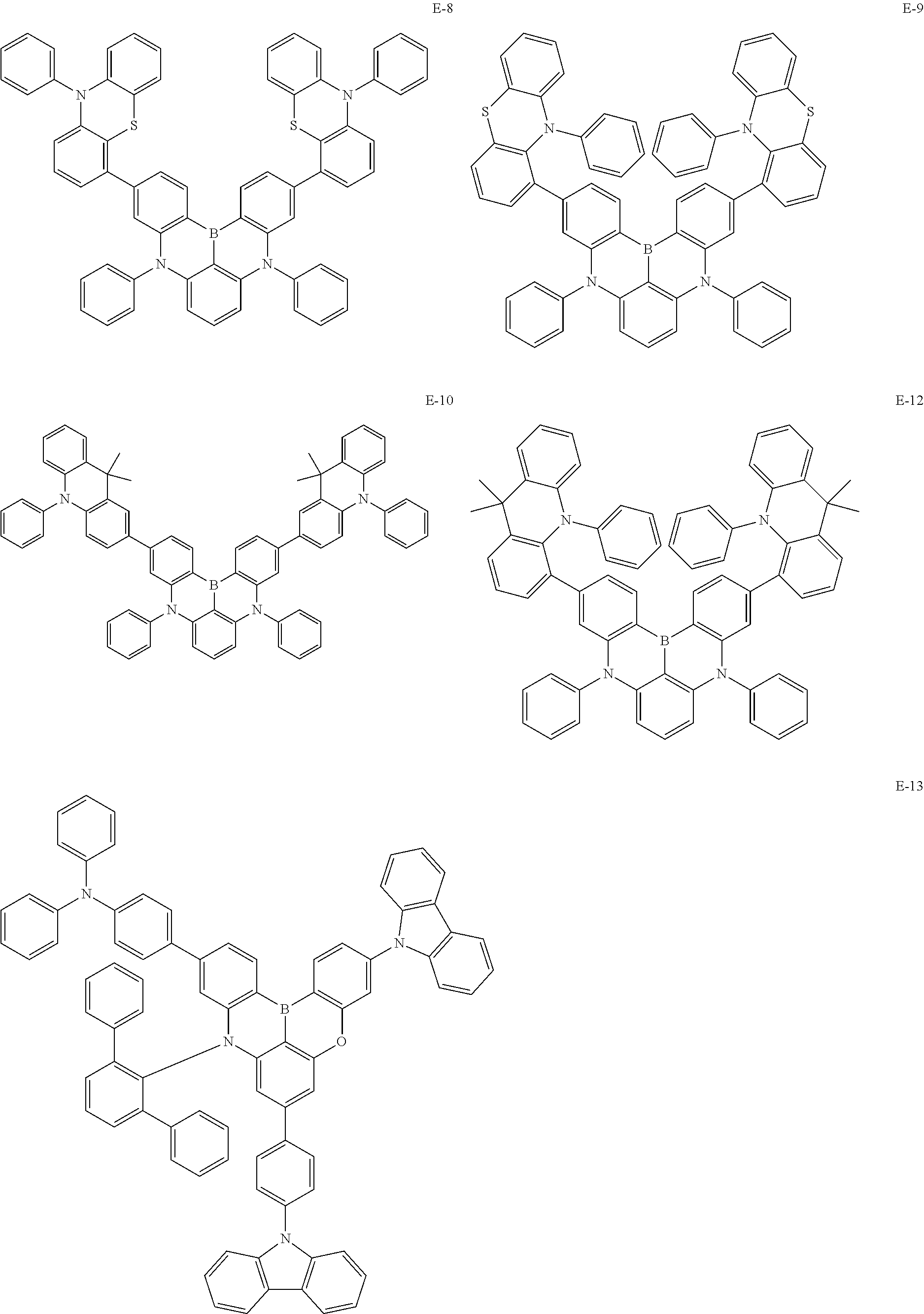 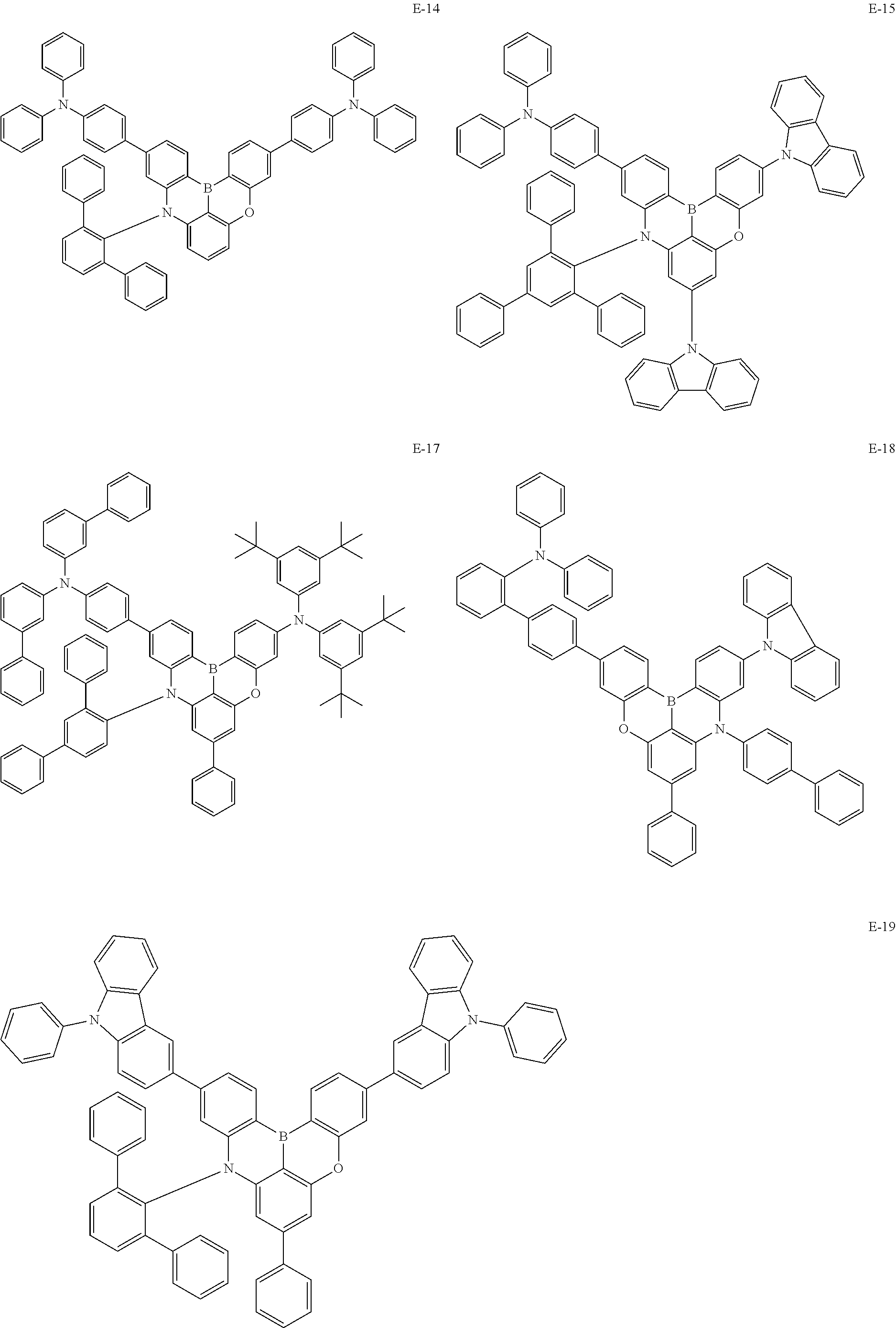 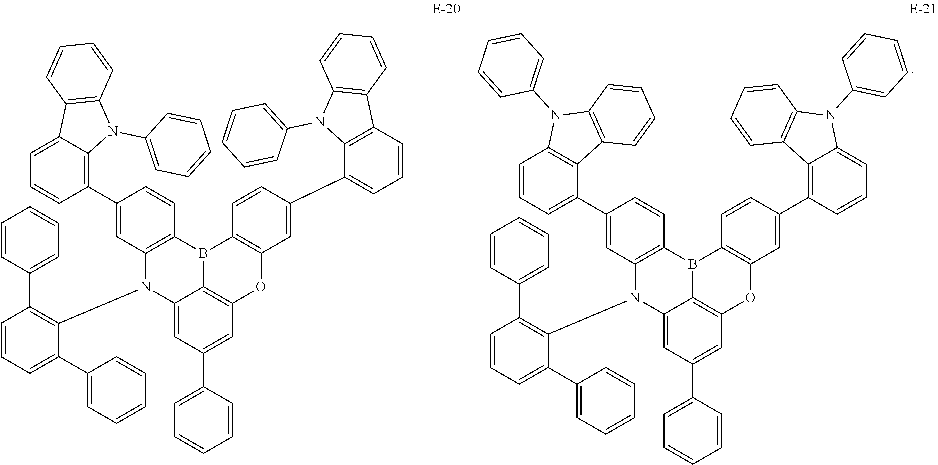 [SMILES: c1ccc(-c2cc3c4c(c2)N(c2c(-c5ccccc5)cccc2-c2ccccc2)c2cc(-c5cccc6c7ccccc7n(-c7ccccc7)c56)ccc2B4c2ccc(-c4cccc5c6ccccc6n(-c6ccccc6)c45)cc2O3)cc1 ; c1ccc(-c2cc3c4c(c2)N(c2c(-c5ccccc5)cccc2-c2ccccc2)c2cc(-c5cccc6c5c5ccccc5n6-c5ccccc5)ccc2B4c2ccc(-c4cccc5c4c4ccccc4n5-c4ccccc4)cc2O3)cc1]
